(19) United States
(12) Patent Application Publication
(10) Pub. No.: US 2013/0130178 A1
(43) Pub. Date: May 23, 2013

(54) ACTINIC-RAY-OR RADIATION-SENSITIVE RESIN COMPOSITION AND METHOD OF FORMING PATTERN THEREWITH

(71) Applicants: Yusuke Iizuka, Shizuoka (JP); Akinori Shibuya, Shizuoka (JP)

(72) Inventors: Yusuke Iizuka, Shizuoka (JP); Akinori Shibuya, Shizuoka (JP)

(73) Assignee: FUJIFILM CORPORATION, Minato-ku, Tokyo (JP)

(21) Appl. No.: 13/807,623

(22) PCT Filed: Aug. 26, 2011
(86) PCT No.: PCT/JP2011/069967

§ 371 Date: Jan. 16, 2013

(30) Foreign Application Priority Data
Aug. 27, 2010 (JP) 2010-191373

(51) Int. Cl. G03F 7/004; G03F 7/20

(52) U.S. Cl. CPC G03F 7/004; G03F 7/20; G03F 7/2041
USPC 430/285.1; 526/242; 526/247; 430/270.1; 430/281.1; 430/325

(57) ABSTRACT

Provided is an actinic-ray- or radiation-sensitive resin composition including a resin (B) containing at least either a fluorine atom or a silicon atom, the resin (B) containing any of repeating units of general formulae (I-1) and (I-2) below:

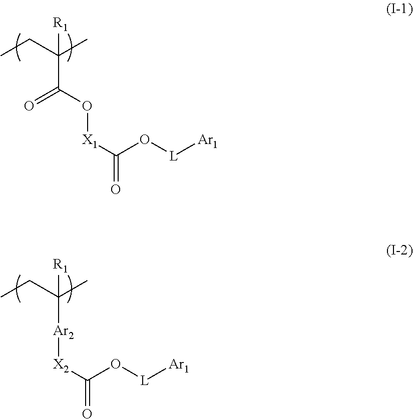

Wherein each of R₁s independently represents a hydrogen atom, an alkyl group or a halogen atom, X₁ represents a bivalent organic group, X₂ represents a single bond or a bivalent organic group, each of Ar₁s independently represents a monovalent aromatic ring group, Ar₂ represents a bivalent aromatic ring group, and each of L's independently represents a single bond or a bivalent organic group.

### CROSS REFERENCE TO RELATED APPLICATIONS

This application is based upon and claims the benefit of priority from prior Japanese Patent Application No. 2010-191373, filed Aug. 27, 2010, the entire contents of which are incorporated herein by reference.

### TECHNICAL FIELD

The present invention relates to an actinic-ray- or radiation-sensitive resin composition and a method of forming a pattern using the same. More particularly, the present invention relates to a composition that is suitable for use in, for example, an ultramicrolithography process applicable to a process for manufacturing a super-LSI or a high-capacity microchip, a process for fabricating a nanoimprint mold, a process for producing a high-density information recording medium, etc., and other photofabrication processes, and relates to a method of forming a pattern using the composition. In particular, the present invention is concerned with a composition that is suitable for exposure using a liquid-immersion projection exposure unit in which a far ultraviolet light of wavelength 300 nm or shorter is employed as a light source and with a method of forming a pattern using the composition.

Herein, the term “actinic rays” or “radiation” means, for example, brightline spectra from a mercury lamp, far ultraviolet represented by an excimer laser, extreme ultraviolet (EUV), X-rays and electron beams (EB). Herein, the term “light” means actinic rays or radiation.

Further, herein, the term “exposure to light” unless otherwise specified means not only irradiation with light, such as light from a mercury lamp, far ultraviolet, X-rays or EUV light, but also lithography using particle beams, such as electron beams and ion beams.

### BACKGROUND ART

The shortening of the wavelength of an exposure light source and the realization of high numerical apertures (high NA) for projector lenses have been advanced in accordance with the miniaturization of semiconductor elements. It is heretofore known to, for achieving the enhancement of resolving power by further wavelength shortening, employ a method in which the space between a projector lens and a sample is filled with a liquid of high refractive index (hereinafter also referred to as an “immersion liquid”), generally called a liquid-immersion method. The liquid-immersion method is effective in all pattern shapes. Further, this method can be combined with a super-resolution technology, such as a phase shift method or a modified illumination method, now under study.

Since the development of the resist for a KrF excimer laser (248 nm), it has been of common practice to, in order to compensate for any sensitivity deterioration caused by light absorption, employ an image forming method through chemical amplification as a resist image forming method. Brief description of a positive image forming method through chemical amplification is given below by way of example. Upon exposure to light, an acid generator is decomposed in exposed areas to thereby generate an acid. At the bake after the exposure (Post-Exposure Bake: PEB), the generated acid is used as a reaction catalyst so that an alkali-insoluble group is converted to an alkali-soluble group. Thereafter, alkali development is carried out to thereby remove the exposed areas. Thus, the relevant image forming method is provided (see, for example, patent references 1 to 5).

The resist for an ArF excimer laser (193 nm) utilizing this chemical amplification mechanism is now becoming mainstream. In this connection, when the exposure is performed by means of a scan-type liquid-immersion exposure machine, the exposure speed is decreased in the event that the immersion liquid fails to move while tracking a moving lens. Thus, an adverse influence thereof on productivity is concerned. When the immersion liquid is water, it is preferred for the resist film to be hydrophobic from the viewpoint of superiority in water tracking properties. On the other hand, an extreme hydrophobicity invites a lowering of developability. Therefore, it is of importance to achieve a good balance between water tracking properties and developability.

Patent references 6 and 7 describe resins comprising repeating units containing base-dissociative groups. These resins still need work from the viewpoint of achieving a good balance between water tracking properties and developability.

### PRIOR ART LITERATURE

### Patent Reference

[Patent reference 1] Jpn. Pat. Appln. KOKAI Publication No. (hereinafter referred to as JP-A-) 2008-268931,
[Patent reference 2] JP-A-2009-249293,
[Patent reference 3] JP-A-2009-157338,
[Patent reference 4] JP-A-2010-122579,
[Patent reference 5] JP-A-2007-178848,
[Patent reference 6] JP-A-2009-175363, and
[Patent reference 7] JP-A-2010-2870.

### DISCLOSURE OF INVENTION

It is an object of the present invention to provide an actinic-ray- or radiation-sensitive resin composition that simultaneously achieves excellent developability and excellent immersion-liquid tracking properties. It is another object of the present invention to provide a method of forming a pattern in which the above composition is used.

Some aspects of the present invention are as follows.

[1] An actinic-ray- or radiation-sensitive resin composition comprising a resin (B) containing at least either a fluorine atom or a silicon atom, the resin (B) containing any of repeating units of general formulae (I-1) and (I-2) below:

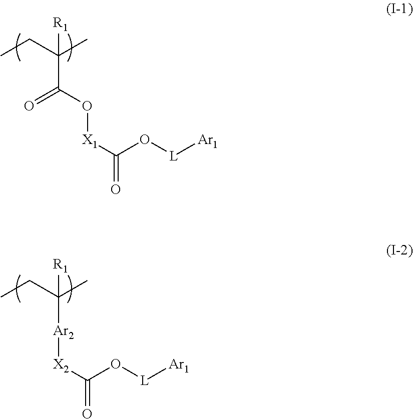

wherein

each of R₁s independently represents a hydrogen atom, an alkyl group or a halogen atom,

X₁ represents a bivalent organic group,

X₂ represents a single bond or a bivalent organic group,

each of Ar₁s independently represents a monovalent aromatic ring group,

Ar₂ represents a bivalent aromatic ring group, and

each of L's independently represents a single bond or a bivalent organic group.

[2] The composition according to item [1], wherein the resin (B) is contained in a content of 0.01 to 20 mass % based on total solids of the composition.

[3] The composition according to claim [1] or [2], wherein the resin (B) further contains a repeating unit containing at least one group selected from the group consisting of:

(x) an alkali-soluble group,

(y) a group that when acted on by an alkali developer, is decomposed to thereby increase its solubility in the alkali developer, and

(z) a group that when acted on by an acid, is decomposed to thereby increase its solubility in an alkali developer.

[4] The composition according to claim [1] or [2], wherein the resin (B) further contains a repeating unit containing (y) a group that when acted on by an alkali developer, is decomposed to thereby increase its solubility in the alkali developer.

[5] The composition according to any one of items [1] to [4], wherein the monovalent aromatic ring group represented by Ar₁ is substituted with an electron withdrawing group.

[6] The composition according to item [5], wherein the electron withdrawing group is at least one member selected from the group consisting of a halogen atom, a halogenated hydrocarbon group and a nitro group.

[7] The composition according to any one of items [1] to [6], further comprising:

a resin (A) that when acted on by an acid, is decomposed to thereby increase its solubility in an alkali developer, and

a compound (C) that when exposed to actinic rays or radiation, generates an acid.

[8] A resist film formed from the composition according to any one of items [1] to [7].

[9] A method of forming a pattern, comprising: forming the composition according to any one of items [1] to [7] into a film,

exposing the film to light, and

developing the exposed film.

[10] The method according to item [9], wherein the exposure is performed through an immersion liquid.

The present invention has made it feasible to provide an actinic-ray- or radiation-sensitive resin composition that simultaneously achieves excellent developability and excellent immersion-liquid tracking properties and to provide a method of forming a pattern in which the above composition is used.

### BEST MODE FOR CARRYING OUT THE INVENTION

Embodiments of the present invention will be described in detail below.

Herein, the groups and atomic groups for which no statement is made as to substitution or nonsubstitution are to be interpreted as including those containing no substituents and also those containing substituents. For example, the “alkyl groups” for which no statement is made as to substitution or nonsubstitution are to be interpreted as including not only the alkyl groups containing no substituents (unsubstituted alkyl groups) but also the alkyl groups containing substituents (substituted alkyl groups).

<Resin (B)>

The actinic-ray- or radiation-sensitive resin composition of the present invention comprises a resin (B) containing at least either a fluorine atom or a silicon atom.

At least one of resins (B) contained in the composition of the present invention contains any of repeating units of general formulae (I-1) and (I-2) below [hereinafter also respectively referred to as repeating unit (R-1) and repeating unit (R-2)].

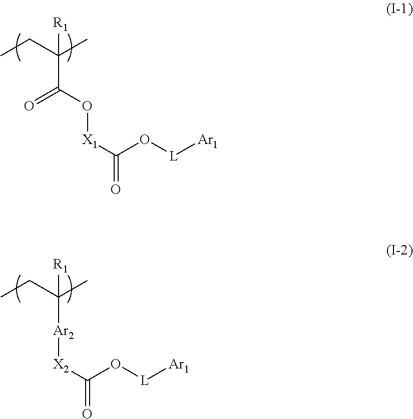

In the formulae, each of R₁s independently represents a hydrogen atom, an alkyl group or a halogen atom. X₁ represents a bivalent organic group. X₂ represents a single bond or a bivalent organic group. Each of Ar₁s independently represents a monovalent aromatic ring group. Ar₂ represents a bivalent aromatic ring group. Each of L's independently represents a single bond or a bivalent organic group.

Favorable developability and immersion-liquid tracking properties can be simultaneously attained by using a resin (B) comprising any of repeating units (R-1) and (R-2). In particular, if so, not only can the number of development defects be reduced but also the receding contact angle can be increased.

The alkyl group represented by R₁ is preferably one having 1 to 5 carbon atoms, most preferably a methyl group. A substituent may further be introduced in the alkyl group represented by R₁. As the substituent, there can be mentioned, for example, a halogen atom, a hydroxyl group, or an alkoxy group, such as a methoxy group, an ethoxy group, an isopropoxy group, a t-butoxy or a benzyloxy group. R₁ is preferably a hydrogen atom or an alkyl group, more preferably a hydrogen atom, a methyl group, a hydroxymethyl group or a trifluoromethyl group.

The bivalent organic group represented by X₁ is preferably, for example, an optionally substituted hydrocarbon group or a group containing a heteroatom.

The expression “substituted” with respect to the hydrocarbon group means that the hydrogen atoms of the hydrocarbon group are partially or wholly replaced by non-hydrogen-atom groups or atoms.

The hydrocarbon group may be an aliphatic hydrocarbon group or an aromatic hydrocarbon group. The aliphatic hydrocarbon group refers to a hydrocarbon group exhibiting no aromaticity.

The aliphatic hydrocarbon group may be saturated or unsaturated. It is generally preferred for the aliphatic hydrocarbon group to be saturated. In particular, as the aliphatic hydrocarbon group, there can be mentioned a linear or branched-chain aliphatic hydrocarbon group, an aliphatic hydrocarbon group containing a ring in its structure, or the like.

The linear or branched-chain aliphatic hydrocarbon group preferably has 1 to 10 carbon atoms, more preferably 1 to 8 carbon atoms, further more preferably 1 to 5 carbon atoms and most preferably 1 or 2 carbon atoms.

The linear-chain aliphatic hydrocarbon group is preferably a linear-chain alkylene group. As such, there can be mentioned, for example, a methylene group [—CH₂—], an ethylene group [—(CH₂)₂—], a trimethylene group [—(CH₂)₃—], a tetramethylene group [—(CH₂)₄—], a pentamethylene group [—(CH₂)₅—] or the like.

The branched-chain aliphatic hydrocarbon group is preferably a branched-chain alkylene group, for example, an alkylalkylene group. As the alkylalkylene group, there can be mentioned, for example, an alkylmethylene group, such as —CH(CH₃)—, —CH(CH₂CH₃)—, —C(CH₃)₂—, —C(CH₃)(CH₂CH₃)—, —C(CH₃)(CH₂CH₂CH₃)— or —C(CH₂CH₃)₂—; an alkylethylene group, such as —CH(CH₃)CH₂—, —CH(CH₃)CH(CH₃)—, —C(CH₃)₂CH₂—, —CH(CH₂CH₃)CH₂— or —C(CH₂CH₃)₂CH₂—; an alkyltrimethylene group, such as —CH(CH₃)CH₂CH₂— or —CH₂CH(CH₃)CH₂—; or an alkyltetramethylene group, such as —CH(CH₃)CH₂CH₂CH₂— or —CH₂CH(CH₃)CH₂CH₂—. It is preferred for the alkyl group contained in each of these alkylalkylene groups to be a linear-chain alkyl group having 1 to 5 carbon atoms.

The introduction of a substituent in each of the chain aliphatic hydrocarbon groups is optional. As the substituent, there can be mentioned, for example, a fluorine atom, a fluorinated lower alkyl group having 1 to 5 carbon atoms, an oxygen atom (═O) or the like.

As the aliphatic hydrocarbon group containing a ring, there can be mentioned a cyclic aliphatic hydrocarbon group (group resulting from the removal of two hydrogen atoms from an aliphatic hydrocarbon ring), a group resulting from the bonding of the cyclic aliphatic hydrocarbon group to a terminal of the above-mentioned chain aliphatic hydrocarbon group or from the presence of the cyclic aliphatic hydrocarbon group in the middle of the above-mentioned chain aliphatic hydrocarbon group, or the like.

The cyclic aliphatic hydrocarbon group preferably has 3 to 20 carbon atoms, more preferably 3 to 12 carbon atoms.

The cyclic aliphatic hydrocarbon group may be a polycyclic group or a monocyclic group. The monocyclic group is preferably a group resulting from the removal of two hydrogen atoms from a monocycloalkane having 3 to 6 carbon atoms. The monocycloalkane is, for example, cyclopentane, cyclohexane or the like.

The polycyclic group is preferably a group resulting from the removal of two hydrogen atoms from a polycycloalkane having 7 to 12 carbon atoms. The polycycloalkane is, for example, adamantane, norbornane, isobornane, tricyclodecane, tetracyclododecane or the like.

The introduction of a substituent in the cyclic aliphatic hydrocarbon group is optional. As the substituent, there can be mentioned, for example, a lower alkyl group having 1 to 5 carbon atoms, a fluorine atom, a fluorinated lower alkyl group having 1 to 5 carbon atoms, an oxygen atom (═O) or the like.

The “heteroatom” of the bivalent group containing a heteroatom refers to an atom other than carbon and hydrogen atoms, for example, an oxygen atom, a nitrogen atom, a sulfur atom, a halogen atom or the like.

As the bivalent group containing a heteroatom, there can be mentioned, for example, —O—, —C(═O)—, —C(═O)—O—, a carbonate bond (—O—C(═O)—O—), —NH—, —NR₀₄ (R₀₄ is an alkyl group)-, —NH—C(═O)—, ═N—, a combination of any of these with a bivalent hydrocarbon group, or the like. The bivalent hydrocarbon group is the same as the above-mentioned optionally substituted hydrocarbon group, preferably a linear or branched-chain aliphatic hydrocarbon group.

The aromatic hydrocarbon group is, for example, a group resulting from the removal of two hydrogen atoms from an optionally substituted aromatic hydrocarbon ring. The ring skeleton of the aromatic hydrocarbon group preferably has 6 to 15 carbon atoms. As such, there can be mentioned, for example, a benzene ring, a naphthalene ring, a phenanthrene ring, an anthracene ring or the like. Of these rings, a benzene ring and a naphthalene ring are especially preferred.

With respect to the aromatic hydrocarbon group, as a substituent optionally introduced in the aromatic ring group, there can be mentioned, for example, a halogen atom, an alkyl group, an alkoxy group, a halogenated lower alkyl group, an oxygen atom (═O) or the like. As the halogen atom, there can be mentioned a fluorine atom, a chlorine atom, an iodine atom, a bromine atom or the like. It is preferred for the substituent optionally introduced in the aromatic hydrocarbon group to be a fluorine atom.

As the bivalent organic group represented by X₂, there can be mentioned, for example, any of those set forth above as the bivalent organic group represented by X₁. X₂ may be a single bond or a bivalent organic group. A single bond is preferred.

The aromatic ring group represented by Ar₁ may be monocyclic or polycyclic. This aromatic ring group may be a heterocyclic group containing a heteroatom, such as a nitrogen atom, an oxygen atom or a sulfur atom.

The aromatic ring group represented by Ar₁ preferably has 6 to 30 carbon atoms. As such an aromatic ring, there can be mentioned, for example, a benzene ring, a naphthalene ring, a pentalene ring, an indene ring, an azulene ring, a heptalene ring, an indecene ring, a perylene ring, a pentacene ring, an acenaphthalene ring, a phenanthrene ring, an anthracene ring, a naphthacene ring, a chrysene ring, a triphenylene ring, a fluorene ring, a biphenyl ring, a pyrrole ring, a furan ring, a thiophene ring, an imidazole ring, an oxazole ring, a thiazole ring, a pyridine ring, a pyrazine ring, a pyrimidine ring, a pyridazine ring, an iodolizine ring, an indole ring, a benzofuran ring, a benzothiophene ring, an isobenzofuran ring, a quinolizine ring, a quinoline ring, a phthalazine ring, a naphthyridine ring, a quinoxaline ring, a quinoxazoline ring, an isoquinoline ring, a carbazole ring, a phenanthridine ring, an acridine ring, a phenanthroline ring, a thianthrene ring, a chromene ring, a xanthene ring, a phenoxathiin ring, a phenothiazine ring or a phenazine ring. Of these rings, a benzene ring, a naphthalene ring and an anthracene ring are preferred. A benzene ring is more preferred.

A substituent may be introduced in the aromatic ring group represented by Ar₁. The substituent is preferably an electron withdrawing group. As the electron withdrawing group, there can be mentioned, for example, a halogen atom such as a fluorine atom, a halogenated hydrocarbon group such as a trifluoromethyl group, a carboxyl group, an alkoxycarbonyl group such as a methoxycarbonyl group, an aryloxycarbonyl group such as a phenoxycarbonyl group, an acyl group such as an acetyl group, a cyano group, an aryl group, a 1-alkenyl group, a nitro group, a sulfonic alkyl ester group, a sulfonic acid group, a sulfon group, a sulfoxy group or the like.

Among these electron withdrawing groups, an alkoxycarbonyl group, an acyl group such as an acetyl group, a cyano group, a halogen atom, a halogenated hydrocarbon group and a nitro group are preferred. A halogen atom, a halogenated hydrocarbon group and a nitro group are more preferred. The alkyl group of the alkoxycarbonyl group is, for example, a linear or branched alkyl group having 2 to 10 carbon atoms, preferably substituted with a fluorine atom.

The bivalent aromatic ring group represented by Ar₂ is, for example, a group resulting from the removal of two hydrogen atoms from an aromatic hydrocarbon ring. A substituent may be introduced in the aromatic hydrocarbon ring.

The ring skeleton of the aromatic ring group represented by Ar₂ preferably has 6 to 15 carbon atoms. As such, there can be mentioned, for example, a benzene ring, a naphthalene ring, a phenanthrene ring, an anthracene ring or the like. Of these rings, a benzene ring and a naphthalene ring are especially preferred.

The introduction of a substituent in the aromatic ring group represented by Ar₂ is optional. The aromatic ring group in which no substituent is introduced is preferred.

With respect to Ar₂, as a substituent optionally introduced in the aromatic ring group, there can be mentioned, for example, a halogen atom, an alkyl group, an alkoxy group, a halogenated lower alkyl group, an oxygen atom (═O) or the like. As the halogen atom, there can be mentioned a fluorine atom, a chlorine atom, an iodine atom, a bromine atom or the like. It is preferred for the substituent to be a fluorine atom.

With respect to Ar₂, when a substituent is introduced in the aromatic ring group, the number of substituents may be 1, or 2 or greater. The number of substituents is preferably 1 or 2, more preferably 1.

The bivalent organic group represented by L is, for example, any of those set forth above in connection with X₁ and X₂. L is preferably a single bond, or an alkylene group, an ether bond, an ester bond, an amido bond, a urethane bond, a urea bond or a connecting group composed of a combination of two or more of these. More preferably, L is a single bond, or an alkylene group, an ether bond, an ester bond or a connecting group composed of a combination of two or more of these. A substituent may further be introduced in the alkylene group.

The repeating units (R-1) and (R-2) are each typically decomposed by the action of an alkali developer to thereby produce a carboxyl group or a carboxylate anion. Namely, each of the repeating units (R-1) and (R-2) typically contains a group that is decomposed by the action of an alkali developer to thereby increase its solubility in the alkali developer (hereinafter also referred to as a polarity conversion group).

Alternatively, the repeating units (R-1) and (R-2) are typically decomposed by the action of an alkali developer to thereby produce compounds of general formula (II) below or anions corresponding to the compounds.

HO-L-Ar₁ (II)

In the formula, Ar₁ and L are as defined above in connection with the repeating units (R-1) and (R-2).

The compounds of general formula (II) above preferably exhibit a pKa value of 4 to 15, more preferably 5 to 14 and further more preferably 5.5 to 13.5. If so, not only is the above decomposition by the action of an alkali developer promoted but also the thermal stability of the repeating units (R-1) and (R-2) is enhanced.

The method of regulating the pKa value of the compounds of general formula (II) above so as to fall within the above ranges is, for example, as follows.

The compounds of general formula (II) are phenols when L is a single bond, and are alcohols when L is a bivalent organic group and when the group OH is bonded to a saturated carbon atom. Generally, the pKa value of the former is lower than that of the latter. Therefore, the pKa value of the compounds of general formula (II) can be lowered by causing L to represent a single bond.

As mentioned above, the aromatic ring group represented by Ar₁ may be substituted with an electron withdrawing group. The pKa value of the compounds of general formula (II) can be lowered by effecting such a substitution.

In the present invention, the acid dissociation index pKa refers to the acid dissociation index pKa in an aqueous solution. The “acid dissociation index” is the logarithm of the reciprocal of the acid dissociation constant and is, for example, one described in kagaku Binran (Chemical Handbook) (II) (Revised 4th Edition, 1993, edited by The Chemical Society of Japan, published by Maruzen Co., Ltd.). The lower the value, the greater the acid strength.

The acid dissociation index pKa in an aqueous solution can be actually measured through, for example, the determination of the acid dissociation constant at 25° C. using an infinitely diluted aqueous solution. Alternatively, the values based on a data base of publicly known literature values and Hammett's substituent constants can be determined by calculation by means of the following software package 1. All the pKa values appearing in this description are those determined by calculation by means of this software package.

Software package 1: Advanced Chemistry Development (ACD/Labs) Software V8.14 for Solaris (1994-2007 ACD/Labs).

Particular examples of the compounds of general formula (II) together with the pKa values thereof are given below.

| Compound | pKa | Compound | pKa |
|---|---|---|---|
| 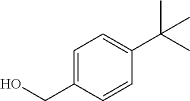 | 14.51 | 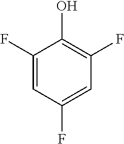 | 7.47 |
| 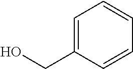 | 14.36 | 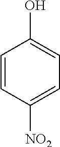 | 7.23 |
| 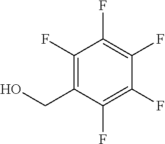 [SMILES: OCc1c(F)c(F)c(F)c(F)c1F] | 13.07 | 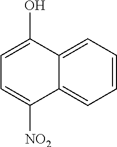 [SMILES: O=[N+]([O-])c1ccc(O)c2ccccc12] | 6.22 |
| 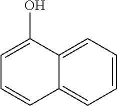 [SMILES: Oc1cccc2ccccc12] | 9.40 | 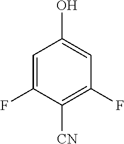 [SMILES: N#Cc1c(F)cc(O)cc1F] | 5.87 |
| 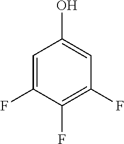 | 8.00 | 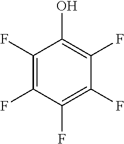 [SMILES: Oc1c(F)c(F)c(F)c(F)c1F] | 5.50 |
| 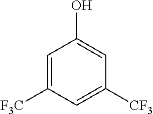 [SMILES: Oc1cc(C(F)(F)F)cc(C(F)(F)F)c1] | 7.96 | 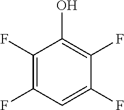 [SMILES: Oc1c(F)c(F)cc(F)c1F] | 5.46 |
| 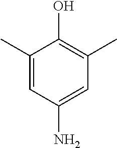 | 7.81 | | |

Specific examples of the repeating units (R-1) and (R-2) are shown below. In the examples, R represents a hydrogen atom, a methyl group, a hydroxymethyl group or a trifluoromethyl group.

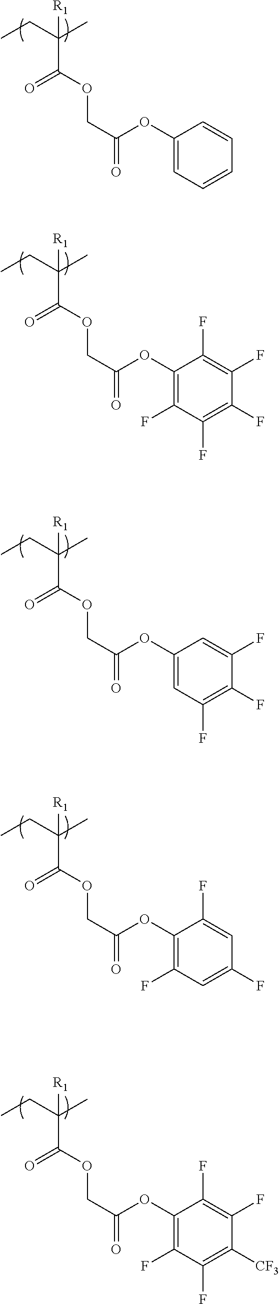

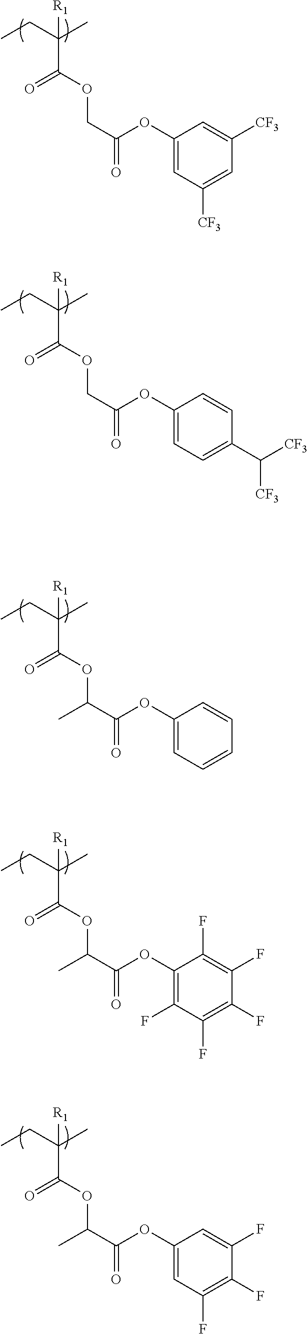

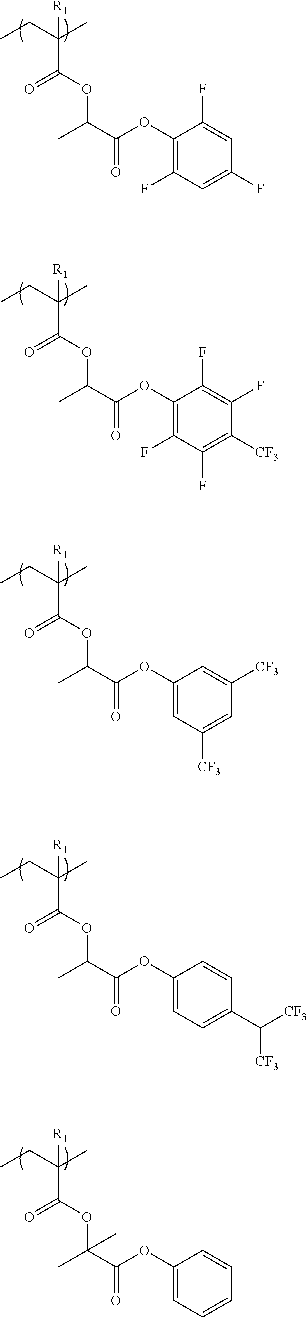

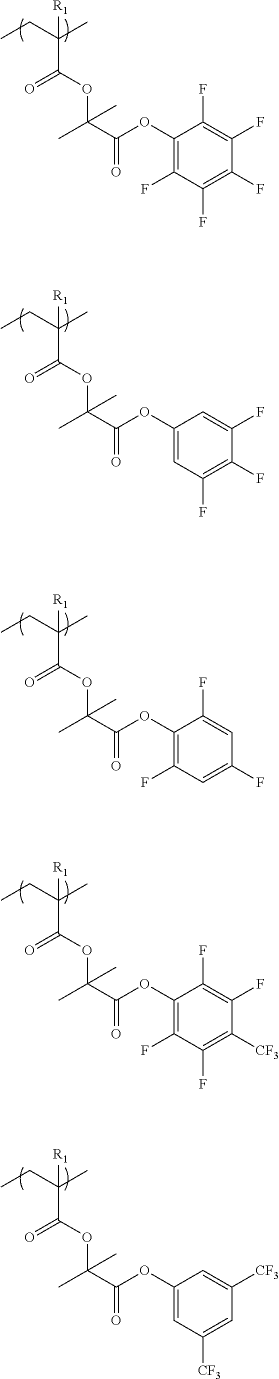

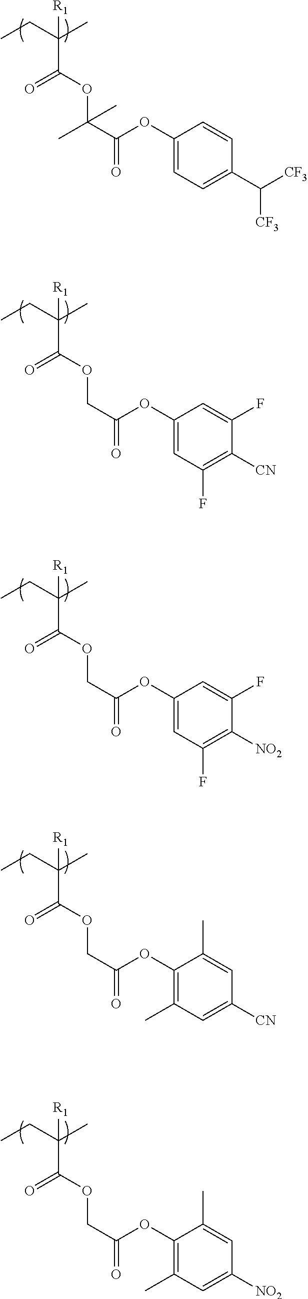

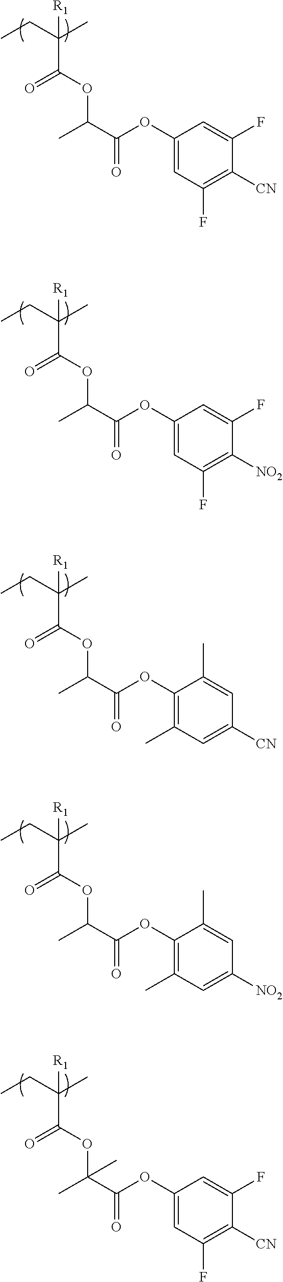

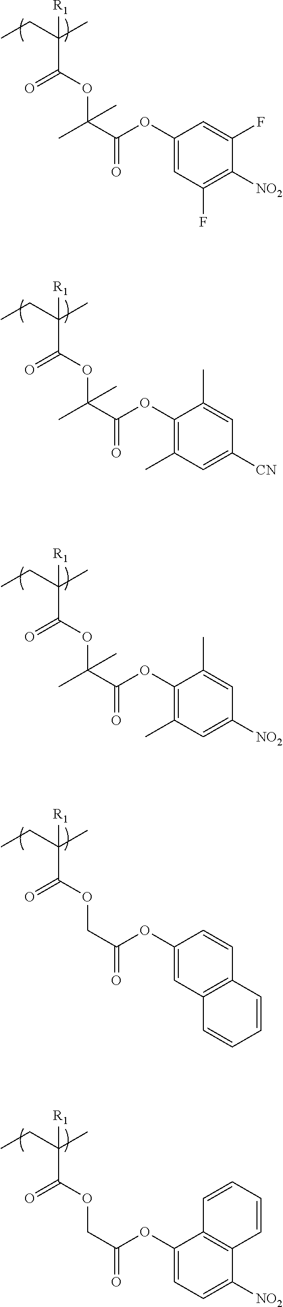

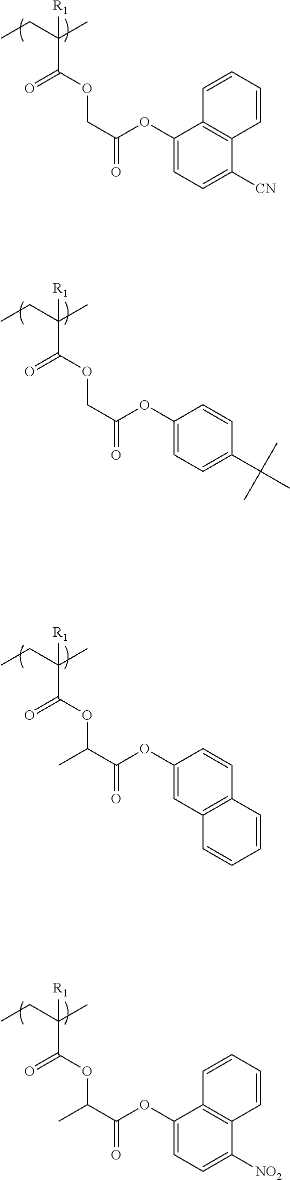

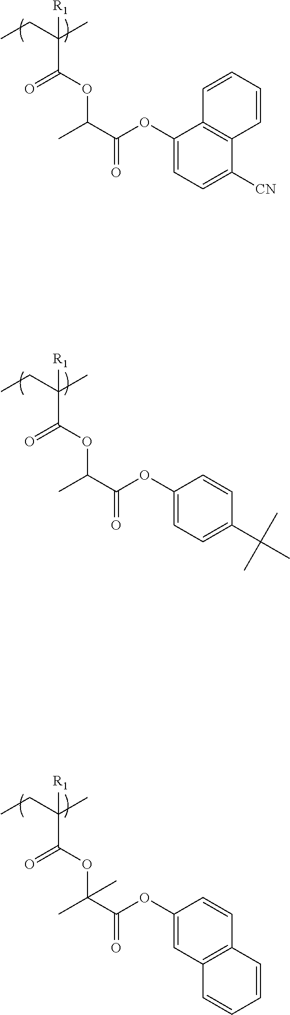

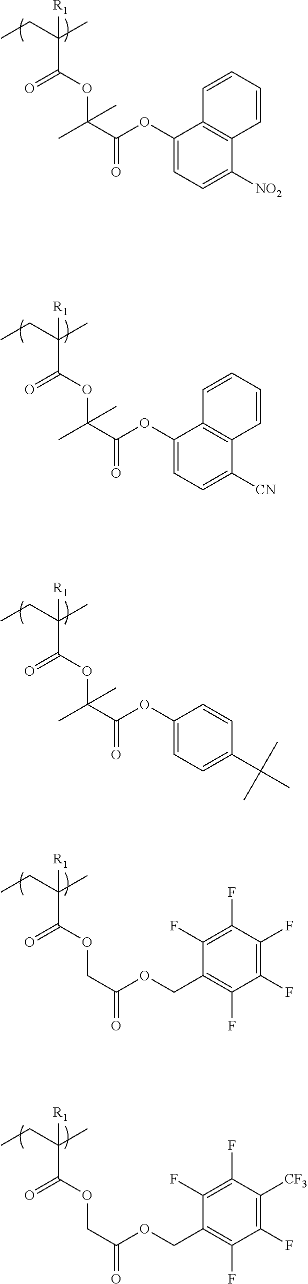

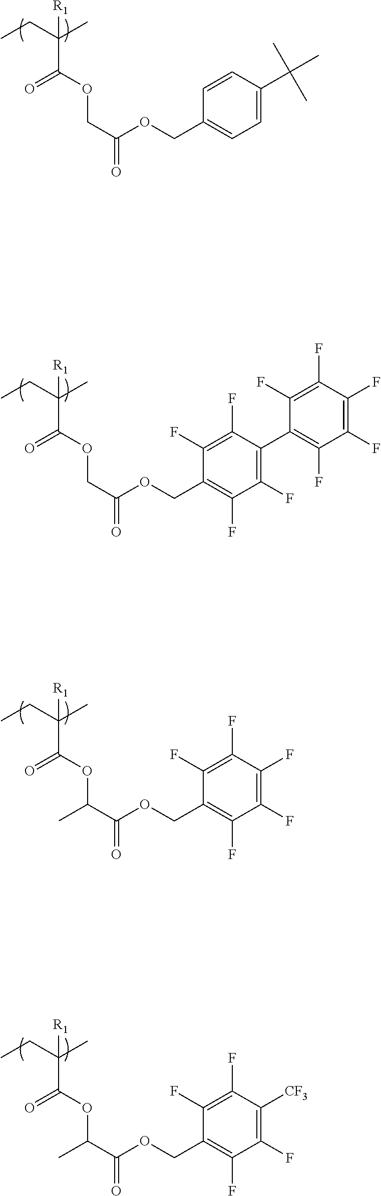

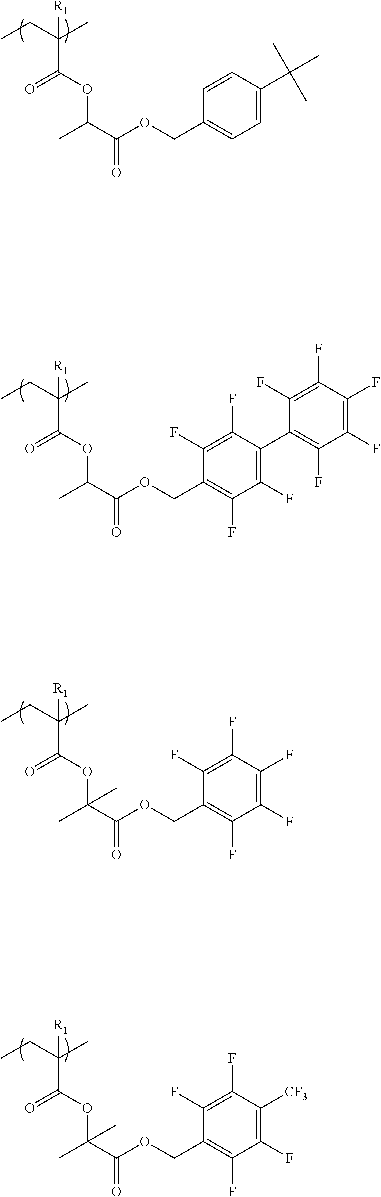

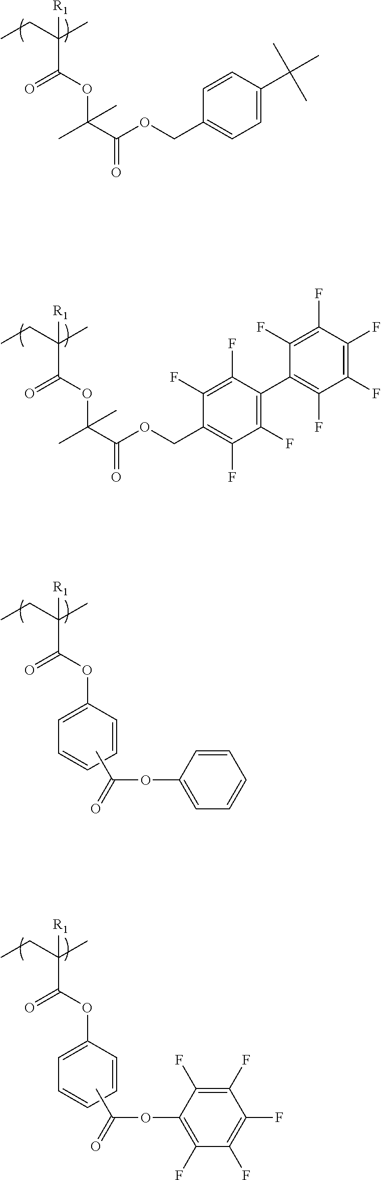

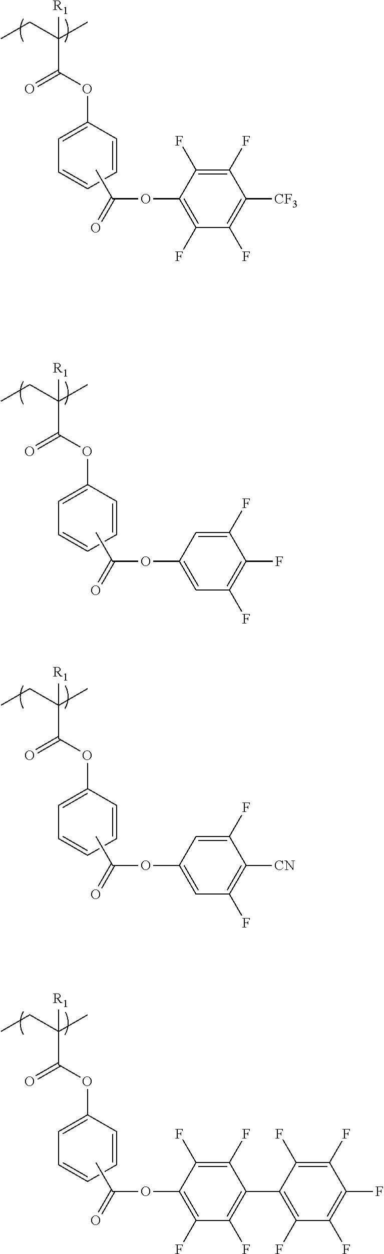

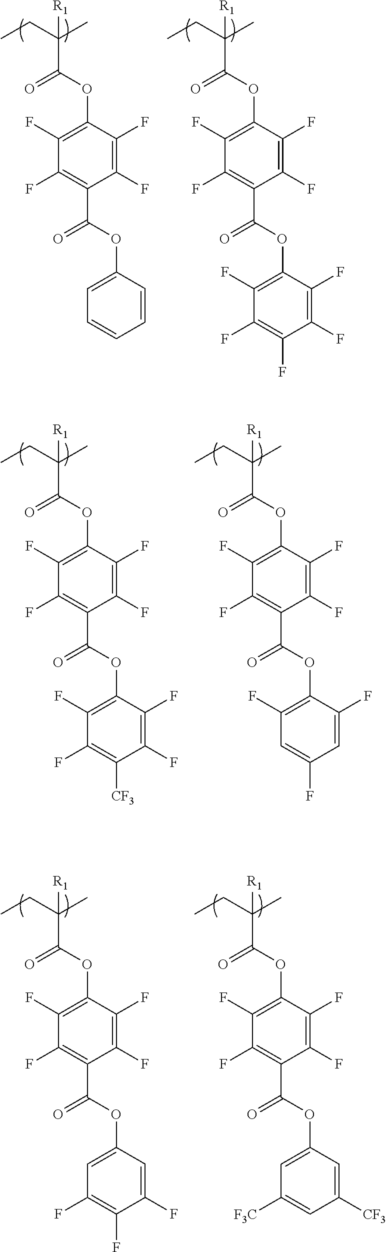

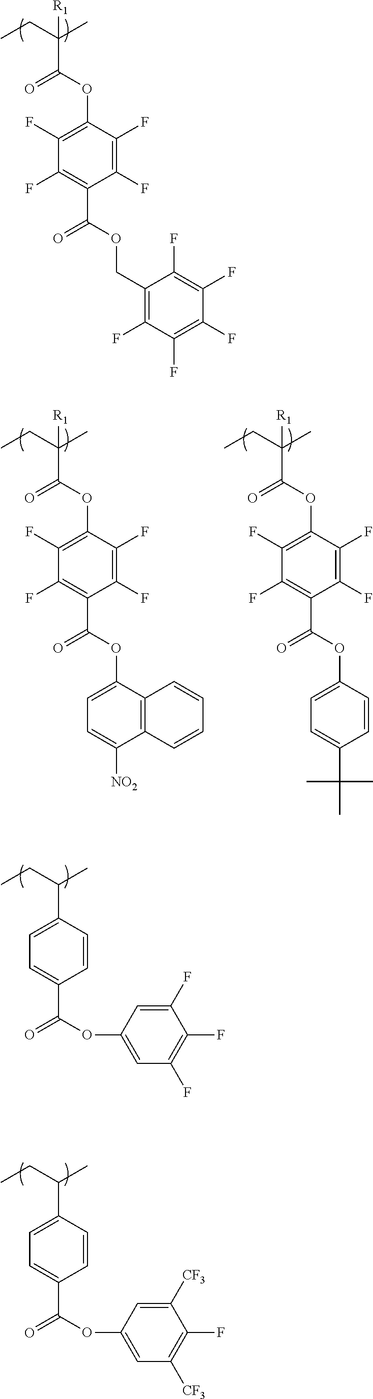

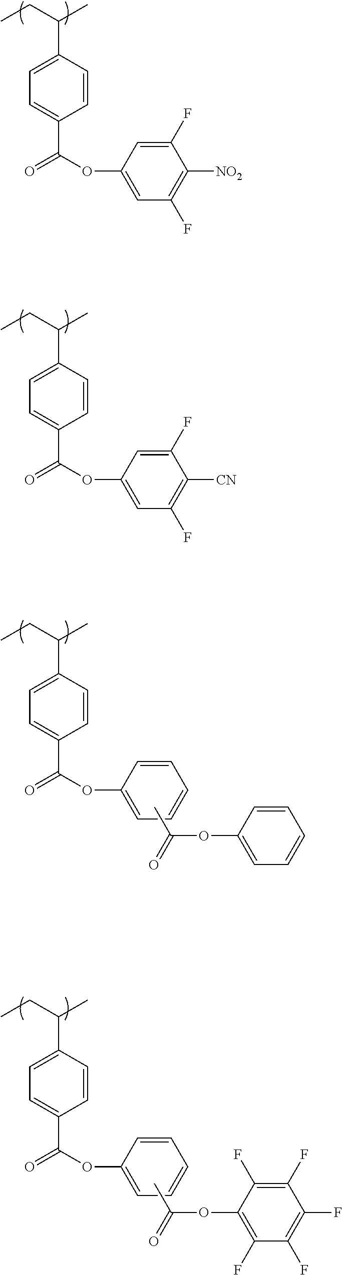

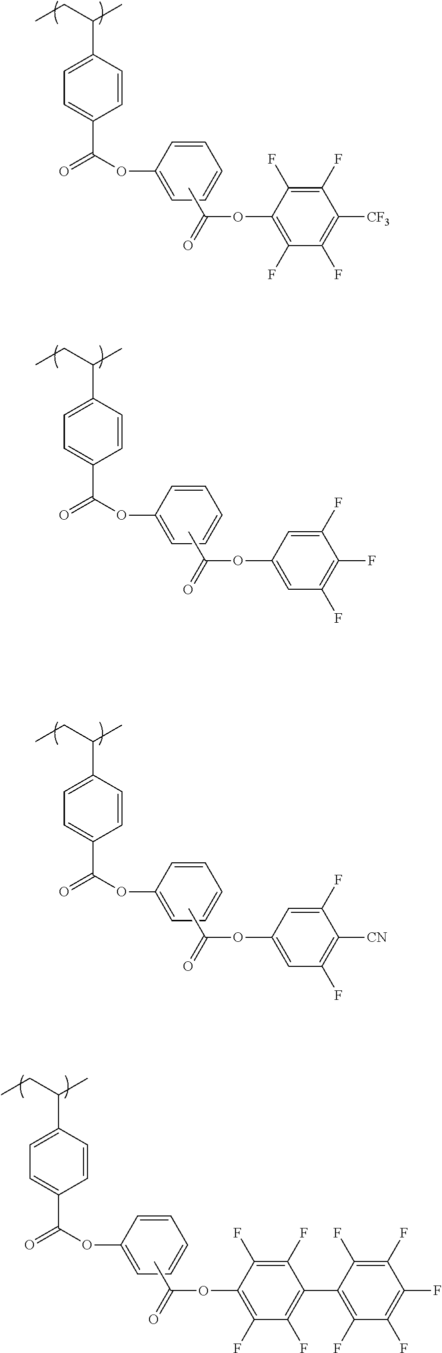

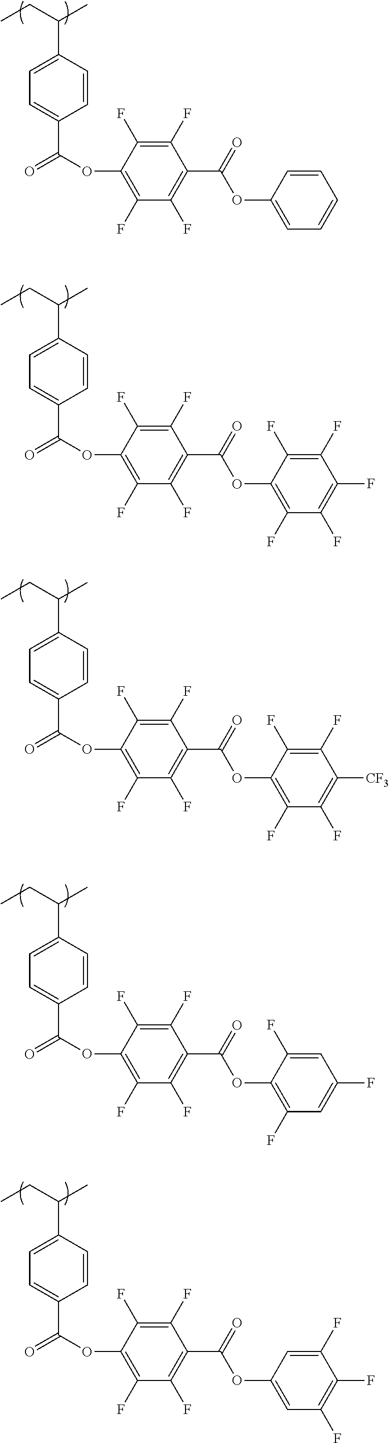

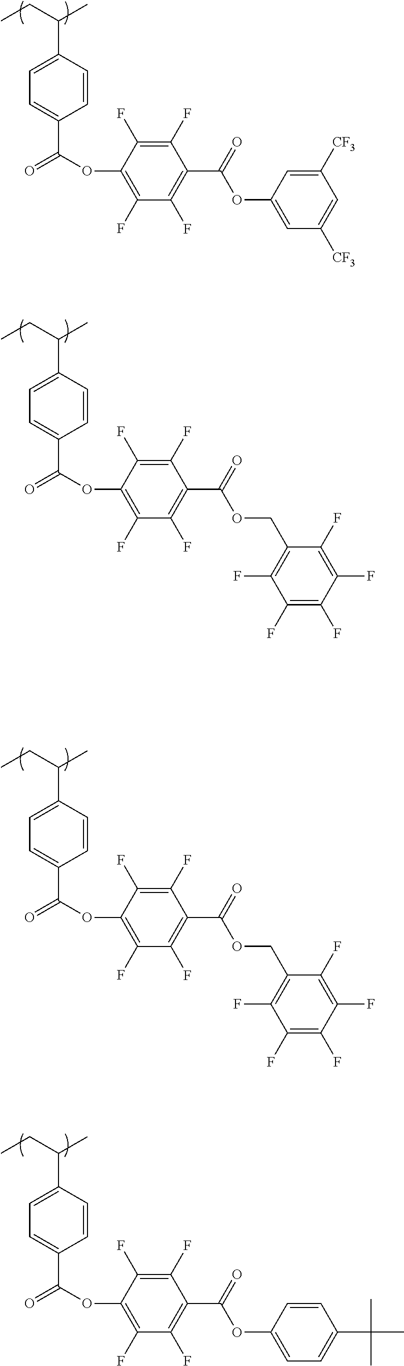

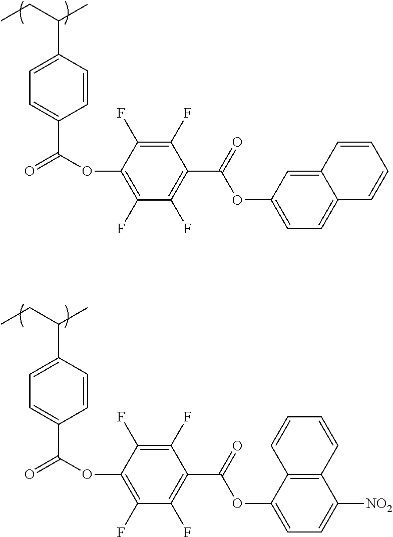

The monomers corresponding to the repeating units (R-1) and (R-2) can be synthesized by heretofore known methods. Some of the methods are described in detail in the Examples to be set forth hereinafter.

One type of the repeating units (R-1) and (R-2) may be used alone, or two or more types thereof may be used in combination. The content of repeating units (R-1) and (R-2) is preferably in the range of 5 to 100 mol %, more preferably 10 to 90 mol % and further more preferably 15 to 80 mol % based on all the repeating units.

The repeating unit containing at least either a fluorine atom or a silicon atom will now be described.

As mentioned hereinbefore, the resin (B) contains at least either a fluorine atom or a silicon atom. The form in which a fluorine atom or a silicon atom is introduced is not particularly limited. The fluorine atom or silicon atom may be contained in the repeating units (R-1) and (R-2), or repeating unit (S) containing a group selected from the group consisting of the groups (x) to (z) to be described hereinafter, or other repeating units.

It is preferred for the repeating unit containing a fluorine atom to be a repeating unit containing as a partial structure an alkyl group having a fluorine atom, a cycloalkyl group having a fluorine atom or an aryl group having a fluorine atom.

The alkyl group having a fluorine atom is a linear or branched alkyl group whose at least one hydrogen atom is replaced by a fluorine atom. The alkyl group preferably has 1 to 10 carbon atoms, more preferably 1 to 4 carbon atoms. A further other substituent may be introduced in the alkyl group.

The cycloalkyl group having a fluorine atom is a mono- or polycycloalkyl group whose at least one hydrogen atom is replaced by a fluorine atom. A further other substituent may be introduced in the cycloalkyl group.

As the aryl group containing a fluorine atom, there can be mentioned one having at least one hydrogen atom of an aryl group, such as a phenyl or naphthyl group, substituted with a fluorine atom. Further, other substituents may be contained.

As preferred alkyl groups containing a fluorine atom, cycloalkyl groups containing a fluorine atom and aryl groups containing a fluorine atom, there can be mentioned groups of the following general formulae (F2) to (F4), which however in no way limit the scope of the present invention.

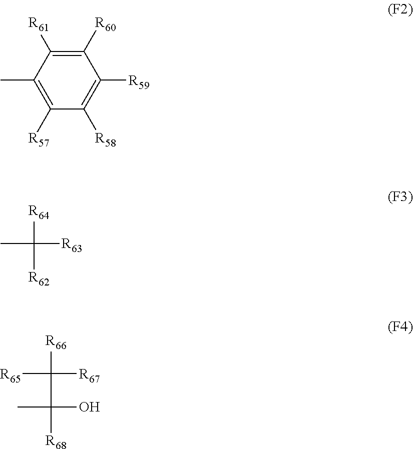

In general formulae (F2) to (F4),

each of R₅₇ to R₆₈ independently represents a hydrogen atom, a fluorine atom or an alkyl group (linear or branched), provided that at least one of each of R₅₇-R₆₁, at least one of each of R₆₂-R₆₄ and at least one of each of R₆₅-R₆₈ represent a fluorine atom or an alkyl group (preferably having 1 to 4 carbon atoms) having at least one hydrogen atom thereof substituted with a fluorine atom.

It is preferred that all of R₅₇-R₆₁ and R₆₅-R₆₇ represent fluorine atoms. Each of R₆₂, R₆₃ and R₆₈ preferably represents a fluoroalkyl group (especially having 1 to 4 carbon atoms), more preferably a perfluoroalkyl group having 1 to 4 carbon atoms. When each of R₆₂ and R₆₃ represents a perfluoroalkyl group, R₆₄ preferably represents a hydrogen atom. R₆₂ and R₆₃ may be bonded with each other to thereby form a ring.

Specific examples of the groups of general formula (F2) include a p-fluorophenyl group, a pentafluorophenyl group, a 3,5-di(trifluoromethyl)phenyl group and the like.

Specific examples of the groups of general formula (F3) include a trifluoromethyl group, a pentafluoropropyl group, a pentafluoroethyl group, a heptafluorobutyl group, a hexafluoroisopropyl group, a heptafluoroisopropyl group, a hexafluoro(2-methyl)isopropyl group, a nonafluorobutyl group, an octafluoroisobutyl group, a nonafluorohexyl group, a nonafluoro-t-butyl group, a perfluoroisopentyl group, a perfluorooctyl group, a perfluoro(trimethyl)hexyl group, a 2,2,3,3-tetrafluorocyclobutyl group, a perfluorocyclohexyl group and the like. Of these, a hexafluoroisopropyl group, a heptafluoroisopropyl group, a hexafluoro(2-methyl)isopropyl group, an octafluoroisobutyl group, a nonafluoro-t-butyl group and a perfluoroisopentyl group are preferred. A hexafluoroisopropyl group and a heptafluoroisopropyl group are more preferred.

Specific examples of the groups of general formula (F4) include —C(CF₃)₂OH, —C(C₂F₅)₂OH, —C(CF₃)(CF₃)OH, —CH(CF₃)OH and the like. —C(CF₃)₂OH is preferred.

The partial structure containing a fluorine atom may be directly bonded to the principal chain, or may be bonded to the principal chain through a group selected from the group consisting of an alkylene group, a phenylene group, an ether group, a thioether group, a carbonyl group, an ester group, an amido group, a urethane group and a ureylene group, or through a group composed of a combination of two or more of these groups.

As preferred repeating units having a fluorine atom, there can be mentioned the repeating units represented by the general formulae below.

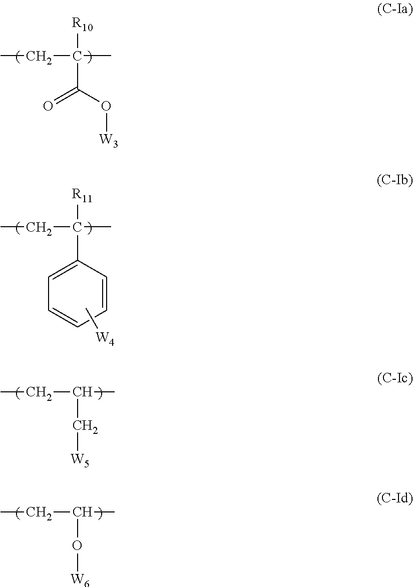

In the formulae, each of R₁₀ and R₁₁ independently represents a hydrogen atom, a fluorine atom or an alkyl group. The alkyl group is preferably a linear or branched alkyl group having 1 to 4 carbon atoms. The alkyl group may have a substituent. As a substituted alkyl group, there can be mentioned, in particular, a fluorinated alkyl group.

Each of W₃ to W₆ independently represents an organic group containing at least one fluorine atom. As such, for example, there can be mentioned the atomic groups of general formulae (F2) to (F4) above.

Further, besides these, the following units may be introduced as the repeating unit containing a fluorine atom.

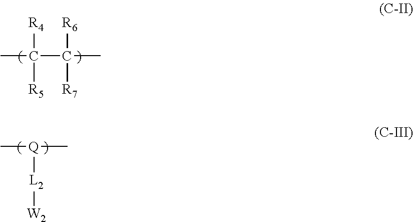

In the formulae, each of R₄ to R₇ independently represents a hydrogen atom, a fluorine atom or an alkyl group. The alkyl group is preferably a linear or branched alkyl group having 1 to 4 carbon atoms. The alkyl group may have a substituent. As a substituted alkyl group, there can be mentioned, in particular, a fluorinated alkyl group.

At least one of R₄ to R₇ represents a fluorine atom. R₄ and R₅, or R₆ and R₇ may cooperate with each other to thereby form a ring.

W₂ represents an organic group containing at least one fluorine atom. As such, for example, there can be mentioned the atomic groups of general formulae (F2) to (F4) above.

L₂ represents a single bond or a bivalent connecting group. As the bivalent connecting group, there can be mentioned a substituted or unsubstituted arylene group, a substituted or unsubstituted alkylene group, a substituted or unsubstituted cycloalkylene group, —O—, —SO₂—, —CO—, —N(R)— (in the formula, R is a hydrogen atom or an alkyl group), —NHSO₂— or a bivalent connecting group consisting of a combination of two or more of these.

Q represents an alicyclic structure. A substituent may be introduced in the alicyclic structure. The alicyclic structure may be monocyclic or polycyclic. The alicyclic structure when being polycyclic may be a bridged one. The alicyclic structure when being monocyclic is preferably a cycloalkyl group having 3 to 8 carbon atoms. As such, there can be mentioned, for example, a cyclopentyl group, a cyclohexyl group, a cyclobutyl group, a cyclooctyl group or the like. As the polycyclic one, there can be mentioned a group with, for example, a bicyclo, tricyclo or tetracyclo structure having 5 or more carbon atoms. A cycloalkyl group having 6 to 20 carbon atoms is preferred. As such, there can be mentioned, for example, an adamantyl group, a norbornyl group, a dicyclopentyl group, a tricyclodecanyl group, a tetracyclododecyl group or the like. The carbon atoms of the cycloalkyl group may be partially replaced with a heteroatom, such as an oxygen atom. It is especially preferred for Q to represent a norbornyl group, a tricyclodecanyl group, a tetracyclododecyl group or the like.

Now, the repeating units containing a silicon atom will be described below. It is preferred for the repeating unit containing a silicon atom to have an alkylsilyl structure (preferably a trialkylsilyl group) or a cyclosiloxane structure as a partial structure having a silicon atom.

As the alkylsilyl structure or cyclosiloxane structure, there can be mentioned, for example, any of the groups of the following general formulae (CS-1) to (CS-3) or the like.

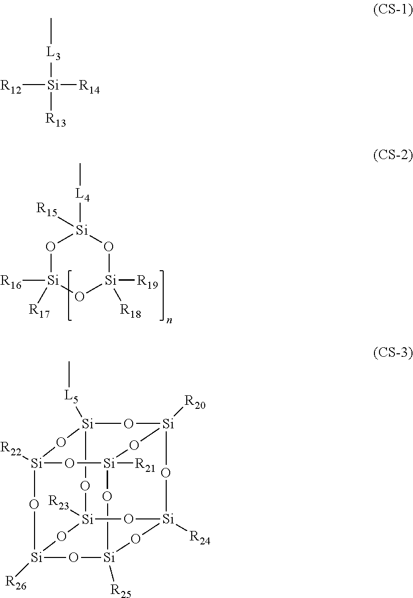

In general formulae (CS-1) to (CS-3),

each of R₁₂ to R₂₆ independently represents a linear or branched alkyl group (preferably having 1 to 20 carbon atoms) or a cycloalkyl group (preferably having 3 to 20 carbon atoms).

Each of L₃ to L₅ represents a single bond or a bivalent connecting group. As the bivalent connecting group, there can be mentioned any one or a combination of two or more groups selected from the group consisting of an alkylene group, a phenylene group, an ether group, a thioether group, a carbonyl group, an ester group, an amido group, a urethane group and a urea group.

In the formulae, n is an integer of 1 to 5. n is preferably an integer of 2 to 4.

It is preferred for the repeating unit containing at least either a fluorine atom or a silicon atom to be a (meth)acrylate repeating unit.

Particular examples of the repeating units each containing at least either a fluorine atom or a silicon atom are shown below, which in no way limit the scope of the present invention. The following particular examples include repeating units (S).

In the particular examples, X₁ represents a hydrogen atom, —CH₃, —F or —CF₃, and X₂ represents —F or —CF₃.

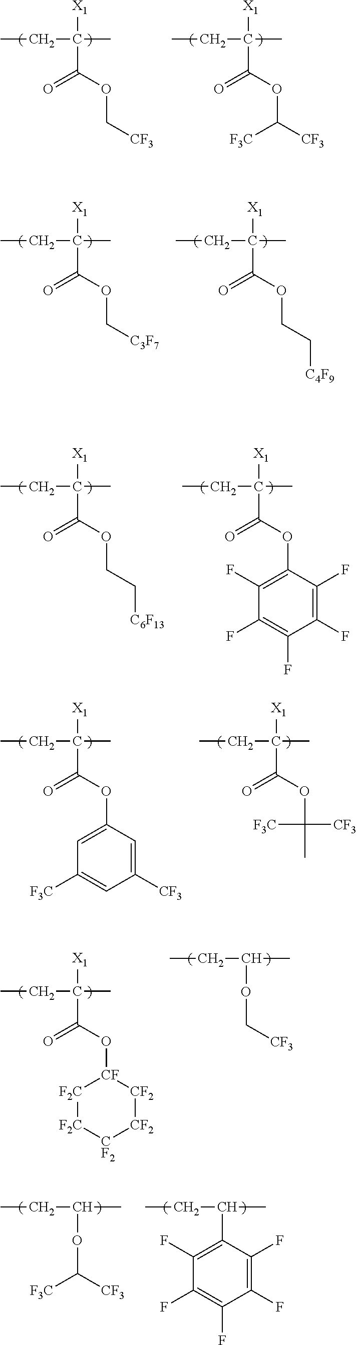

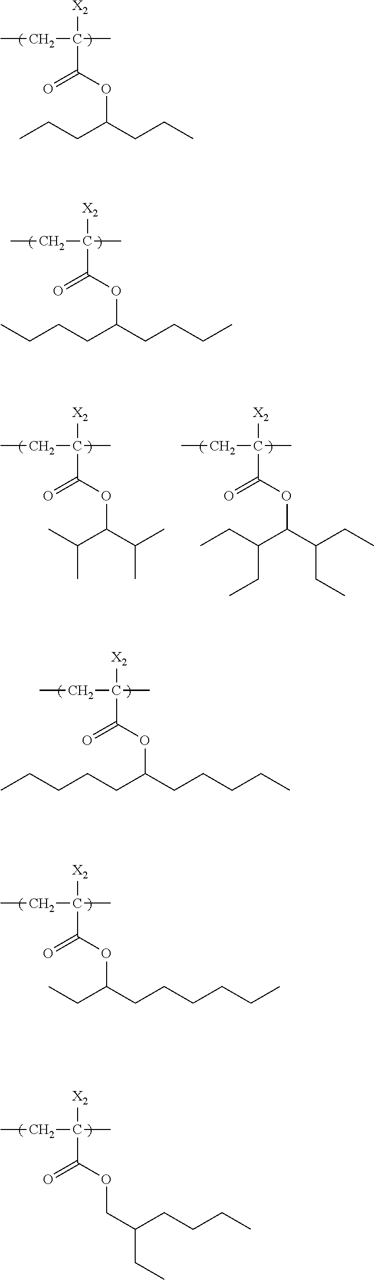

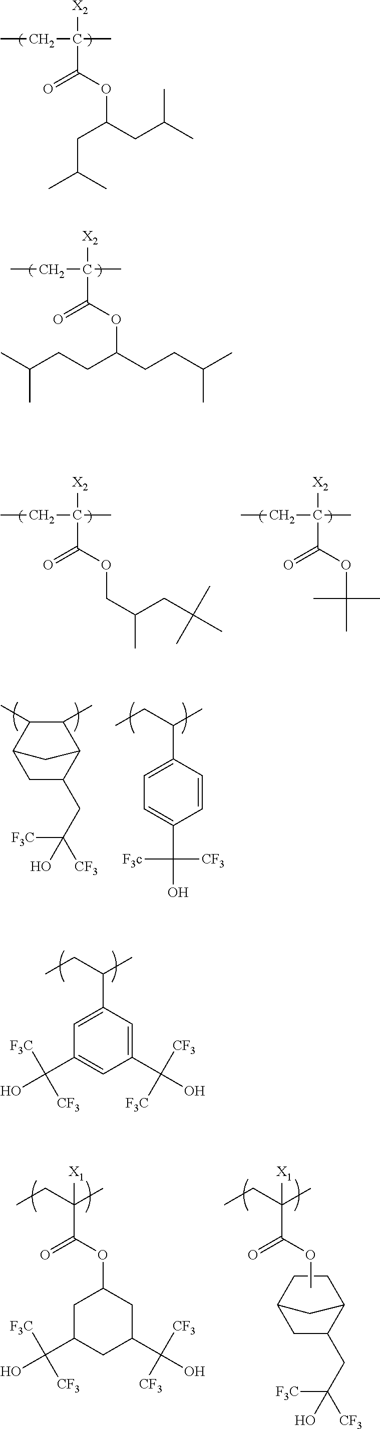

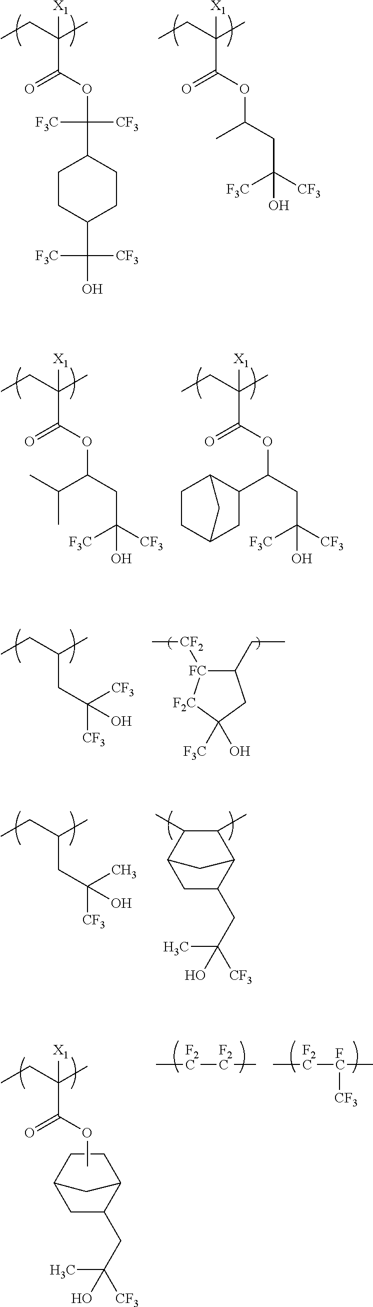

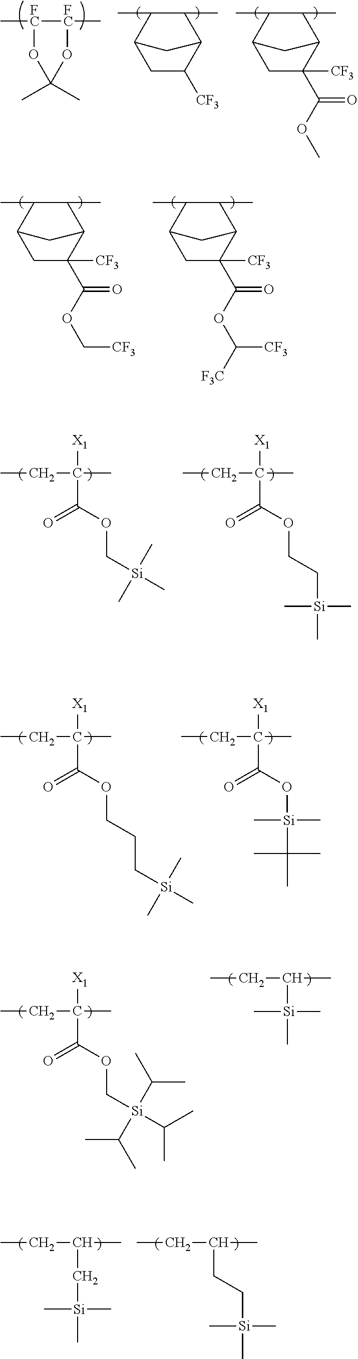

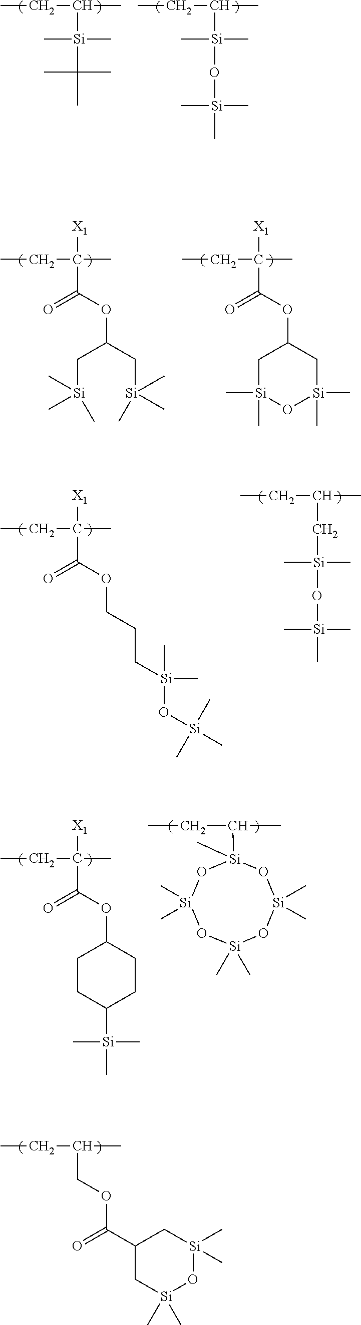

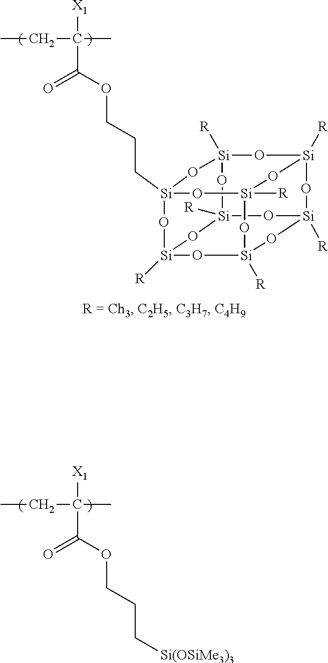

It is preferred for the resin (B) to be a copolymer comprising any of the repeating units (R-1) and (R-2) and one or more other repeating units. Enhanced immersion-liquid tracking properties can be attained by using this copolymer as compared with those realized by using homopolymers each comprising any of the repeating units constituting the copolymer alone. Namely, when this copolymer is employed, the hydrophobicity of the resin (B) as a whole can be enhanced without any excess increase of the hydrophobicity of each of the repeating units constituting the same. Therefore, favorable immersion-liquid tracking properties and developability can be simultaneously attained at high levels by employing this copolymer.

It is especially preferred for the repeating unit to be combined with the repeating units (R-1) and (R-2) to be a repeating unit (S) containing at least one group selected from the group consisting of the following groups (x) to (z). Namely, it is preferred for at least one of the resins (B) to contain the repeating unit (S) in addition to the repeating units (R-1) and (R-2).

The mentioned groups are:

(x) an alkali-soluble group,

(y) a group that is decomposed by the action of an alkali developer to thereby increase its solubility in the alkali developer (polarity conversion group), and

(z) a group that is decomposed by the action of an acid to thereby increase its solubility in an alkali developer.

The resin (B) preferably contains at least either an alkali-soluble group (x) or a polarity conversion group (y), more preferably at least a polarity conversion group (y).

As the alkali-soluble group (x), there can be mentioned a phenolic hydroxyl group, a carboxylate group, a fluoroalcohol group, a sulfonate group, a sulfonamido group, a sulfonylimido group, an (alkylsulfonyl)(alkylcarbonyl)methylene group, an (alkylsulfonyl)(alkylcarbonyl)imido group, a bis(alkylcarbonyl)methylene group, a bis(alkylcarbonyl)imido group, a bis(alkylsulfonyl)methylene group, a bis(alkylsulfonyl)imido group, a tris(alkylcarbonyl)methylene group, a tris(alkylsulfonyl)methylene group or the like.

As preferred alkali-soluble groups, there can be mentioned a fluoroalcohol group (preferably hexafluoroisopropanol group), a sulfonimido group and a bis(carbonyl)methylene group.

As the repeating unit having an alkali soluble group (x), preferred use is made of any of a repeating unit resulting from direct bonding of an alkali soluble group to the principal chain of a resin like a repeating unit of acrylic acid or methacrylic acid, a repeating unit resulting from bonding, via a connecting group, of an alkali soluble group to the principal chain of a resin and a repeating unit resulting from polymerization with the use of a chain transfer agent or polymerization initiator having an alkali soluble group to thereby introduce the same in a polymer chain terminal.

The content ratio of repeating units having an alkali soluble group (x) is preferably in the range of 1 to 50 mol %, more preferably 3 to 35 mol % and still more preferably 5 to 20 mol % based on all the repeating units of the hydrophobic resin.

Specific examples of the repeating units having an alkali-soluble group (x) will be shown below.

In the formulae, Rx represents H, CH₃, CF₃ or CH₂OH.

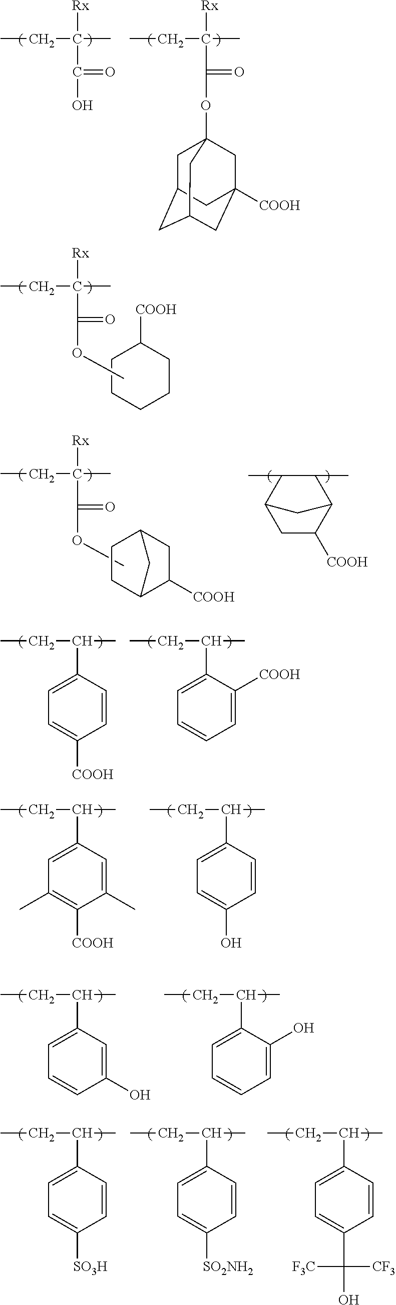

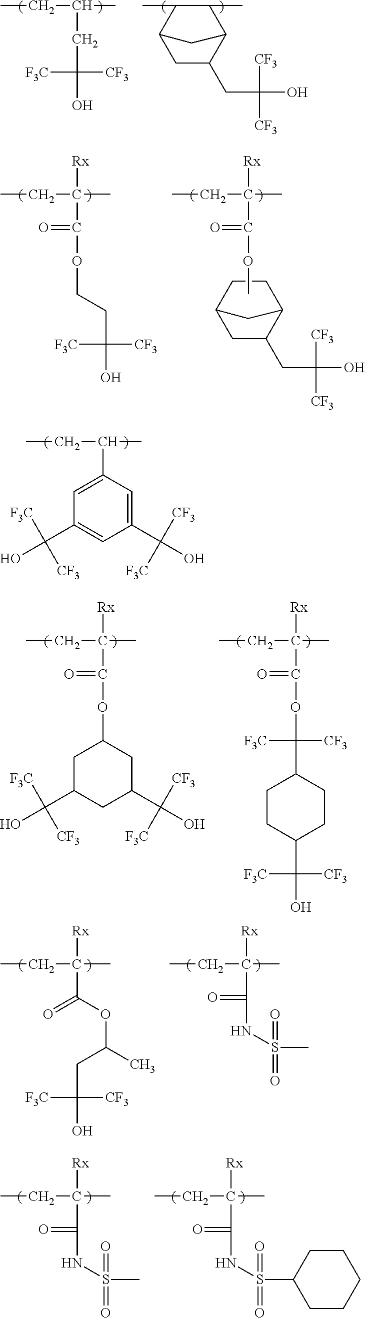

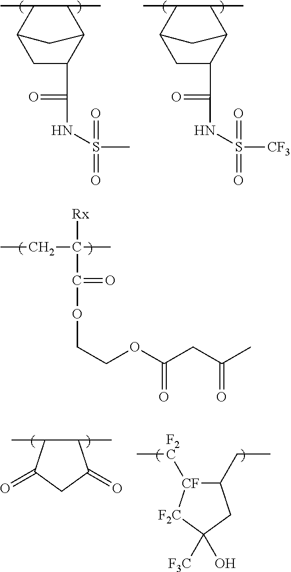

As the polarity conversion group (y), there can be mentioned, for example, a lactone group, a carboxylic ester group (—COO—), an acid anhydride group (—C(O)OC(O)—), an acid imido group (—NHCONH—), a carboxylic thioester group (—COS—), a carbonic ester group (—OC(O)O—), a sulfuric ester group (—OSO₂O—), a sulfonic ester group (—SO₂O—) or the like. A lactone group is particularly preferred.

The polarity conversion group (y) is contained in, for example, two modes which are both preferred. In one mode, the polarity conversion group (y) is contained in a repeating unit of an acrylic ester or methacrylic ester and introduced in a side chain of a resin. In the other mode, the polarity conversion group is introduced in a terminal of a polymer chain by using a polymerization initiator or chain transfer agent containing the polarity conversion group (y) in the stage of polymerization.

As particular examples of the repeating units (b) containing the polarity conversion group (y), there can be mentioned a repeating unit containing a lactone structure described later with respect to resin (A).

Further, the repeating unit (b) containing the polarity conversion group (y) is preferred to contain at least one of a fluorine atom and a silicone atom. Resins containing such a repeating unit (b) possesses hydrophobicity and particularly preferred from the standpoint of suppressing development defects.

As the repeating unit (b), there can be mentioned, for example, any of the repeating units of formula (KO) below.

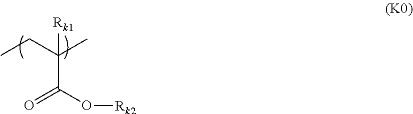

In the formula, Rₖ₁ represents a hydrogen atom, a halogen atom, a hydroxyl group, an alkyl group, a cycloalkyl group, an aryl group or a group containing a polarity conversion group.

Rₖ₂ represents an alkyl group, a cycloalkyl group, an aryl group or a group containing a polarity conversion group.

Here, at least one of Rₖ₁ and Rₖ₂ is a group containing a polarity conversion group.

The polarity conversion group, as mentioned above, refers to a group that is decomposed by the action of an alkali developer to thereby increase its solubility in the alkali developer. It is preferred for the polarity conversion group to be a group represented by X in the partial structures of general formulae (KA-1) and (KB-1) below.

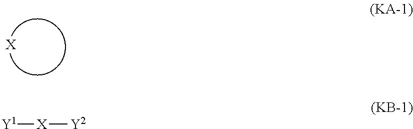

In general formulae (KA-1) and (KB-1), X represents a carboxylic ester group (—COO—), an acid anhydride group (—C(O)OC(O)—), an acid imido group (—NHCONH—), a carboxylic thioester group (—COS—), a carbonic ester group (—OC(O)O—), a sulfuric ester group (—OSO₂O—) or a sulfonic ester group (—SO₂O—).

Y¹ and Y² may be identical to or different from each other, and each thereof represents an electron withdrawing group.

The repeating unit (by) contains a preferred group whose solubility in an alkali developer is increased by containing a group with the partial structure of general formula (KA-1) or (KB-1). When the partial structure has no bonding hand as in the case of the partial structure of general formula (KA-1) or the partial structure of general formula (KB-1) in which Y¹ and Y² are monovalent, the above group with the partial structure refers to a group containing a monovalent or higher-valent group resulting from the deletion of at least one arbitrary hydrogen atom from the partial structure.

The partial structure of general formula (KA-1) or (KB-1) is linked at its arbitrary position to the principal chain of the hydrophobic resin via a substituent.

The partial structure of general formula (KA-1) is a structure in which a ring structure is formed in cooperation with a group represented by X.

In general formula (KA-1), X is preferably a carboxylic ester group (namely, in the case of the formation of a lactone ring structure as KA-1), an acid anhydride group or a carbonic ester group. More preferably, X is a carboxylic ester group.

A substituent may be introduced in the ring structure of general formula (KA-1). For example, when Zₖₐ₁ is a substituent, nka substituents may be introduced.

Zₖₐ₁, or each of a plurality of Zₖₐ₁s independently, represents a halogen atom, an alkyl group, a cycloalkyl group, an ether group, a hydroxyl group, an amido group, an aryl group, a lactone ring group or an electron withdrawing group.

Zₖₐ₁s may be linked to each other to thereby form a ring. As the ring formed by the mutual linkage of Zₖₐ₁s, there can be mentioned, for example, a cycloalkyl ring or a heterocycle (for example, a cycloether ring or a lactone ring).

The above nka is an integer of 0 to 10, preferably 0 to 8, more preferably 0 to 5, further more preferably 1 to 4 and most preferably 1 to 3.

The electron withdrawing groups represented by Zₖₐ₁ are the same as those represented by Y¹ and Y² to be described hereinafter. These electron withdrawing groups may be substituted with other electron withdrawing groups.

Zₖₐ₁ is preferably an alkyl group, a cycloalkyl group, an ether group, a hydroxyl group or an electron withdrawing group. Zₖₐ₁ is more preferably an alkyl group, a cycloalkyl group or an electron withdrawing group. It is preferred for the ether group to be one substituted with, for example, an alkyl group or a cycloalkyl group, namely, to be an alkyl ether group or the like. The electron withdrawing group is as mentioned above.

As the halogen atom represented by Zₖₐ₁, there can be mentioned a fluorine atom, a chlorine atom, a bromine atom, an iodine atom or the like. Among these, a fluorine atom is preferred.

The alkyl group represented by Zₖₐ₁ may contain a substituent, and may be linear or branched. The linear alkyl group preferably has 1 to 30 carbon atoms, more preferably 1 to 20 carbon atoms. As the linear alkyl group, there can be mentioned, for example, a methyl group, an ethyl group, an n-propyl group, an n-butyl group, a sec-butyl group, a t-butyl group, an n-pentyl group, an n-hexyl group, an n-heptyl group, an n-octyl group, an n-nonyl group, an n-decanyl group or the like. The branched alkyl group preferably has 3 to 30 carbon atoms, more preferably 3 to 20 carbon atoms. As the branched alkyl group, there can be mentioned, for example, an i-propyl group, an i-butyl group, a t-butyl group, an i-pentyl group, a t-pentyl group, an i-hexyl group, a t-hexyl group, an i-heptyl group, a t-heptyl group, an i-octyl group, a t-octyl group, an i-nonyl group, a t-decanyl (t-decanoyl) group or the like. It is preferred for the alkyl group represented by Zₖₐ₁ to be one having 1 to 4 carbon atoms, such as a methyl group, an ethyl group, an n-propyl group, an i-propyl group, an n-butyl group, an i-butyl group or a t-butyl group.

The cycloalkyl group represented by Zₖₐ₁ may contain a substituent and may be monocyclic or polycyclic. When polycyclic, the cycloalkyl group may be a bridged one. Namely, in that case, the cycloalkyl group may have a bridged structure. The monocycloalkyl group is preferably a cycloalkyl group having 3 to 8 carbon atoms. As such a cycloalkyl group, there can be mentioned, for example, a cyclopropyl group, a cyclopentyl group, a cyclohexyl group, a cyclobutyl group, a cyclooctyl group or the like. As the polycycloalkyl group, there can be mentioned a group with, for example, a bicyclo, tricyclo or tetracyclo structure having 5 or more carbon atoms. This polycycloalkyl group is preferably a cycloalkyl group having 6 to 20 carbon atoms. As such, there can be mentioned, for example, an adamantyl group, a norbornyl group, an isobornyl group, a camphonyl group, a bicyclopentyl group, an α-pinanyl group, a tricyclodecanyl group, a tetracyclododecyl group, an androstanyl group, any of the following structures or the like. The carbon atoms of each of the cycloalkyl groups may be partially replaced with a heteroatom, such as an oxygen atom.

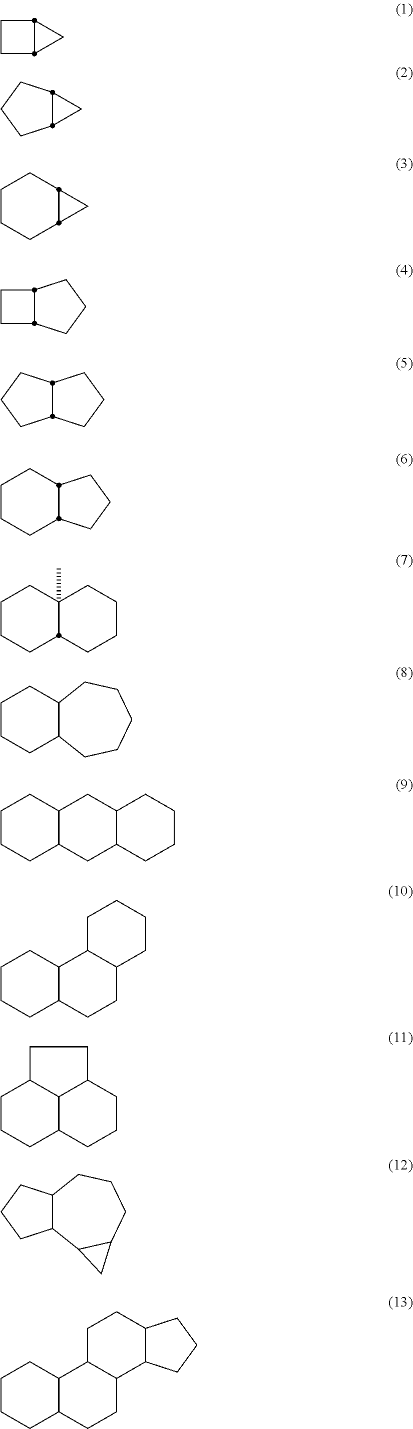

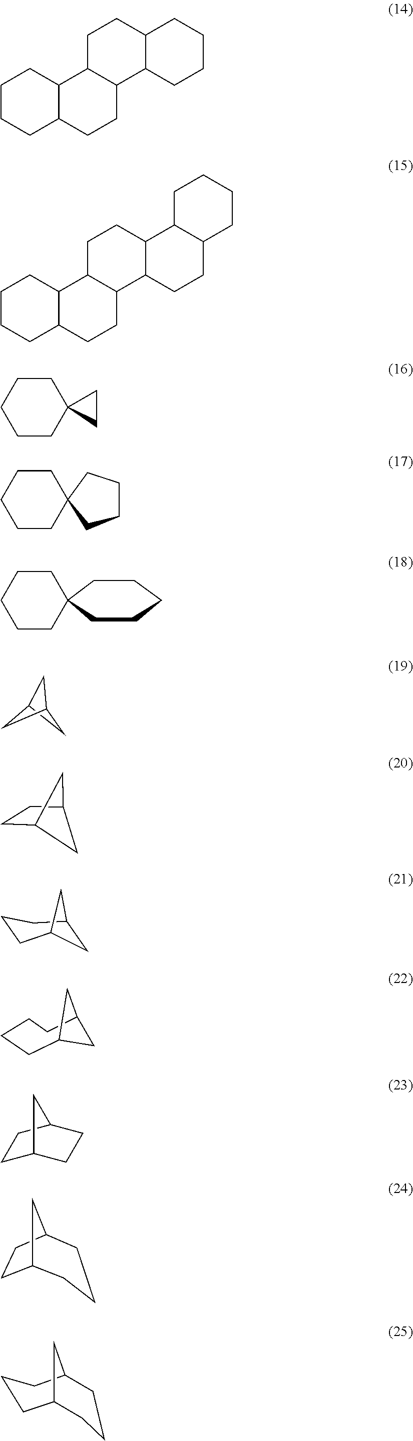

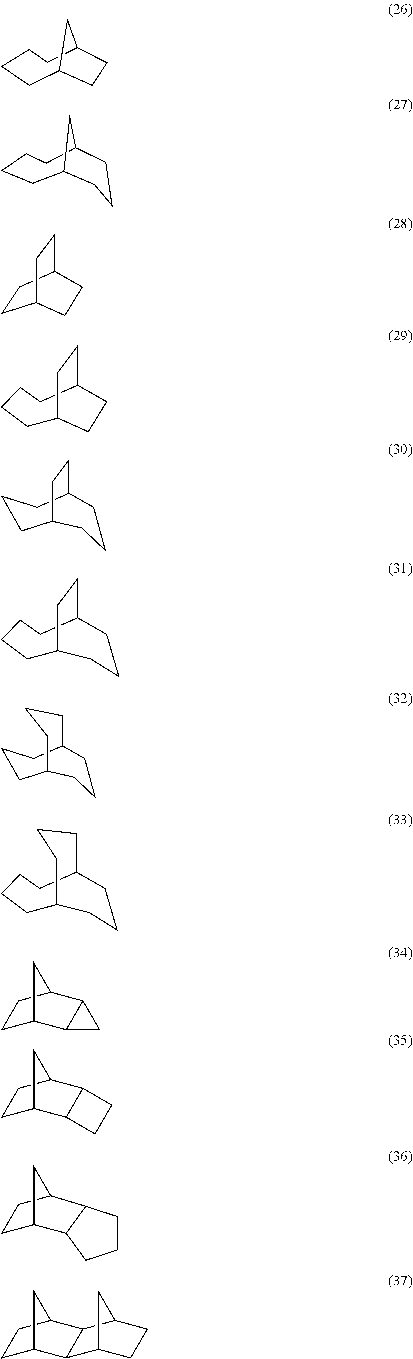

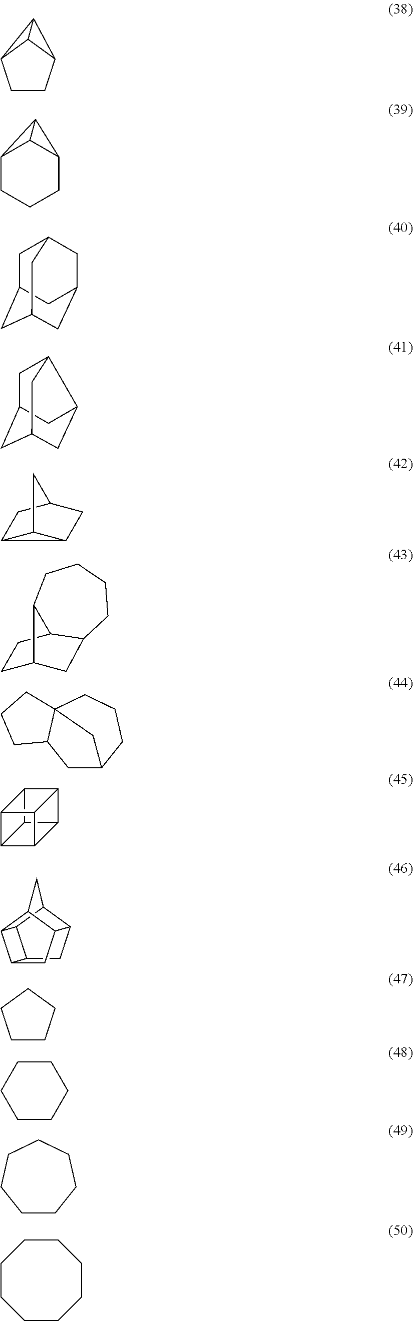

As preferred alicyclic moieties among the above, there can be mentioned an adamantyl group, a noradamantyl group, a decalin group, a tricyclodecanyl group, a tetracyclododecanyl group, a norbornyl group, a cedrol group, a cyclohexyl group, a cycloheptyl group, a cyclooctyl group, a cyclodecanyl group and a cyclododecanyl group. As more preferred alicyclic moieties, there can be mentioned an adamantyl group, a decalin group, a norbornyl group, a cedrol group, a cyclohexyl group, a cycloheptyl group, a cyclooctyl group, a cyclodecanyl group, a cyclododecanyl group and a tricyclodecanyl group.

As a substituent that can be introduced in these alicyclic structures, there can be mentioned an alkyl group, a halogen atom, a hydroxyl group, an alkoxy group, a carboxyl group or an alkoxycarbonyl group. The alkyl group is preferably a lower alkyl group, such as a methyl group, an ethyl group, a propyl group, an isopropyl group or a butyl group. More preferably, the alkyl group is a methyl group, an ethyl group, a propyl group or an isopropyl group. As preferred alkoxy groups, there can be mentioned those each having 1 to 4 carbon atoms, such as a methoxy group, an ethoxy group, a propoxy group and a butoxy group. As a substituent that may be introduced in these alkyl and alkoxy groups, there can be mentioned a hydroxyl group, a halogen atom, an alkoxy group (preferably having 1 to 4 carbon atoms) or the like.

Further substituents may be introduced in these groups. As further substituents, there can be mentioned a hydroxyl group; a halogen atom (fluorine, chlorine, bromine or iodine); a nitro group; a cyano group; the above alkyl groups; an alkoxy group, such as a methoxy group, an ethoxy group, a hydroxyethoxy group, a propoxy group, a hydroxypropoxy group, an n-butoxy group, an isobutoxy group, a sec-butoxy group or a t-butoxy group; an alkoxycarbonyl group, such as a methoxycarbonyl group or an ethoxycarbonyl group; an aralkyl group, such as a benzyl group, a phenethyl group or a cumyl group; an aralkyloxy group; an acyl group, such as a formyl group, an acetyl group, a butyryl group, a benzoyl group, a cyanamyl group or a valeryl group; an acyloxy group, such as a butyryloxy group; the above alkenyl groups; an alkenyloxy group, such as a vinyloxy group, a propenyloxy group, an allyloxy group or a butenyloxy group; the above aryl groups; an aryloxy group, such as a phenoxy group; an aryloxycarbonyl group, such as a benzoyloxy group; and the like.

Preferably, X of general formula (KA-1) represents a carboxylic ester group and the partial structure of general formula (KA-1) is a lactone ring. A 5- to 7-membered lactone ring is preferred.

Further, as shown in formulae (KA-1-1) to (KA-1-17) below, the 5- to 7-membered lactone ring as the partial structure of general formula (KA-1) is preferably condensed with another ring structure in such a fashion that a bicyclo structure or a spiro structure is formed.

The peripheral ring structures to which the ring structure of general formula (KA-1) may be bonded can be, for example, those shown in formulae (KA-1-1) to (KA-1-17) below, or those similar to the same.

It is preferred for the structure containing the lactone ring structure of general formula (KA-1) to be the structure of any of formulae (KA-1-1) to (KA-1-17) below. The lactone structure may be directly bonded to the principal chain. As preferred structures, there can be mentioned those of formulae (KA-1-1), (KA-1-4), (KA-1-5), (KA-1-6), (KA-1-13), (KA-1-14) and (KA-1-17).

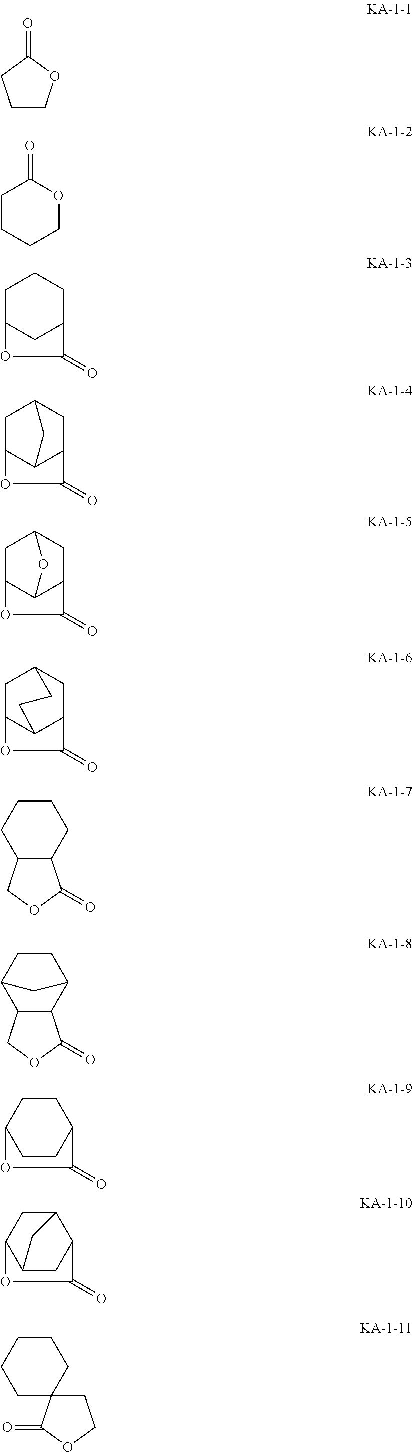

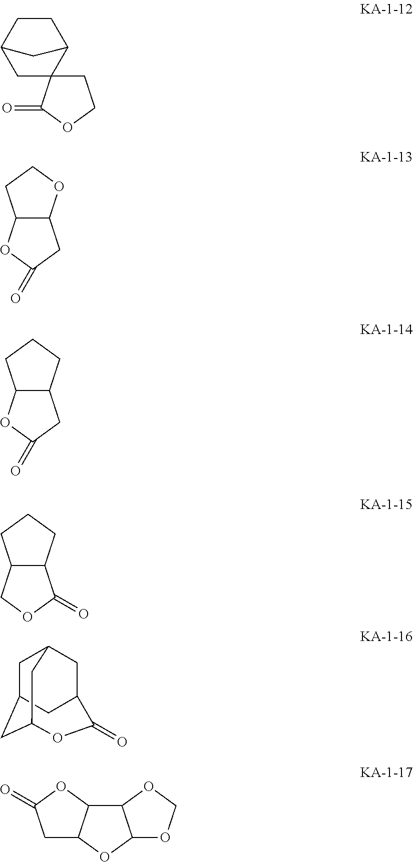

A substituent may or may not be introduced in the above structures containing the lactone ring structure.

As preferred substituents, there can be mentioned the same as the substituents Zₖₐ₁ that may be introduced in the ring structure of general formula (KA-1) above.

In general formula (KB-1), X is preferably a carboxylic ester group (—COO—).

In general formula (KB-1), each of Y¹ and Y² independently represents an electron withdrawing group.

The electron withdrawing group has the partial structure of formula (EW) below. In formula (EW), * represents either a bonding hand directly bonded to the structure of general formula (KA-1) or a bonding hand directly bonded to X of general formula (KB-1).

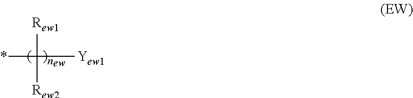

In formula (EW),

n_{ew} is the number of repetitions of each of the connecting groups of the formula —C(R_{ew1})(R_{ew2})—, being an integer of 0 or 1. When n_{ew} is 0, a single bond is represented, indicating the direct bonding of Y_{ew1}.

Y_{ew1} can be any of a halogen atom, a cyano group, a nitrile group, a nitro group, any of the halo(cyclo)alkyl groups or haloaryl groups of the formula —C(R_{f1})(R_{f2})—R_{f3} to be described hereinafter, an oxy group, a carbonyl group, a sulfonyl group, a sulfinyl group and a combination thereof. The electron withdrawing groups may have, for example, the following structures. Herein, the “halo(cyclo)alkyl group” refers to an at least partially halogenated alkyl group or cycloalkyl group. The “haloaryl group” refers to an at least partially halogenated aryl group. In the following structural formulae, each of R_{ew3} and R_{ew4} independently represents an arbitrary structure. Regardless of the types of the structures of R_{ew3} and R_{ew4}, the partial structures of formula (EW) exhibit electron withdrawing properties, and may be linked to, for example, the principal chain of the resin. Preferably, each of R_{ew3} and R_{ew4} is an alkyl group, a cycloalkyl group or a fluoroalkyl group.

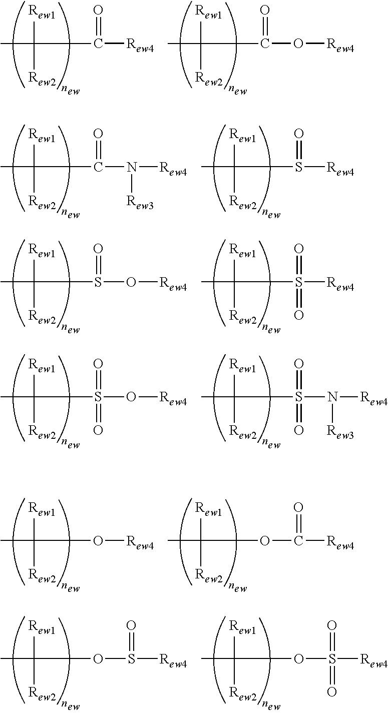

When Y_{ew1} is a bivalent or higher-valent group, the remaining bonding hand or hands form a bond with an arbitrary atom or substituent. At least any of the groups represented by Y_{ew1}, R_{ew1} and R_{ew2} may be linked via a further substituent to the principal chain of the hydrophobic resin.

Y_{ew1} is preferably a halogen atom or any of the halo(cyclo)alkyl groups or haloaryl groups of the formula —C(R_{f1})(R_{f2})—R_{f3}.

Each of R_{ew1} and R_{ew2} independently represents an arbitrary substituent, for example, a hydrogen atom, an alkyl group, a cycloalkyl group or an aryl group.

At least two of R_{ew1}, R_{ew2} and Y_{ew1} may be linked to each other to thereby form a ring.

In the above formula, R_{f1} represents a halogen atom, a perhaloalkyl group, a perhalocycloalkyl group or a perhaloaryl group. R_{f1} is preferably a fluorine atom, a perfluoroalkyl group or a perfluorocycloalkyl group, more preferably a fluorine atom or a trifluoromethyl group.

Each of R_{f2} and R_{f3} independently represents a hydrogen atom, a halogen atom or an organic group. R_{f2} and R_{f3} may be linked to each other to thereby form a ring. As the organic group, there can be mentioned, for example, an alkyl group, a cycloalkyl group, an alkoxy group or the like. It is preferred for R_{f2} to represent the same groups as R_{f1} or to be linked to R_{f3} to thereby form a ring.

R_{f1} to R_{f3} may be linked to each other to thereby form a ring. As the formed ring, there can be mentioned a (halo)cycloalkyl ring, a (halo)aryl ring or the like.

As the (halo)alkyl groups represented by R_{f1} to R_{f3}, there can be mentioned, for example, the alkyl groups mentioned above as being represented by Zₖₐ₁ and structures resulting from halogenation thereof.

As the (per)halocycloalkyl groups and (per)haloaryl groups represented by R_{f1} to R_{f3} or contained in the ring formed by the mutual linkage of R_{f2} and R_{f3}, there can be mentioned, for example, structures resulting from halogenation of the cycloalkyl groups mentioned above as being represented by Zₖₐ₁, preferably fluorocycloalkyl groups of the formula —C₍ₙ₎F₍₂ₙ₋₂₎ H and perfluoroaryl groups of the formula —C₍ₙ₎F₍ₙ₋₁₎. The number of carbon atoms, n, is not particularly limited. Preferably, however, it is in the range of 5 to 13, more preferably 6.

As preferred rings that may be formed by the mutual linkage of at least two of R_{ew1}, R_{ew2} and Y_{ew1}, there can be mentioned cycloalkyl groups and heterocyclic groups. Preferred heterocyclic groups are lactone ring groups. As the lactone rings, there can be mentioned, for example, the structures of formulae (KA-1-1) to (KA-1-17) above.

The repeating unit (b) may contain two or more of the partial structures of general formula (KA-1), or two or more of the partial structures of general formula (KB-1), or both any one of the partial structures of general formula (KA-1) and any one of the partial structures of general formula (KB-1).

A part or the whole of any of the partial structures of general formula (KA-1) may double as the electron withdrawing group represented by Y¹ or Y² of general formula (KB-1). For example, when X of general formula (KA-1) is a carboxylic ester group, the carboxylic ester group can function as the electron withdrawing group represented by Y¹ or Y² of general formula (KB-1).

The repeating unit (b) may be a repeating unit (b′) containing at least either a fluorine atom or a silicon atom and a polarity conversion group simultaneously introduced in the same side chain thereof, or a repeating unit (b*) containing a polarity conversion group but containing neither a fluorine atom nor a silicon atom, or a repeating unit (b″) in which a polarity conversion group is introduced in its one side chain while at least either a fluorine atom or a silicon atom is introduced in a side chain other than the above side chain within the same repeating unit. However, it is preferred for the resin (B) to contain the repeating unit (b′) as the repeating unit (b).

When the resin (B) contains the repeating unit (b*), it is preferred for the resin (B) to be a copolymer with a repeating unit (above-mentioned repeating unit (b)) containing at least either a fluorine atom or a silicon atom. In the repeating unit (b″), it is preferred for the side chain containing a polarity conversion group and the side chain containing at least either a fluorine atom or a silicon atom to be bonded to the same carbon atom of the principal chain, namely to be in a positional relationship shown in formula (K1) below.

In the formula, B1 represents a partial structure containing a group whose solubility is increased in an alkali developer, and B2 represents a partial structure containing at least either a fluorine atom or a silicon atom.

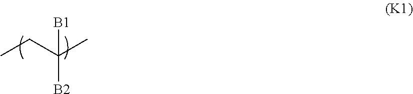

In the repeating unit (b*) and repeating unit (b″), it is highly preferred for the polarity conversion group to be a partial structure expressed by —COO— in the structures of general formula (KA-1).

The receding contact angle with water of the resin composition film after alkali development can be decreased by the polarity conversion achieved by the decomposition of the polarity conversion group by the action of an alkali developer. The decrease of the receding contact angle between water and the film after alkali development is preferred from the viewpoint of the inhibition of development defects.

The receding contact angle with water of the resin composition film after alkali development is preferably 50° or less, more preferably 40° or less, at 23±3° C. in a humidity of 45±5%.

The receding contact angle refers to a contact angle determined when the contact line at a droplet-substrate interface draws back. It is generally known that the receding contact angle is useful in the simulation of droplet mobility in a dynamic condition. In brief, the receding contact angle can be defined as the contact angle exhibited at the recession of the droplet interface at the time of, after application of a droplet discharged from a needle tip onto a substrate, re-indrawing the droplet into the needle. Generally, the receding contact angle can be measured according to a method of contact angle measurement known as the dilation/contraction method.

The above receding contact angle of the film after alkali development refers to the contact angle obtained by measuring the following film by the dilation/contraction method mentioned in the Examples to be described hereinafter. Namely, an organic antireflection film ARC29A (produced by Nissan Chemical Industries, Ltd.) was applied onto a silicon wafer (8-inch caliber) and baked at 205° C. for 60 seconds, thereby forming a 98 nm-thick antireflection film. Each of the compositions of the present invention was applied thereonto and baked at 120° C. for 60 seconds, thereby forming a 120 nm-thick film. The film was developed with an aqueous solution of tetramethylammonium hydroxide (2.38 mass %) for 30 seconds, rinsed with pure water and spin dried. The contact angle of the thus obtained film was measured in accordance with the dilation/contraction method.

The rate of hydrolysis of the resin (B) in an alkali developer is preferably 0.001 nm/sec or greater, more preferably 0.01 nm/sec or greater, further more preferably 0.1 nm/sec or greater and most preferably 1 nm/sec or greater.

Herein, the rate of hydrolysis of the resin (B) in an alkali developer refers to the rate of decrease of the thickness of a resin film formed from only the resin (B) in 23° C. TMAH (aqueous solution of tetramethylammonium hydroxide) (2.38 mass %).

It is preferred for the resin (B) to contain a repeating unit (b) containing at least two polarity conversion groups and contain at least either a fluorine atom or a silicon atom.

When the repeating unit (b) contains at least two polarity conversion groups, it is preferred for the repeating unit to contain a group with any of the partial structures having two polarity conversion groups of general formula (KY-1) below. When the structure of general formula (KY-1) has no bonding hand, a group with a mono- or higher-valent group resulting from the removal of at least any arbitrary one of the hydrogen atoms contained in the structure is referred to.

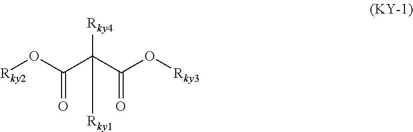

In general formula (KY-1),

each of R_{ky1} and R_{ky4} independently represents a hydrogen atom, a halogen atom, an alkyl group, a cycloalkyl group, a carbonyl group, a carbonyloxy group, an oxycarbonyl group, an ether group, a hydroxyl group, a cyano group, an amido group or an aryl group. Alternatively, both R_{ky1} and R_{ky4} may be bonded to the same atom to thereby form a double bond. For example, both R_{ky1} and R_{ky4} may be bonded to the same oxygen atom to thereby form a part (═O) of a carbonyl group.

Each of R_{ky2} and R_{ky3} independently represents an electron withdrawing group. Alternatively, R_{ky1} and R_{ky2} are linked to each other to thereby form a lactone structure, while R_{ky3} is an electron withdrawing group. The formed lactone structure is preferably any of the above-mentioned structures (KA-1-1) to (KA-1-17). As the electron withdrawing group, there can be mentioned any of the same groups as mentioned above with respect to Y¹ and Y² of general formula (KB-1). This electron withdrawing group is preferably a halogen atom, or any of the halo(cyclo)alkyl groups or haloaryl groups of the formula —C(R_{f1})(R_{f2})—R_{f3} above. Preferably, R_{ky3} is a halogen atom, or any of the halo(cyclo)alkyl groups or haloaryl groups of the formula —C(R_{f1})(R_{f2})—R_{f3} above, while R_{ky2} is either linked to R_{ky1} to thereby form a lactone ring, or an electron withdrawing group containing no halogen atom.

R_{ky1}, R_{ky2} and R_{ky4} may be linked to each other to thereby form a monocyclic or polycyclic structure.

As R_{ky1} and R_{ky4}, there can be mentioned, for example, the same groups as set forth above with respect to Zₖₐ₁ of general formula (KA-1).

The lactone rings formed by the mutual linkage of R_{ky1} and R_{ky2} preferably have the structures of formulae (KA-1-1) to (KA-1-17) above. As the electron withdrawing groups, there can be mentioned those set forth above as being represented by Y¹ and Y² of general formula (KB-1) above.

It is preferred for the structure of general formula (KY-1) to be the structure of general formula (KY-2) below. The structure of general formula (KY-2) refers to a group with a mono- or higher-valent group resulting from the removal of at least any arbitrary one of the hydrogen atoms contained in the structure.

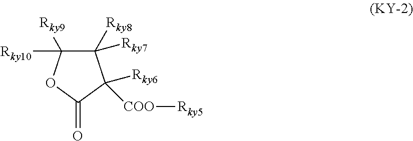

In formula (KY-2),

each of R_{ky6} to R_{ky10} independently represents a hydrogen atom, a halogen atom, an alkyl group, a cycloalkyl group, a carbonyl group, a carbonyloxy group, an oxycarbonyl group, an ether group, a hydroxyl group, a cyano group, an amido group or an aryl group.

At least two of R_{ky6} to R_{ky10} may be linked to each other to thereby form a monocyclic or polycyclic structure.

R_{ky5} represents an electron withdrawing group. As the electron withdrawing group, there can be mentioned any of the same groups as set forth above with respect to Y¹ and Y². This electron withdrawing group is preferably a halogen atom, or any of the halo(cyclo)alkyl groups or haloaryl groups of the formula —C(R_{f1})(R_{f2})—R_{f3} above.

As R_{ky5} to R_{ky10}, there can be mentioned, for example, the same groups as set forth above with respect to Zₖₐ₁ of formula (KA-1).

It is more preferred for the structure of formula (KY-2) to be the partial structure of general formula (KY-3) below.

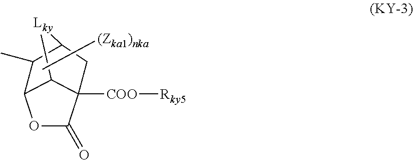

In formula (KY-3),

Zₖₐ₁ and nka are as defined above in connection with general formula (KA-1). R_{ky5} is as defined above in connection with formula (KY-2).

L_{ky} represents an alkylene group, an oxygen atom or a sulfur atom. As the alkylene group represented by L_{ky}, there can be mentioned a methylene group, an ethylene group or the like. L_{ky} is preferably an oxygen atom or a methylene group, more preferably a methylene group.

The repeating units (b) are not limited as long as they are derived by polymerization, such as addition polymerization, condensation polymerization or addition condensation. Preferred repeating units are those obtained by the addition polymerization of a carbon to carbon double bond. As such repeating units, there can be mentioned, for example, acrylate repeating units (including the family having a substituent at the α- and/or β-position), styrene repeating units (including the family having a substituent at the α- and/or β-position), vinyl ether repeating units, norbornene repeating units, repeating units of maleic acid derivatives (maleic anhydride, its derivatives, maleimide, etc.) and the like. Of these, acrylate repeating units, styrene repeating units, vinyl ether repeating units and norbornene repeating units are preferred. Acrylate repeating units, vinyl ether repeating units and norbornene repeating units are more preferred. Acrylate repeating units are most preferred.

The repeating unit (b) may be a repeating unit with the following partial structure.

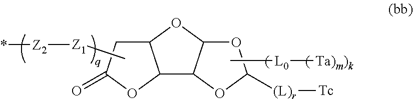

In general formula (bb),

Z₁, or each of Z₁s independently, represents a single bond, an ether bond, an ester bond, an amido bond, a urethane bond or a urea bond, preferably an ester bond.

Z₂, or each of Z₂s independently, represents a chain- or cycloalkylene group, preferably an alkylene group having 1 or 2 carbon atoms or a cycloalkylene group having 5 to 10 carbon atoms.

Ta, or each of Ta's independently, represents an alkyl group, a cycloalkyl group, an alkoxy group, a nitrile group, a hydroxyl group, an amido group, an aryl group or an electron withdrawing group (having the same meaning as that of the electron withdrawing group represented by Y¹ or Y² of general formula (KB-1) above). An alkyl group, a cycloalkyl group and an electron withdrawing group are preferred. An electron withdrawing group is more preferred. Two or more Ta's may be bonded to each other to thereby form a ring.

L₀ represents a single bond or a hydrocarbon group with a valence of m+1 (preferably having 20 or less carbon atoms). A single bond is preferred. L₀ is a single bond when m is 1. The hydrocarbon group with a valence of m+1 represented by L₀ is, for example, one resulting from the removal of any m−1 hydrogen atoms from an alkylene group, a cycloalkylene group, a phenylene group or a combination thereof.

L, or each of L's independently, represents a carbonyl group, a carbonyloxy group or an ether group.

Tc represents a hydrogen atom, an alkyl group, a cycloalkyl group, a nitrile group, a hydroxyl group, an amido group, an aryl group or an electron withdrawing group (having the same meaning as that of the electron withdrawing group represented by Y¹ or Y² of general formula (KB-1)).

In the formula, * represents a bonding hand to the principal chain or a side chain of the resin. Specifically, the partial structure of formula (bb) may be directly bonded to the principal chain, or may be bonded to a side chain of the resin.

In the formula, m is an integer of 1 to 28, preferably an integer of 1 to 3, more preferably 1;

k is an integer of 0 to 2, preferably 1;

q is an integer of 0 to 5, preferably 1 or 2; and

r is an integer of 0 to 5.

The moiety -(L)ᵣ-Tc may be replaced with -L₀-(Ta)ₘ.

Among the lactone structures of general formula (bb), those in which a fluorine atom or a group containing a fluorine atom is introduced as a substituent in the location remotest from the above * (location at which the number of intervening atoms is the greatest) and those in which a fluorine atom is introduced in the side chain within the same repeating unit other than the side chain on the sugar lactone side (repeating unit (b″)) are also preferred.

As further particular structures of the repeating units (bb), the repeating units with the following partial structures are preferred.

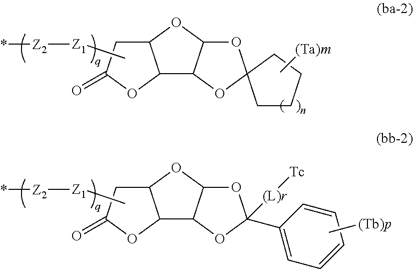

In general formulae (ba-2) and (bb-2),

n is an integer of 0 to 11, and

p is an integer of 0 to 5.

Tb, or each of Tb's independently, represents an alkyl group, a cycloalkyl group, an alkoxy group, a nitrile group, a hydroxyl group, an amido group, an aryl group or an electron withdrawing group (having the same meaning as that of the electron withdrawing group represented by Y¹ or Y² of general formula (KB-1)). When there are a plurality of Tb's, they may be bonded to each other to thereby form a ring.

Z₁, Z₂, Ta, Tc, L, *, m, q and r are as defined above in connection with general formula (bb). Preferred examples thereof are also the same.

The repeating unit (b) can be a repeating unit with the partial structure of general formula (KY-4) below.

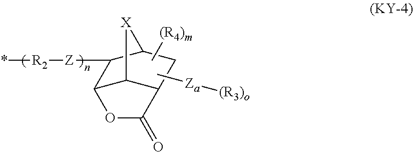

In general formula (KY-4),

R₂ represents a chain or cyclic alkylene group, provided that when there are a plurality of R₂s, they may be identical to or different from each other.

R₃ represents a linear, branched or cyclic hydrocarbon group whose hydrogen atoms on constituent carbons are partially or entirely substituted with fluorine atoms.

R₄ represents a halogen atom, a cyano group, a hydroxyl group, an amido group, an alkyl group, a cycloalkyl group, an alkoxy group, a phenyl group, an acyl group, an alkoxycarbonyl group or any of the groups of the formula R—C(═O)— or R—C(═O)O— in which R is an alkyl group or a cycloalkyl group. When there are a plurality of R₄s, they may be identical to or different from each other. Two or more R₄s may be bonded to each other to thereby form a ring.

X represents an alkylene group, an oxygen atom or a sulfur atom.

Each of Z and Za represents a single bond, an ether bond, an ester bond, an amido bond, a urethane bond or a urea bond. When there are a plurality thereof, they may be identical to or different from each other.

In the formula, * represents a bonding hand to the principal chain or a side chain of the resin;

o is the number of substituents, being an integer of 1 to 7;

m is the number of substituents, being an integer of 0 to 7; and

n is the number of repetitions, being an integer of 0 to 5.

The structure —R₂—Z— is preferably the structure of formula —(CH2)l-COO— in which l is an integer of 1 to 5.

The repeating unit (b) is preferably a repeating unit with the partial structure of general formula (KY-5) below.

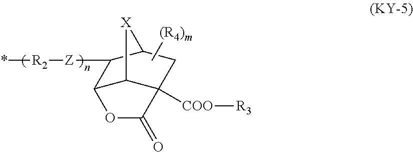

In general formula (KY-5),

R₂ represents a chain or cyclic alkylene group, provided that when there are a plurality of R₂s, they may be identical to or different from each other.

R₃ represents a linear, branched or cyclic hydrocarbon group whose hydrogen atoms on constituent carbons are partially or entirely substituted with fluorine atoms.

R₄ represents a halogen atom, a cyano group, a hydroxyl group, an amido group, an alkyl group, a cycloalkyl group, an alkoxy group, a phenyl group, an acyl group, an alkoxycarbonyl group or any of the groups of the formula R—C(═O)— or R—C(═O)O— in which R is an alkyl group or a cycloalkyl group. When there are a plurality of R₄s, they may be identical to or different from each other. Two or more R₄s may be bonded to each other to thereby form a ring.

X represents an alkylene group, an oxygen atom or a sulfur atom.

Z represents a single bond, an ether bond, an ester bond, an amido bond, a urethane bond or a urea bond. When there are a plurality thereof, they may be identical to or different from each other.

In the formula, * represents a bonding hand to the principal chain or a side chain of the resin;

n is the number of repetitions, being an integer of 0 to 5; and

m is the number of substituents, being an integer of 0 to 7.

The structure —R₂—Z— is preferably the structure of formula —(CH2)l-COO— in which l is an integer of 1 to 5.

Moreover, as particular structures of the repeating units (b), there can be mentioned the repeating units with the following partial structures.

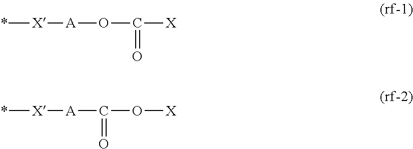

In general formulae (rf-1) and (rf-2),

X′ represents an electron withdrawing substituent, preferably a carbonyloxy group, an oxycarbonyl group, an alkylene group substituted with a fluorine atom or a cycloalkylene group substituted with a fluorine atom.

A represents a single bond or a bivalent connecting group, preferably a single bond, an alkylene group optionally substituted with a fluorine atom or a cycloalkylene group optionally substituted with a fluorine atom.

X represents an electron withdrawing group, preferably a fluoroalkyl group, a fluorocycloalkyl group, an aryl group substituted with fluorine or a fluoroalkyl group, or an aralkyl group substituted with fluorine or a fluoroalkyl group.

* represents a bonding hand to the principal chain or a side chain of the resin, namely, a bonding hand bonded to the principal chain of the resin through a single bond or a connecting group.

When X′ is a carbonyloxy group or an oxycarbonyl group, A is not a single bond.

As the partial structure having a fluorine atom within the repeating unit (b), there can be mentioned those set forth above, preferably any of the groups of general formulae (F2) to (F4) above.

As the partial structure having a silicon atom within the repeating unit (b), there can be mentioned those set forth above, preferably any of the groups of general formulae (CS-1) to (CS-3) above.

The content of repeating unit (b) in the resin (B), based on all the repeating units of the resin (B), is preferably in the range of 10 to 99 mol %, more preferably 20 to 97 mol %, further more preferably 30 to 95 mol % and most preferably 40 to 95 mol %.

Particular examples of the repeating units containing polarity conversion groups are shown below, which are nonlimiting.

In the formulae, Ra represents a hydrogen atom, a fluorine atom, a methyl group or a trifluoromethyl group.

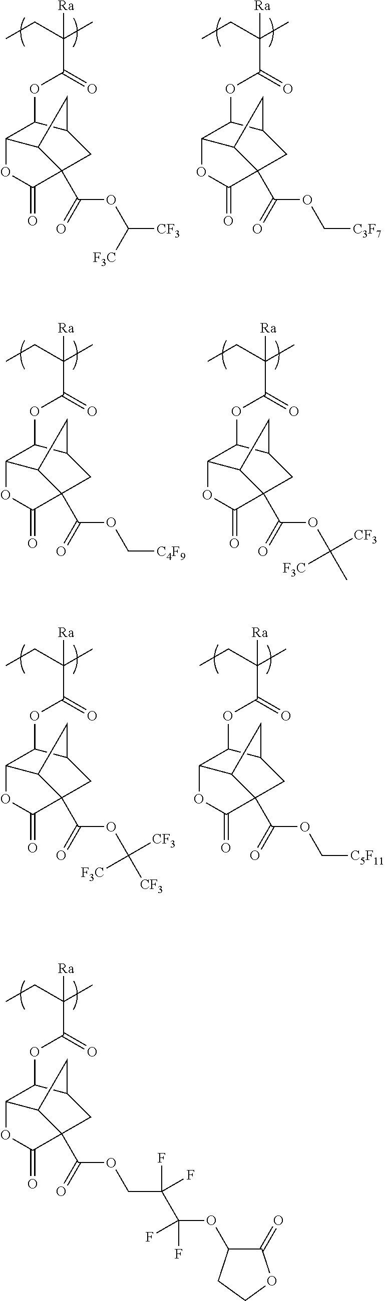

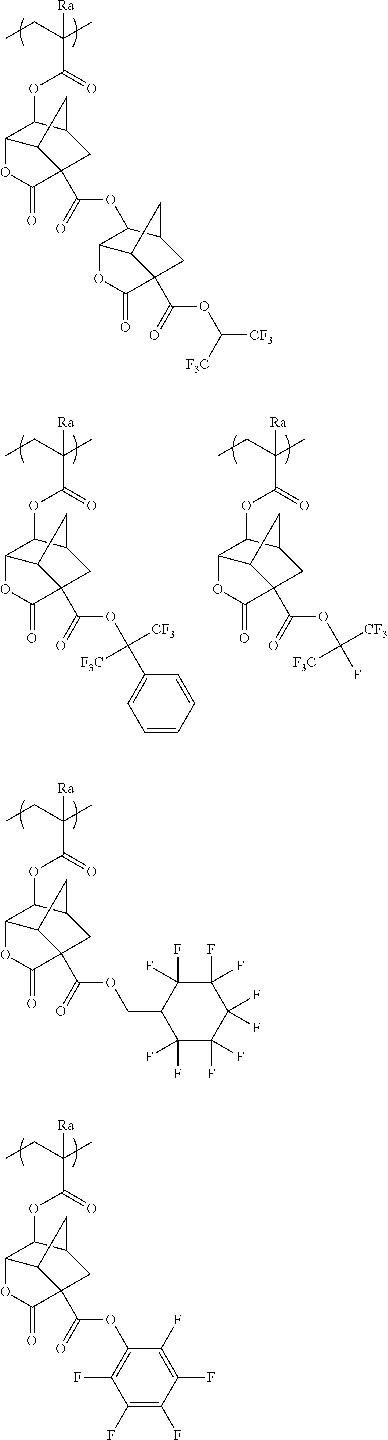

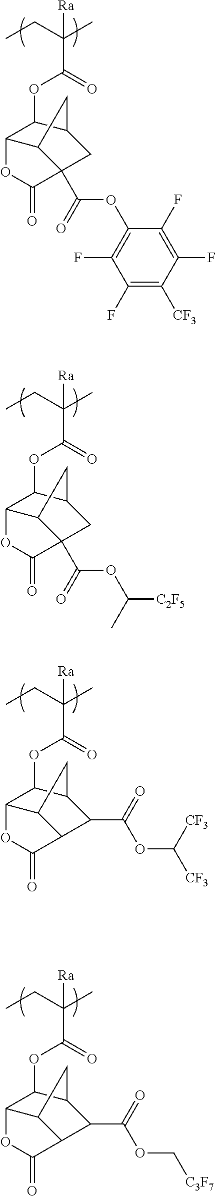

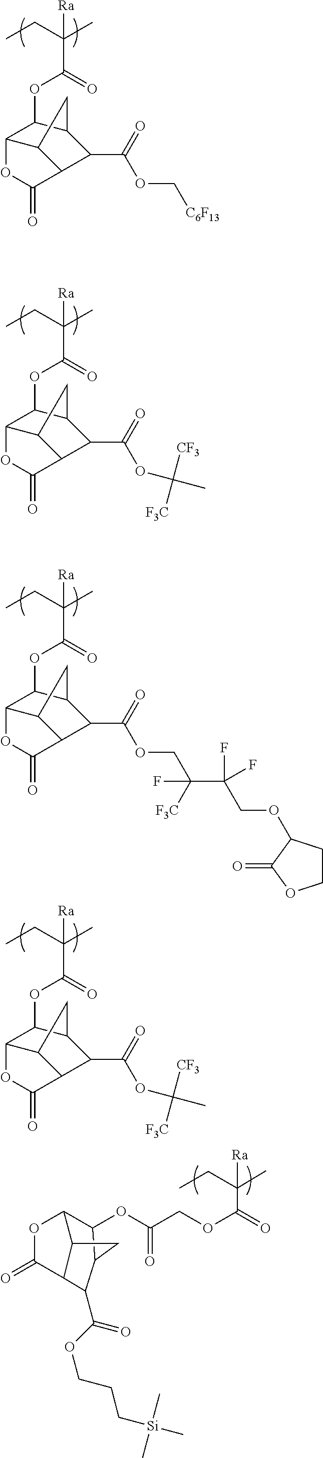

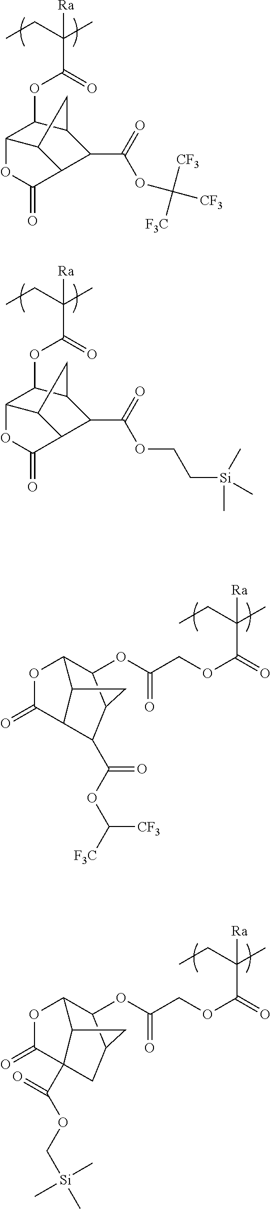

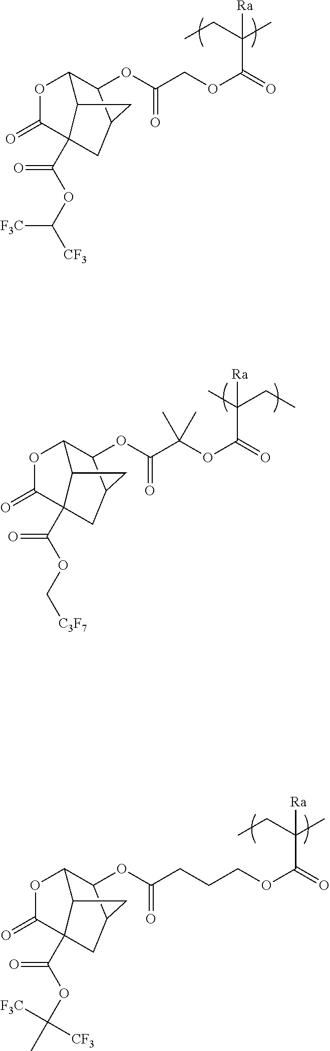

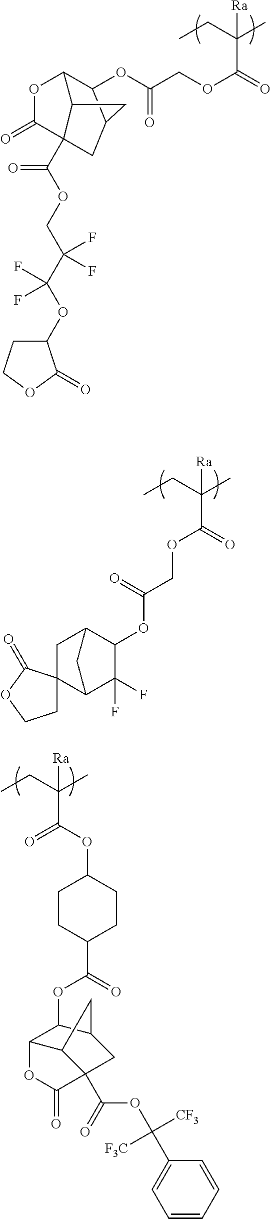

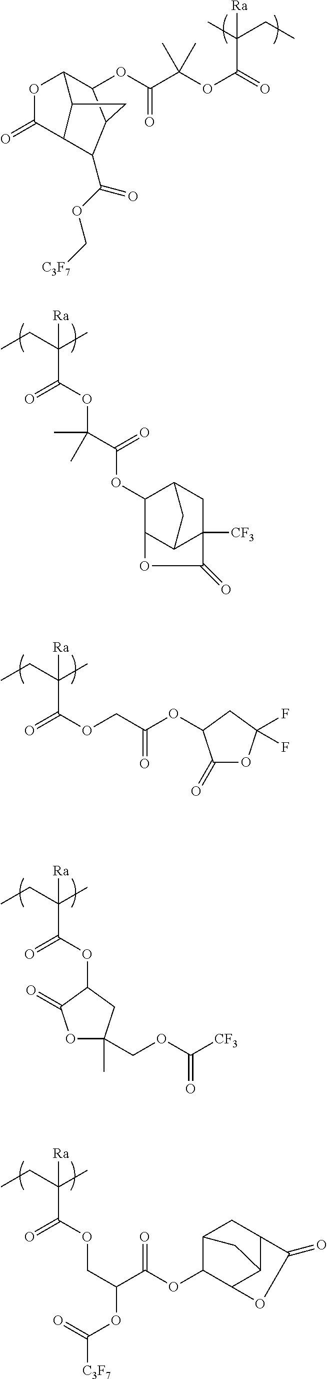

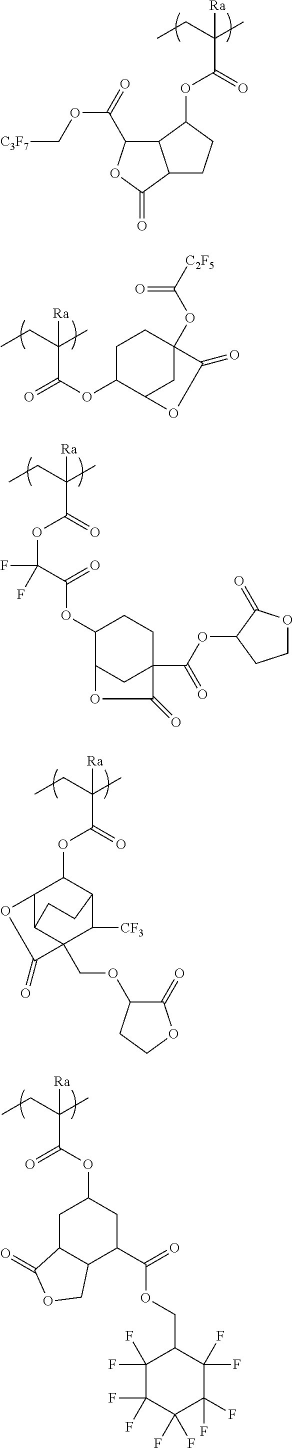

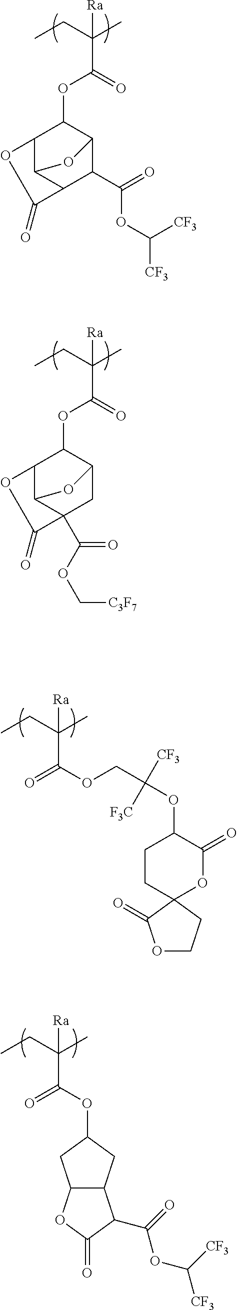

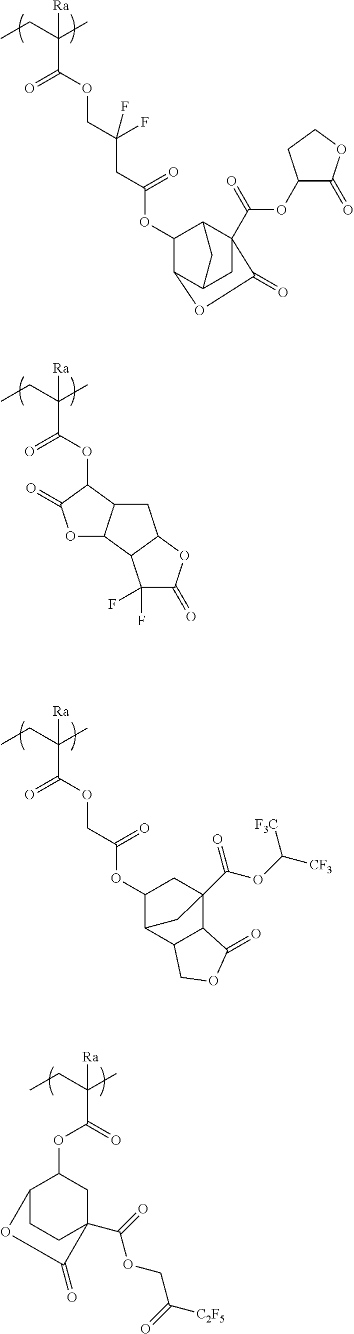

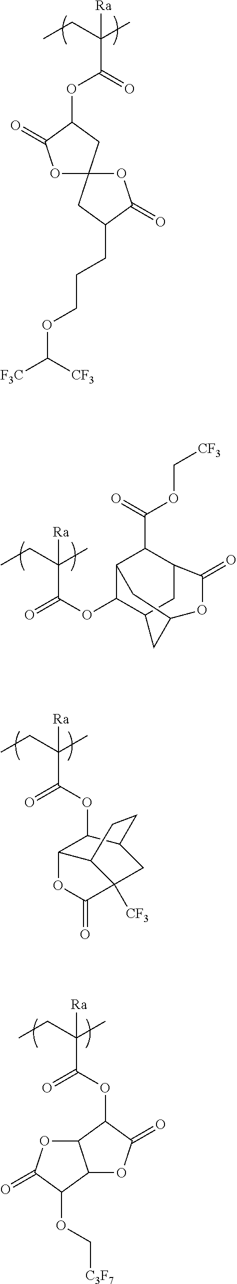

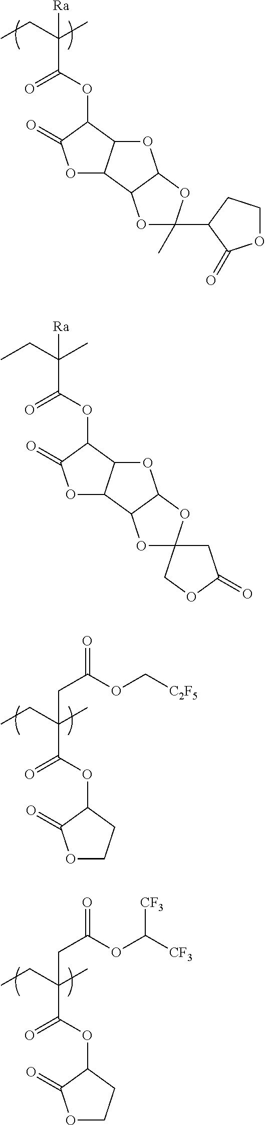

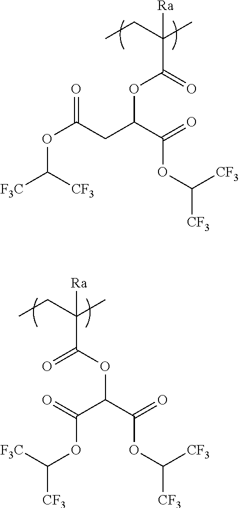

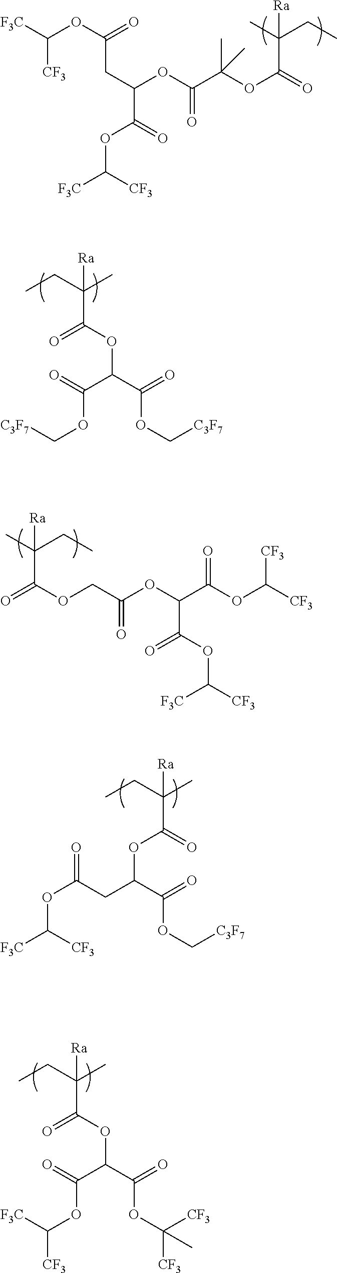

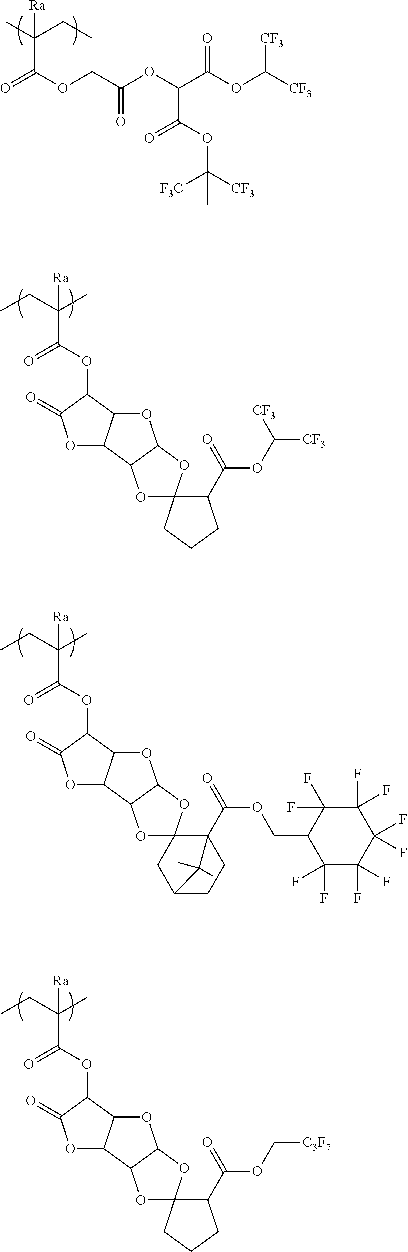

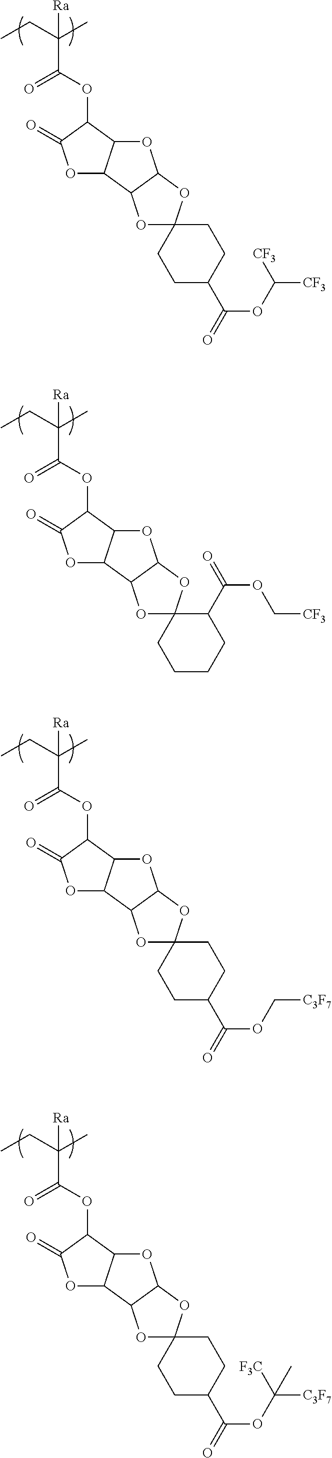

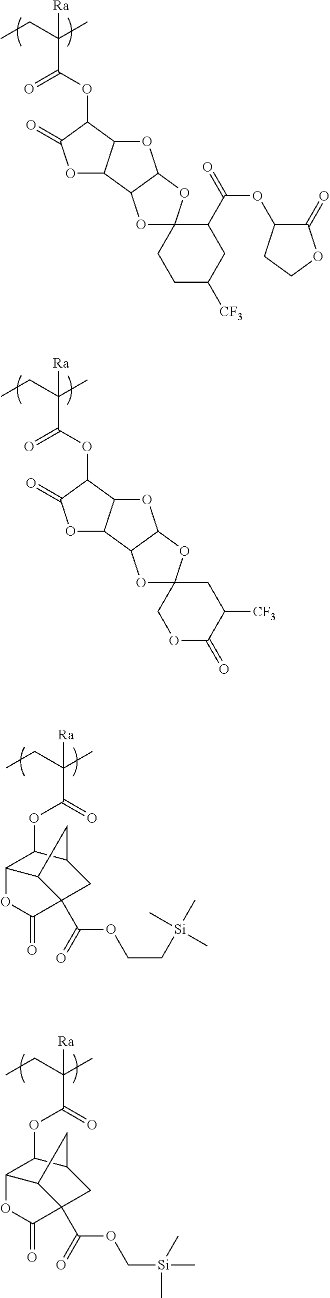

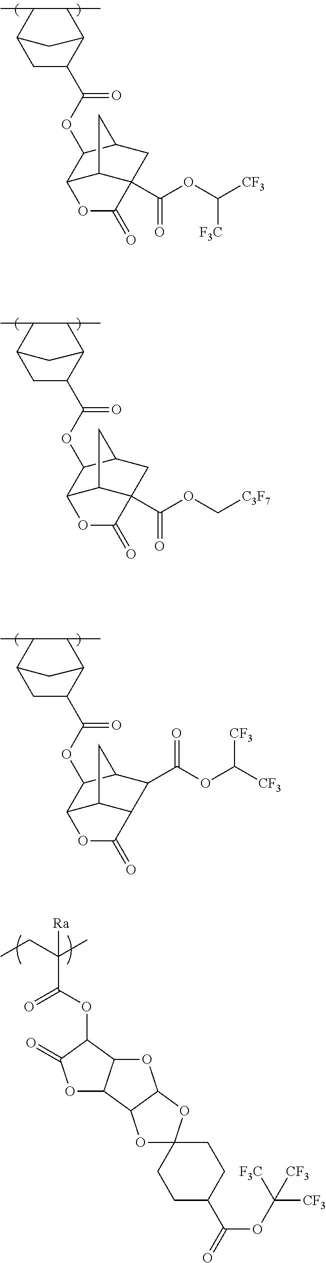

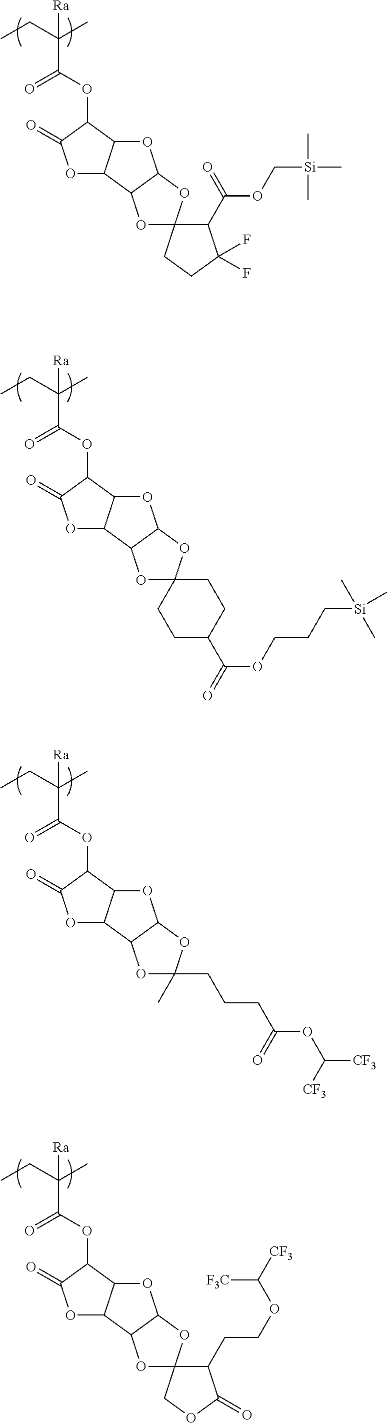

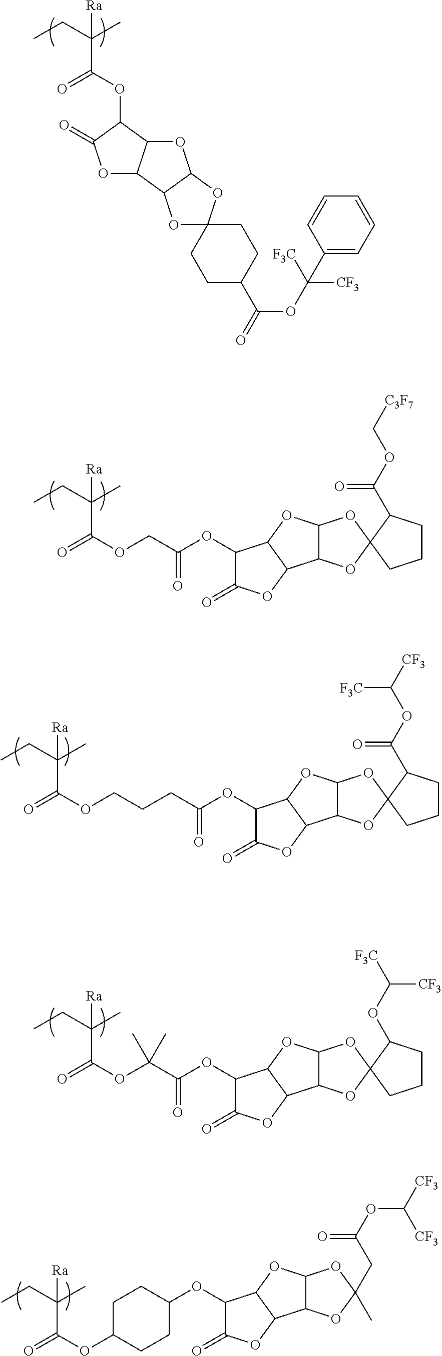

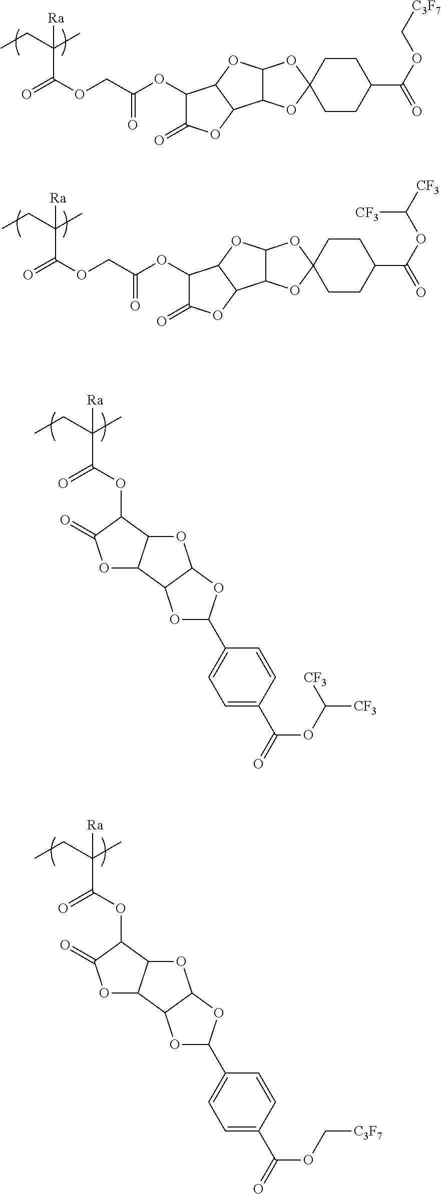

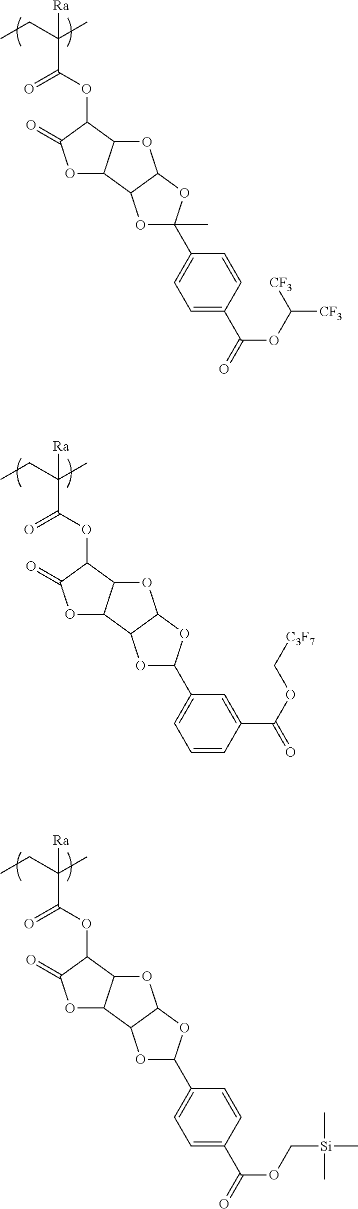

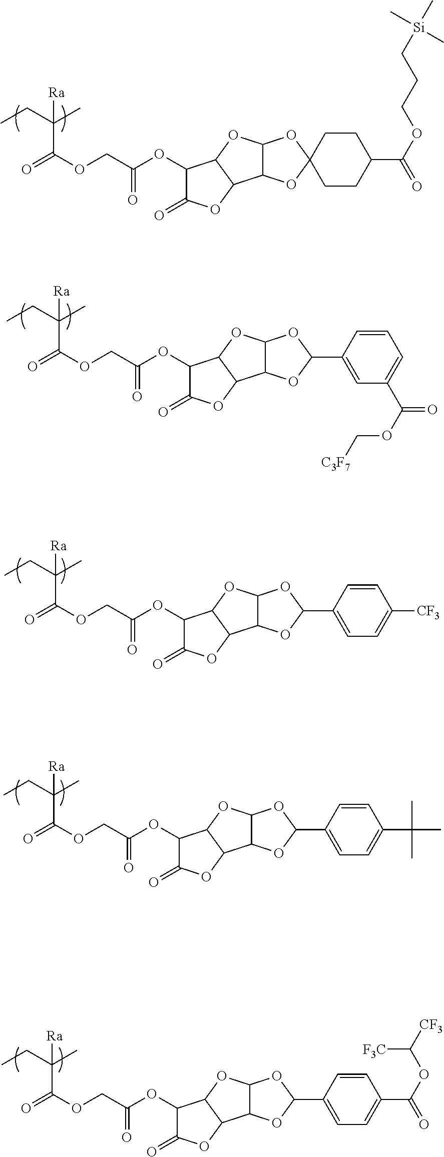

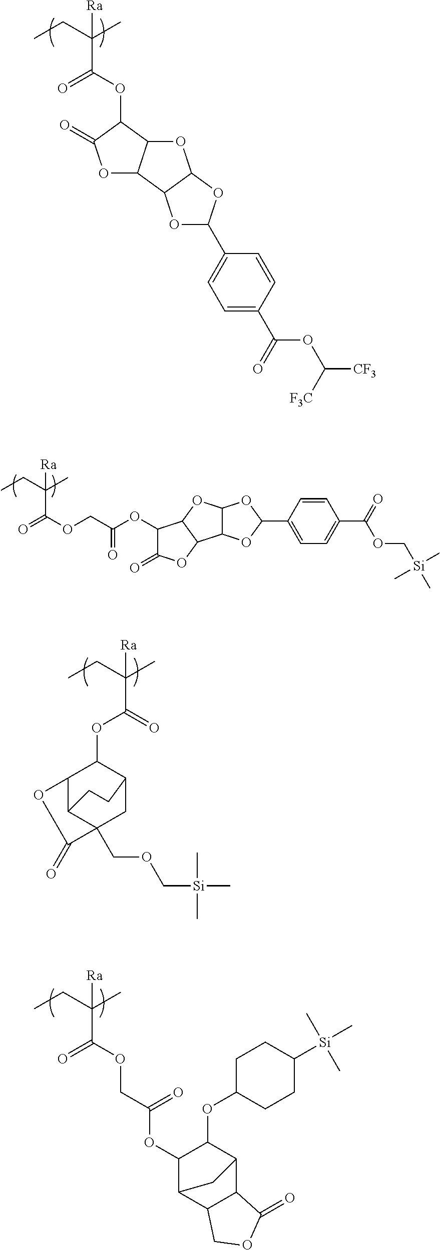

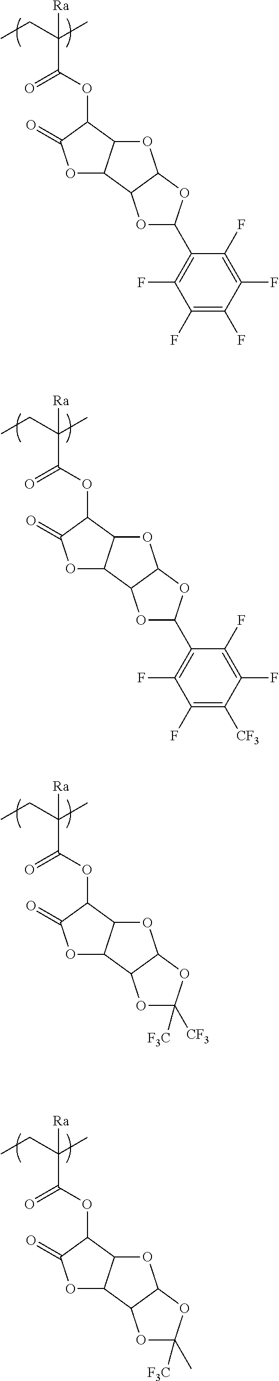

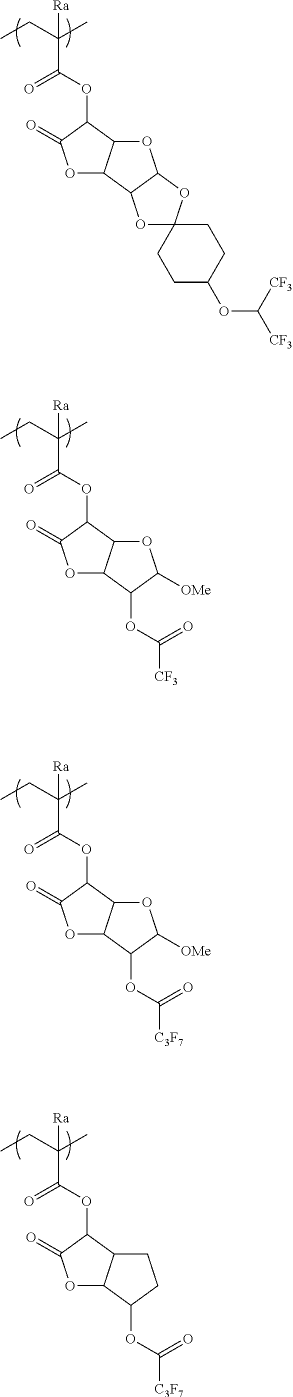

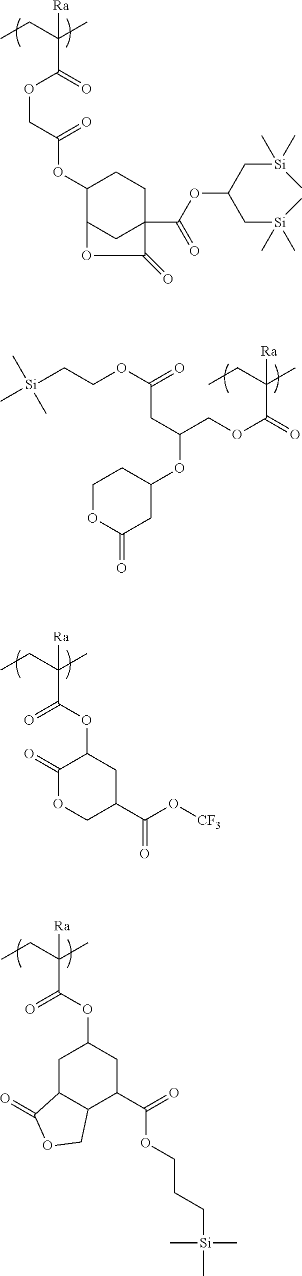

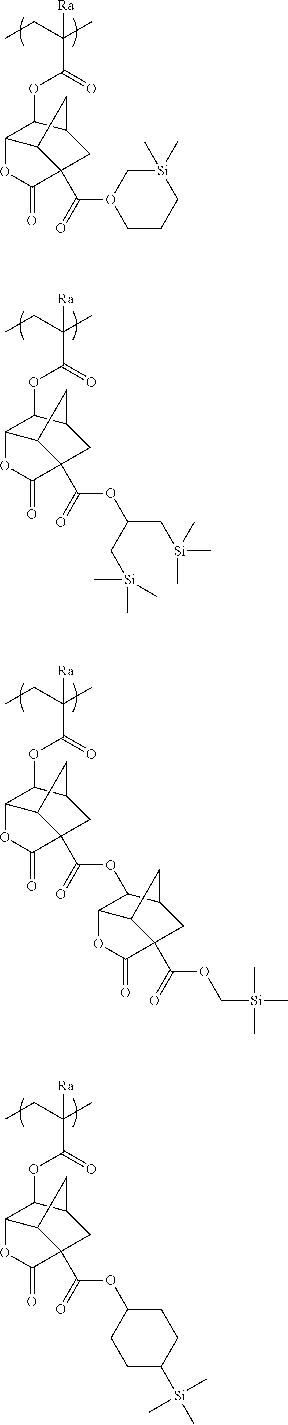

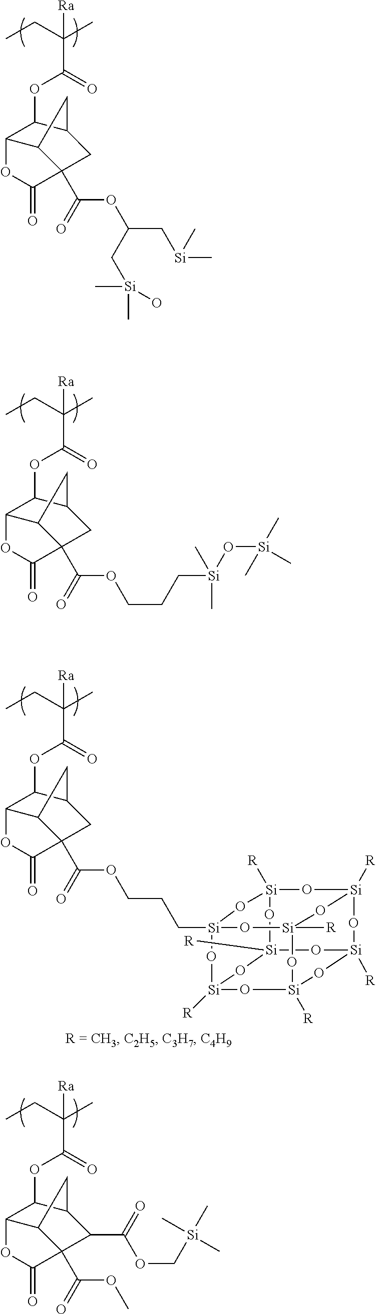

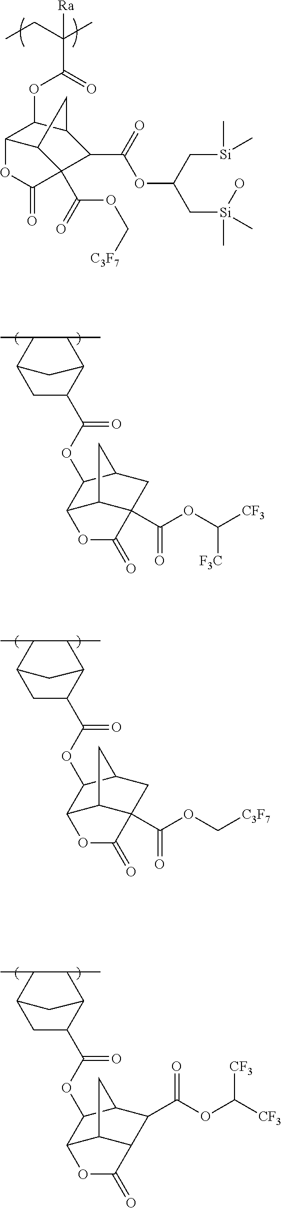

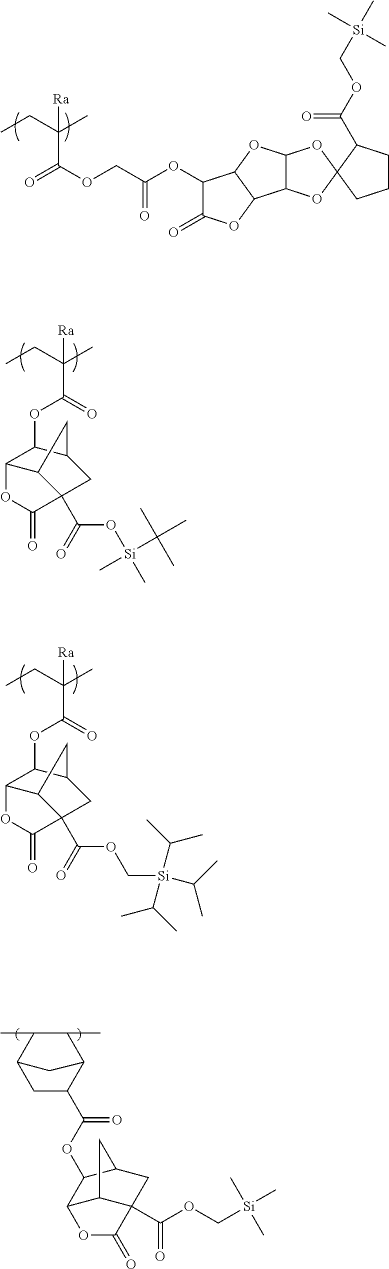

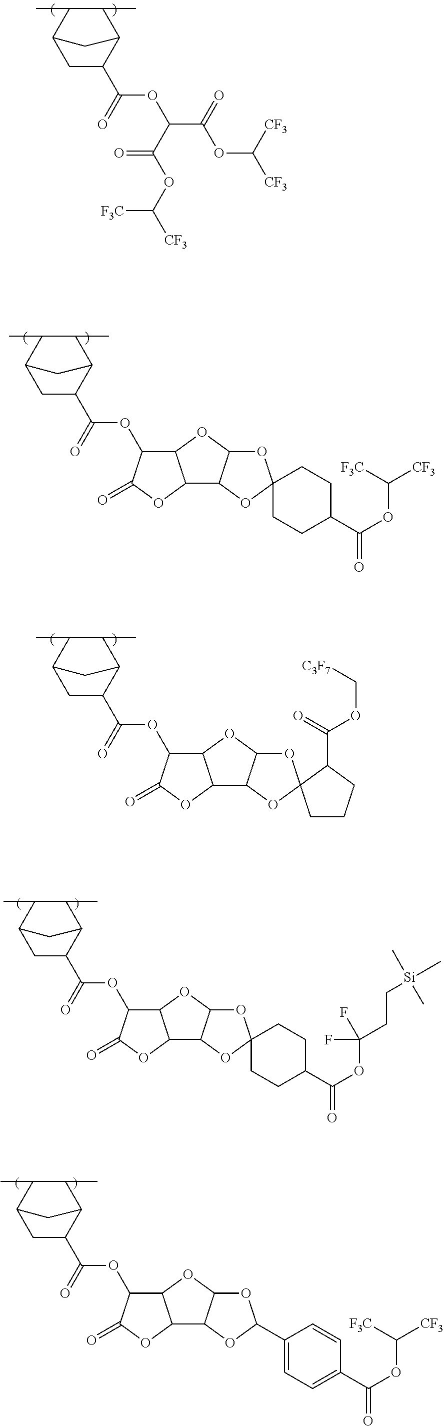

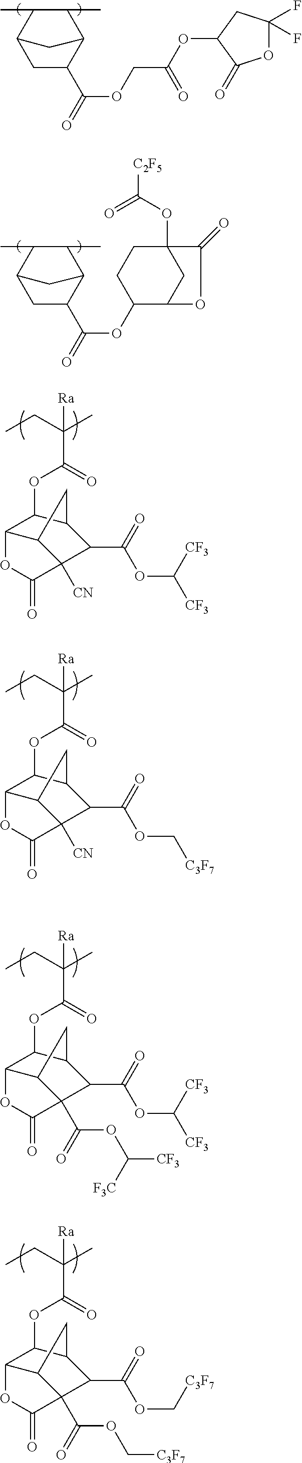

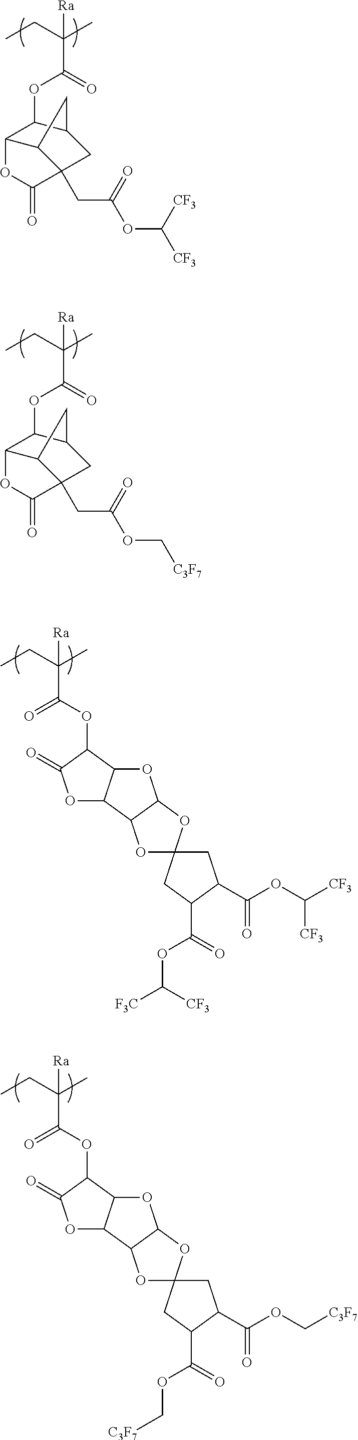

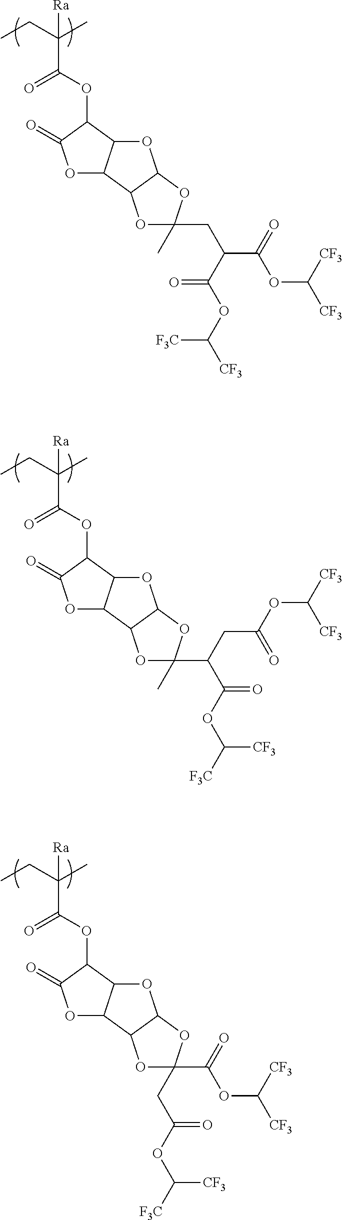

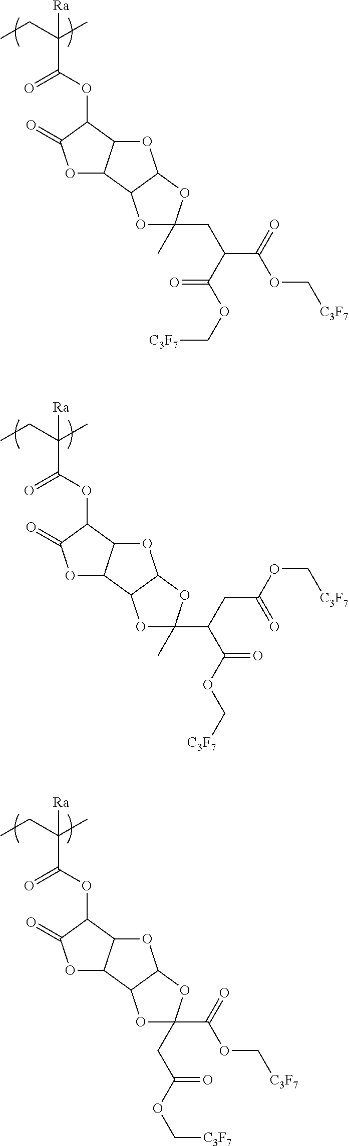

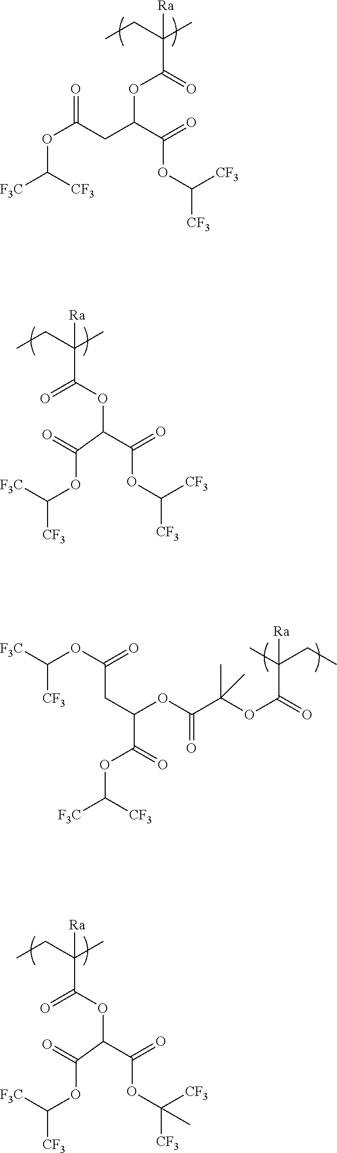

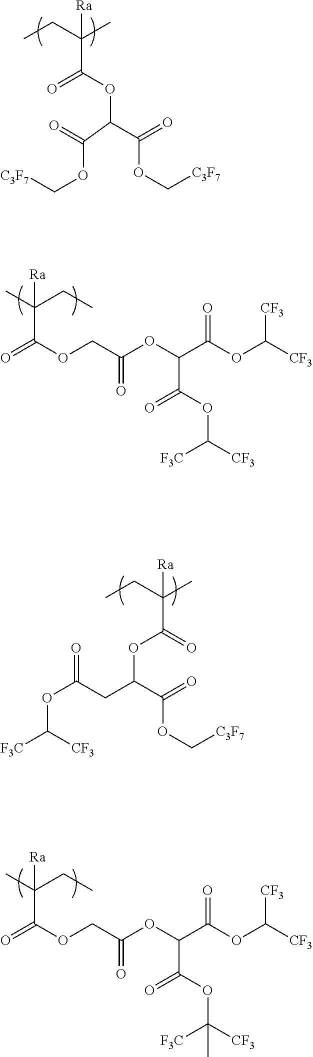

The repeating unit containing a group that is decomposed by the action of an acid (z) contained in the resin (B) can be the same as the repeating unit containing an acid-decomposable group mentioned with respect to the resin (A) to be described hereinafter.

The content of repeating unit containing a group that is decomposed by the action of an acid (z) in the resin (B), based on all the repeating units of the resin (B), is preferably in the range of 1 to 80 mol %, more preferably 10 to 80 mol % and further more preferably 20 to 60 mol %.

It is preferred for the content of any one of the repeating unit containing an alkali-soluble group (x), repeating unit containing a polarity conversion group (y) and repeating unit containing a group that is decomposed by the action of an acid (z) in the resin (B) to be not less than 45 mol % based on all the repeating units of the resin (B). Enhanced developability can be realized by causing the content of any one thereof to be not less than 45 mol %. The content is more preferably in the range of 50 to 99 mol %, further more preferably 60 to 90 mol %. The repeating unit contained in an amount of 45 mol % or more is preferably the repeating unit containing a polarity conversion group (y).

The resin (B) may further contain any of the repeating units of general formulae (IIIa) and (IIIb) below.

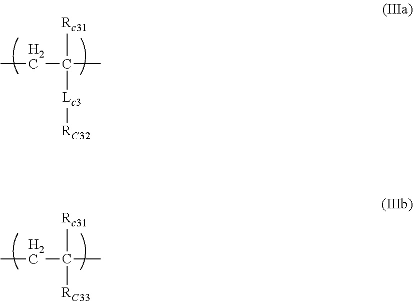

In general formulae (IIIa) and (IIIb),

R_{c31} represents a hydrogen atom, an alkyl group, an optionally fluorinated alkyl group, a cyano group or any of the groups of the formula —CH₂—O-Rac₂ in which Rac₂ represents a hydrogen atom, an alkyl group or an acyl group. R_{c31} is preferably a hydrogen atom, a methyl group, a hydroxymethyl group or a trifluoromethyl group, most preferably a hydrogen atom or a methyl group.

R_{c32} represents a group comprising an alkyl group, a cycloalkyl group, an alkenyl group or a cycloalkenyl group. This group may be substituted with a fluorine atom or a silicon atom.

L_{c3} represents a single bond or a bivalent connecting group.

R_{c33} represents an aryl group.

In general formula (IIIa), the alkyl group represented by R_{c32} is preferably a linear or branched alkyl group having 3 to 20 carbon atoms.

The cycloalkyl group is preferably a cycloalkyl group having 3 to 20 carbon atoms.

The alkenyl group is preferably an alkenyl group having 3 to 20 carbon atoms.

The cycloalkenyl group is preferably a cycloalkenyl group having 3 to 20 carbon atoms.

Preferably, R_{c32} represents an unsubstituted alkyl group or an alkyl group substituted with a fluorine atom.

The bivalent connecting group represented by L_{c3} is preferably an alkylene group (preferably having 1 to 5 carbon atoms), an oxy group, a phenylene group or an ester bond (group of the formula —OCO—).

In general formula (IIIb), the aryl group represented by R_{c33} is preferably a phenyl group or naphthyl group having 6 to 20 carbon atoms. A substituent may be introduced in these groups.

The resin (B) may further contain any of the repeating units represented by general formula (CII-AB) below.

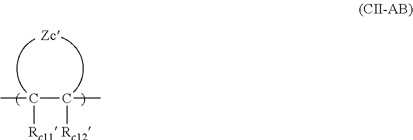

In formula (CII-AB),

each of R_{c11}′ and R_{c12}′ independently represents a hydrogen atom, a cyano group, a halogen atom or an alkyl group.

Zc′ represents an atomic group required for forming an alicyclic structure in cooperation with two carbon atoms (C—C) to which R_{c11′} and R_{c12}′ are respectively bonded.

Specific examples of the repeating units represented by the general formulae (IIIa), (IIIb) or (CII-AB) will be shown below, which however in no way limit the scope of the present invention. In the formulae, Ra represents H, CH₃, CH₂OH, CF₃ or CN.

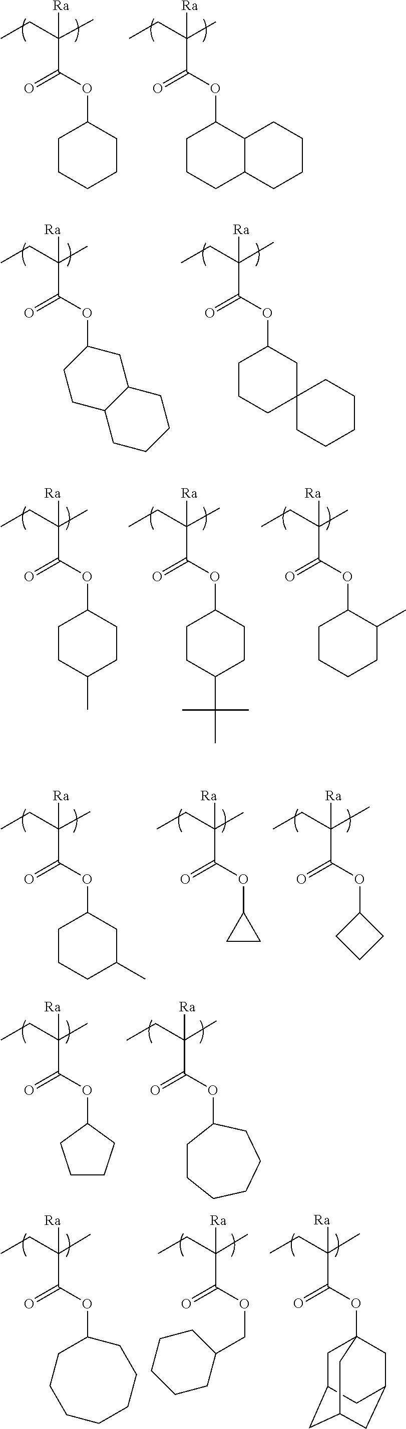

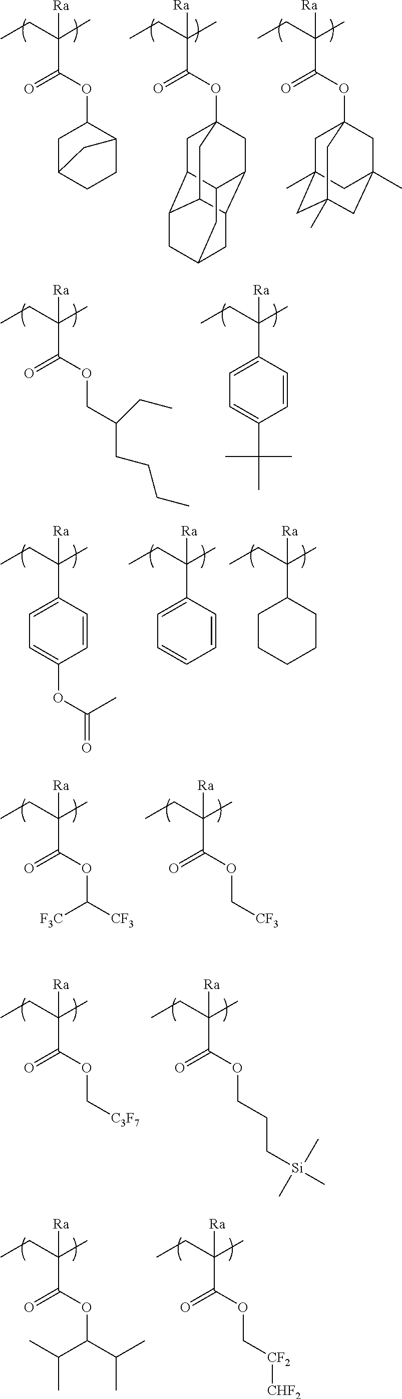

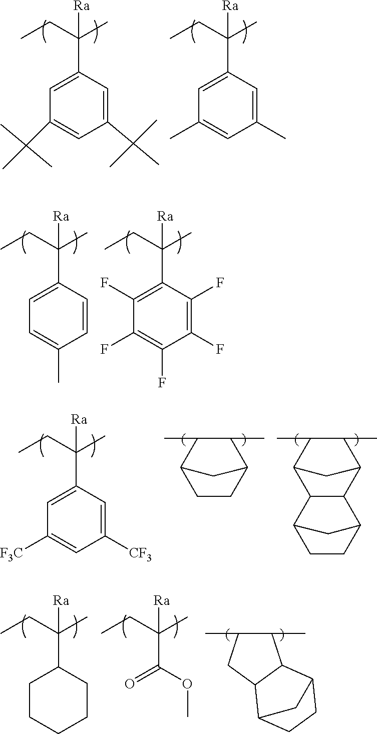

Impurities such as metals in the resin (B) should naturally be of low quantity as in the resin (A) to be described hereinafter. The content of residual monomers and oligomer components is preferably in the range of 0 to 10 mass %, more preferably 0 to 5 mass %, and still more preferably 0 to 1 mass %. Accordingly, there can be obtained a composition being free from in-liquid foreign matters and a change in sensitivity, etc. over time. From the viewpoint of resolving power, resist profile, side wall of resist pattern, roughness, etc., the molecular weight distribution (Mw/Mn, also referred to as the degree of dispersal) thereof is preferably in the range of 1 to 3, more preferably 1 to 2, still more preferably 1 to 1.8, and most preferably 1 to 1.5.

A variety of commercially available products can be used as the resin (B), and also the resin can be synthesized in accordance with conventional methods (for example, by radical polymerization). As general synthesizing methods, a batch polymerization method in which a monomer species and an initiator are dissolved in a solvent and heated to carry out polymerization and a dropping polymerization method in which a solution of monomer species and initiator is dropped into a hot solvent over a period of 1 to 10 hours can be exemplified. Of these, the dropping polymerization method is preferred. As a reaction solvent, ethers such as tetrahydrofuran, 1,4-dioxane or diisopropyl ether, ketones such as methyl ethyl ketone or methyl isobutyl ketone, ester solvents such as ethyl acetate, amide solvents such as dimethylformamide or dimethylacetamide, and the aforementioned solvent capable of dissolving the composition according to the present invention, such as propylene glycol monomethyl ether acetate (PGMEA), propylene glycol monomethyl ether (PGME) or cyclohexanone can be exemplified. Preferably, the polymerization is carried out with the use of the same solvent as that used in the composition according to the present invention. This would inhibit particle generation during storage.

The polymerization reaction is preferably carried out in an atmosphere consisting of an inert gas such as nitrogen or argon. In the initiation of polymerization, a commercially available radical initiator (azo initiator, peroxide, etc.) is used as the polymerization initiator. Among the radical initiators, an azo initiator is preferred, and azo initiators having an ester group, a cyano group and a carboxy group are more preferred. As specific preferred initiators, azobisisobutyronitrile, azobisdimethylvaleronitrile, and dimethyl 2,2′-azobis(2-methylpropionate) can be exemplified. The reaction concentration is in the range of 5 to 50 mass %, preferably 30 to 50 mass %. The reaction temperature is generally in the range of 10° to 150° C., preferably 30° to 120° C., and more preferably 60° to 100° C.

After the completion of the reaction, the mixture is allowed to stand still to cool to room temperature and purified. In the purification, use is made of routine methods, such as a liquid-liquid extraction method in which residual monomers and oligomer components are removed by water washing or by the use of a combination of appropriate solvents, a method of purification in solution form such as ultrafiltration capable of extraction removal of only components of a given molecular weight or below, a re-precipitation method in which a resin solution is dropped into a poor solvent to coagulate the resin in the poor solvent and thus remove residual monomers, etc. and a method of purification in solid form such as washing of a resin slurry obtained by filtration with the use of a poor solvent. For example, the reaction solution is brought into contact with a solvent wherein the resin is poorly soluble or insoluble (poor solvent) amounting to 10 or less, preferably 10 to 5 times the volume of the reaction solution to precipitate the resin as a solid.

The solvent for use in the operation of precipitation or re-precipitation from a polymer solution (precipitation or re-precipitation solvent) is not limited as long as the solvent is a poor solvent for the polymer. According to the type of polymer, use can be made of any one appropriately selected from among a hydrocarbon, a halogenated hydrocarbon, a nitro compound, an ether, a ketone, an ester, a carbonate, an alcohol, a carboxylic acid, water, a mixed solvent containing these solvents, and the like. Of these, it is preferred to employ a solvent containing at least an alcohol (especially methanol or the like) or water as the precipitation or re-precipitation solvent.

The amount of precipitation or re-precipitation solvent used can be determined according to intended efficiency, yield, etc. and is generally in the range of 100 to 10,000 parts by mass, preferably 200 to 2,000 parts by mass, and more preferably 300 to 1,000 parts by mass per 100 parts by mass of the polymer solution.

The temperature at which the precipitation or re-precipitation is carried out can be determined according to efficiency and operation easiness, and is generally in the range of about 0° to 50° C., and preferably about room temperature (for example, about 20° to 35° C.). The operation of precipitation or re-precipitation can be carried out by a known method such as a batch or continuous method, with the use of a common mixing vessel such as an agitation vessel.

The polymer obtained by the precipitation or re-precipitation is generally subjected to common solid/liquid separation, such as filtration or centrifugal separation, and dried before use. The filtration is carried out with the use of a filter medium ensuring solvent resistance, preferably under pressure. The drying is performed at about 30° C. to 100° C., preferably about 30° C. to 50° C. at ordinary pressure or reduced pressure (preferably at reduced pressure).

Alternatively, after the resin precipitation and separation, the obtained resin may be once more dissolved in a solvent and brought into contact with a solvent wherein the resin is poorly soluble or insoluble. Specifically, the method may include the steps of, after the completion of the radical polymerization reaction, bringing the polymer into contact with a solvent wherein the polymer is poorly soluble or insoluble to thereby precipitate a resin (step a), separating the resin from the solution (step b), re-dissolving the resin in a solvent to thereby obtain a resin solution (A) (step c), thereafter bringing the resin solution (A) into contact with a solvent wherein the resin is poorly soluble or insoluble amounting to less than 10 times (preferably 5 times or less) the volume of the resin solution (A) to thereby precipitate a resin solid (step d), and separating the precipitated resin (step e).

Specific examples of the resin (B) will be shown below. In the specific examples, R₁ represents a hydrogen atom, a methyl group, a halogen atom or a trifluoromethyl group.

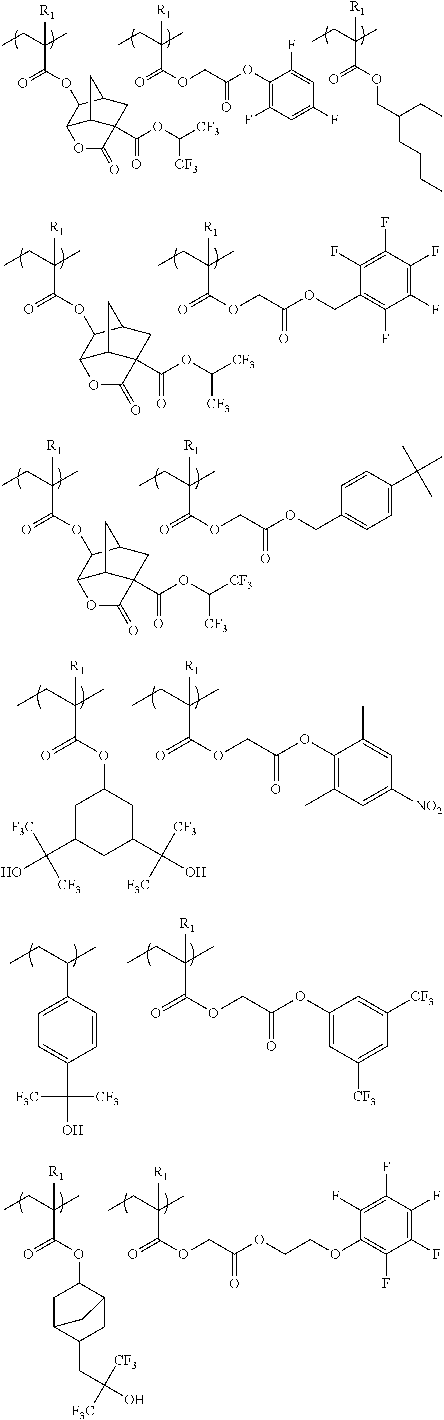

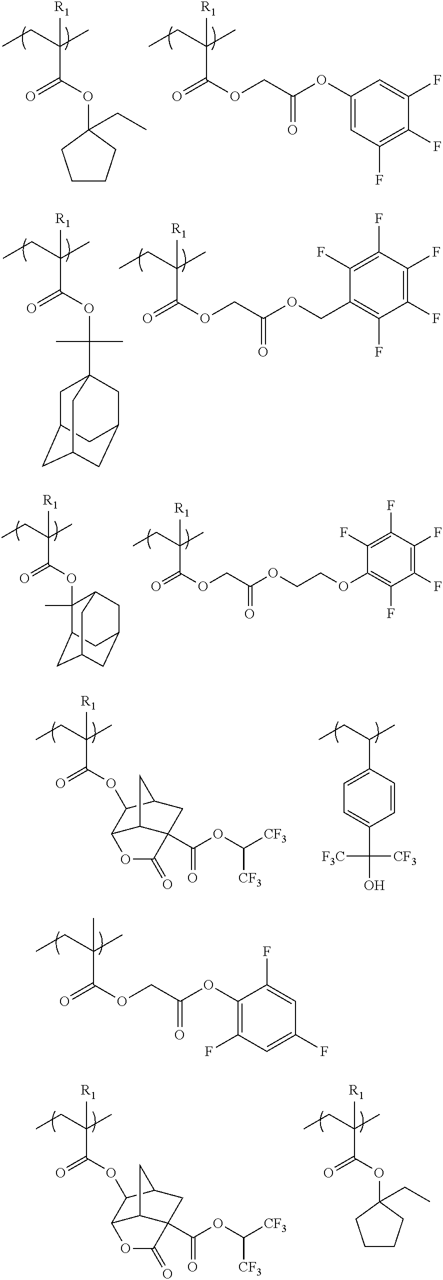

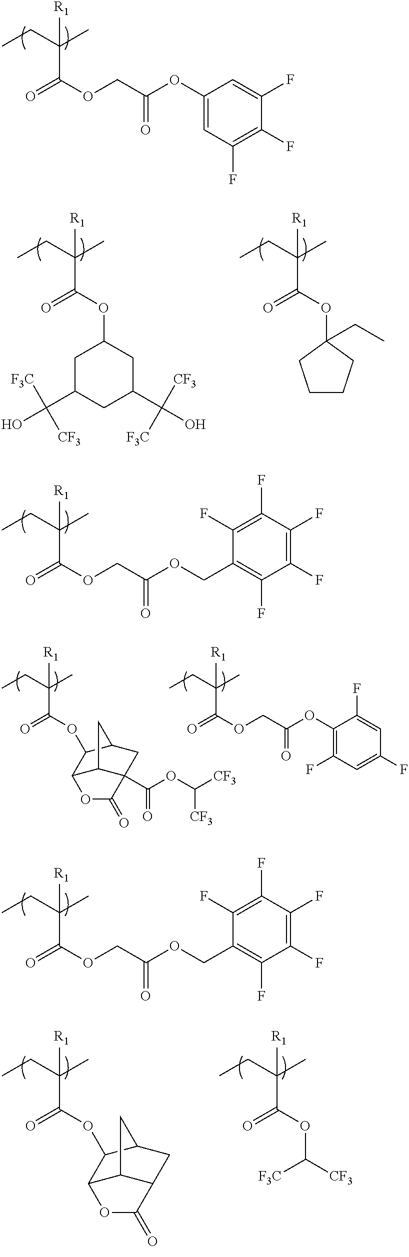

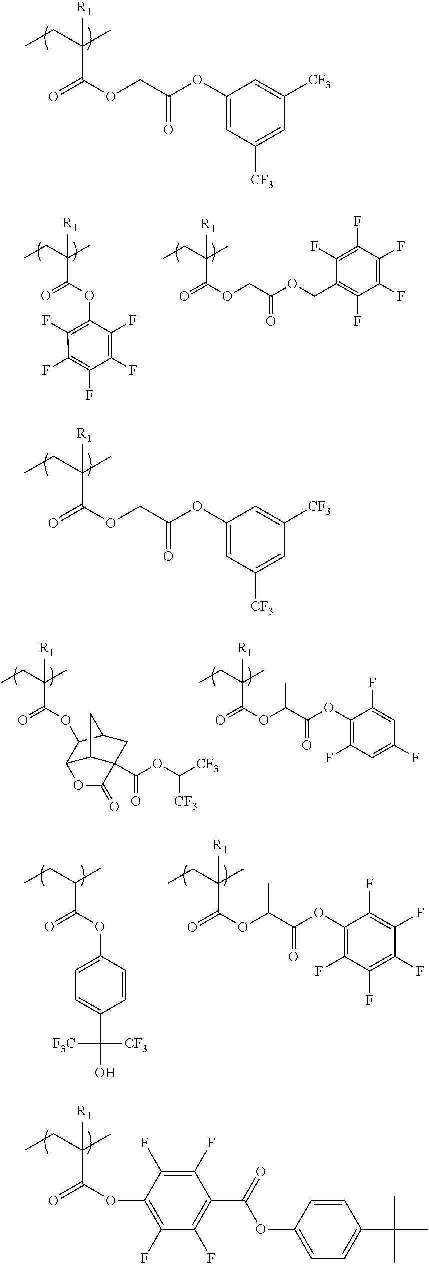

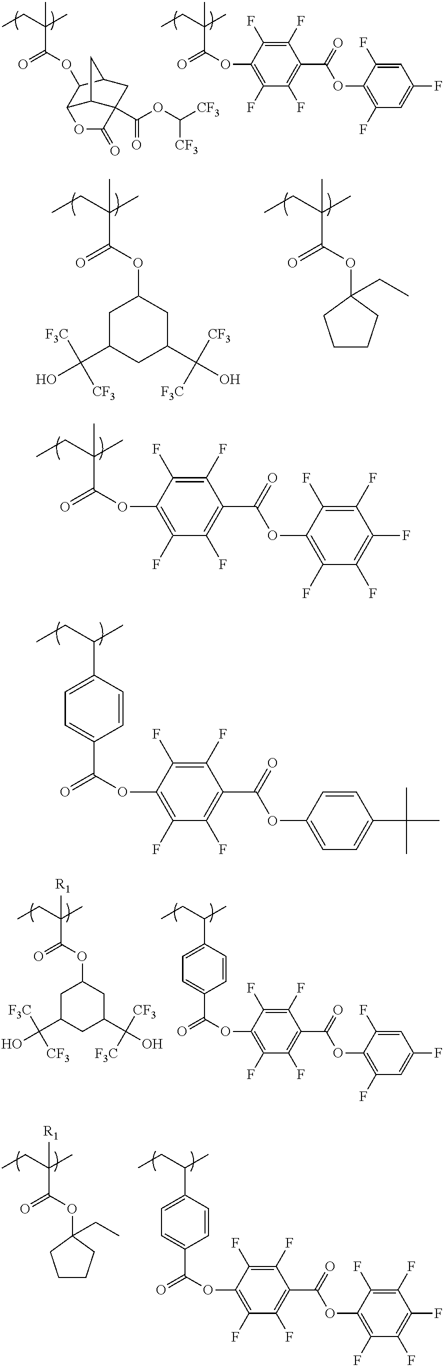

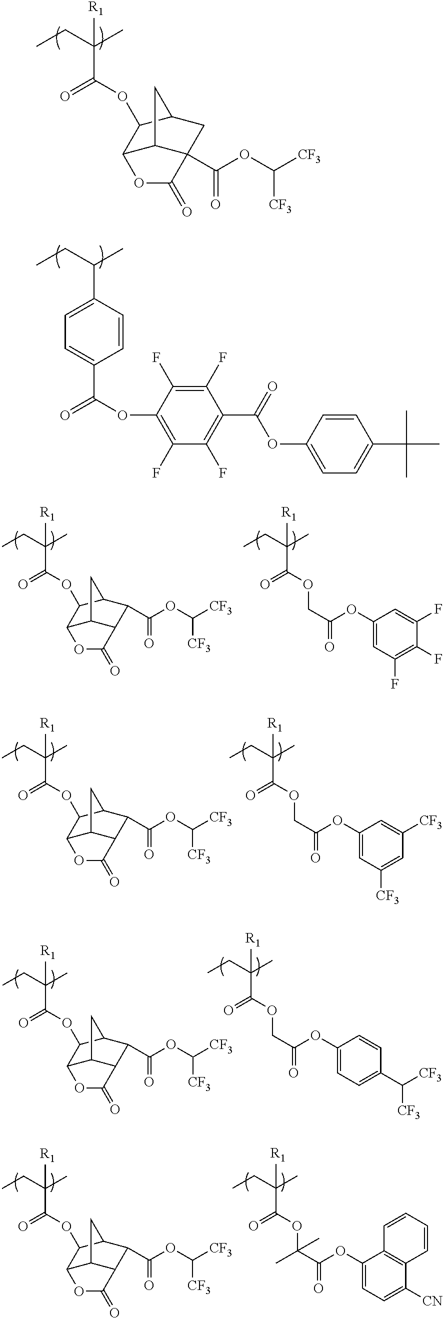

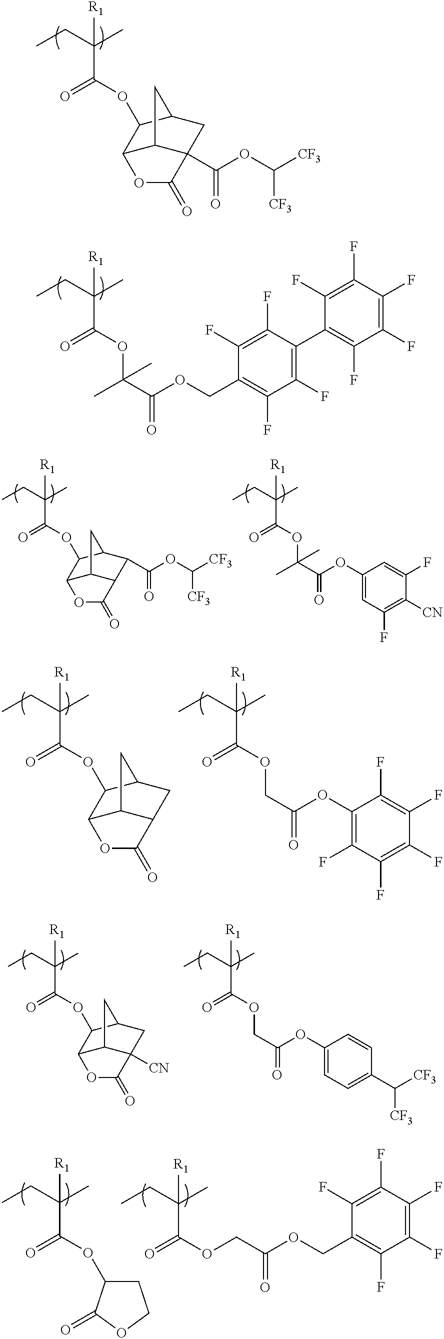

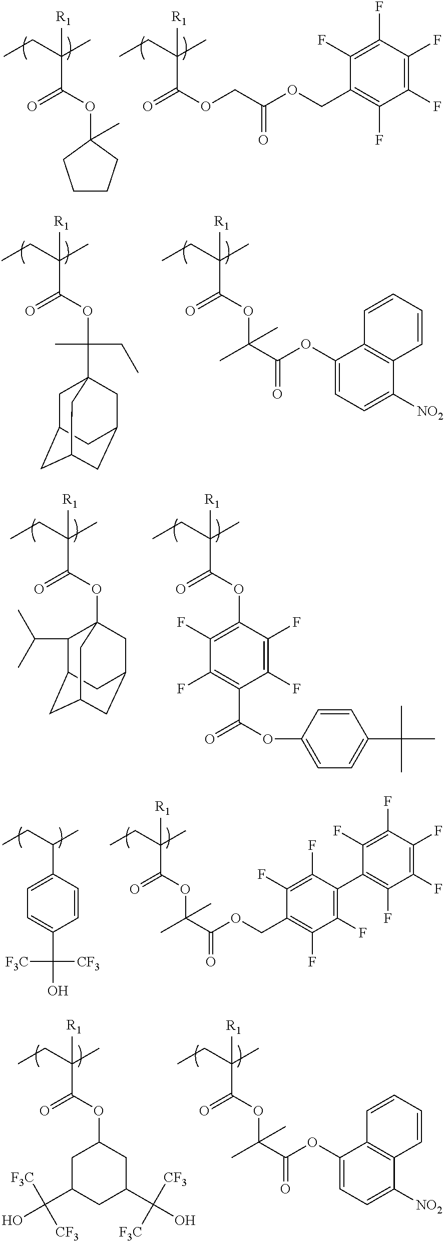

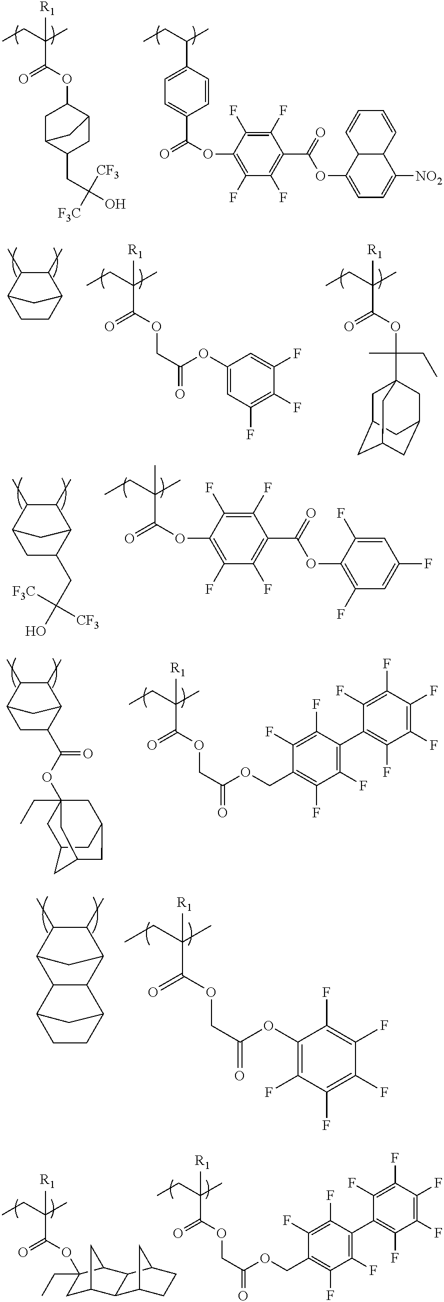

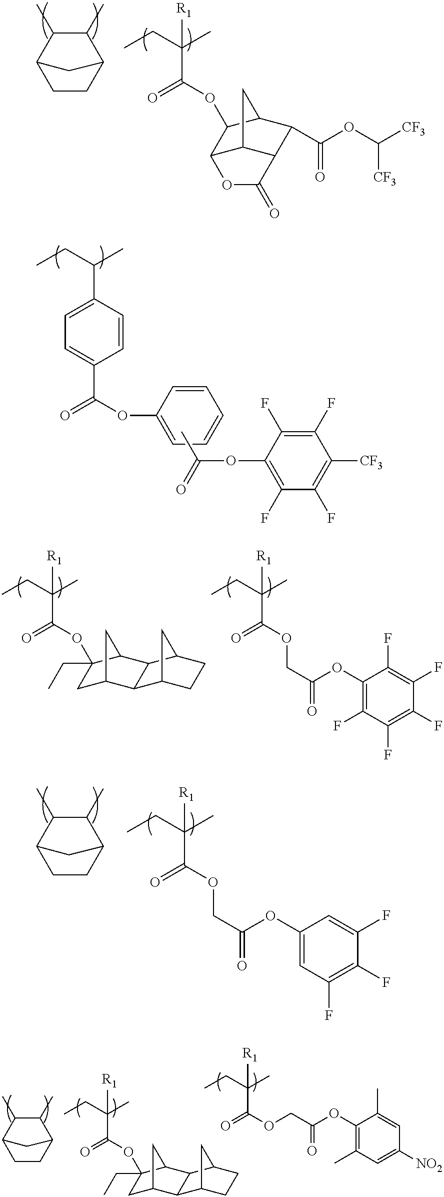

When the hydrophobic resin (B) containing at least either a fluorine atom or a silicon atom is contained, the resin (B) is unevenly distributed in a surface layer portion of the film formed from the actinic-ray- or radiation-sensitive resin composition. When the immersion medium is water, the receding contact angle of the film surface with respect to water is increased so that the immersion-water tracking properties can be enhanced.

The receding contact angle of the film of the composition of the present invention after the bake of the coating but prior to the exposure thereof is preferably in the range of 60° to 90°, more preferably 65° or greater, further more preferably 70° or greater and most preferably 75° or greater at the exposure temperature, generally room temperature 23±3° C. in a humidity of 45±5%.

Although the resin (B) is unevenly localized on any interface, as different from the surfactant, the resin does not necessarily have to have a hydrophilic group in its molecule and does not need to contribute toward uniform mixing of polar/nonpolar substances.

In the operation of liquid immersion exposure, it is needed for the liquid for liquid immersion to move on a wafer while tracking the movement of an exposure head involving high-speed scanning on the wafer and thus forming an exposure pattern. Therefore, the contact angle of the liquid for liquid immersion with respect to the resist film in dynamic condition is important, and it is required for the actinic ray-sensitive or radiation-sensitive resin composition to be capable of tracking the high-speed scanning of the exposure head without leaving droplets.

When the resin (B) contains fluorine atoms, the content of the fluorine atoms based on the molecular weight of the resin (B) is preferably in the range of 5 to 80 mass %, and more preferably 10 to 80 mass %. The repeating unit containing fluorine atoms preferably exists in the resin (B) in an amount of 10 to 100 mass %, more preferably 30 to 100 mass %.

When the resin (B) contains silicon atoms, the content of the silicon atoms based on the molecular weight of the resin (B) is preferably in the range of 2 to 50 mass %, more preferably 2 to 30 mass %. The repeating unit containing silicon atoms preferably exists in the resin (B) in an amount of 10 to 90 mass %, more preferably 20 to 80 mass %.

The total content of fluorine atom and silicon atom in the resin (B), based on the molecular weight of the resin (B), is preferably in the range of 5 to 80 mass %, more preferably 10 to 80 mass %. The repeating unit containing at least either a fluorine atom or a silicon atom is preferably contained in an amount of 10 to 100 mass %, more preferably 30 to 100 mass %, based on all the repeating units of the resin (B).

The standard-polystyrene-equivalent weight average molecular weight of the resin (B) is preferably in the range of 1000 to 100,000, more preferably 2000 to 50,000 and further more preferably 3000 to 30,000.

A single type of resin (B) may be used alone, or two or more types thereof may be used in combination. In the latter instance, use may be made of two or more types of resins (B) containing repeating units (R-1) and (R-2), or at least one type of resin (B) containing any of the repeating units (R-1) and (R-2) combined with at least one type of resin (B′) not containing any of the repeating units (R-1) and (R-2).

As the units constituting the resin (B′), there can be mentioned, for example, the above-mentioned repeating unit containing a fluorine atom or a silicon atom, units (x) to (z) and the like.

When the resin (B) containing any of the repeating units (R-1) and (R-2) is used in combination with the resin (B′) not containing any of the repeating units (R-1) and (R-2), the mass ratio of the former resin to the latter resin is, for example, 50/50 or higher, typically 70/30 or higher.

The content of resin (B) in the actinic-ray- or radiation-sensitive resin composition, based on the total solids of the actinic-ray- or radiation-sensitive resin composition, is preferably in the range of 0.01 to 20 mass %, more preferably 0.1 to 15 mass %, further more preferably 0.1 to 10 mass % and most preferably 0.5 to 8 mass %.

<Resin (A) that is Decomposed by the Action of an Acid to Thereby Increase its Solubility in an Alkali Developer>

The actinic-ray- or radiation-sensitive resin composition of the present invention may contain a resin (A) that is decomposed by the action of an acid to thereby increase its solubility in an alkali developer. The resin (A) is a resin that is different in the components from the above-described resin (B), and hereinafter is also referred to as an “acid-decomposable resin” or the like.

In the acid-decomposable resin (A), a group that is decomposed by the action of an acid to thereby produce an alkali-soluble group (hereinafter also referred to as “acid-decomposable group”) is introduced in the principal chain or side chain, or both the principal chain and the side chain, of the resin.

The resin (A) is preferably insoluble or hardly soluble in an alkali developer.

The acid-decomposable group preferably has a structure in which an alkali-soluble group is protected by a group removable by degradation upon the action of acid.

As the alkali-soluble group, there can be mentioned a phenolic hydroxyl group, a carboxyl group, a fluoroalcohol group, a sulfonate group, a sulfonamido group, a sulfonylimido group, an (alkylsulfonyl)(alkylcarbonyl)methylene group, an (alkylsulfonyl)(alkylcarbonyl)imido group, a bis(alkylcarbonyl)methylene group, a bis(alkylcarbonyl)imido group, a bis(alkylsulfonyl)methylene group, a bis(alkylsulfonyl)imido group, a tris(alkylcarbonyl)methylene group, a tris(alkylsulfonyl)methylene group or the like.

As preferred alkali-soluble groups, there can be mentioned a carboxyl group, a fluoroalcohol group (preferably hexafluoroisopropanol) and a sulfonate group.

The acid-decomposable group is preferably a group as obtained by substituting the hydrogen atom of any of these alkali-soluble groups with an acid eliminable group.

As the acid eliminable group, there can be mentioned, for example, —C(R₃₆)(R₃₇)(R₃₈), —C(R₃₆)(R₃₇)(OR₃₉), —C(R₀₁)(R₀₂)(OR₃₉) or the like.

In the formulae, each of R₃₆ to R₃₉ independently represents an alkyl group, a cycloalkyl group, an aryl group, an aralkyl group or an alkenyl group. R₃₆ and R₃₇ may be bonded to each other to thereby form a ring structure.

Each of R₀₁ to R₀₂ independently represents a hydrogen atom, an alkyl group, a cycloalkyl group, an aryl group, an aralkyl group or an alkenyl group.

Preferably, the acid-decomposable group is a cumyl ester group, an enol ester group, an acetal ester group, a tertiary alkyl ester group or the like. A tertiary alkyl ester group is more preferred.

The repeating unit with an acid-decomposable group is preferably any of those of the following general formula (AI).

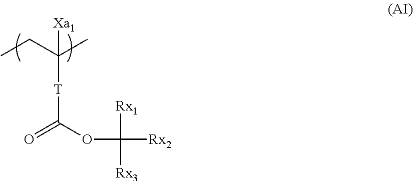

In general formula (AI),

Xa₁ represents a hydrogen atom, an optionally substituted methyl group, or a group represented by —CH₂—R₉. R₉ represents a hydroxyl group or a monovalent organic group. R₉ preferably represents an alkyl or an acyl group having 5 or less carbon atoms, more preferably an alkyl group having 3 or less carbon atoms, and further more preferably a methyl group. Xa₁ preferably represents a hydrogen atom, a methyl group, a trifluoromethyl group or a hydroxymethyl group.

T represents a single bond or a bivalent connecting group.

Each of Rx₁ to Rx₃ independently represents a linear or branched alkyl group or a mono- or polycyclic cycloalkyl group.

At least two of Rx₁ to Rx₃ may be bonded to each other to thereby form a monocyclic or polycyclic cycloalkyl group.

As the bivalent connecting group represented by T, there can be mentioned, for example, an alkylene group, a group of the formula —(COO-Rt)- or a group of the formula —(O-Rt)-. In the formulae, Rt represents an alkylene group or a cycloalkylene group.

T is preferably a single bond or a group of the formula —(COO-Rt)-. Rt is preferably an alkylene group having 1 to 5 carbon atoms, more preferably a —CH₂— group or —(CH₂)₃— group.

The alkyl group represented by each of Rx₁ to Rx₃ is preferably one having 1 to 4 carbon atoms, such as a methyl group, an ethyl group, an n-propyl group, an isopropyl group, an n-butyl group, an isobutyl group or a t-butyl group.

The cycloalkyl group represented by each of Rx₁ to Rx₃ is preferably a monocyclic cycloalkyl group, such as a cyclopentyl group or a cyclohexyl group, or a polycyclic cycloalkyl group, such as a norbornyl group, a tetracyclodecanyl group, a tetracyclododecanyl group or an adamantyl group.

The cycloalkyl group formed by at least two of Rx₁ to Rx₃ is preferably a monocyclic cycloalkyl group, such as a cyclopentyl group or a cyclohexyl group, or a polycyclic cycloalkyl group, such as a norbornyl group, a tetracyclodecanyl group, a tetracyclododecanyl group or an adamantyl group. Monocyclic cycloalkyl groups having 5 or 6 carbon atoms are especially preferred.

In an especially preferred mode, Rx₁ is a methyl group or an ethyl group, and Rx₂ and Rx₃ are bonded to each other to thereby form any of the above-mentioned cycloalkyl groups.

One or more substituents may further be introduced in each of the groups above. As the substituents, there can be mentioned, for example, an alkyl group (preferably having 1 to 4 carbon atoms), a halogen atom, a hydroxy group, an alkoxy group (preferably having 1 to 4 carbon atoms), a carboxyl group, an alkoxycarbonyl group (preferably having 2 to 6 carbon atoms). Preferably, each of the substituents has 8 or less carbon atoms.

The content of the repeating unit containing a acid-decomposable group based on all the repeating units of the resin is preferably in the range of 20 to 70 mol %, and more preferably 30 to 50 mol %.

Preferred examples of the repeating unit containing a acid-decomposable group will be shown below, which however in no way limit the scope of the present invention.

In the specific examples, Rx and Xa1 each represents a hydrogen atom, CH₃, CF₃, or CH₂OH. Each of Rxa and Rxb represents an alkyl group having 1 to 4 carbon atoms. Z or each of Zs independently represents a substituent containing a polar group. P represents 0 or positive integer.

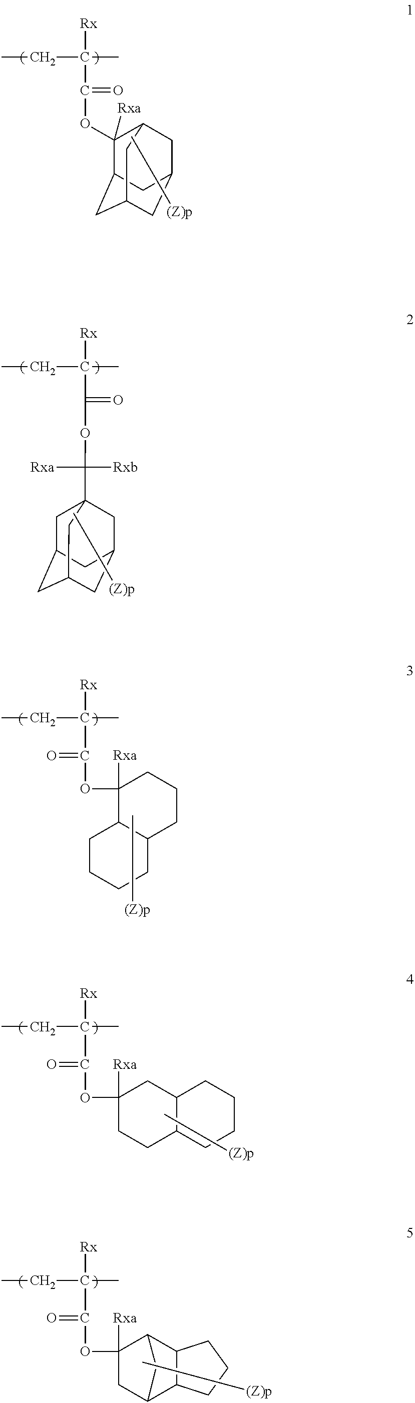

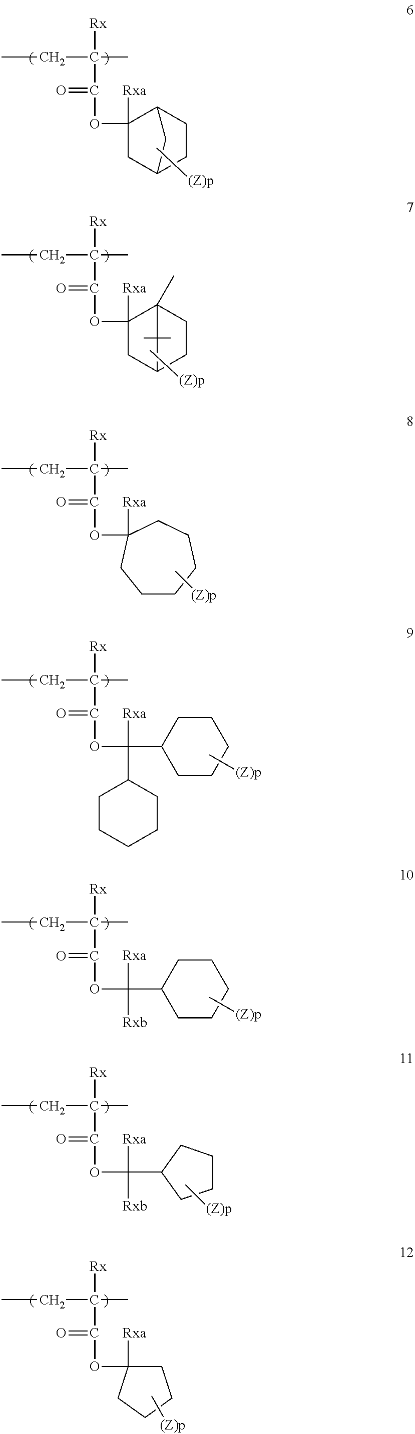

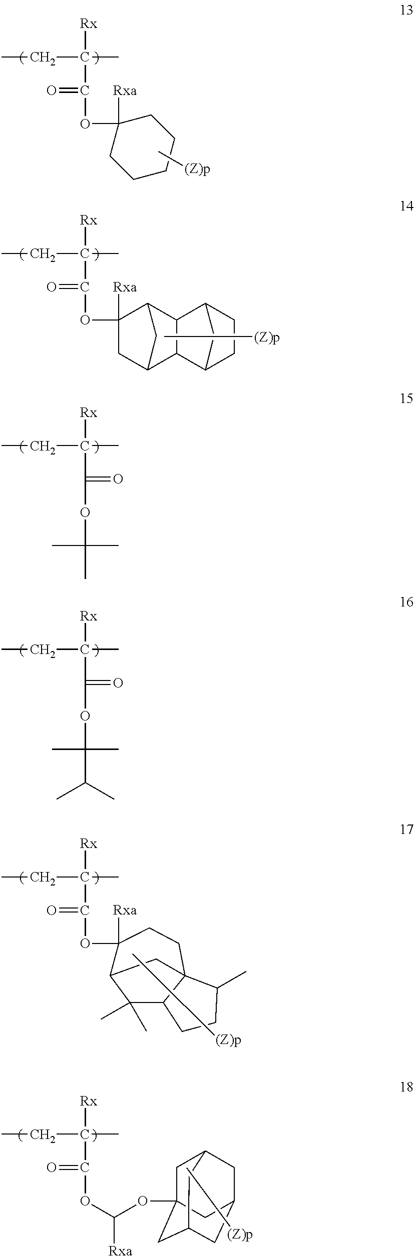

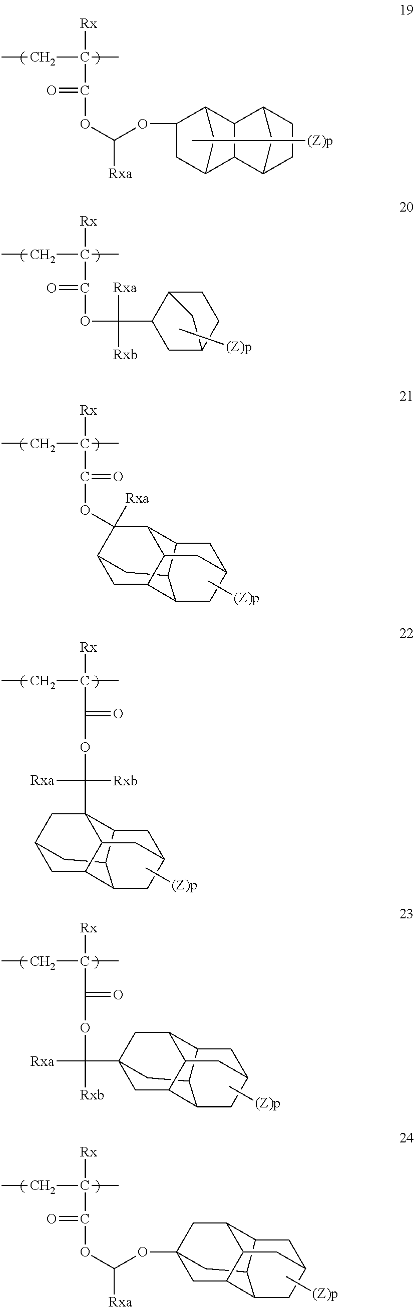

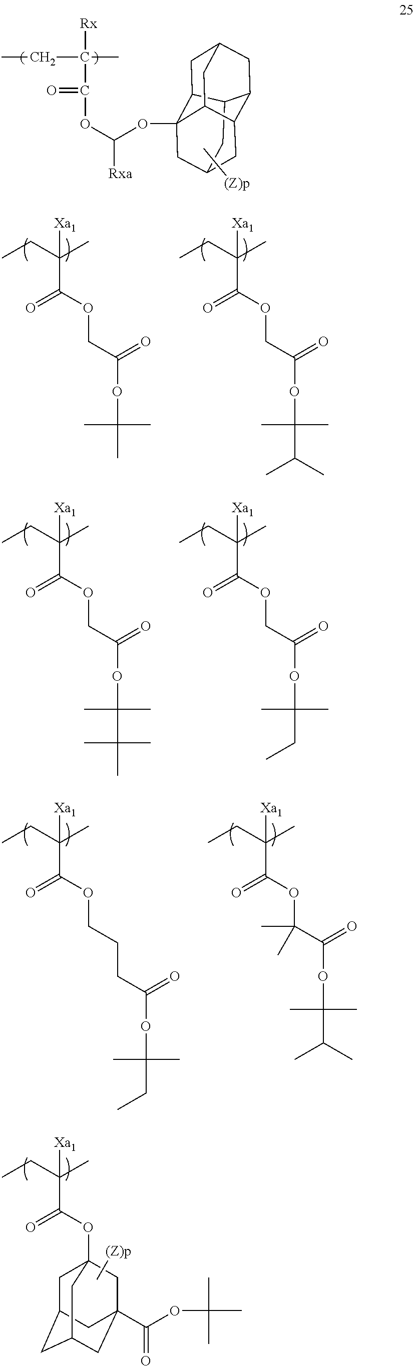

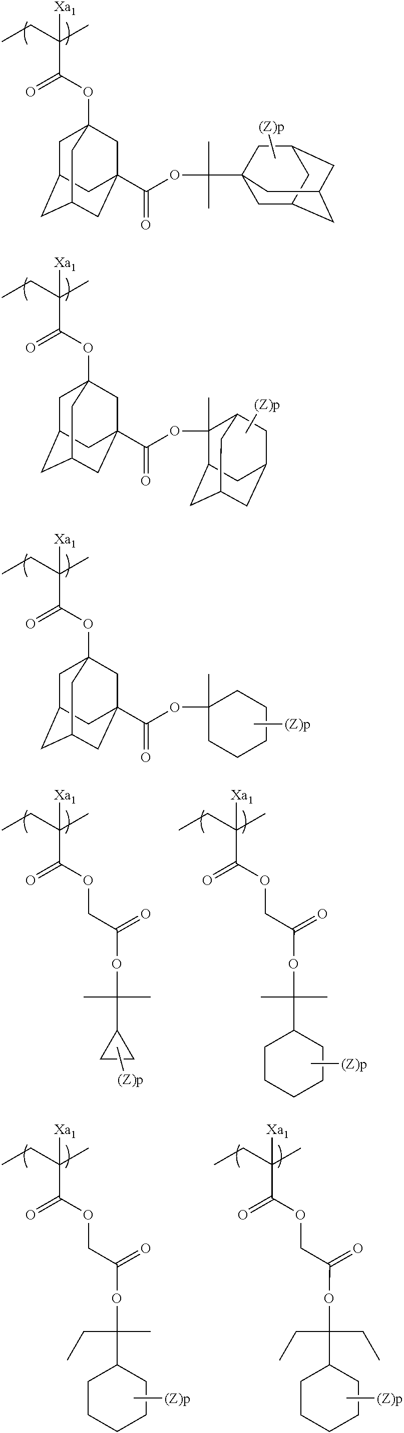

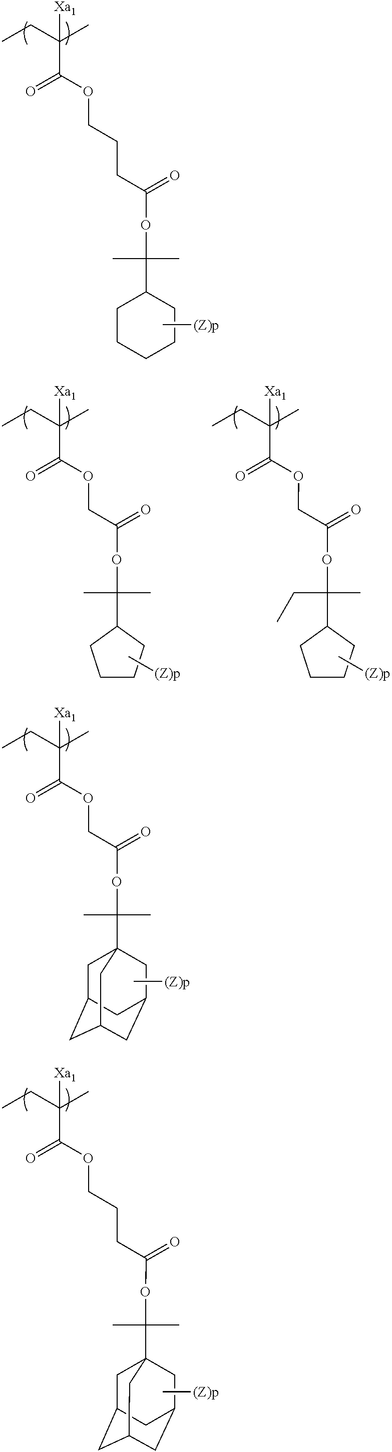

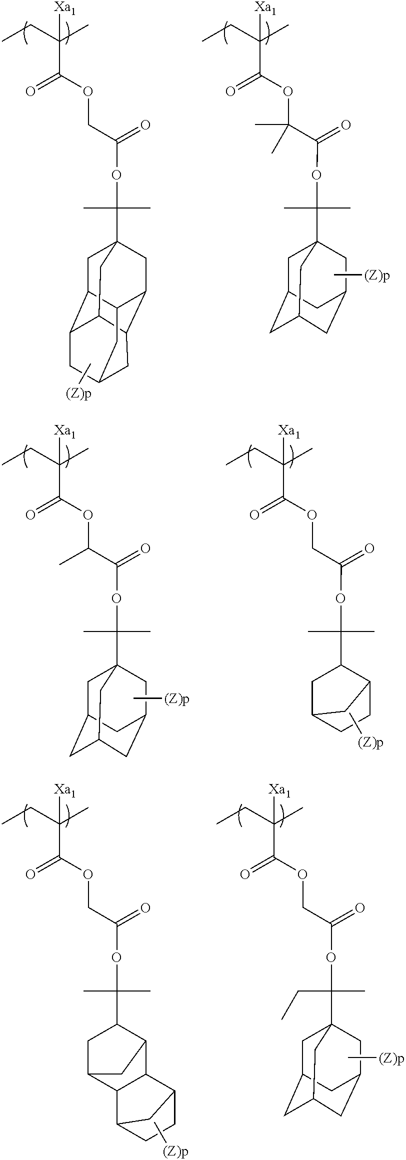

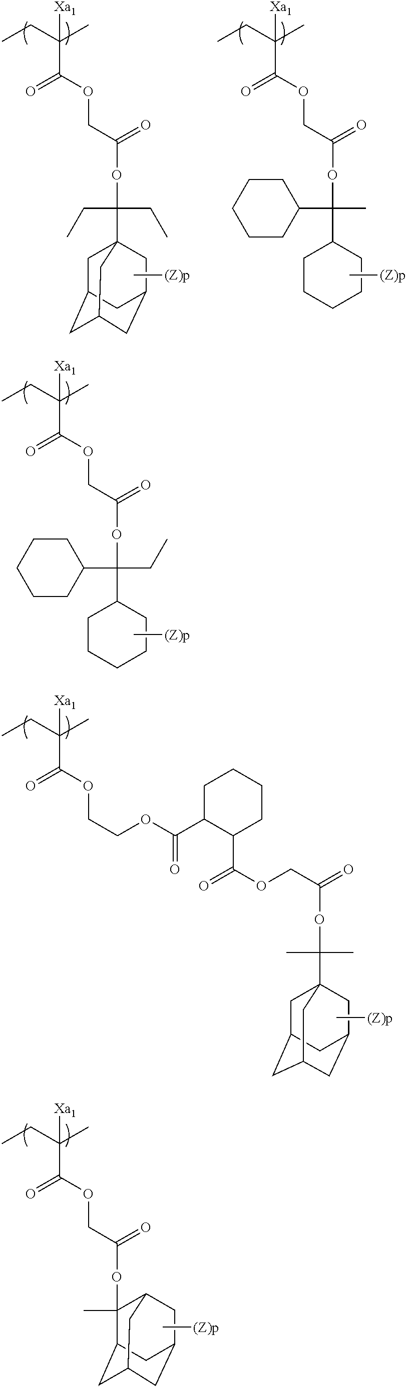

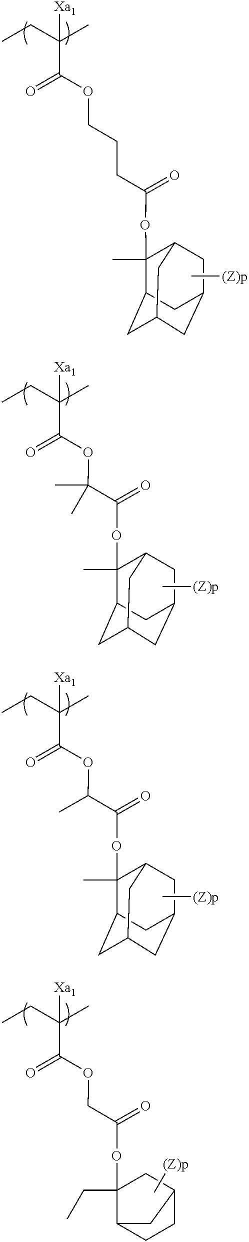

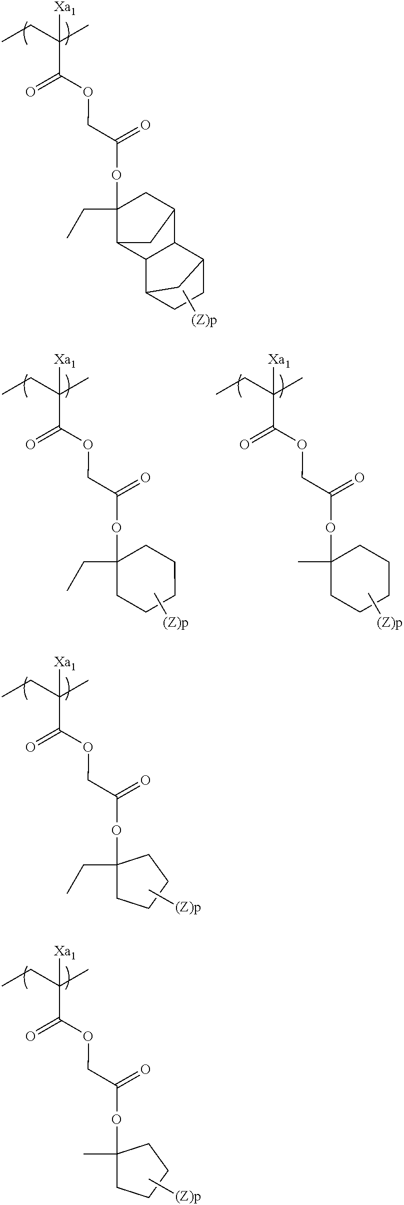

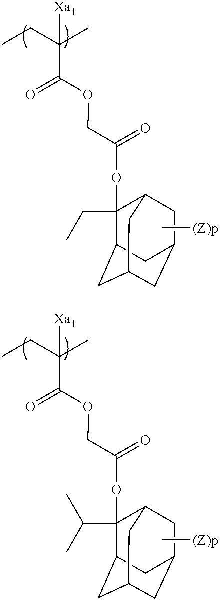

It is more preferred for the acid-decomposable resin to contain, as the repeating units of general formula (AI), any of the repeating units of general formula (I) below and/or any of the repeating units of general formula (II) below.

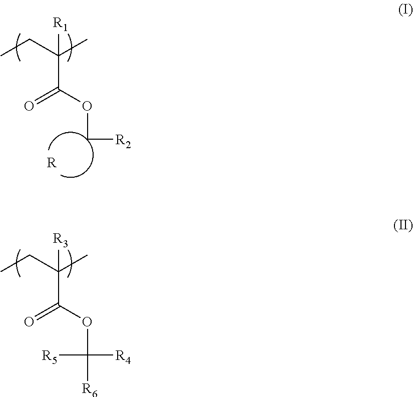

In formulae (I) and (II),

each of R₁ and R₃ independently represents a hydrogen atom, an optionally substituted methyl group or any of the groups of the formula —CH₂—R₉. R₉ represents a monovalent organic group.

Each of R₂, R₄, R₅ and R₆ independently represents an alkyl group or a cycloalkyl group.

R represents an atomic group required for forming an alicyclic structure in cooperation with a carbon atom.

R₁ preferably represents a hydrogen atom, a methyl group, a trifluoromethyl group or a hydroxymethyl group.

The alkyl group represented by R₂ may be linear or branched, and one or more substituents may be introduced therein.

The cycloalkyl group represented by R₂ may be monocyclic or polycyclic, and a substituent may be introduced therein.

R₂ preferably represents an alkyl group, more preferably an alkyl group having 1 to 10 carbon atoms, further more preferably 1 to 5 carbon atoms. As examples thereof, there can be mentioned a methyl group and an ethyl group.

R represents an atomic group required for forming an alicyclic structure in cooperation with a carbon atom. The alicyclic structure formed by R is preferably an alicyclic structure of a single ring, and preferably has 3 to 7 carbon atoms, more preferably 5 or 6 carbon atoms.

R₃ preferably represents a hydrogen atom or a methyl group, more preferably a methyl group.

Each of the alkyl groups represented by R₄, R₅ and R₆ may be linear or branched, and one or more substituents may be introduced therein. The alkyl groups are preferably those each having 1 to 4 carbon atoms, such as a methyl group, an ethyl group, an n-propyl group, an isopropyl group, an n-butyl group, an isobutyl group and a t-butyl group.

Each of the cycloalkyl groups represented by R₄, R₅ and R₆ may be monocyclic or polycyclic, and a substituent may be introduced therein. The cycloalkyl groups are preferably a monocyclic cycloalkyl group, such as a cyclopentyl group or a cyclohexyl group, and a polycyclic cycloalkyl group, such as a norbornyl group, a tetracyclodecanyl group, a tetracyclododecanyl group or an adamantyl group.

As the repeating units of general formula (I), there can be mentioned, for example, those of general formula (I-a) below.

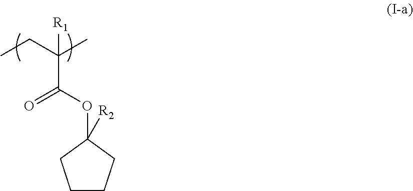

In the formula, R₁ and R₂ have the same meaning as in general formula (I).

The repeating units of general formula (II) are preferably those of general formula (II-1) below.

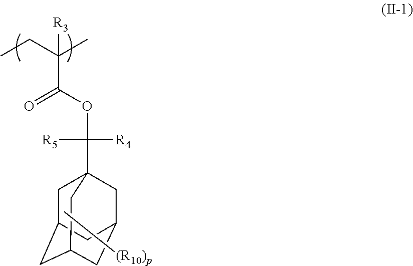

In general formula (II-1),

R₃ to R₅ have the same meaning as in general formula (II).

R₁₀ represents a substituent containing a polar group. When a plurality of R₁₀s exist, they may be identical to or different from each other. As the substituent containing a polar group, there can be mentioned, for example, a linear or branched alkyl group, or cycloalkyl group, in which a hydroxyl group, a cyano group, an amino group, an alkylamido group or a sulfonamido group is introduced. An alkyl group in which a hydroxyl group is introduced is preferred. An isopropyl group is especially preferred as the branched alkyl group.

In the formula, p is an integer of 0 to 15, preferably in the range of 0 to 2, and more preferably 0 or 1.

It is more preferred for the acid-decomposable resin to be a resin containing, as the repeating units of general formula (AI), at least either any of the repeating units of general formula (I) or any of the repeating units of general formula (II). In another form, it is more preferred for the acid-decomposable resin to be a resin containing, as the repeating units of general formula (AI), at least two types selected from among the repeating units of general formula (I).

When the resin (A) contains a plurality of acid-decomposable repeating units, the following combinations are preferred. In the following formulae, R each independently represents a hydrogen atom or a methyl group.

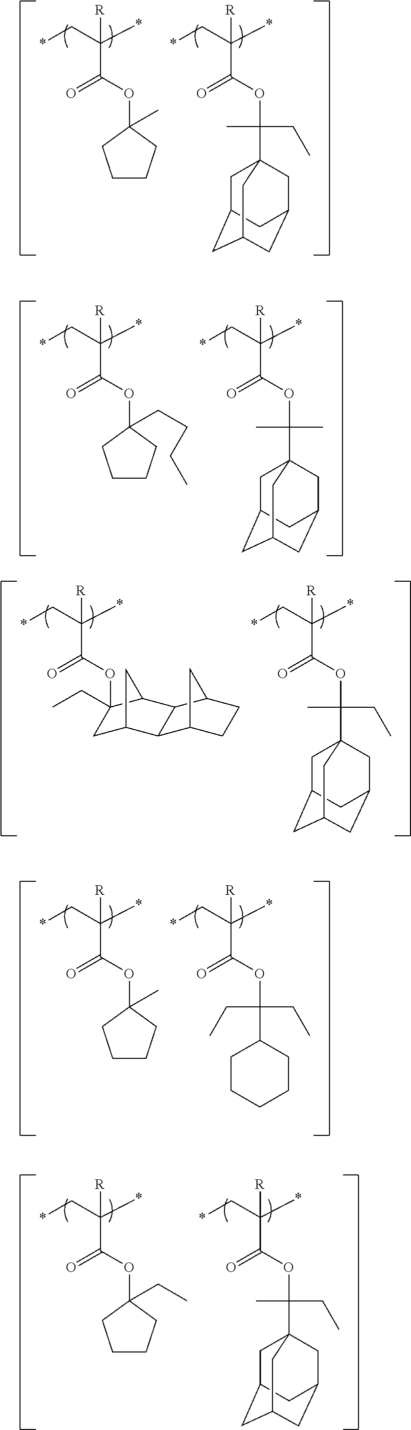

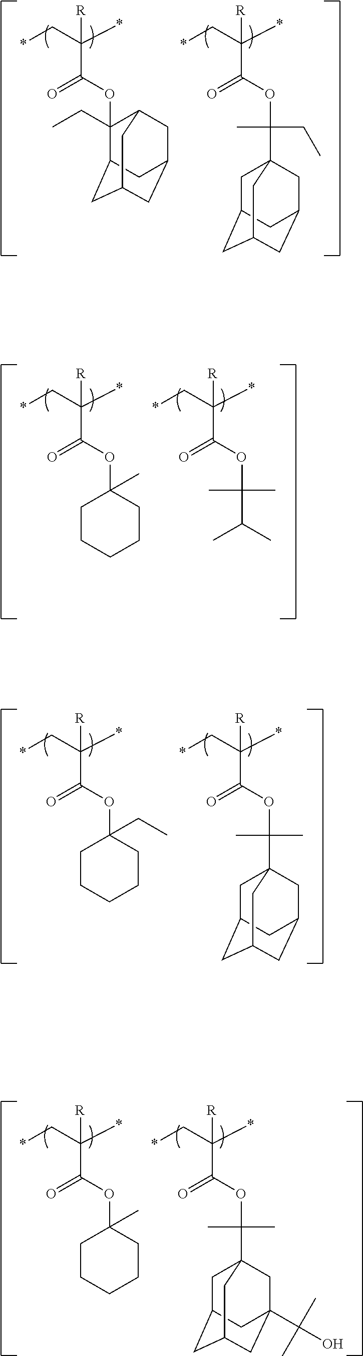

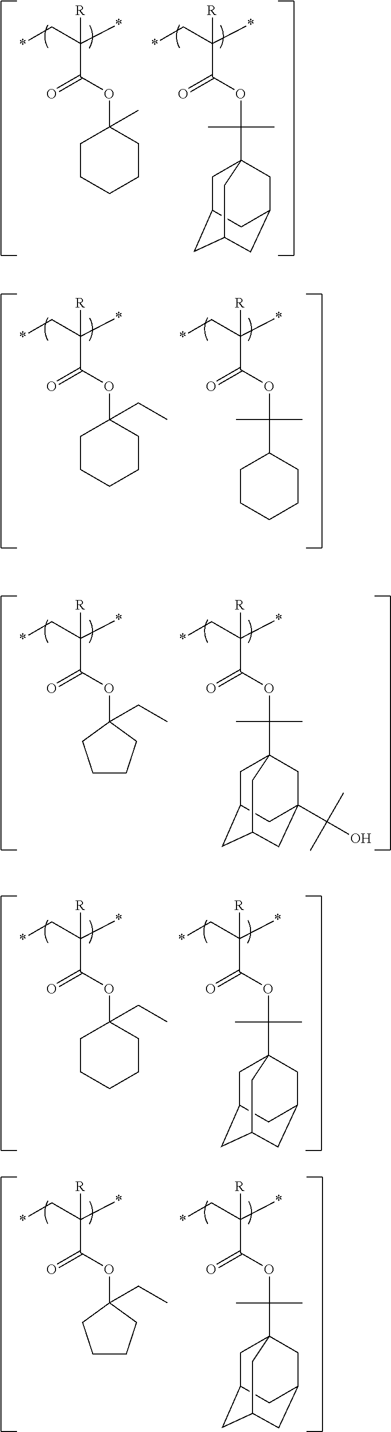

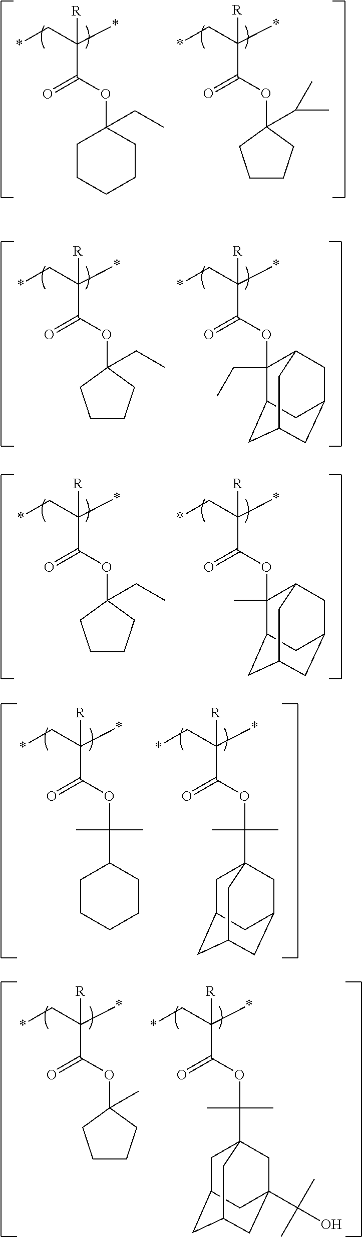

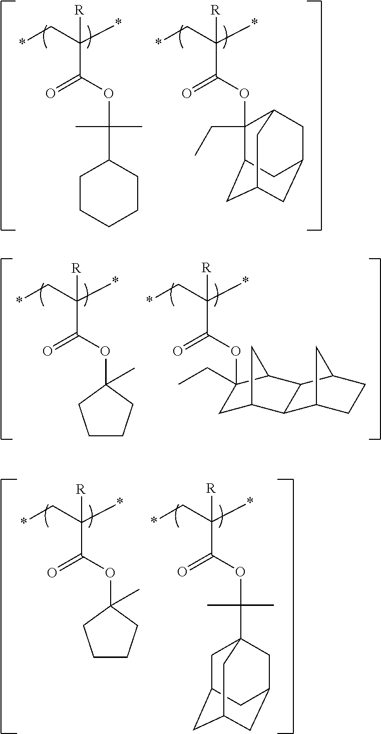

The resin (A) preferably contains a repeating unit having a lactone structure represented by general formula (III) below.

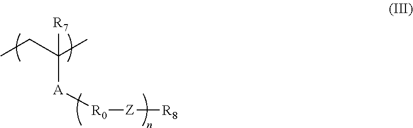

In formula (III),

A represents an ester bond (—COO—) or an amido bond (—CONH—).

Ro, each independently in the presence of two or more groups, represents an alkylene group, a cycloalkylene group or a combination thereof.

Z, each independently in the presence of two or more groups, represents an ether bond, an ester bond, an amido bond, a urethane bond
(a group represented by

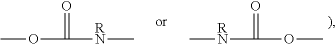

or a urea bond
(a group represented by

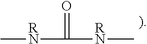

Each of Rs independently represents a hydrogen atom, an alkyl group, cycloalkyl group or an aryl group.

R₈ represents a monovalent organic group with a lactone structure.

n represents the number of repetitions of the structure of the formula —R₀—Z— and is an integer of 1 to 5.

R₇ represents a hydrogen atom, a halogen atom or an alkyl group.

Each of the alkylene group and cycloalkylene group represented by R₀ may have a substituent.

Z preferably represents an ether bond or an ester bond, most preferably an ester bond.

The alkyl group represented by R₇ is preferably an alkyl group having 1 to 4 carbon atoms, more preferably a methyl group or an ethyl group and most preferably a methyl group. The alkyl group represented by R₇ may be substituted. As substituents, there can be mentioned, for example, a halogen atom such as a fluorine atom, a chlorine atom or a bromine atom, a mercapto group, a hydroxyl group, an alkoxy group such as a methoxy group, an ethoxy group, an isopropoxy group, a t-butoxy group or a benzyloxy group, an acyl group such as an acetyl group or a propionyl group, an acetoxy group and the like. R₇ is preferably a hydrogen atom, a methyl group, a trifluoromethyl group or a hydroxymethyl group.

The alkylene group represented by R₀ is preferably a chain alkylene group having 1 to 10 carbon atoms, more preferably 1 to 5 carbon atoms, for example, a methylene group, an ethylene group, a propylene group or the like. The cycloalkylene group is preferably a cycloalkylene group having 3 to 20 carbon atoms. As such, there can be mentioned, for example, cyclohexylene, cyclopentylene, norbornylene, adamantylene or the like. The chain alkylene groups are preferred from the viewpoint of the exertion of the effect of the present invention. A methylene group is most preferred.

The monovalent organic group with a lactone structure represented by R₈ is not limited as long as the lactone structure is contained. As particular examples thereof, there can be mentioned the lactone structures of general formulae (LC1-1) to (LC1-17) to be described hereinafter. Of these, the structures of general formula (LC1-4) are most preferred. In general formulae (LC1-1) to (LC1-17), n₂ is more preferably 2 or less.

R₈ preferably represents a monovalent organic group with an unsubstituted lactone structure or a monovalent organic group with a lactone structure substituted with a methyl group, a cyano group or an alkoxycarbonyl group. More preferably, R₈ represents a monovalent organic group with a lactone structure substituted with a cyano group (cyanolactone).

Specific examples of the repeating units having a group with a lactone structure represented by general formula (III) will be shown below, which however in no way limit the scope of the present invention. In the specific examples, R represents a hydrogen atom, an optionally substituted alkyl group or a halogen atom. R is preferably a hydrogen atom, a methyl group, a hydroxymethyl group or an acetoxymethyl group.

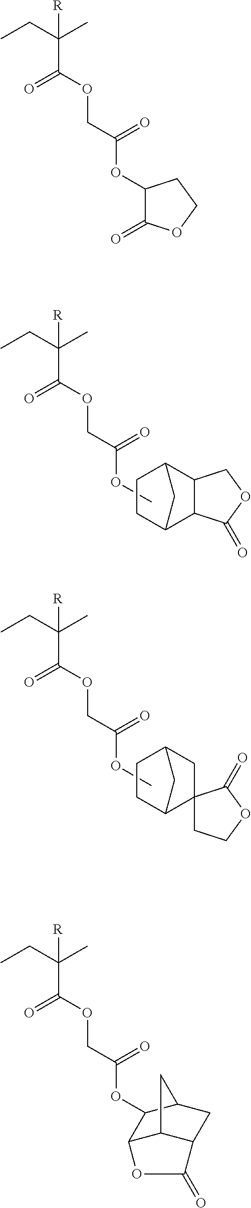

The repeating units having a lactone structure are preferably those of general formula (III-1) below.

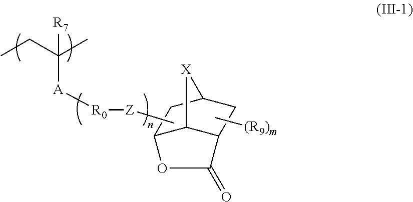

In general formula (III-1),

R₇, A, R₀, Z and n are as defined in general formula (III) above.

R₉, when m≧2 each of Rb's independently, represents an alkyl group, a cycloalkyl group, an alkoxycarbonyl group, a cyano group, a hydroxyl group or an alkoxy group. When m≧2, two or more R₉'s may be bonded to each other to thereby form a ring.

X represents an alkylene group, an oxygen atom or a sulfur atom.

In the formula, m is the number of substituents, being an integer of 0 to 5; and preferably 0 or 1.

The alkyl group represented by R₉ is preferably an alkyl group having 1 to 4 carbon atoms, more preferably a methyl group or an ethyl group, and most preferably a methyl group. As the cycloalkyl group, there can be mentioned, for example, a cyclopropyl group, a cyclobutyl group, a cyclopentyl group or a cyclohexyl group. As the alkoxycarbonyl group, there can be mentioned, for example, a methoxycarbonyl group, an ethoxycarbonyl group, an n-butoxycarbonyl group or a t-butoxycarbonyl group. As the alkoxy group, there can be mentioned, for example, a methoxy group, an ethoxy group, a propoxy group, isopropoxy group or a butoxy group. These groups may have one or more substituents. As such substituents, there can be mentioned, for example, a hydroxyl group; an alkoxy group such as a methoxy group or an ethoxy group; a cyano group; and a halogen atom such as a fluorine atom. More preferably, R₉ is a methyl group, a cyano group or an alkoxycarbonyl group, further more preferably a cyano group.

As the alkylene group represented by X, there can be mentioned, for example, a methylene group or an ethylene group. X is preferably an oxygen atom or a methylene group, more preferably a methylene group.

When m≧1, it is preferred for the substitution with at least one R₉ to take place at the α- or β-position of the carbonyl group of the lactone. The substitution with R₉ at the α-position of the carbonyl group of the lactone is especially preferred.

Specific examples of the repeating units having a group with a lactone structure represented by formula (III-1) will be shown below, which however in no way limit the scope of the present invention. In the specific examples, R represents a hydrogen atom, an optionally substituted alkyl group or a halogen atom. R is preferably a hydrogen atom, a methyl group, a hydroxymethyl group or an acetoxymethyl group.

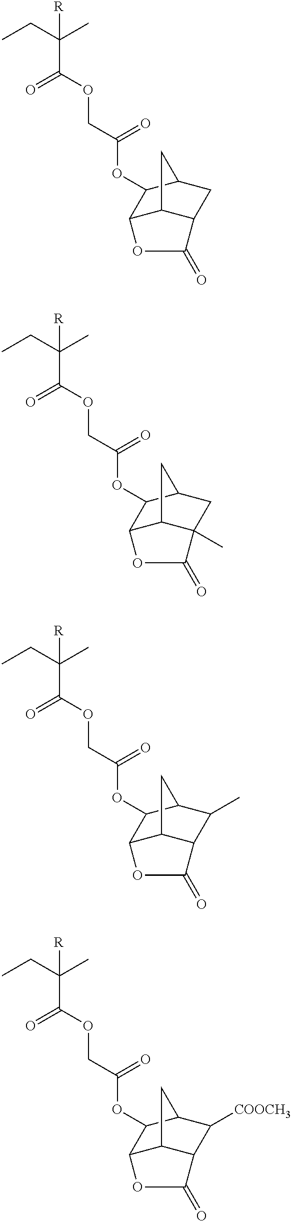

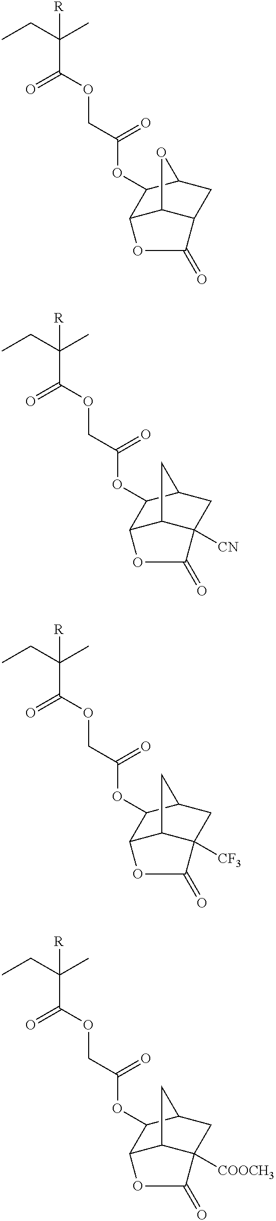

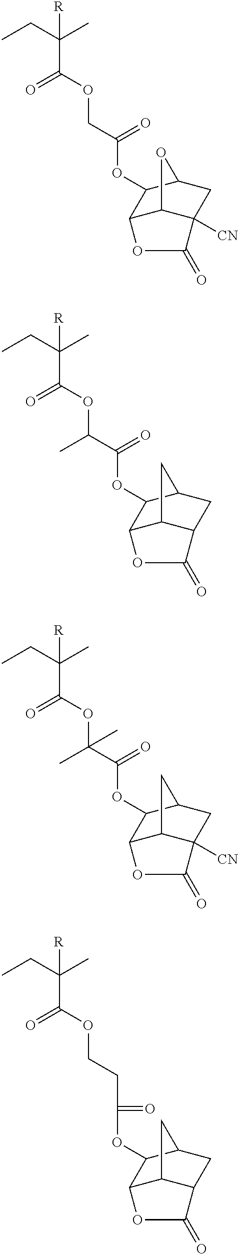

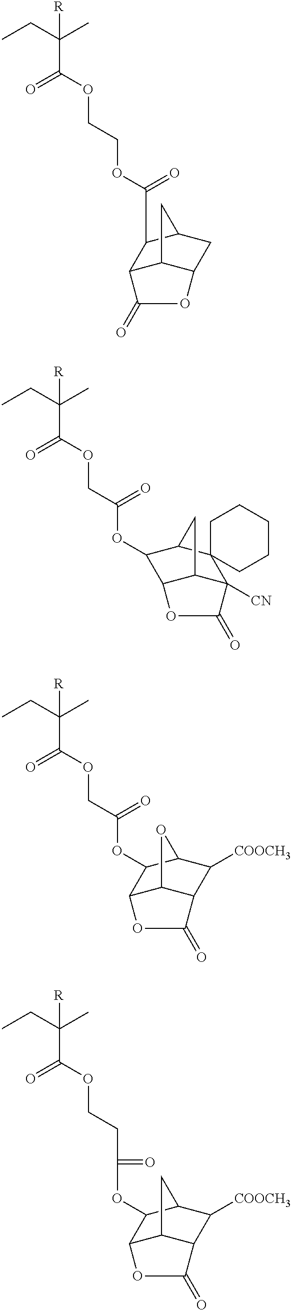

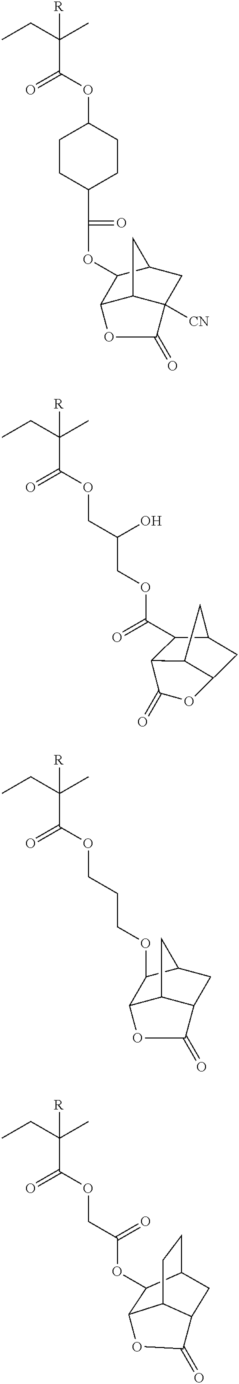

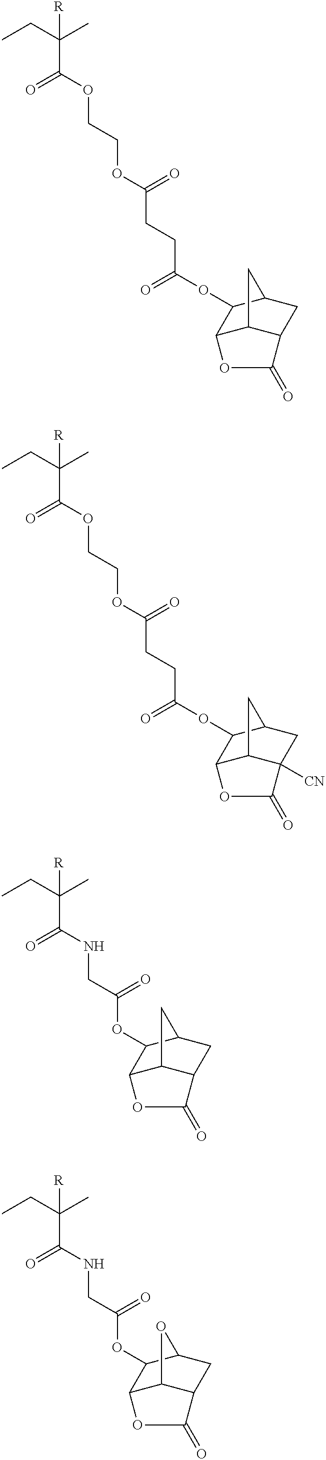

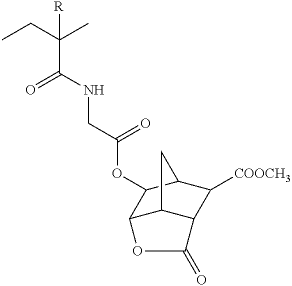

The content of any of the repeating units of general formula (III), the total content when two or more types thereof are contained, is preferably in the range of 15 to 60 mol %, more preferably 20 to 60 mol % and further more preferably 30 to 50 mol %, based on all the repeating units of the resin (A).

The resin (A) may contain a repeating unit containing a lactone group besides the units of general formula (III).

Any lactone groups can be employed as long as a lactone structure is possessed therein. However, lactone structures of a 5 to 7-membered ring are preferred, and in particular, those resulting from condensation of lactone structures of a 5 to 7-membered ring with other cyclic structures effected in a fashion to form a bicyclo structure or spiro structure are preferred. The possession of repeating units having a lactone structure represented by any of the following general formulae (LC1-1) to (LC1-17) is more preferred. The lactone structures may be directly bonded to the principal chain of the resin. Preferred lactone structures are those of formulae (LC1-1), (LC1-4), (LC1-5), (LC1-6), (LC1-13), (LC1-14) and (LC1-17). The use of these specified lactone structures would ensure improvement in the LWR and development defect.

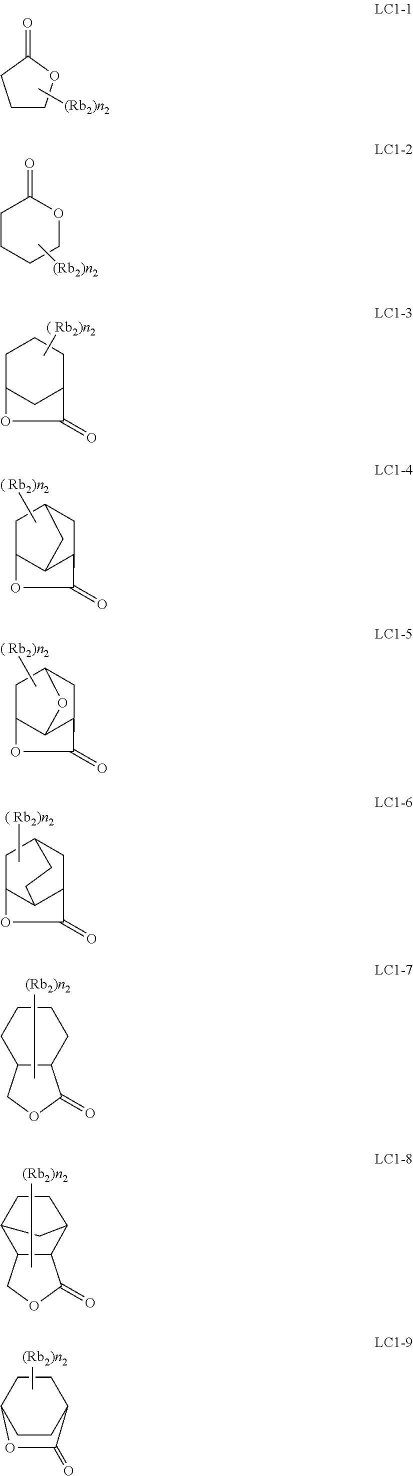

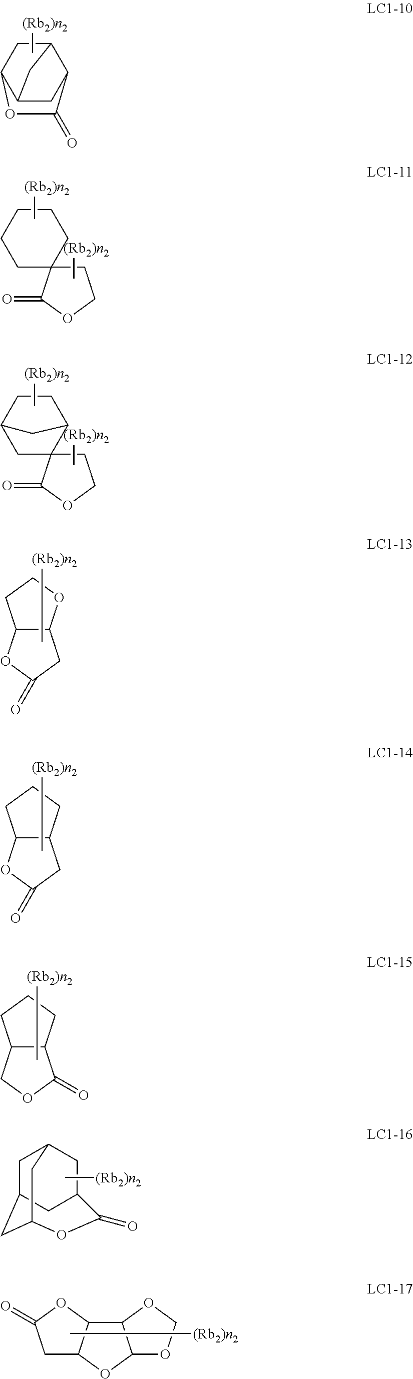

The presence of a substituent (Rb₂) on the portion of the lactone structure is optional. As a preferred substituent (Rb₂), there can be mentioned an alkyl group having 1 to 8 carbon atoms, a cycloalkyl group having 4 to 7 carbon atoms, an alkoxy group having 1 to 8 carbon atoms, an alkoxycarbonyl group having 1 to 8 carbon atoms, a carboxyl group, a halogen atom, a hydroxyl group, a cyano group, an acid-decomposable group or the like. Of these, an alkyl group having 1 to 4 carbon atoms, a cyano group and an acid-decomposable group are more preferred. In the formulae, n₂ is an integer of 0 to 4. When n₂ is 2 or greater, the plurality of present substituents (Rb₂) may be identical to or different from each other. Further, the plurality of present substituents (Rb₂) may be bonded to each other to thereby form a ring.

As the repeating units containing a lactone structure besides the units of general formula (III), a repeating unit represented by general formula (AII′) below can be exemplified.

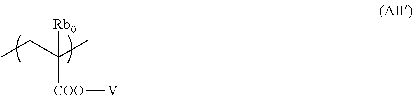

In general formula (AII′),

Rb₀ represents a hydrogen atom, a halogen atom or an alkyl group having 1 to 4 carbon atoms. As preferred substituents that may be introduced in the alkyl group represented by Rb₀, there can be mentioned a hydroxyl group and a halogen atom. As the halogen atom, there can be mentioned a fluorine atom, a chlorine atom, a bromine atom or an iodine atom. Preferably, Rb₀ represents a hydrogen atom, a methyl group, a hydroxymethyl group, or a trifluoromethyl group, and more preferably a hydrogen atom or a methyl group.

V represents any of the groups of the general formulae (LC1-1) to (LC1-17).

Specific examples of repeating unit containing a lactone structure besides the units of general formula (III) will be shown below, which in no way limit the scope of the present invention.

In the formulae, Rx represents H, CH₃, CH₂OH, or CF₃.

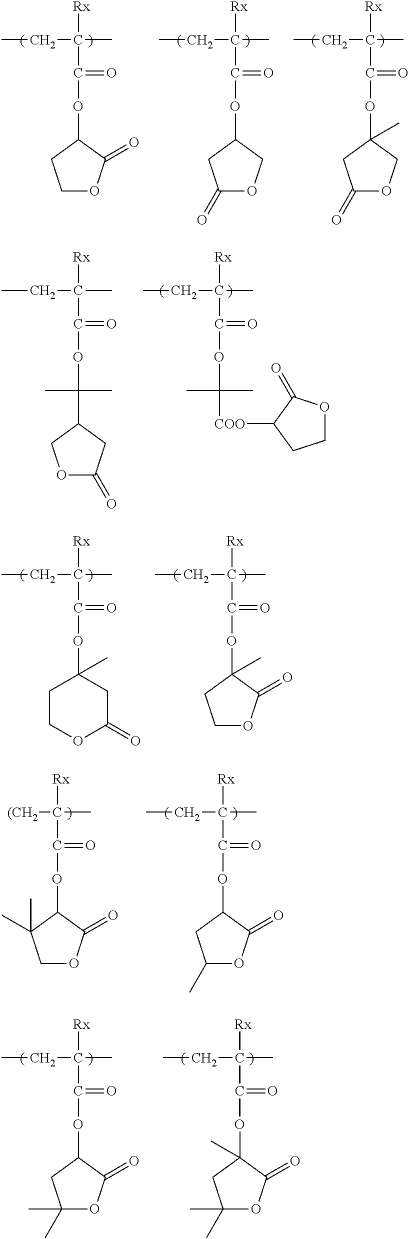

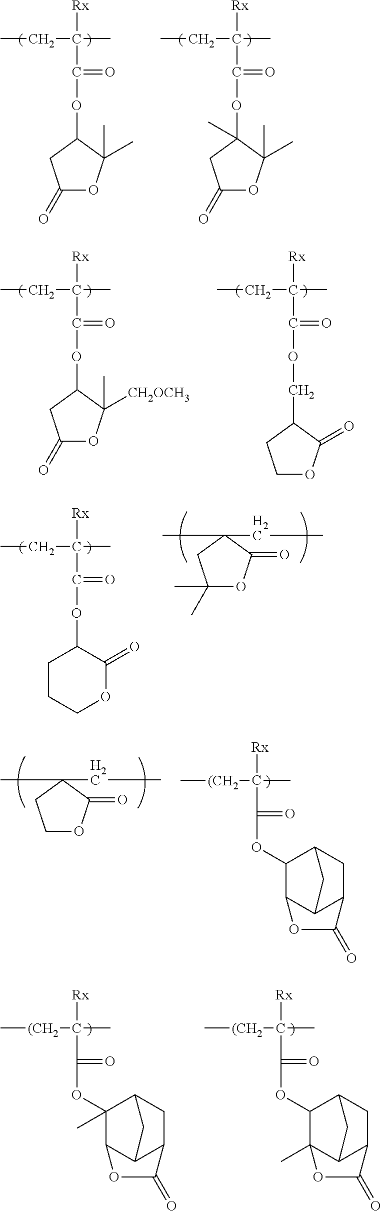

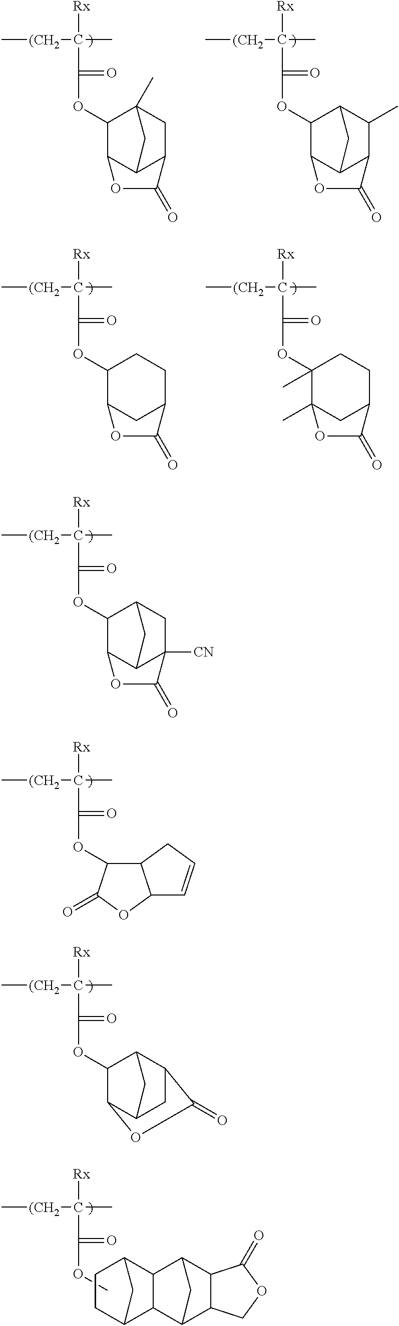

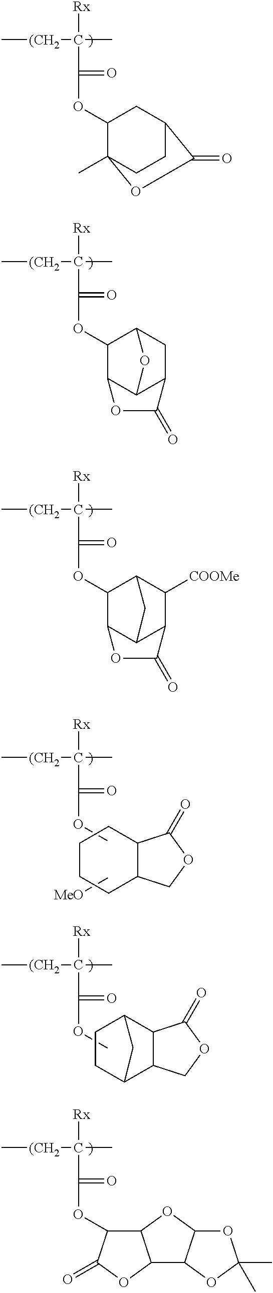

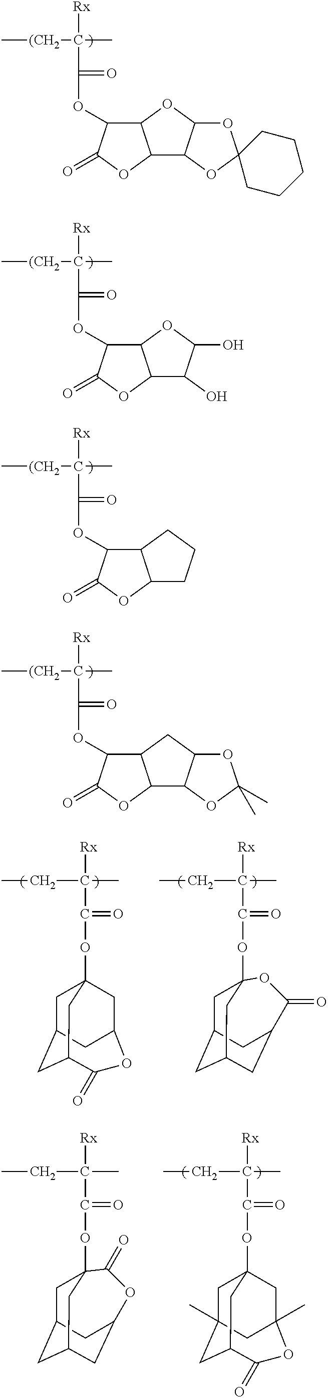

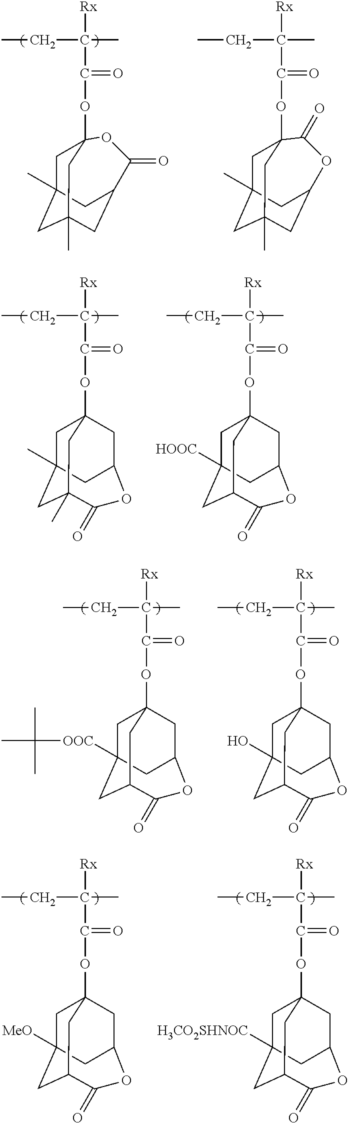

As especially preferred repeating units each containing a lactone group other than the units of general formula (III), there can be mentioned the following repeating units. Favorable pattern profile and iso/dense bias can be realized by selecting most appropriate lactone groups.

In the formulae, Rx represents H, CH₃, CH₂OH, or CF₃.

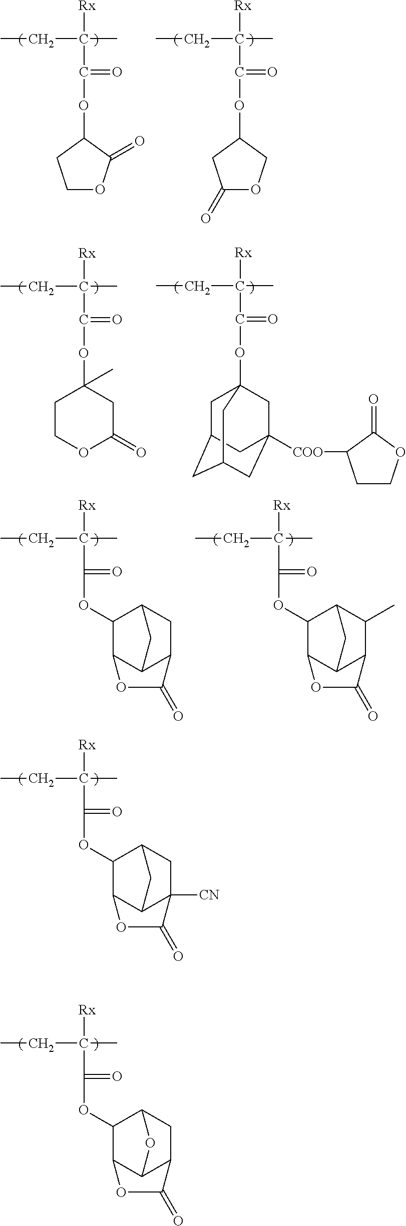

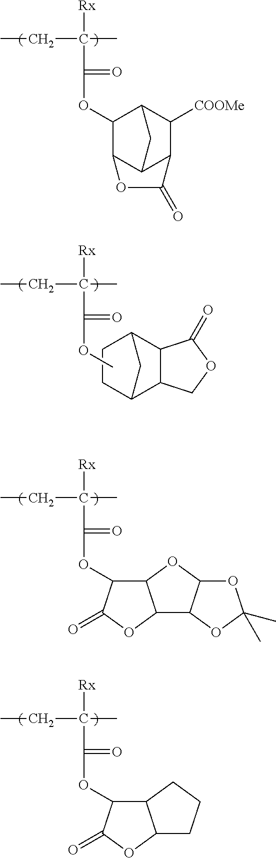

The repeating unit having a lactone group is generally present in the form of optical isomers. Any of the optical isomers may be used. It is both appropriate to use a single type of optical isomer alone and to use a plurality of optical isomers in the form of a mixture. When a single type of optical isomer is mainly used, the optical purity thereof is preferably 90% ee or higher, more preferably 95% ee or higher.

The content of repeating unit containing a lactone group other than the repeating units of general formula (III), the total content when two or more types thereof are contained, is preferably in the range of 15 to 60 mol %, more preferably 20 to 50 mol % and further more preferably 30 to 50 mol %, based on all the repeating units of the resin.

In order to enhance the effect of the present invention, two or more types of lactone repeating units selected from among those of general formula (III) can be used in combination. When such a combinational use is conducted, it is preferred to select two or more from among the lactone repeating units of general formula (III) in which n is 1 and use them in combination.

The resin (A) may further contain a repeating unit containing a hydroxy group or a cyano group other than repeating units represented by general formulae (AI) and (III). The containment of this repeating unit would realize enhancements of adhesion to substrate and developer affinity.

The repeating unit containing a hydroxy group or a cyano group is preferably a repeating unit having an alicyclic hydrocarbon structure substituted with a hydroxy group or a cyano group. Further, the repeating unit containing a hydroxy group or a cyano group is preferably free from the acid-decomposable group. In the alicyclic hydrocarbon structure substituted with a hydroxy group or a cyano group, the alicyclic hydrocarbon structure preferably consists of an adamantyl group, a diamantyl group or a norbornane group. As preferred alicyclic hydrocarbon structures substituted with a hydroxy group or a cyano group, the partial structures represented by the following general formulae (VIIa) to (VIId) can be exemplified.

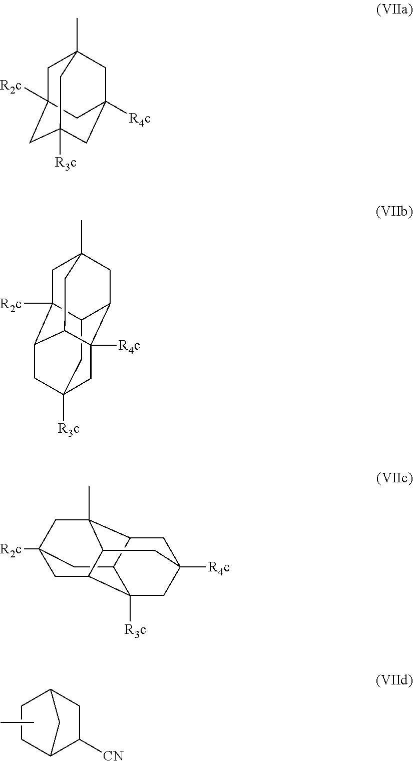

In the general formulae (VIIa) to (VIIc),

each of R₂c to R₄c independently represents a hydrogen atom, a hydroxy group or a cyano group, with the proviso that at least one of the R₂c to R₄c represents a hydroxy group or a cyano group. Preferably, one or two of the R₂c to R₄c are hydroxy groups and the remainder is a hydrogen atom. In the general formula (VIIa), more preferably, two of the R₂c to R₄c are hydroxy groups and the remainder is a hydrogen atom.

As the repeating units having any of the partial structures represented by the general formulae (VIIa) to (VIId), those of the following general formulae (Alla) to (AIId) can be exemplified.

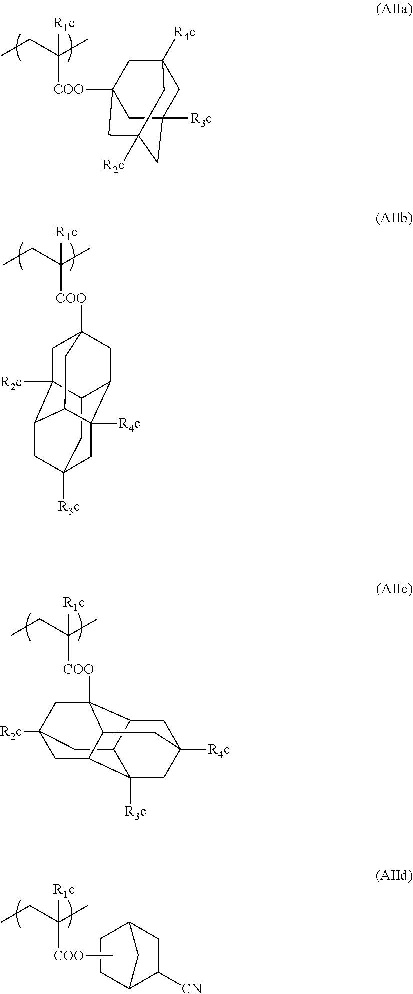

In general formulae (Alla) to (AIId),

R₁c represents a hydrogen atom, a methyl group, a trifluoromethyl group or a hydroxymethyl group.

R₂c to R₄c have the same meaning as those of the general formulae (VIIa) to (VIIc).

The content of the repeating unit containing a hydroxyl group or a cyano group based on all the repeating units of the resin (A) is preferably in the range of 5 to 40 mol %, more preferably 5 to 30 mol % and further more preferably 10 to 25 mol %.

Specific examples of the repeating units containing a hydroxyl group or a cyano group will be shown below, which however in no way limit the scope of the present invention.

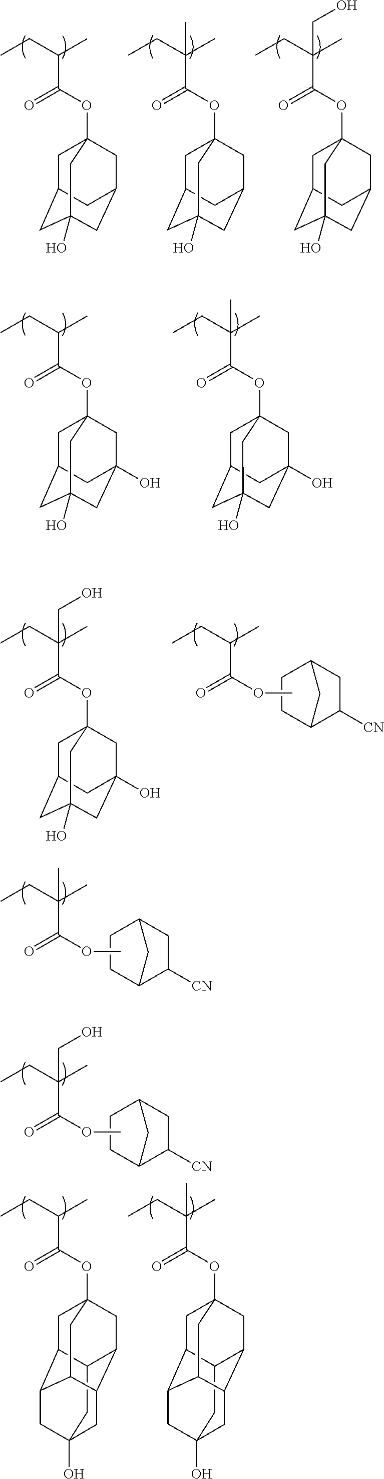

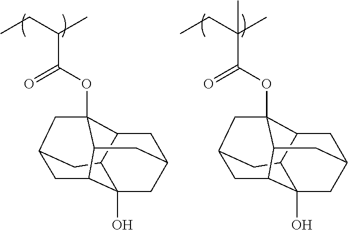

The resin for use in the composition of the present invention may contain a repeating unit containing an alkali-soluble group. As the alkali-soluble group, there can be mentioned a phenolic hydroxyl group, a carboxyl group, a sulfonamido group, a sulfonylimido group, a bisulfonylimido group or an aliphatic alcohol substituted at its α-position with an electron withdrawing group (for example, a hexafluoroisopropanol group). It is more preferred to contain a repeating unit containing a carboxyl group. The incorporation of the repeating unit containing an alkali-soluble group increases the resolution in contact hole usage. The repeating unit containing an alkali-soluble group is preferably any of a repeating unit wherein the alkali-soluble group is directly bonded to the principal chain of a resin such as a repeating unit of acrylic acid or methacrylic acid, a repeating unit wherein the alkali-soluble group is bonded via a connecting group to the principal chain of a resin and a repeating unit wherein the alkali-soluble group is introduced in a terminal of a polymer chain by the use of a chain transfer agent or polymerization initiator having the alkali-soluble group in the stage of polymerization. The connecting group may have a mono- or polycyclohydrocarbon structure. The repeating unit of acrylic acid or methacrylic acid is especially preferred.

The content of the repeating unit containing an alkali-soluble group based on all the repeating units of the resin is preferably in the range of 0 to 20 mol %, more preferably 3 to 15 mol % and further more preferably 2 to 10 mol %.

Specific examples of the repeating units containing an alkali-soluble group will be shown below, which however in no way limit the scope of the present invention.

In the specific examples, Rx represents H, CH₃, CH₂OH, or CF₃.

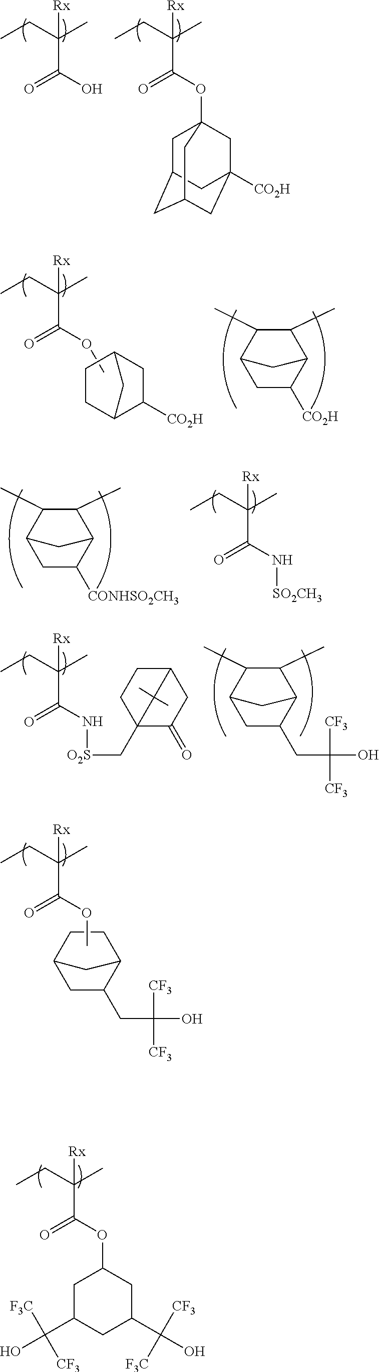

The resin (A) may further contain a repeating unit having an alicyclic hydrocarbon structure containing no polar group, which repeating unit exhibits no acid decomposability. As the repeating unit, there can be mentioned, for example, any of those of general formula (IV) below.

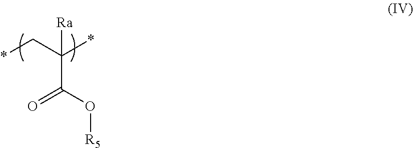

In the general formula (IV), R₅ represents a hydrocarbon group having at least one cyclic structure in which neither a hydroxyl group nor a cyano group is contained.

Ra represents a hydrogen atom, an alkyl group or a group of the formula —CH₂—O-Ra₂ in which Ra₂ represents a hydrogen atom, an alkyl group or an acyl group. Ra is preferably a hydrogen atom, a methyl group, a hydroxymethyl group or a trifluoromethyl group, further preferably a hydrogen atom or a methyl group.

The cyclic structures contained in R₅ include a monocyclic hydrocarbon group and a polycyclic hydrocarbon group. As the monocyclic hydrocarbon group, a cycloalkyl group having 3 to 12 carbon atoms and a cycloalkenyl group having 3 to 12 carbon atoms can be exemplified. Preferably, the monocyclic hydrocarbon group is a monocyclic hydrocarbon group having 3 to 7 carbon atoms. As such, a cyclopentyl group and a cyclohexyl group can be exemplified.

The polycyclic hydrocarbon groups include ring-assembly hydrocarbon groups and crosslinked-ring hydrocarbon groups.

As the ring-assembly hydrocarbon groups, for example, a bicyclohexyl group and a perhydronaphthalenyl group can be exemplified.

As the crosslinked-ring hydrocarbon rings, there can be mentioned, for example, bicyclic hydrocarbon rings, such as pinane, bornane, norpinane, norbornane and bicyclooctane rings (e.g., bicyclo[2.2.2]octane ring or bicyclo[3.2.1]octane ring); tricyclic hydrocarbon rings, such as homobledane, adamantane, tricyclo[5.2.1.0^{2,6}]decane and tricyclo[4.3.1.1^{2,5}]undecane rings; and tetracyclic hydrocarbon rings, such as tetracyclo[4.4.0.1^{2,5}.1^{7,10}]dodecane and perhydro-1,4-methano-5,8-methanonaphthalene rings.

Further, the crosslinked-ring hydrocarbon rings include condensed-ring hydrocarbon rings, for example, condensed rings resulting from condensation of multiple 5- to 8-membered cycloalkane rings, such as perhydronaphthalene (decalin), perhydroanthracene, perhydrophenanthrene, perhydroacenaphthene, perhydrofluorene, perhydroindene and perhydrophenalene rings.

As preferred crosslinked-ring hydrocarbon rings, there can be mentioned a norbornyl group, an adamantyl group, a bicyclooctanyl group, a tricyclo[5.2.1.0^{2,6}]decanyl group and the like. As more preferred crosslinked-ring hydrocarbon rings, there can be mentioned a norbornyl group and an adamantyl group.

These alicyclic hydrocarbon groups may have one or more substituents. As preferred substituents, a halogen atom, an alkyl group, a hydroxyl group protected by a protective group, and an amino group protected by a protective group can be exemplified. The halogen atom is preferably a bromine, chlorine or fluorine atom. The alkyl group is preferably a methyl, ethyl, butyl or t-butyl group. The alkyl group may further have one or more substituents. As the optional substituent, a halogen atom, an alkyl group, a hydroxyl group protected by a protective group, and an amino group protected by a protective group can be exemplified.

As the protective group, an alkyl group, a cycloalkyl group, an aralkyl group, a substituted methyl group, a substituted ethyl group, an alkoxycarbonyl group and an aralkyloxycarbonyl group can be exemplified. Preferred alkyl groups include alkyl groups having 1 to 4 carbon atoms. Preferred substituted methyl groups include methoxymethyl, methoxythiomethyl, benzyloxymethyl, t-butoxymethyl and 2-methoxyethoxymethyl groups. Preferred substituted ethyl groups include 1-ethoxyethyl and 1-methyl-1-methoxyethyl groups. Preferred acyl groups include aliphatic acyl groups having 1 to 6 carbon atoms, such as formyl, acetyl, propionyl, butyryl, isobutyryl, valeryl and pivaloyl groups. Preferred alkoxycarbonyl groups include alkoxycarbonyl groups having 1 to 4 carbon atoms and the like.

The content of the repeating unit having an alicyclic hydrocarbon structure containing no polar group, which repeating unit exhibits no acid decomposability, based on all the repeating units of the resin (A) is preferably in the range of 0 to 40 mol %, more preferably 1 to 20 mol %.

Specific examples of the repeating unit having an alicyclic hydrocarbon structure containing no polar group, which repeating unit exhibits no acid decomposability will be shown below, which however in no way limit the scope of the present invention. In the formulae, Ra represents H, CH₃, CH₂OH or CF₃.

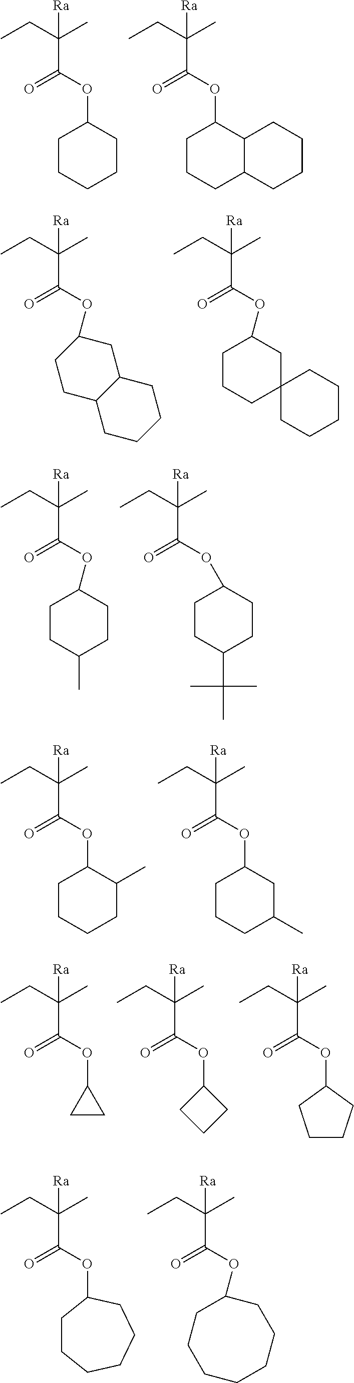

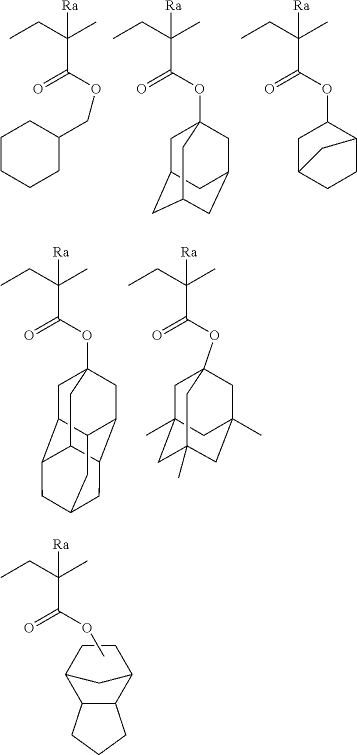

Various repeating structural units other than those mentioned hereinbefore can be introduced in the resin (A) in order to regulate the dry etching resistance, standard developer adaptability, adherence to substrates, resist profile, and generally required properties for resist, such as resolving power, heat resistance, sensitivity, and the like.

As such other repeating structural units, those corresponding to the following monomers can be exemplified, which however are nonlimiting.

Such other repeating structural units would permit fine regulation of the properties required to have by the resin for use in the composition of the present invention, especially, (1) solubility in applied solvents, (2) film forming easiness (glass transition temperature), (3) alkali developability, (4) film thinning (selection of hydrophilicity/hydrophobicity and alkali soluble group), (5) adhesion of unexposed areas to substrate, and (6) dry etching resistance, etc.

As the above-mentioned monomers, compounds having an unsaturated bond capable of addition polymerization, selected from among acrylic esters, methacrylic esters, acrylamides, methacrylamides, allyl compounds, vinyl ethers, vinyl esters and the like can be exemplified.

The monomers are not limited to the above, and unsaturated compounds capable of addition polymerization that are copolymerizable with the monomers corresponding to the above various repeating structural units can be used in the copolymerization.

The molar ratios of individual repeating structural units contained in the resin (A) for use in the composition of the present invention are appropriately determined from the viewpoint of regulation of not only the resist dry etching resistance but also the standard developer adaptability, substrate adhesion, resist profile and generally required properties of resists such as resolving power, heat resistance and sensitivity.

When the composition of the present invention is used in ArF exposure, it is preferred for the resin (A) to contain no aromatic group from the viewpoint of transparency to ArF light. It is especially preferred for the acid-decomposable resin to contain an alicyclic hydrocarbon structure of a single ring or multiple rings.

Further, it is preferred for the resin (A) to contain neither a fluorine atom nor a silicon atom from the viewpoint of compatibility with the resin (B).

Preferred resin (A) is that whose repeating units consisting of (meth)acrylate repeating units. In that instance, use can be made of any of a resin wherein all the repeating units consist of methacrylate repeating units, a resin wherein all the repeating units consist of acrylate repeating units and a resin wherein all the repeating units consist of methacrylate repeating units and acrylate repeating units. However, it is preferred for the acrylate repeating units to account for 50 mol % or less of all the repeating units. Further, a copolymer containing 20 to 50 mol % of (meth)acrylate repeating unit having an acid-decomposable group; 20 to 50 mol % of (meth)acrylate repeating unit having a lactone structure; 5 to 30 mol % of (meth)acrylate repeating unit containing a hydroxy group or a cyano group; and 0 to 20 mol % of other (meth)acrylate repeating units is also preferred.

In the event of exposing the composition of the present invention to KrF excimer laser beams, electron beams, X-rays or high-energy light rays of wavelength 50 nm or less (EUV, etc.), it is preferred for the resin (A) to further have hydroxystyrene repeating units. More preferably, the resin has hydroxystyrene repeating units, hydroxystyrene repeating units protected by an acid-decomposable group and acid-decomposable repeating units of a (meth)acrylic acid tertiary alkyl ester, etc.

As preferred hydroxystyrene repeating units having an acid-decomposable group, there can be mentioned, for example, repeating units derived from t-butoxycarbonyloxystyrene, a 1-alkoxyethoxystyrene and a (meth)acrylic acid tertiary alkyl ester. Repeating units derived from a 2-alkyl-2-adamantyl (meth)acrylate and a dialkyl(1-adamantyl)methyl (meth)acrylate are more preferred.

The resin (A) of the present invention can be synthesized by conventional techniques (for example, radical polymerization). As general synthetic methods, there can be mentioned, for example, a batch polymerization method in which a monomer species and an initiator are dissolved in a solvent and heated so as to accomplish polymerization and a dropping polymerization method in which a solution of monomer species and initiator is added by dropping to a heated solvent over a period of 1 to 10 hours. The dropping polymerization method is preferred. As a reaction solvent, there can be mentioned, for example, an ether, such as tetrahydrofuran, 1,4-dioxane or diisopropyl ether; a ketone, such as methyl ethyl ketone or methyl isobutyl ketone; an ester solvent, such as ethyl acetate; an amide solvent, such as dimethylformamide or dimethylacetamide; or the solvent capable of dissolving the composition of the present invention, such as propylene glycol monomethyl ether acetate, propylene glycol monomethyl ether or cyclohexanone, to be described hereinafter. It is preferred to perform the polymerization with the use of the same solvent as employed in the actinic-ray- or radiation-sensitive resin composition of the present invention. This would inhibit any particle generation during storage.

The polymerization reaction is preferably carried out in an atmosphere of inert gas, such as nitrogen or argon. The polymerization is initiated by the use of a commercially available radical initiator (azo initiator, peroxide, etc.) as a polymerization initiator. Among the radical initiators, an azo initiator is preferred. An azo initiator having an ester group, a cyano group or a carboxyl group is especially preferred. As preferred initiators, there can be mentioned azobisisobutyronitrile, azobisdimethylvaleronitrile, dimethyl 2,2′-azobis(2-methylpropionate) and the like. According to necessity, a supplementation of initiator or divided addition thereof may be effected. After the completion of the reaction, the reaction mixture is poured into a solvent. The desired polymer is recovered by a method for powder or solid recovery, etc. The concentration during the reaction is in the range of 5 to 50 mass %, preferably 10 to 30 mass %. The reaction temperature is generally in the range of 10° to 150° C., preferably 30° to 120° C. and more preferably 60° to 100° C.

Further, the operation of dissolving a synthesized resin in a solvent to thereby obtain a solution and heating the solution at about 30 to 90° C. for about 30 minutes to 4 hours as described in, for example, JP-A-2009-037108 may be added in order to inhibit any aggregation, etc. of the resin after the preparation of the composition.

The weight average molecular weight of the resin (A) in terms of polystyrene molecular weight as measured by GPC is preferably in the range of 1000 to 200,000, more preferably 2000 to 20,000, still more preferably 3000 to 15,000 and further preferably 5000 to 13,000. The regulation of the weight average molecular weight to 1000 to 200,000 would prevent deteriorations of heat resistance and dry etching resistance and also prevent deterioration of developability and increase of viscosity leading to poor film forming property.

Use is made of the resin whose dispersity (molecular weight distribution) is usually in the range of 1 to 3, preferably 1 to 2.6, more preferably 1 to 2 and most preferably 1.4 to 2.0. The lower the molecular weight distribution, the more excellent the resolving power and resist profile and the smoother the side wall of the resist pattern to thereby attain an excellence in roughness.

The resin (A) of the present invention may either be used individually or in combination.

In the present invention, the content ratio of the resin (A) based on the total solid content of the whole composition is preferably in the range of 30 to 99 mass %, and more preferably 60 to 95 mass %.

<Compound that when Exposed to Actinic Rays or Radiation, Generates an Acid.>

The composition of the present invention contains a compound that when exposed to actinic rays or radiation, generates an acid (hereinafter referred to as an “acid generator”).

As the acid generator, use can be made of a member appropriately selected from among a photoinitiator for photocationic polymerization, a photoinitiator for photoradical polymerization, a photo-achromatic agent and photo-discoloring agent for dyes, any of publicly known compounds that generate an acid when exposed to actinic rays or radiation employed in microresists, etc., and mixtures thereof.

As the acid generator, a diazonium salt, a phosphonium salt, a sulfonium salt, an iodonium salt, an imide sulfonate, an oxime sulfonate, diazosulfone, disulfone and o-nitrobenzyl sulfonate can be exemplified.

Further, use can be made of compounds obtained by introducing any of the above groups or compounds that generate an acid when exposed to actinic rays or radiation in a polymer principal chain or side chain, for example, compounds described in U.S. Pat. No. 3,849,137, DE 3914407, JP-A's-63-26653, 55-164824, 62-69263, 63-146038, 63-163452, 62-153853, 63-146029, etc.

Furthermore, use can be made of compounds that generate an acid when exposed to light described in U.S. Pat. No. 3,779,778, EP 126,712, etc.

As preferred compounds among the acid generators, those represented by the following general formulae (ZI), (ZII) and (ZIII) can be exemplified.

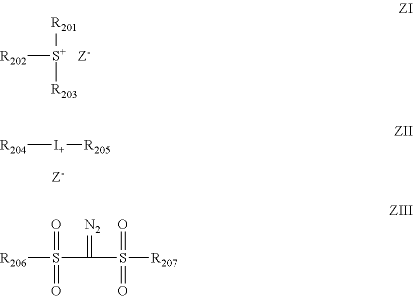

In the above general formula (ZI), each of R₂₀₁, R₂₀₂ and R₂₀₃ independently represents an organic group.

The number of carbon atoms in the organic group represented by R₂₀₁, R₂₀₂ and R₂₀₃ is generally in the range of 1 to 30, preferably 1 to 20.

Two of R₂₀₁ to R₂₀₃ may be bonded to each other via a single bond or a connecting group to thereby form a ring structure. As the connecting group, there can be mentioned, for example, an ether bond, a thioether bond, an ester bond, an amido bond, a carbonyl group, a methylene group or an ethylene group. As the group formed by the mutual bonding of two of R₂₀₁ to R₂₀₃, there can be mentioned, for example, an alkylene group, such as a butylene group or a pentylene group.

Z⁻ represents a nonnucleophilic anion.

As the nonnucleophilic anion represented by Z⁻, a sulfonate anion, a carboxylate anion, a sulfonylimido anion, a bis(alkylsulfonyl)imido anion, and a tris(alkylsulfonyl)methyl anion can be exemplified.

The nonnucleophilic anion means an anion whose capability of inducing a nucleophilic reaction is extremely low. Any decomposition over time attributed to an intramolecular nucleophilic reaction can be suppressed by the use of this anion. Therefore, when this anion is used, the stability over time of the relevant composition and the film formed therefrom can be enhanced.

As the sulfonate anion, an aliphatic sulfonate anion, an aromatic sulfonate anion, and a camphor sulfonate anion can be exemplified.

As the carboxylate anion, an aliphatic carboxylate anion, an aromatic carboxylate anion, and an aralkyl carboxylate anion can be exemplified.

The aliphatic moiety of the aliphatic sulfonate anion may be an alkyl group or a cycloalkyl group, being preferably an alkyl group having 1 to 30 carbon atoms or a cycloalkyl group having 3 to 30 carbon atoms. As such, a methyl group, an ethyl group, a propyl group, an isopropyl group, an n-butyl group, an isobutyl group, a sec-butyl group, a pentyl group, a neopentyl group, a hexyl group, a heptyl group, an octyl group, a nonyl group, a decyl group, an undecyl group, a dodecyl group, a tridecyl group, a tetradecyl group, a pentadecyl group, a hexadecyl group, a heptadecyl group, an octadecyl group, a nonadecyl group, an eicosyl group, a cyclopropyl group, a cyclopentyl group, a cyclohexyl group, an adamantyl group, a norbornyl group and a bornyl group can be exemplified.

As a preferred aromatic group of the aromatic sulfonate anion, an aryl group having 6 to 14 carbon atoms, such as a phenyl group, a tolyl group and a naphthyl group can be exemplified.

The alkyl group, cycloalkyl group and aryl group of the aliphatic sulfonate anion and aromatic sulfonate anion may have one or more substituents. As the substituent of the alkyl group, cycloalkyl group and aryl group of the aliphatic sulfonate anion and aromatic sulfonate anion, a nitro group, a halogen atom (fluorine atom, chlorine atom, bromine atom or iodine atom), a carboxy group, a hydroxy group, an amino group, a cyano group, an alkoxy group (preferably having 1 to 15 carbon atoms), a cycloalkyl group (preferably having 3 to 15 carbon atoms), an aryl group (preferably having 6 to 14 carbon atoms), an alkoxycarbonyl group (preferably having 2 to 7 carbon atoms), an acyl group (preferably having 2 to 12 carbon atoms), an alkoxycarbonyloxy group (preferably having 2 to 7 carbon atoms), an alkylthio group (preferably having 1 to 15 carbon atoms), an alkylsulfonyl group (preferably having 1 to 15 carbon atoms), an alkyliminosulfonyl group (preferably having 2 to 15 carbon atoms), an aryloxysulfonyl group (preferably having 6 to 20 carbon atoms), an alkylaryloxysulfonyl group (preferably having 7 to 20 carbon atoms), a cycloalkylaryloxysulfonyl group (preferably having 10 to 20 carbon atoms), an alkyloxyalkyloxy group (preferably having 5 to 20 carbon atoms), and a cycloalkylalkyloxyalkyloxy group (preferably having 8 to 20 carbon atoms) can be exemplified. The aryl group or ring structure of these groups may further have an alkyl group (preferably having 1 to 15 carbon atoms) as its substituent.

As the aliphatic moiety of the aliphatic carboxylate anion, the same alkyl groups and cycloalkyl groups as mentioned with respect to the aliphatic sulfonate anion can be exemplified.

As the aromatic group of the aromatic carboxylate anion, the same aryl groups as mentioned with respect to the aromatic sulfonate anion can be exemplified.

As a preferred aralkyl group of the aralkyl carboxylate anion, an aralkyl group having 6 to 12 carbon atoms, such as a benzyl group, a phenethyl group, a naphthylmethyl group, a naphthylethyl group, and a naphthylbutyl group can be exemplified.

The alkyl group, cycloalkyl group, aryl group and aralkyl group of the aliphatic carboxylate anion, aromatic carboxylate anion and aralkyl carboxylate anion may have one or more substituents. As the substituent of the alkyl group, cycloalkyl group, aryl group and aralkyl group of the aliphatic carboxylate anion, aromatic carboxylate anion and aralkyl carboxylate anion, the same halogen atom, alkyl group, cycloalkyl group, alkoxy group, and alkylthio group, etc. as mentioned with respect to the aromatic sulfonate anion can be exemplified.

As the sulfonylimido anion, a saccharin anion can be exemplified.

The alkyl group of the bis(alkylsulfonyl)imido anion and tris(alkylsulfonyl)methyl anion is preferably an alkyl group having 1 to 5 carbon atoms. As such, a methyl group, an ethyl group, a propyl group, an isopropyl group, an n-butyl group, an isobutyl group, a sec-butyl group, a pentyl group, and a neopentyl group can be exemplified. As a substituent of these alkyl groups, a halogen atom, an alkyl group substituted with a halogen atom, an alkoxy group, an alkylthio group, an alkyloxysulfonyl group, an aryloxysulfonyl group, and a cycloalkylaryloxysulfonyl group can be exemplified. An alkyl group substituted with one or more fluorine atoms is preferred.

As the other nonnucleophilic anions, there can be mentioned, for example, phosphorus fluoride, boron fluoride, antimony fluoride and the like.

The nonnucleophilic anion represented by Z⁻ is preferably selected from among an aliphatic sulfonate anion substituted at its α-position of sulfonic acid with a fluorine atom, an aromatic sulfonate anion substituted with one or more fluorine atoms or a group having a fluorine atom, a bis(alkylsulfonyl)imido anion whose alkyl group is substituted with one or more fluorine atoms and a tris(alkylsulfonyl)methide anion whose alkyl group is substituted with one or more fluorine atoms. More preferably, the nonnucleophilic anion is a perfluorinated aliphatic sulfonate anion having 4 to 8 carbon atoms or a benzene sulfonate anion having a fluorine atom. Still more preferably, the nonnucleophilic anion is a nonafluorobutane sulfonate anion, a perfluorooctane sulfonate anion, a pentafluorobenzene sulfonate anion or a 3,5-bis(trifluoromethyl)benzene sulfonate anion.

The non-nucleophilic anion represented by Z⁻ is preferably expressed by, for example, general formula (LD1) below:

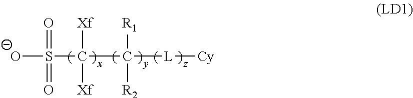

In the formula,

each of Xf's independently represents a fluorine atom or an alkyl group substituted with at least one fluorine atom.

Each of R₁ and R₂ independently represents a group selected from the group consisting of a hydrogen atom, a fluorine atom, an alkyl group and an alkyl group substituted with at least one fluorine atom. When two or more R¹s or R²s are contained, the two or more may be identical to or different from each other.

L, or each of L's independently, represents a single bond or a bivalent connecting group.

Cy represents a group with a cyclic structure.

In the formula, x is an integer of 1 to 20,

y is an integer of 0 to 10, and

z is an integer of 0 to 10.

Xf represents a fluorine atom or an alkyl group substituted with at least one fluorine atom. The alkyl group preferably has 1 to 10 carbon atoms, more preferably 1 to 4 carbon atoms. The alkyl group substituted with at least one fluorine atom is preferably a perfluoroalkyl group.

Xf is preferably a fluorine atom or a perfluoroalkyl group having 1 to 4 carbon atoms. In particular, Xf is preferably a fluorine atom, CF₃, C₂F₅, C₃F₇, C₄F₉, C₅F₁₁, C₆F₁₃, C₇F₁₅, C₈F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉ or CH₂CH₂C₄F₉.

Each of R₁ and R₂ independently represents a group selected from the group consisting of a hydrogen atom, a fluorine atom, an alkyl group and an alkyl group substituted with at least one fluorine atom. Each of the alkyl group and the alkyl group of the alkyl group substituted with at least one fluorine atom preferably has 1 to 4 carbon atoms. More preferably, each of R₁ and R₂ is a perfluoroalkyl group having 1 to 4 carbon atoms. In particular, there can be mentioned, for example, CF₃, C₂F₅, C₃F₇, C₄F₉, C₅F₁₁, C₆F₁₃, C₇F₁₅, C₈F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉ or CH₂CH₂C₄F₉. Of these, CF₃ is preferred.

L represents a single bond or a bivalent connecting group. As the bivalent connecting group, there can be mentioned, for example, —COO—, —OCO—, —CONH—, —CO—, —O—, —S—, —SO—, —SO₂—, an alkylene group, a cycloalkylene group or an alkenylene group. Of these, —COO—, —OCO—, —CONH—, —CO—, —O— and —SO₂— are preferred. —COO—, —OCO—, —CONH— and —SO₂— are more preferred.

Cy represents a group with a cyclic structure. As the group with a cyclic structure, there can be mentioned, for example, an alicyclic group, an aryl group or a group with a heterocyclic structure.

The alicyclic group may be monocyclic or polycyclic. As the alicyclic group that is monocyclic, there can be mentioned, for example, a monocycloalkyl group, such as a cyclopentyl group, a cyclohexyl group or a cyclooctyl group. As the alicyclic group that is polycyclic, there can be mentioned, for example, a polycycloalkyl group, such as a norbornyl group, a tricyclodecanyl group, a tetracyclodecanyl group, a tetracyclododecanyl group or an adamantyl group. Of the mentioned groups, alicyclic groups with a bulky structure having at least 7 carbon atoms, such as a norbornyl group, a tricyclodecanyl group, a tetracyclodecanyl group, a tetracyclododecanyl group and an adamantyl group, are preferred from the viewpoint of inhibition of any in-film diffusion in the PEB (post-exposure bake) operation and enhancement of MEEF (Mask Error Enhancement Factor).

The aryl group may be monocyclic or polycyclic. As the aryl group, there can be mentioned, for example, a phenyl group, a naphthyl group, a phenanthryl group or an anthryl group. Of these, a naphthyl group exhibiting a relatively low light absorbance at 193 nm is preferred.

The group with a heterocyclic structure may be monocyclic or polycyclic. The polycyclic structure is superior in the inhibition of any acid diffusion. It is optional for the group with a heterocyclic structure to have aromaticity. As the heterocycle having aromaticity, there can be mentioned, for example, a furan ring, a thiophene ring, a benzofuran ring, a benzothiophene ring, a dibenzofuran ring, a dibenzothiophene ring or a pyridine ring. As the heterocycle having no aromaticity, there can be mentioned, for example, a tetrahydropyran ring, a lactone ring or a decahydroisoquinoline ring. It is especially preferred for the heterocycle of the group with a heterocyclic structure to be a furan ring, a thiophene ring, a pyridine ring or a decahydroisoquinoline ring.

A substituent may be introduced in the above group with a cyclic structure. As the substituent, there can be mentioned, for example, an alkyl group, a cycloalkyl group, an aryl group, a hydroxyl group, an alkoxy group, an ester group, an amido group, a urethane group, a ureido group, a thioether group, a sulfonamido group or a sulfonic ester group. The alkyl group may be in the form of a linear or branched chain. It is preferred for the alkyl group to have 1 to 12 carbon atoms. The cycloalkyl group may be monocyclic or polycyclic. It is preferred for the cycloalkyl group to have 3 to 12 carbon atoms. The aryl group preferably has 6 to 14 carbon atoms.

In the formula, x is preferably 1 to 8, more preferably 1 to 4 and most preferably 1; y is preferably 0 to 4, more preferably 0; and z is preferably 0 to 8, more preferably 0 to 4.

Also, the non-nucleophilic anion represented by Z⁻ is preferably expressed by, for example, general formula (LD2) below.

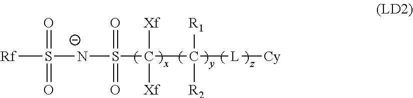

In general formula (LD2), Xf, R₁, R₂, L, Cy, x, y and z are as defined above in connection with general formula (LD1). Rf is a group containing a fluorine atom.

As the group containing a fluorine atom represented by Rf, there can be mentioned, for example, an alkyl group containing at least one fluorine atom, a cycloalkyl group containing at least one fluorine atom or an aryl group containing at least one fluorine atom.

These alkyl group, cycloalkyl group and aryl group may be those substituted with a fluorine atom, or those substituted with another substituent containing a fluorine atom. When Rf is a cycloalkyl group containing at least one fluorine atom or an aryl group containing at least one fluorine atom, the other substituent containing a fluorine atom can be, for example, an alkyl group substituted with at least one fluorine atom.

Further, these alkyl group, cycloalkyl group and aryl group may further be substituted with a substituent containing no fluorine atom. As this substituent, there can be mentioned, for example, any of those mentioned above with respect to Cy wherein no fluorine atom is contained.

As the alkyl group containing at least one fluorine atom represented by Rf, there can be mentioned, for example, any of those mentioned hereinbefore as the alkyl group substituted with at least one fluorine atom, represented by Xf. As the cycloalkyl group containing at least one fluorine atom represented by Rf, there can be mentioned, for example, a perfluorocyclopentyl group or a perfluorocyclohexyl group. As the aryl group containing at least one fluorine atom represented by Rf, there can be mentioned, for example, a perfluorophenyl group.

As the organic groups represented by R₂₀₁, R₂₀₂ and R₂₀₃, there can be mentioned, for example, the corresponding groups of compounds (ZI-1), (ZI-2), (ZI-3) or (ZI-4) to be described hereinafter.

Compounds having two or more of the structures of the general formula (ZI) may be used as the acid generator. For example, use may be made of a compound having a structure in which at least one of the R₂₀₁ to R₂₀₃ of one of the compounds of the general formula (ZI) is bonded to at least one of the R₂₀₁ to R₂₀₃ of another of the compounds of the general formula (ZI).

As preferred (ZI) components, the following compounds (ZI-1) to (ZI-4) can be exemplified.

The compounds (ZI-1) are arylsulfonium compounds of the general formula (ZI) wherein at least one of R₂₀₁ to R₂₀₃ is an aryl group, namely, compounds containing an arylsulfonium as a cation.

In the arylsulfonium compounds, all of the R₂₀₁ to R₂₀₃ may be aryl groups. It is also appropriate that the R₂₀₁ to R₂₀₃ are partially an aryl group and the remainder is an alkyl group or a cycloalkyl group.

As the arylsulfonyl compound, there can be mentioned, for example, a triarylsulfonium compound, a diarylalkylsulfonium compound, an aryldialkylsulfonium compound, a diarylcycloalkylsulfonium compound and an aryldicycloalkylsulfonium compound.

The aryl group of the arylsulfonium compounds is preferably a phenyl group or a naphthyl group, more preferably a phenyl group. The aryl group may be one having a heterocyclic structure containing an oxygen atom, nitrogen atom, sulfur atom or the like. As the heterocyclic structure, there can be mentioned, for example, a pyrrole, a furan, a thiophene, an indole, a benzofuran and a benzothiophene. When the arylsulfonium compound has two or more aryl groups, the two or more aryl groups may be identical to or different from each other.

The alkyl group or cycloalkyl group contained in the arylsulfonium compound according to necessity is preferably a linear or branched alkyl group having 1 to 15 carbon atoms or a cycloalkyl group having 3 to 15 carbon atoms. As such, a methyl group, an ethyl group, a propyl group, an n-butyl group, a sec-butyl group, a t-butyl group, a cyclopropyl group, a cyclobutyl group, and a cyclohexyl group can be exemplified.

The aryl group, alkyl group or cycloalkyl group represented by R₂₀₁ to R₂₀₃ may have one or more substituents. As the substituent, an alkyl group (for example, 1 to 15 carbon atoms), a cycloalkyl group (for example, 3 to 15 carbon atoms), an aryl group (for example, 6 to 14 carbon atoms), an alkoxy group (for example, 1 to 15 carbon atoms), a halogen atom, a hydroxy group, and a phenylthio group can be exemplified. Preferred substituents are a linear or branched alkyl group having 1 to 12 carbon atoms, a cycloalkyl group having 3 to 12 carbon atoms and a linear, branched or cyclic alkoxy group having 1 to 12 carbon atoms. More preferred substituents are an alkyl group having 1 to 6 carbon atoms and an alkoxy group having 1 to 6 carbon atoms. The substituents may be contained in any one of the three R₂₀₁ to R₂₀₃, or alternatively may be contained in all three of R₂₀₁ to R₂₀₃. When R₂₀₁ to R₂₀₃ represent a phenyl group, the substituent preferably lies at the p-position of the phenyl group.

Now, the compounds (ZI-2) will be described.

The compounds (ZI-2) are compounds represented by the formula (ZI) wherein each of R₂₀₁ to R₂₀₃ independently represents an organic group having no aromatic ring. The aromatic rings include an aromatic ring having a heteroatom.

The organic group having no aromatic ring represented by R₂₀₁ to R₂₀₃ generally has 1 to 30 carbon atoms, preferably 1 to 20 carbon atoms.

Preferably, each of R₂₀₁ to R₂₀₃ independently represents an alkyl group, a 2-oxoalkyl group, an alkoxycarbonylmethyl group, an allyl group, and a vinyl group. More preferred groups include a linear or branched 2-oxoalkyl group and an alkoxycarbonylmethyl group. Especially preferred is a linear or branched 2-oxoalkyl group.

As preferred alkyl groups and cycloalkyl groups represented by R₂₀₁ to R₂₀₃, a linear or branched alkyl group having 1 to 10 carbon atoms (for example, a methyl group, an ethyl group, a propyl group, a butyl group or a pentyl group) and a cycloalkyl group having 3 to 10 carbon atoms (for example, a cyclopentyl group, a cyclohexyl group or a norbornyl group) can be exemplified. As more preferred alkyl groups, a 2-oxoalkyl group and an alkoxycarbonylmethyl group can be exemplified. As more preferred cycloalkyl group, a 2-oxocycloalkyl group can be exemplified.

The 2-oxoalkyl group may be linear or branched. A group having >C═O at the 2-position of the above-described alkyl group can be preferably exemplified.

The 2-oxocycloalkyl group is preferably a group having >C═O at the 2-position of the above-described cycloalkyl group.

As preferred alkoxy groups of the alkoxycarbonylmethyl group, alkoxy groups having 1 to 5 carbon atoms can be exemplified. As such, there can be mentioned, for example, a methoxy group, an ethoxy group, a propoxy group, a butoxy group and a pentoxy group.

The organic groups containing no aromatic ring represented by R₂₀₁ to R₂₀₃ may further have one or more substituents. As the substituents, a halogen atom, an alkoxy group (having, for example, 1 to 5 carbon atoms), a hydroxy group, a cyano group and a nitro group can be exemplified.

Now the compounds (ZI-3) will be described. The compounds (ZI-3) are those represented by the following general formula (ZI-3) which have a phenacylsulfonium salt structure.

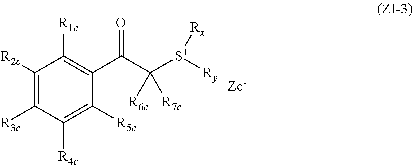

In the formula (ZI-3),

each of R_{1c} to R_{5c} independently represents a hydrogen atom, an alkyl group, a cycloalkyl group, an alkoxy group, a halogen atom, or a phenylthio group.

Each of R_{6c} and R_{7c} independently represents a hydrogen atom, an alkyl group, a cycloalkyl group, halogen atom, a cyano group or an aryl group.

Each of Rₓ and R_{y} independently represents an alkyl group, a cycloalkyl group, a 2-oxoalkyl group, a 2-oxocycloalkyl group, an alkoxycarbonylalkyl group, an allyl group or a vinyl group.

Any two or more of R_{1c} to R_{5c}, and R_{6c} and R_{7c}, and Rₓ and R_{y} may be bonded with each other to thereby form a ring structure. This ring structure may contain an oxygen atom, a sulfur atom, an ester bond or an amido bond. As the group formed by bonding of any two or more of R_{1c} to R_{5c}, and R_{6c} and R_{7c}, and Rₓ and R_{y}, there can be mentioned a butylene group, a pentylene group or the like.

Zc⁻ represents a nonnucleophilic anion. There can be mentioned the same nonnucleophilic anions as mentioned with respect to the Z⁻ of the general formula (ZI).

The alkyl group represented by R_{1c} to R_{7c} may be linear or branched. As such, there can be mentioned, for example, an alkyl group having 1 to 20 carbon atoms, preferably a linear or branched alkyl group having 1 to 12 carbon atoms (for example, a methyl group, an ethyl group, a linear or branched propyl group, a linear or branched butyl group or a linear or branched pentyl group). As the cycloalkyl group, there can be mentioned, for example, a cycloalkyl group having 3 to 8 carbon atoms (for example, a cyclopentyl group or a cyclohexyl group).

The alkoxy group represented by R_{1c} to R_{5c} may be linear, or branched, or cyclic. As such, there can be mentioned, for example, an alkoxy group having 1 to 10 carbon atoms, preferably a linear or branched alkoxy group having 1 to 5 carbon atoms (for example, a methoxy group, an ethoxy group, a linear or branched propoxy group, a linear or branched butoxy group or a linear or branched pentoxy group) and a cycloalkoxy group having 3 to 8 carbon atoms (for example, a cyclopentyloxy group or a cyclohexyloxy group).

Preferably, any one of R_{1c} to R_{5c} is a linear or branched alkyl group, a cycloalkyl group or a linear, branched or cyclic alkoxy group. More preferably, the sum of carbon atoms of R_{1c} to R_{5c} is in the range of 2 to 15. Accordingly, there can be attained an enhancement of solvent solubility and inhibition of particle generation during storage.

Each of the aryl groups represented by R_{6c} and R_{7c} preferably has 5 to 15 carbon atoms. As such, there can be mentioned, for example, a phenyl group or a naphthyl group.

When R_{6c} and R_{7c} are bonded to each other to thereby form a ring, the group formed by the bonding of R_{6c} and R_{7c} is preferably an alkylene group having 2 to 10 carbon atoms. As such, there can be mentioned, for example, an ethylene group, a propylene group, a butylene group, a pentylene group, a hexylene group or the like. Further, the ring formed by the bonding of R_{6c} and R_{7c} may have a heteroatom, such as an oxygen atom, in the ring.

As the alkyl groups and cycloalkyl groups represented by Rₓ and R_{y}, there can be mentioned the same alkyl groups and cycloalkyl groups as set forth above with respect to R_{1c} to R_{7c}.

As the 2-oxoalkyl group and 2-oxocycloalkyl group, there can be mentioned the alkyl group and cycloalkyl group represented by R_{1c} to R_{7c} having >C═O at the 2-position thereof.

With respect to the alkoxy group of the alkoxycarbonylalkyl group, there can be mentioned the same alkoxy groups as mentioned above with respect to R_{1c} to R_{5c}. As the alkyl group thereof, there can be mentioned, for example, an alkyl group having 1 to 12 carbon atoms, preferably a linear alkyl group having 1 to 5 carbon atoms (e.g., a methyl group or an ethyl group).

The allyl groups are not particularly limited. However, preferred use is made of an unsubstituted allyl group or an allyl group substituted with a cycloalkyl group of a single ring or multiple rings.

The vinyl groups are not particularly limited. However, preferred use is made of an unsubstituted vinyl group or a vinyl group substituted with a cycloalkyl group of a single ring or multiple rings.

As the ring structure that may be formed by the mutual bonding of Rₓ and R_{y}, there can be mentioned a 5-membered or 6-membered ring, especially preferably a 5-membered ring (namely, a tetrahydrothiophene ring), formed by bivalent Rₓ and R_{y} (for example, a methylene group, an ethylene group, a propylene group or the like) in cooperation with the sulfur atom of general formula (ZI-3).

Each of Rₓ and R_{y} is preferably an alkyl group or cycloalkyl group having preferably 4 or more carbon atoms. The alkyl group or cycloalkyl group has more preferably 6 or more carbon atoms and still more preferably 8 or more carbon atoms.

Specific examples of the cation part in the compound (ZI-3) will be described below.

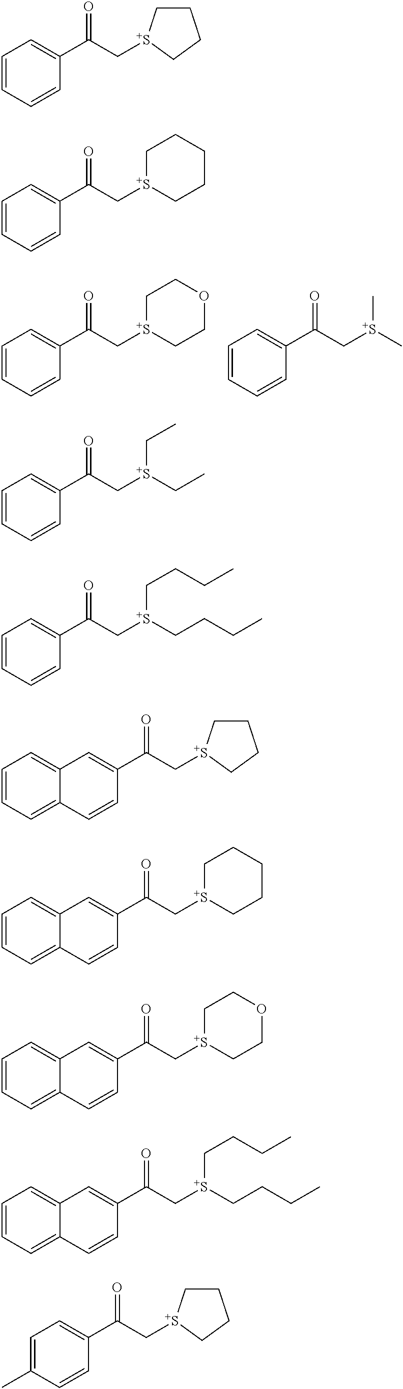

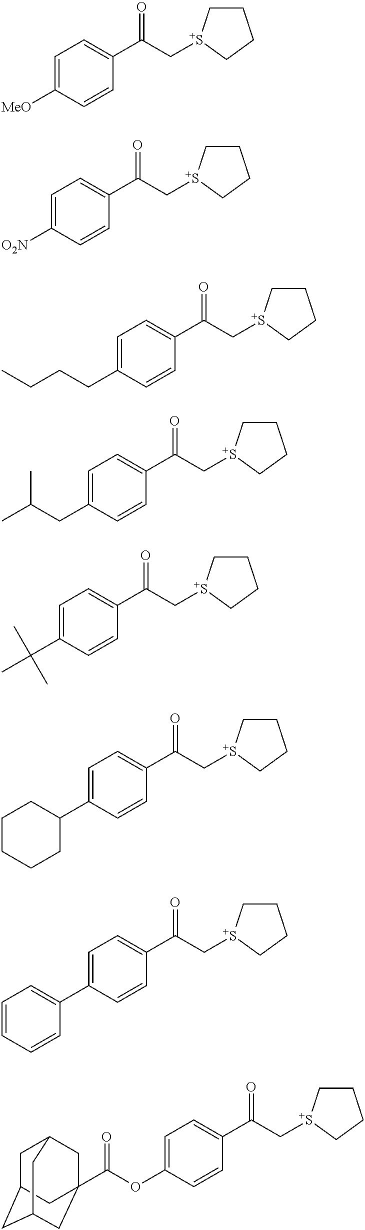

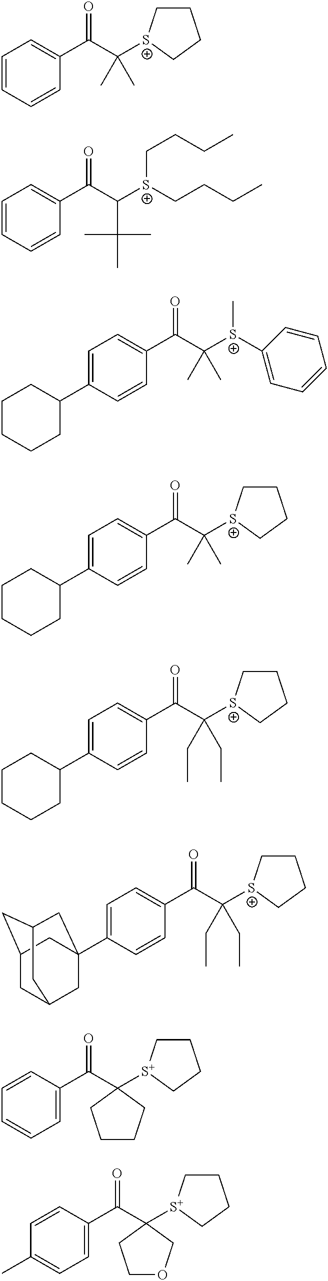

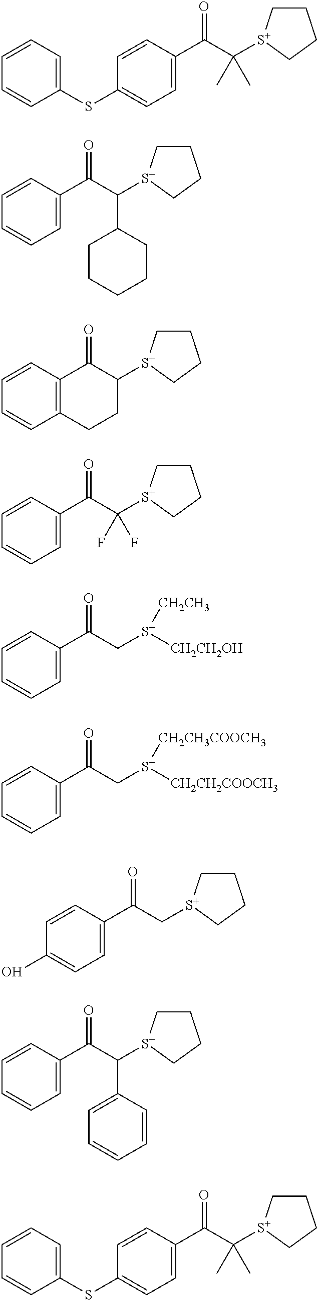

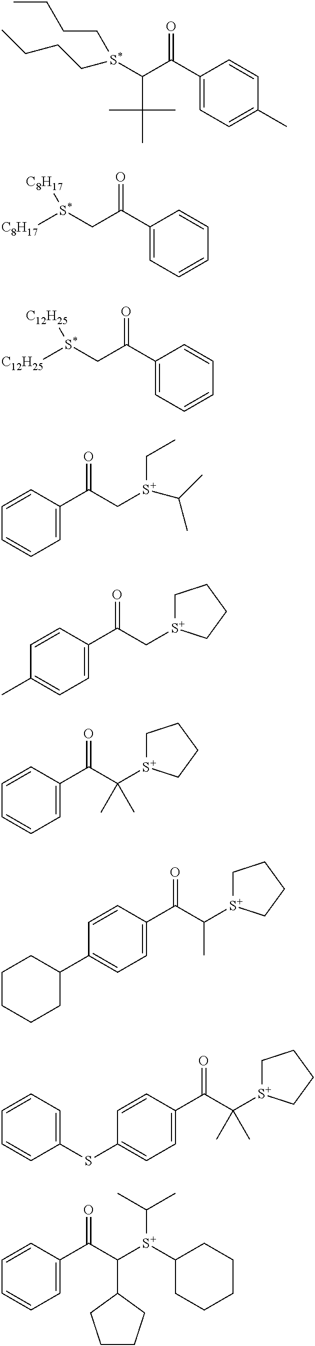

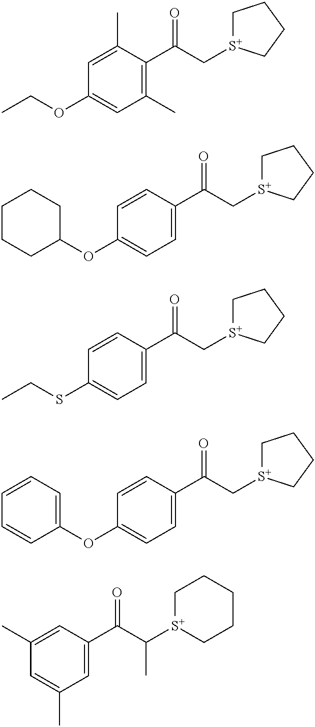 [SMILES: CCOc1cc(C)c(C(=O)C[S+]2CCCC2)c(C)c1 ; O=C(C[S+]1CCCC1)c1ccc(OC2CCCCC2)cc1 ; CCSc1ccc(C(=O)C[S+]2CCCC2)cc1 ; O=C(C[S+]1CCCC1)c1ccc(Oc2ccccc2)cc1 ; Cc1cc(C)cc(C(=O)C(C)[S+]2CCCCC2)c1]

The compounds (ZI-4) are those of general formula (ZI-4) below.

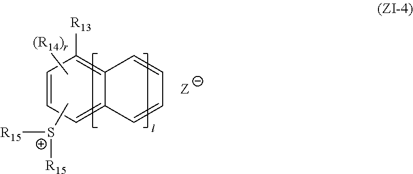

In general formula (ZI-4),

R₁₃ represents any of a hydrogen atom, a fluorine atom, a hydroxyl group, an alkyl group, a cycloalkyl group, an alkoxy group, an alkoxycarbonyl group and a group with a cycloalkyl skeleton of a single ring or multiple rings. These groups may have one or more substituents.

R₁₄, each independently in the instance of R₁₄s, represents any of an alkyl group, a cycloalkyl group, an alkoxy group, an alkoxycarbonyl group, an alkylcarbonyl group, an alkylsulfonyl group, a cycloalkylsulfonyl group and a group with a cycloalkyl skeleton of a single ring or multiple rings. These groups may have one or more substituents.

Each of R₁₅s independently represents an alkyl group, a cycloalkyl group or a naphthyl group, provided that the two R₁₅s may be bonded to each other to thereby form a ring. These groups may have one or more substituents.

In the formula, l is an integer of 0 to 2, and r is an integer of 0 to 8.

Z⁻ represents a nonnucleophilic anion. As such, there can be mentioned any of the same nonnucleophilic anions as mentioned with respect to the Z⁻ of the general formula (ZI).

In general formula (ZI-4), the alkyl groups represented by R₁₃, R₁₄ and R₁₅ may be linear or branched and preferably each have 1 to 10 carbon atoms. As such, there can be mentioned a methyl group, an ethyl group, an n-propyl group, an i-propyl group, an n-butyl group, a 2-methylpropyl group, a 1-methylpropyl group, a t-butyl group, an n-pentyl group, a neopentyl group, an n-hexyl group, an n-heptyl group, an n-octyl group, a 2-ethylhexyl group, an n-nonyl group, an n-decyl group and the like. Of these alkyl groups, a methyl group, an ethyl group, an n-butyl group, a t-butyl group and the like are preferred.

As the cycloalkyl groups represented by R₁₃, R₁₄ and R₁₅, there can be mentioned cyclopropyl, cyclobutyl, cyclopentyl, cyclohexyl, cycloheptyl, cyclooctyl, cyclododecanyl, cyclopentenyl, cyclohexenyl, cyclooctadienyl, norbornyl, tricyclodecanyl, tetracyclodecanyl, adamantyl and the like. Cyclopropyl, cyclopentyl, cyclohexyl and cyclooctyl are especially preferred.

The alkoxy groups represented by R₁₃ and R₁₄ may be linear or branched and preferably each have 1 to 10 carbon atoms. As such, there can be mentioned, for example, a methoxy group, an ethoxy group, an n-propoxy group, an i-propoxy group, an n-butoxy group, a 2-methylpropoxy group, a 1-methylpropoxy group, a t-butoxy group, an n-pentyloxy group, a neopentyloxy group, an n-hexyloxy group, an n-heptyloxy group, an n-octyloxy group, a 2-ethylhexyloxy group, an n-nonyloxy group, an n-decyloxy group and the like. Of these alkoxy groups, a methoxy group, an ethoxy group, an n-propoxy group, an n-butoxy group and the like are preferred.

The alkoxycarbonyl group represented by R₁₃ and R₁₄ may be linear or branched and preferably has 2 to 11 carbon atoms. As such, there can be mentioned, for example, a methoxycarbonyl group, an ethoxycarbonyl group, an n-propoxycarbonyl group, an i-propoxycarbonyl group, an n-butoxycarbonyl group, a 2-methylpropoxycarbonyl group, a 1-methylpropoxycarbonyl group, a t-butoxycarbonyl group, an n-pentyloxycarbonyl group, a neopentyloxycarbonyl group, an n-hexyloxycarbonyl group, an n-heptyloxycarbonyl group, an n-octyloxycarbonyl group, a 2-ethylhexyloxycarbonyl group, an n-nonyloxycarbonyl group, an n-decyloxycarbonyl group and the like. Of these alkoxycarbonyl groups, a methoxycarbonyl group, an ethoxycarbonyl group, an n-butoxycarbonyl group and the like are preferred.

As the groups with a cycloalkyl skeleton of a single ring or multiple rings represented by R₁₃ and R₁₄, there can be mentioned, for example, a cycloalkyloxy group of a single ring or multiple rings and an alkoxy group with a cycloalkyl group of a single ring or multiple rings. These groups may further have one or more substituents.

With respect to each of the cycloalkyloxy groups of a single ring or multiple rings represented by R₁₃ and R₁₄, the sum of carbon atoms thereof is preferably 7 or greater, more preferably in the range of 7 to 15. Further, having a cycloalkyl skeleton of a single ring is preferred. The cycloalkyloxy group of a single ring of which the sum of carbon atoms is 7 or greater is one composed of a cycloalkyloxy group, such as a cyclopropyloxy group, a cyclobutyloxy group, a cyclopentyloxy group, a cyclohexyloxy group, a cycloheptyloxy group, a cyclooctyloxy group or a cyclododecanyloxy group, optionally having a substituent selected from among an alkyl group such as methyl, ethyl, propyl, butyl, pentyl, hexyl, heptyl, octyl, dodecyl, 2-ethylhexyl, isopropyl, sec-butyl, t-butyl or isoamyl, a hydroxyl group, a halogen atom (fluorine, chlorine, bromine or iodine), a nitro group, a cyano group, an amido group, a sulfonamido group, an alkoxy group such as methoxy, ethoxy, hydroxyethoxy, propoxy, hydroxypropoxy or butoxy, an alkoxycarbonyl group such as methoxycarbonyl or ethoxycarbonyl, an acyl group such as formyl, acetyl or benzoyl, an acyloxy group such as acetoxy or butyryloxy, a carboxyl group and the like, provided that the sum of carbon atoms thereof, including those of any optional substituent introduced in the cycloalkyl group, is 7 or greater.

As the cycloalkyloxy group of multiple rings of which the sum of carbon atoms is 7 or greater, there can be mentioned a norbornyloxy group, a tricyclodecanyloxy group, a tetracyclodecanyloxy group, an adamantyloxy group or the like.

With respect to each of the alkyloxy groups having a cycloalkyl skeleton of a single ring or multiple rings represented by R₁₃ and R₁₄, the sum of carbon atoms thereof is preferably 7 or greater, more preferably in the range of 7 to 15. Further, the alkoxy group having a cycloalkyl skeleton of a single ring is preferred. The alkoxy group having a cycloalkyl skeleton of a single ring of which the sum of carbon atoms is 7 or greater is one composed of an alkoxy group, such as methoxy, ethoxy, propoxy, butoxy, pentyloxy, hexyloxy, heptoxy, octyloxy, dodecyloxy, 2-ethylhexyloxy, isopropoxy, sec-butoxy, t-butoxy or isoamyloxy, substituted with the above optionally substituted cycloalkyl group of a single ring, provided that the sum of carbon atoms thereof, including those of the substituents, is 7 or greater. For example, there can be mentioned a cyclohexylmethoxy group, a cyclopentylethoxy group, a cyclohexylethoxy group or the like. A cyclohexylmethoxy group is preferred.

As the alkoxy group having a cycloalkyl skeleton of multiple rings of which the sum of carbon atoms is 7 or greater, there can be mentioned a norbornylmethoxy group, a norbornylethoxy group, a tricyclodecanylmethoxy group, a tricyclodecanylethoxy group, a tetracyclodecanylmethoxy group, a tetracyclodecanylethoxy group, an adamantylmethoxy group, an adamantylethoxy group and the like. Of these, a norbornylmethoxy group, a norbornylethoxy group and the like are preferred.

With respect to the alkyl group of the alkylcarbonyl group represented by R₁₄, there can be mentioned the same specific examples as mentioned above with respect to the alkyl groups represented by R₁₃ to R₁₅.

The alkylsulfonyl and cycloalkylsulfonyl groups represented by R₁₄ may be linear, branched or cyclic and preferably each have 1 to 10 carbon atoms. As such, there can be mentioned, for example, a methanesulfonyl group, an ethanesulfonyl group, an n-propanesulfonyl group, an n-butanesulfonyl group, a tert-butanesulfonyl group, an n-pentanesulfonyl group, a neopentanesulfonyl group, an n-hexanesulfonyl group, an n-heptanesulfonyl group, an n-octanesulfonyl group, a 2-ethylhexanesulfonyl group, an n-nonanesulfonyl group, an n-decanesulfonyl group, a cyclopentanesulfonyl group, a cyclohexanesulfonyl group and the like. Of these alkylsulfonyl and cycloalkylsulfonyl groups, a methanesulfonyl group, an ethanesulfonyl group, an n-propanesulfonyl group, an n-butanesulfonyl group, a cyclopentanesulfonyl group, a cyclohexanesulfonyl group and the like are preferred.

Each of the groups may have one or more substituents. As such substituents, there can be mentioned, for example, a halogen atom (e.g., a fluorine atom), a hydroxyl group, a carboxyl group, a cyano group, a nitro group, an alkoxy group, an alkoxyalkyl group, an alkoxycarbonyl group, an alkoxycarbonyloxy group or the like.

As the alkoxy group, there can be mentioned, for example, a linear, branched or cyclic alkoxy group having 1 to 20 carbon atoms, such as a methoxy group, an ethoxy group, an n-propoxy group, an i-propoxy group, an n-butoxy group, a 2-methylpropoxy group, a 1-methylpropoxy group, a t-butoxy group, a cyclopentyloxy group or a cyclohexyloxy group.

As the alkoxyalkyl group, there can be mentioned, for example, a linear, branched or cyclic alkoxyalkyl group having 2 to 21 carbon atoms, such as a methoxymethyl group, an ethoxymethyl group, a 1-methoxyethyl group, a 2-methoxyethyl group, a 1-ethoxyethyl group or a 2-ethoxyethyl group.

As the alkoxycarbonyl group, there can be mentioned, for example, a linear, branched or cyclic alkoxycarbonyl group having 2 to 21 carbon atoms, such as a methoxycarbonyl group, an ethoxycarbonyl group, an n-propoxycarbonyl group, an i-propoxycarbonyl group, an n-butoxycarbonyl group, a 2-methylpropoxycarbonyl group, a 1-methylpropoxycarbonyl group, a t-butoxycarbonyl group, a cyclopentyloxycarbonyl group or a cyclohexyloxycarbonyl group.

As the alkoxycarbonyloxy group, there can be mentioned, for example, a linear, branched or cyclic alkoxycarbonyloxy group having 2 to 21 carbon atoms, such as a methoxycarbonyloxy group, an ethoxycarbonyloxy group, an n-propoxycarbonyloxy group, an i-propoxycarbonyloxy group, an n-butoxycarbonyloxy group, a t-butoxycarbonyloxy group, a cyclopentyloxycarbonyloxy group or a cyclohexyloxycarbonyloxy group.

The cyclic structure that may be formed by the bonding of the two R₁₅s to each other is preferably a 5- or 6-membered ring, especially a 5-membered ring (namely, a tetrahydrothiophene ring) formed by two bivalent R₁₅s in cooperation with the sulfur atom of general formula (ZI-4). The cyclic structure may condense with an aryl group or a cycloalkyl group. The bivalent R₁₅s may have substituents. As such substituents, there can be mentioned, for example, a hydroxyl group, a carboxyl group, a cyano group, a nitro group, an alkoxy group, an alkoxyalkyl group, an alkoxycarbonyl group, an alkoxycarbonyloxy group and the like as mentioned above. It is especially preferred for the R₁₅ of general formula (ZI-4) to be a methyl group, an ethyl group, the above-mentioned bivalent group allowing two R₁₅s to be bonded to each other so as to form a tetrahydrothiophene ring structure in cooperation with the sulfur atom of the general formula (ZI-4), or the like.

Each of R₁₃ and R₁₄ may have one or more substituents. As such substituents, there can be mentioned, for example, a hydroxyl group, an alkoxy group, an alkoxycarbonyl group, a halogen atom (especially, a fluorine atom) or the like.

In the formula, 1 is preferably 0 or 1, more preferably 1, and r is preferably 0 to 2.

Specific examples of the cation part in the compound (ZI-4) will be shown below.

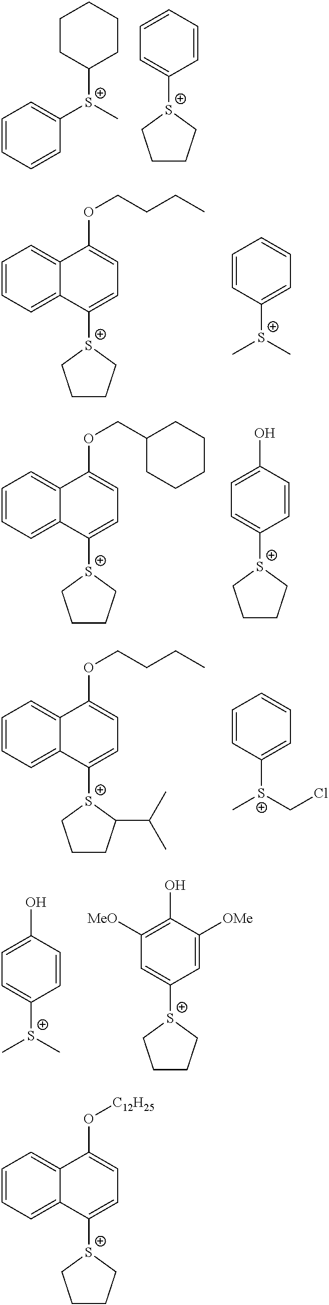

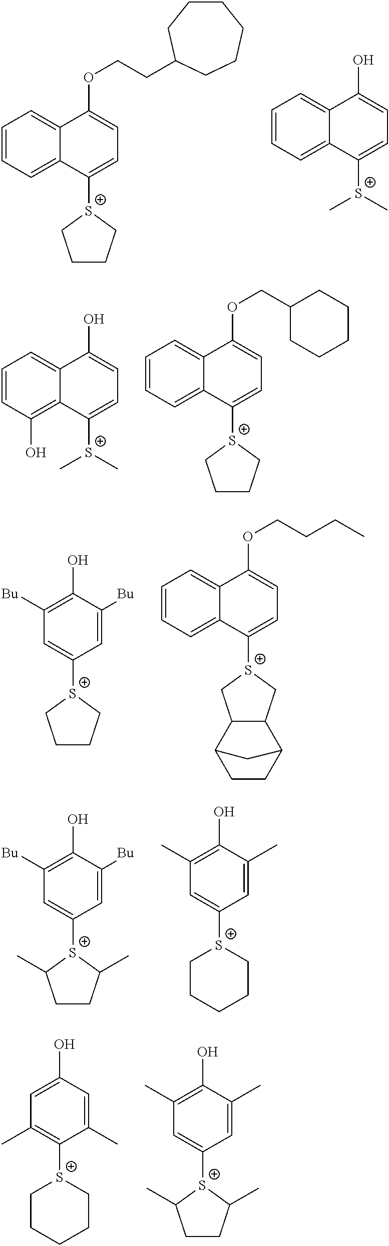

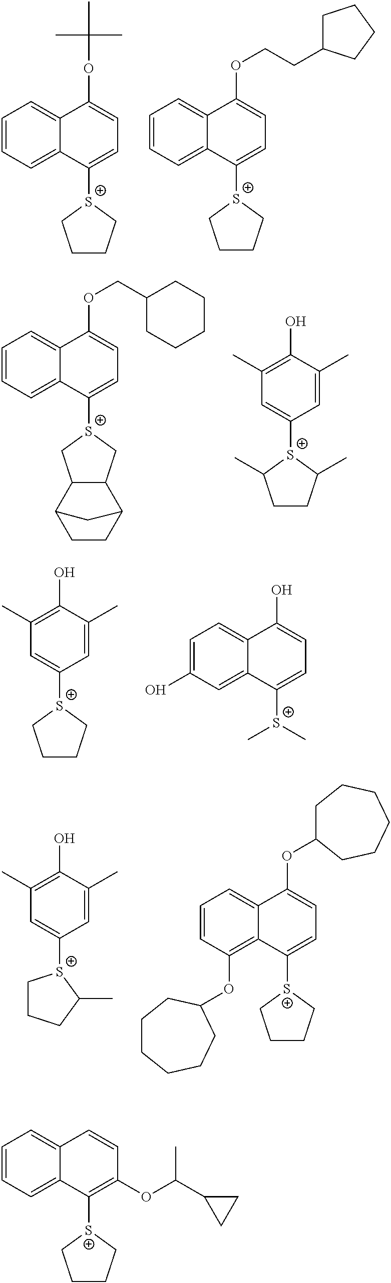

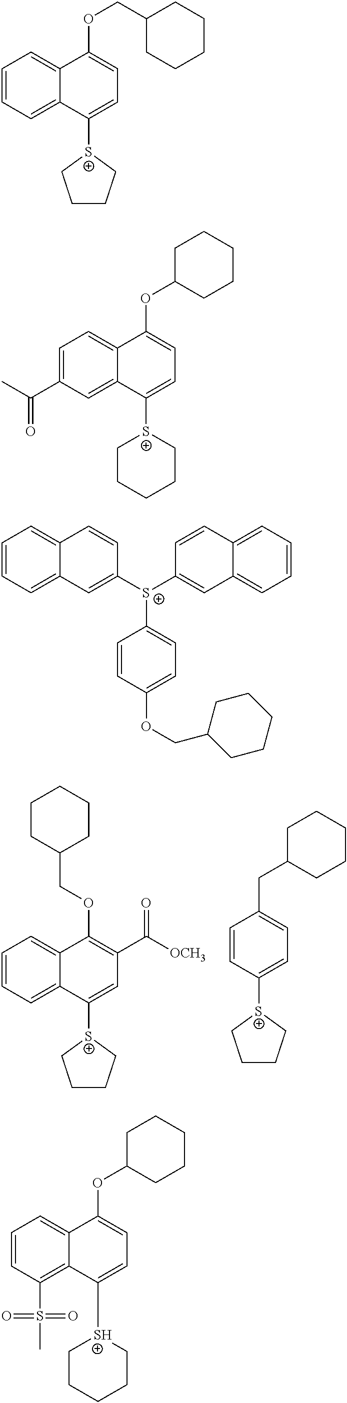

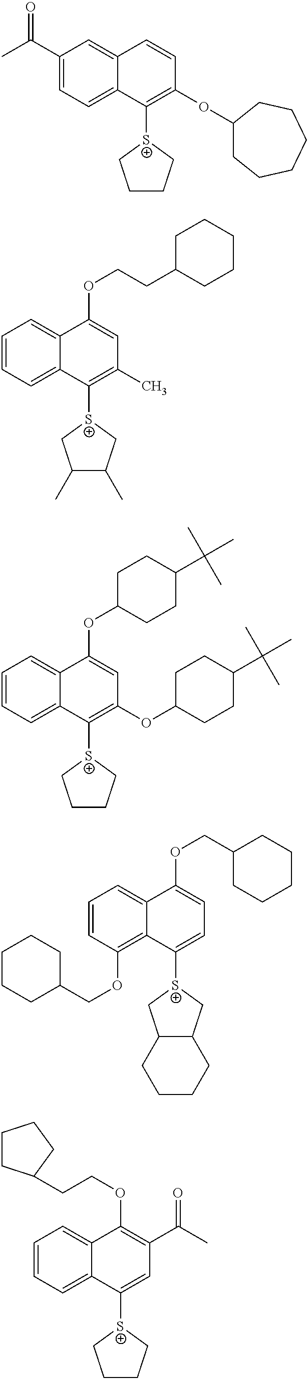 [SMILES: CC(=O)c1ccc2c([S+]3CCCC3)c(OC3CCCCCC3)ccc2c1 ; Cc1cc(OCCC2CCCCC2)c2ccccc2c1[S+]1CC(C)C(C)C1 ; CC(C)(C)C1CCC(Oc2cc(OC3CCC(C(C)(C)C)CC3)c3ccccc3c2[S+]2CCCC2)CC1 ; c1cc(OCC2CCCCC2)c2c([S+]3CC4CCCCC4C3)ccc(OCC3CCCCC3)c2c1 ; CC(=O)c1cc([S+]2CCCC2)c2ccccc2c1OCCC1CCCC1]

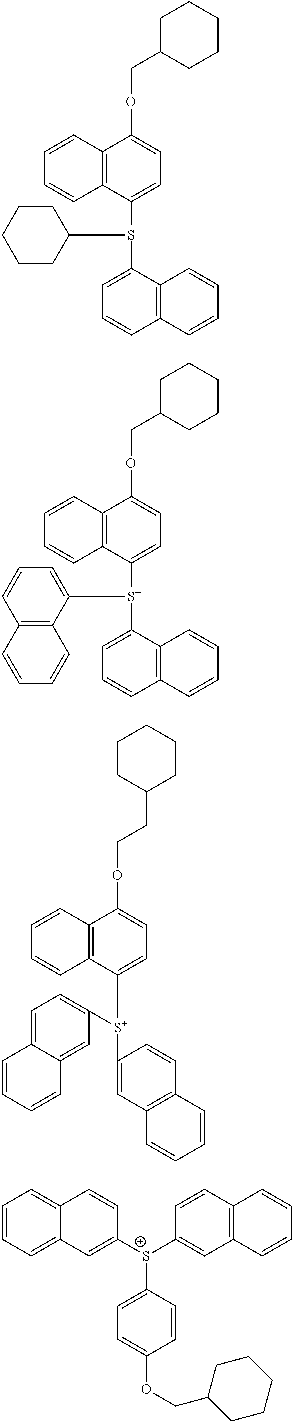 [SMILES: c1ccc2c([S+](c3ccc(OCC4CCCCC4)c4ccccc34)C3CCCCC3)cccc2c1 ; c1ccc2c([S+](c3cccc4ccccc34)c3ccc(OCC4CCCCC4)c4ccccc34)cccc2c1 ; c1ccc2cc([S+](c3ccc4ccccc4c3)c3ccc(OCCC4CCCCC4)c4ccccc34)ccc2c1 ; c1ccc2cc([S+](c3ccc(OCC4CCCCC4)cc3)c3ccc4ccccc4c3)ccc2c1]

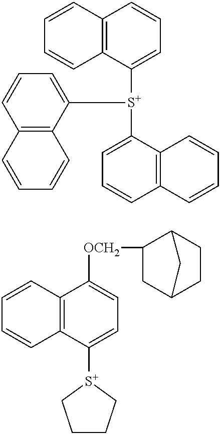

Now, general formulae (ZII) and (ZIII) will be described.

In general formulae (ZII) and (ZIII),

each of R₂₀₄ to R₂₀₇ independently represents an aryl group, an alkyl group or a cycloalkyl group.

The aryl group represented by each of R₂₀₄ to R₂₀₇ is preferably a phenyl group or a naphthyl group, more preferably a phenyl group. The aryl group may be one having a heterocyclic structure containing an oxygen atom, nitrogen atom, sulfur atom, etc. As the heterocyclic structure, there can be mentioned, for example, a pyrrole, a furan, a thiophene, an indole, a benzofuran and a benzothiophene.

As preferred alkyl groups and cycloalkyl groups represented by R₂₀₄ to R₂₀₇, a linear or branched alkyl group having 1 to 10 carbon atoms and a cycloalkyl group having 3 to 10 carbon atoms can be exemplified. As the alkyl group, for example, a methyl group, an ethyl group, a propyl group, a butyl group and a pentyl group can be exemplified. As the cycloalkyl group, for example, a cyclopentyl group, a cyclohexyl group and a norbornyl group can be exemplified.

The aryl group, alkyl group and cycloalkyl group represented by R₂₀₄ to R₂₀₇ may have one or more substituents. As a possible substituent on the aryl group, alkyl group and cycloalkyl group represented by R₂₀₄ to R₂₀₇, an alkyl group (having, for example, 1 to 15 carbon atoms), a cycloalkyl group (having, for example, 3 to 15 carbon atoms), an aryl group (having, for example, 6 to 15 carbon atoms), an alkoxy group (having, for example, 1 to 15 carbon atoms), a halogen atom, a hydroxy group, and a phenylthio group can be exemplified.

Z⁻ represents a nonnucleophilic anion. As such, the same nonnucleophilic anions as mentioned with respect to the Z⁻ in the general formula (ZI) can be exemplified.

As the acid generators, the compounds represented by the following general formulae (ZIV), (ZV) and (ZVI) can further be exemplified.

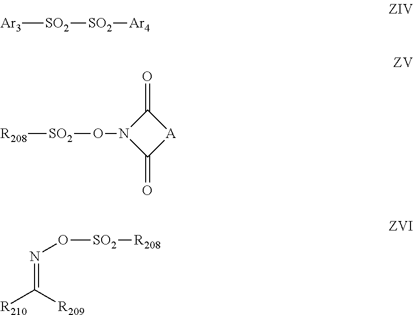

In the general formulae (ZIV) to (ZVI),

each of Ar₃ and Ar₄ independently represents an aryl group.

Each of R₂₀₈, R₂₀₉ and R₂₁₀ independently represents an alkyl group, a cycloalkyl group or an aryl group.

A represents an alkylene group, an alkenylene group or an arylene group.

Among the acid generators, the compounds represented by the general formulae (ZI) to (ZIII) are more preferred.

As a preferred acid generator, a compound that generates an acid having one sulfonate group or imido group. As a more preferred acid generator, a compound that generates a monovalent perfluoroalkanesulfonic acid, a compound that generates a monovalent aromatic sulfonic acid substituted with one or more fluorine atoms or fluorine-atom-containing group, and a compound that generates a monovalent imidic acid substituted with one or more fluorine atoms or fluorine-atom-containing group can be exemplified. As a still more preferred acid generator, any of sulfonium salts of fluorinated alkanesulfonic acid, fluorinated benzenesulfonic acid, fluorinated imidic acid and fluorinated methide acid can be exemplified. As acid generators, it is especially preferred for the generated acid to be a fluorinated alkanesulfonic acid, fluorinated benzenesulfonic acid or fluorinated imidic acid, each of which having pKa's of −1 or below in order to improve the sensitivity.

Especially preferred examples of the acid generators will be shown below.

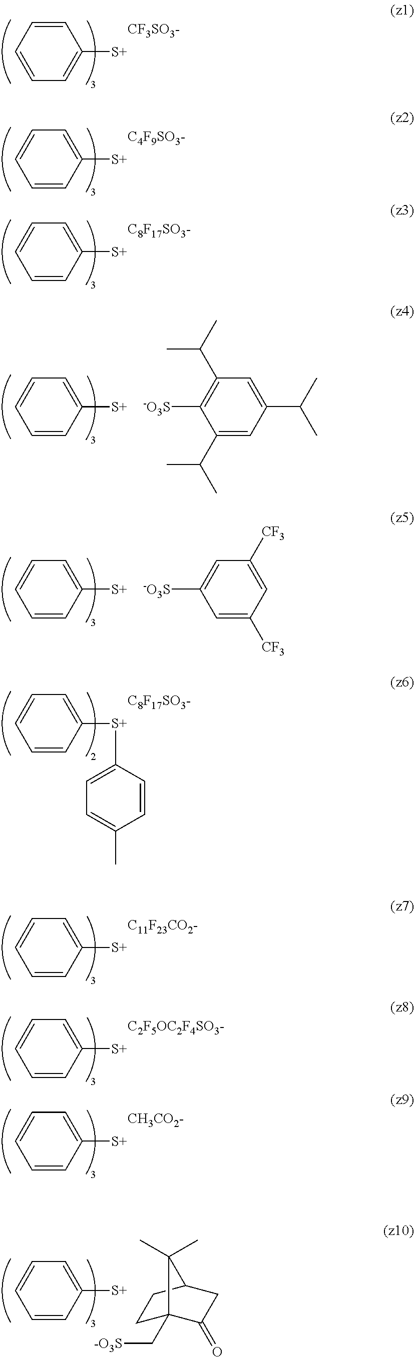

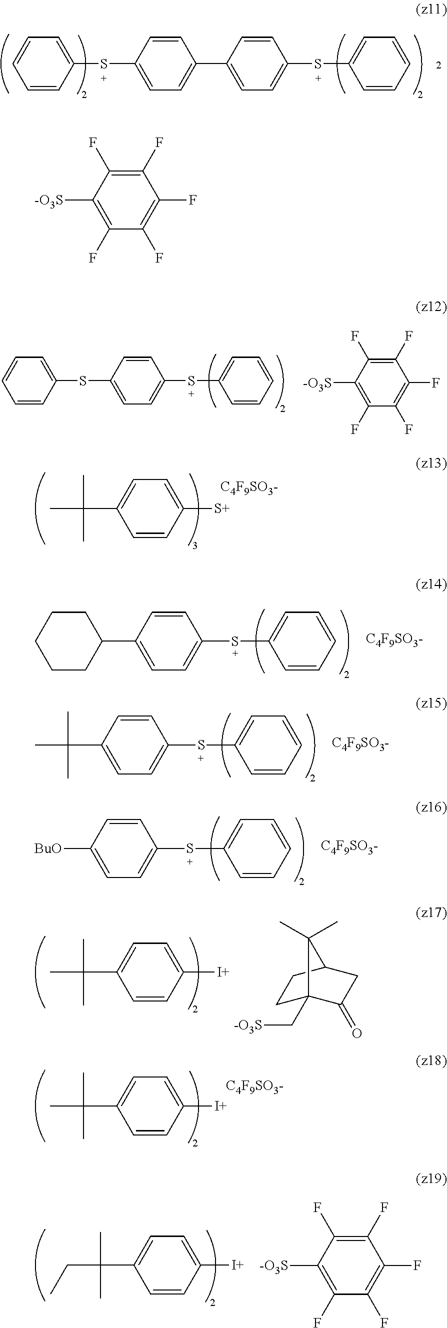

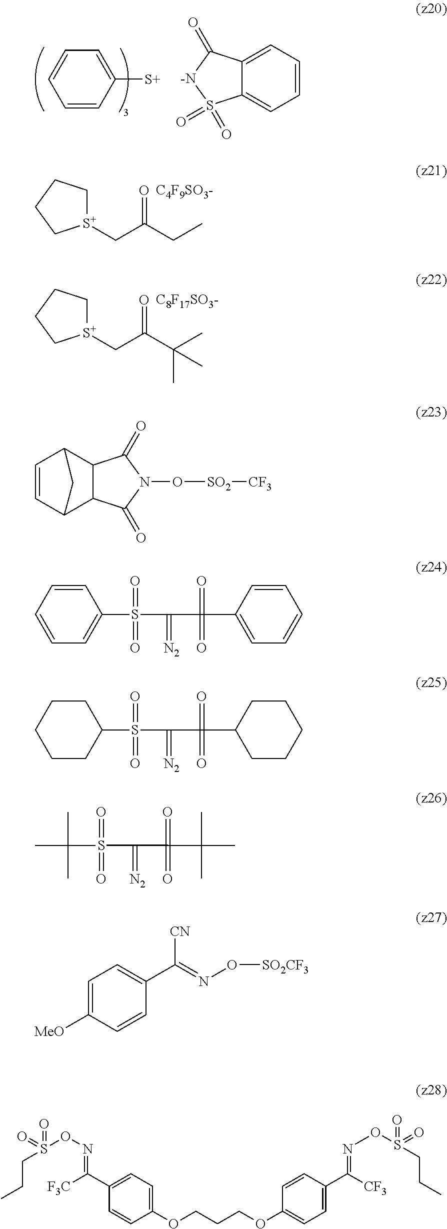

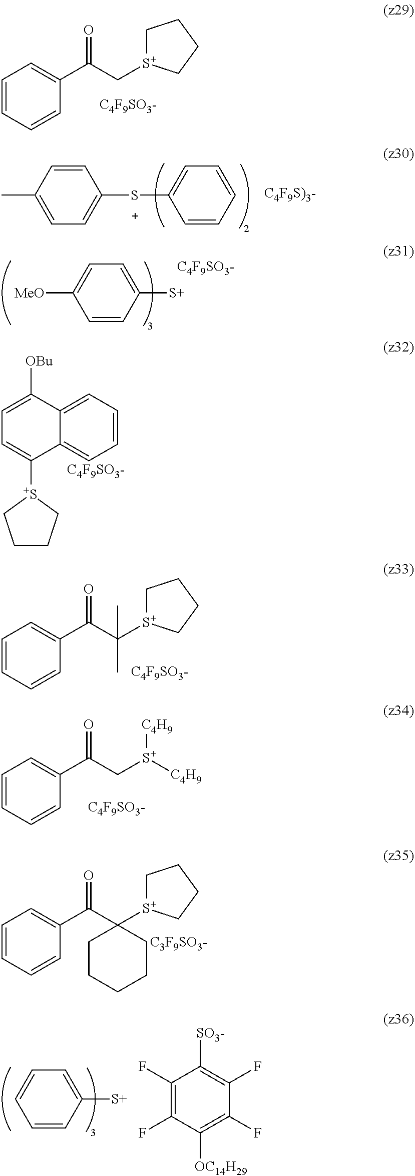

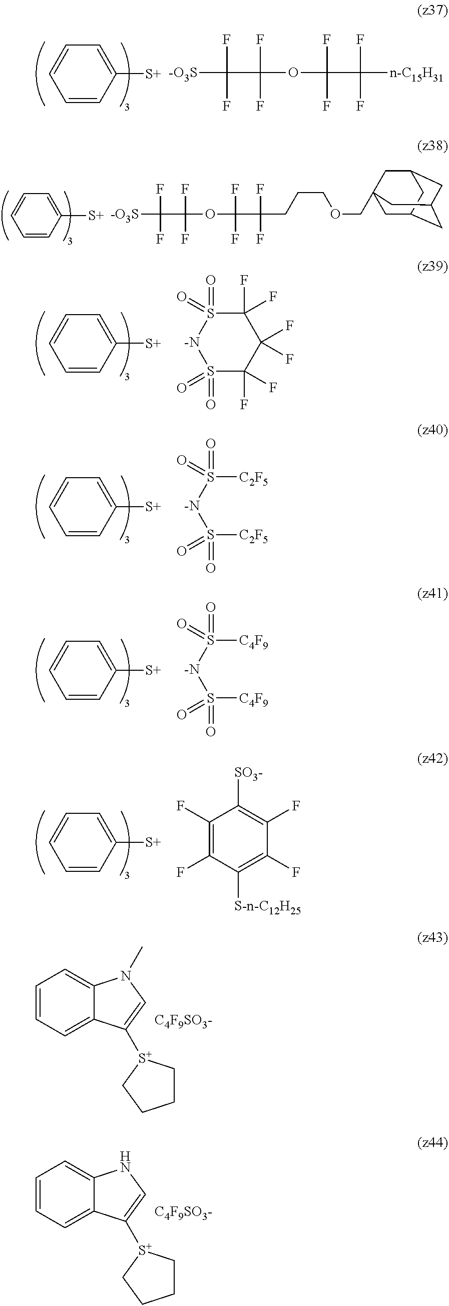

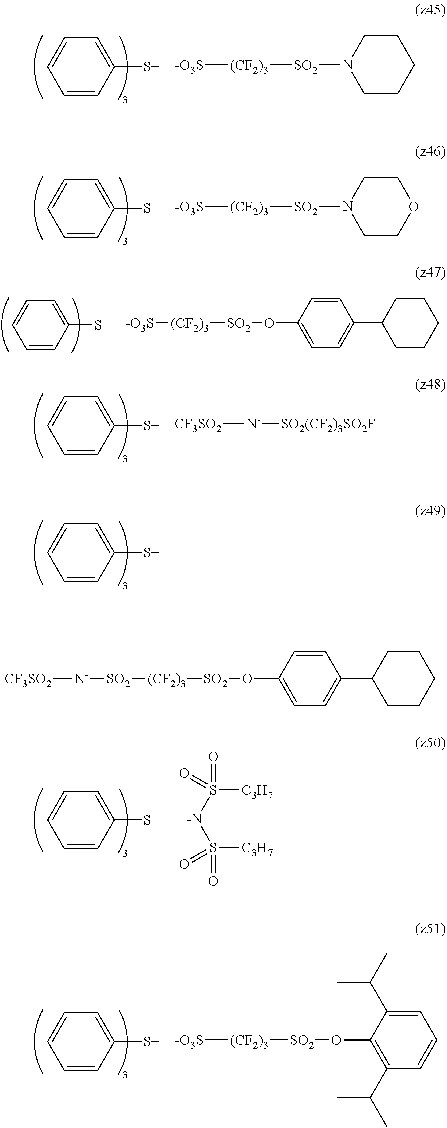

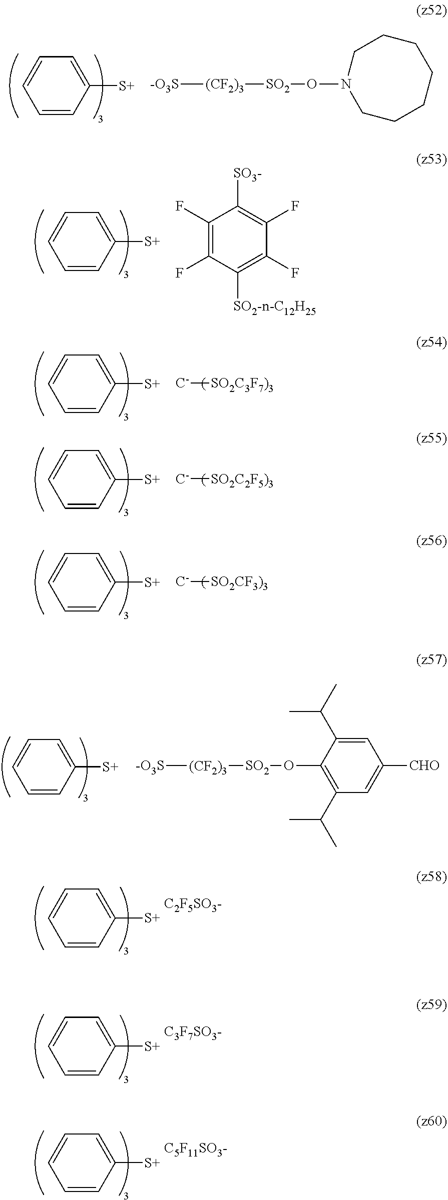

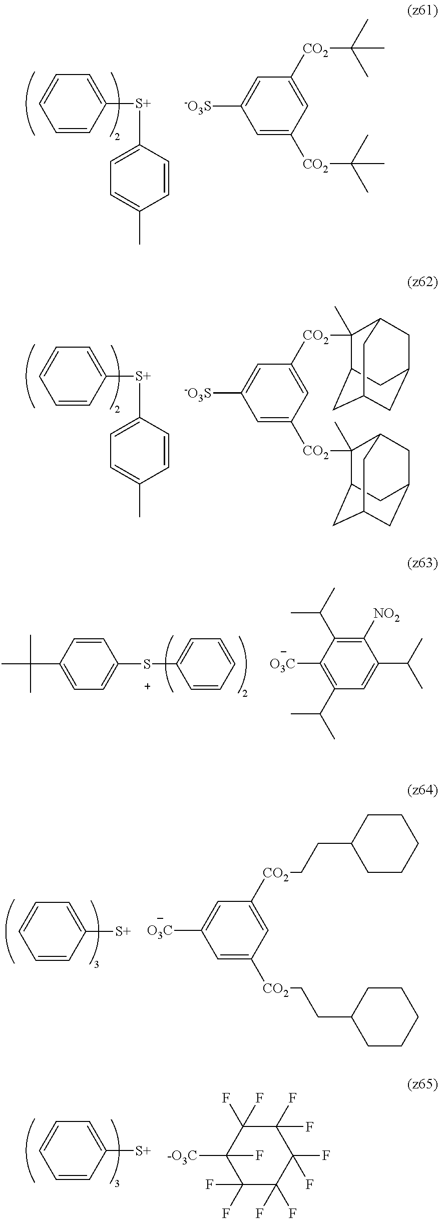

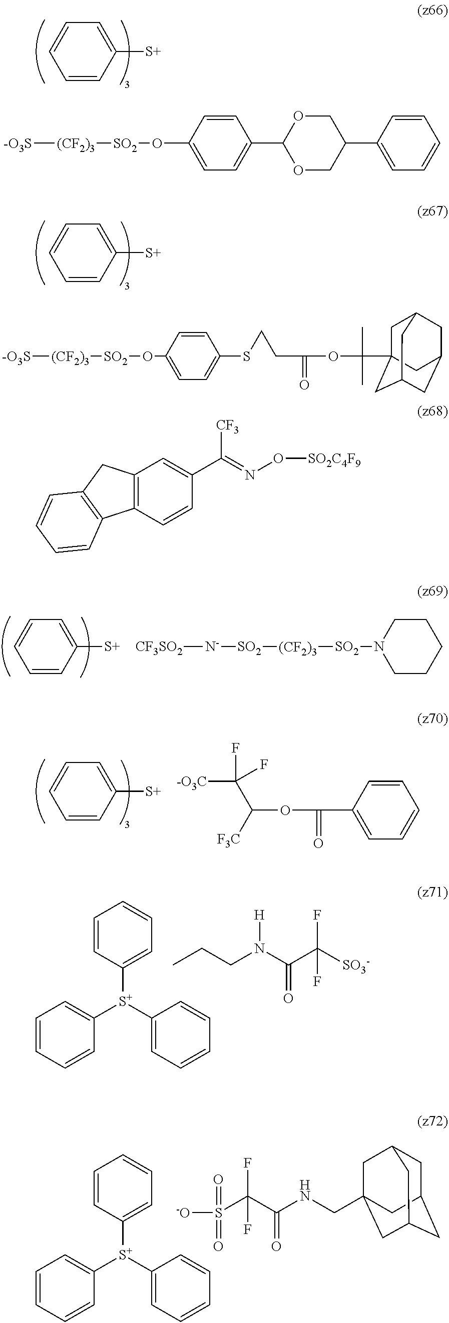

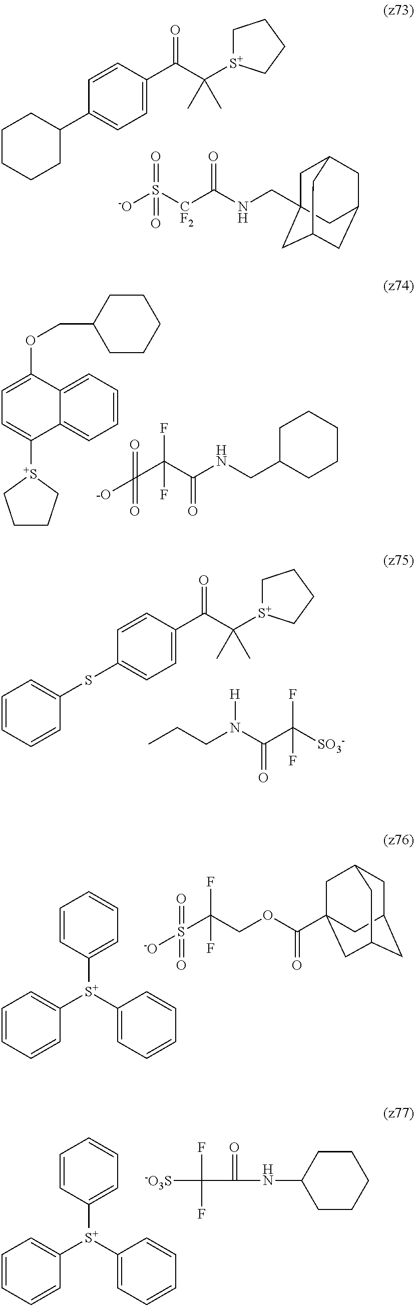

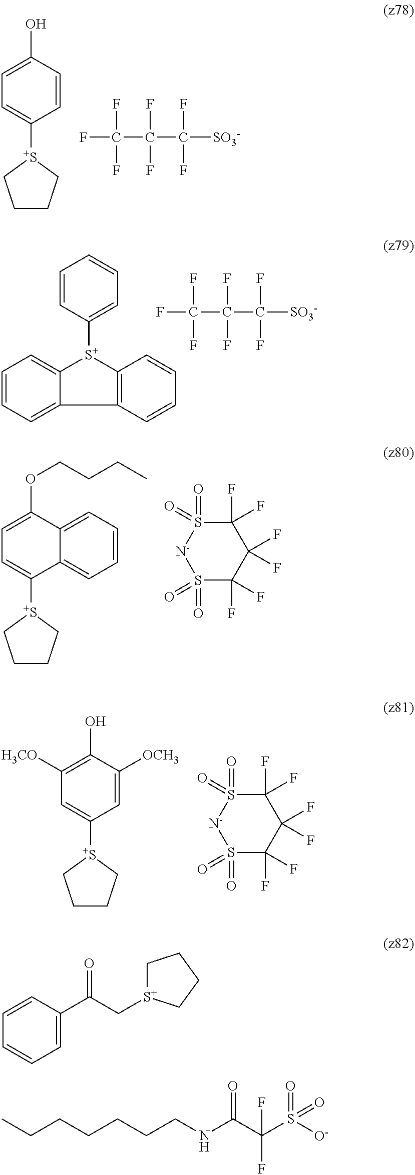

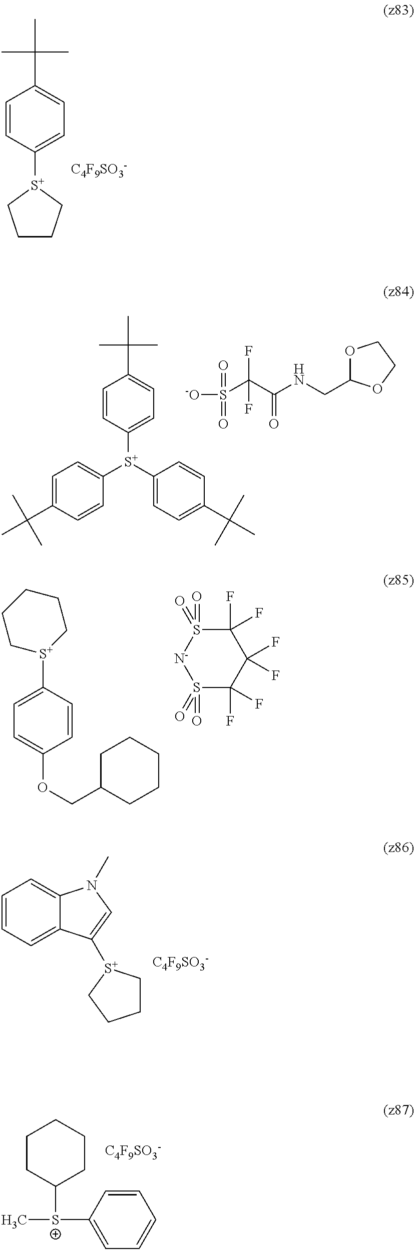

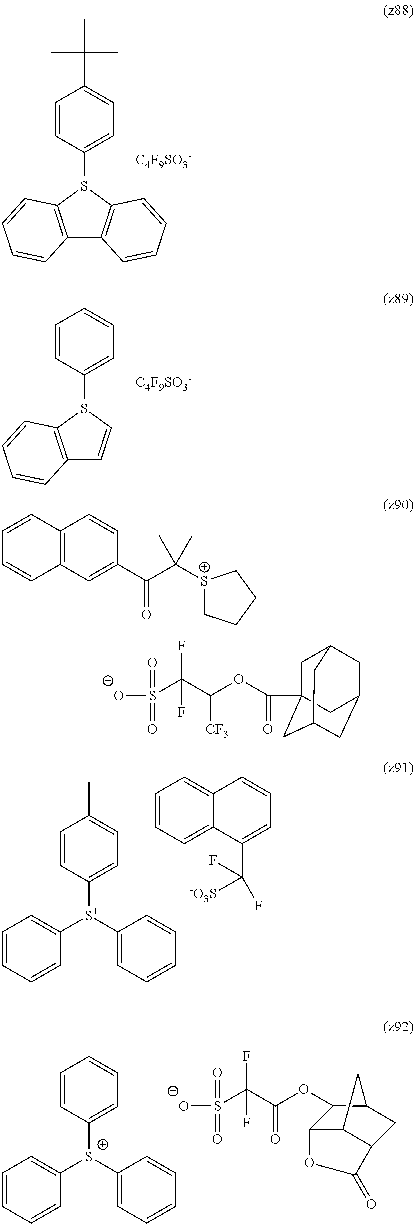

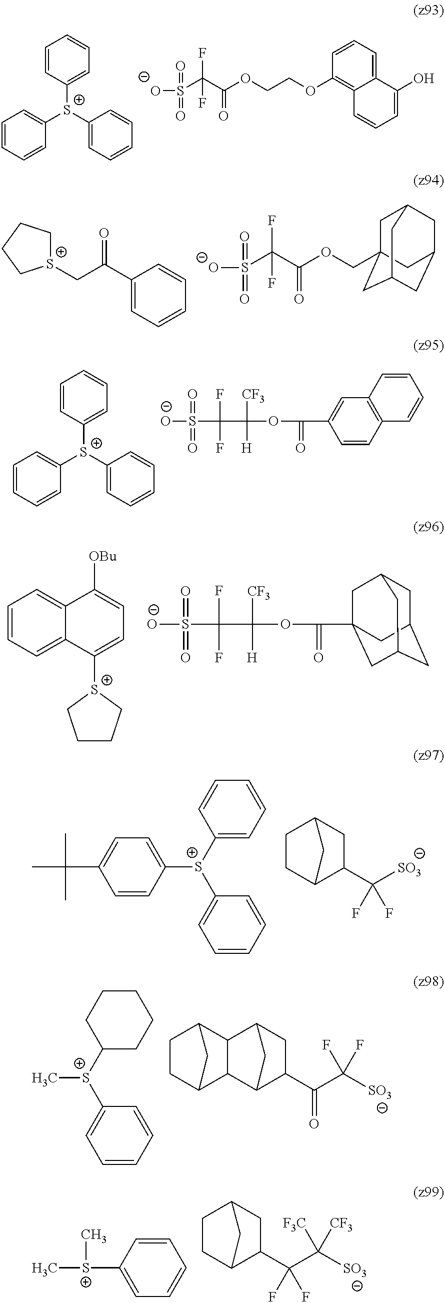

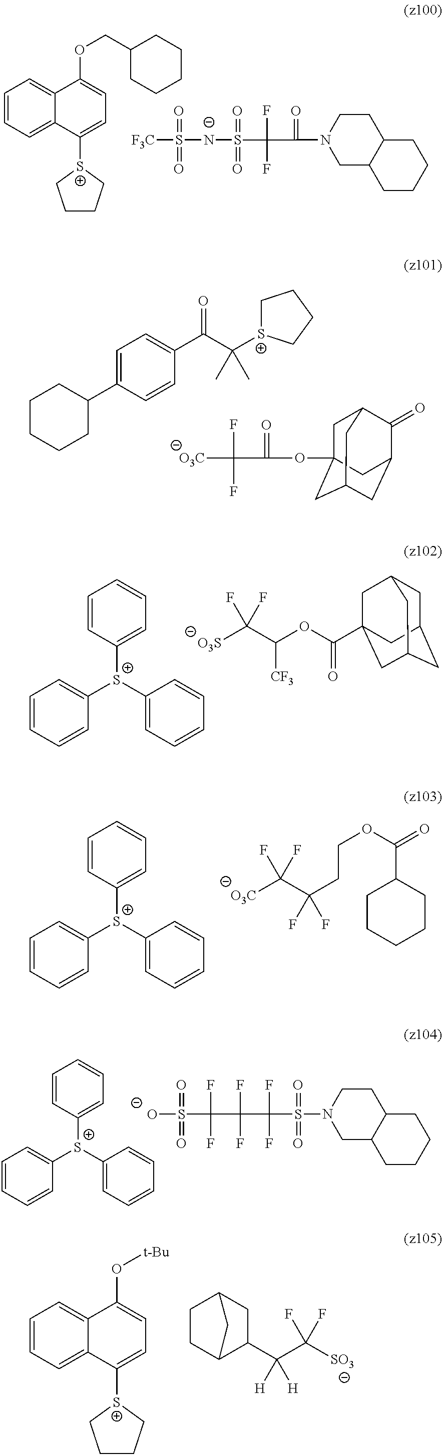

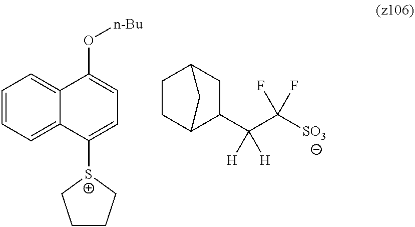

The acid generators can be used either individually or in combination of two or more kinds.

When the composition of the present invention contains an acid generator, the content thereof based on the total solids of the composition is preferably in the range of 0.1 to 30 mass %, more preferably 0.5 to 25 mass %, further more preferably 3 to 20 mass %, and particularly preferably 3 to 15 mass %.

When the acid generator is represented by the general formulae (ZI-3) or (ZI-4), the content thereof based on the total solids of the composition is preferably in the range of 5 to 20 mass %, more preferably 8 to 20 mass %, further more preferably 10 to 20 mass %, and particularly preferably 10 to 15 mass %.

<Basic Compound>

The composition of the present invention preferably contains a basic compound so as to decrease any performance alteration over time from exposure to heating.

As preferred basic compounds, there can be mentioned the compounds having the structures of the following formulae (A) to (E).

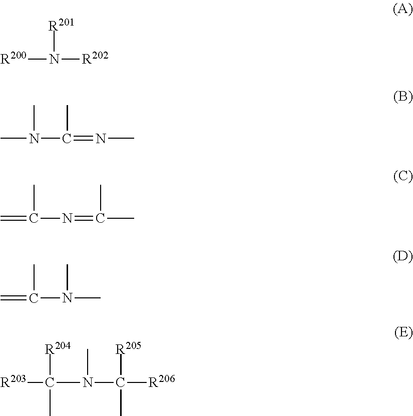

In the general formulae (A) and (E),

R²⁰⁰, R²⁰¹ and R²⁰² may be identical to or different from each other and each represent a hydrogen atom, an alkyl group (preferably having 1 to 20 carbon atoms), a cycloalkyl group (preferably having 3 to 20 carbon atoms) or an aryl group (having 6 to 20 carbon atoms). R²⁰¹ and R²⁰² may be bonded with each other to thereby form a ring. R²⁰³, R²⁰⁴, R²⁰⁵ and R²⁰⁶ may be identical to or different from each other and each represent an alkyl group having 1 to 20 carbon atoms.

With respect to the above alkyl group, as a preferred substituted alkyl group, there can be mentioned an aminoalkyl group having 1 to 20 carbon atoms, a hydroxyalkyl group having 1 to 20 carbon atoms or a cyanoalkyl group having 1 to 20 carbon atoms.

More preferably, in these general formulae (A) and (E) the alkyl group is unsubstituted.

As preferred compounds, there can be mentioned guanidine, aminopyrrolidine, pyrazole, pyrazoline, piperazine, aminomorpholine, aminoalkylmorpholine, piperidine and the like. Further, as preferred compounds, there can be mentioned compounds with an imidazole structure, a diazabicyclo structure, an onium hydroxide structure, an onium carboxylate structure, a trialkylamine structure, an aniline structure or a pyridine structure, alkylamine derivatives having a hydroxyl group and/or an ether bond, aniline derivatives having a hydroxyl group and/or an ether bond and the like.

As the compounds with an imidazole structure, there can be mentioned imidazole, 2,4,5-triphenylimidazole, benzimidazole, 2-phenylbenzoimidazole and the like. As the compounds with a diazabicyclo structure, there can be mentioned 1,4-diazabicyclo[2,2,2]octane, 1,5-diazabicyclo[4,3,0]non-5-ene, 1,8-diazabicyclo[5,4,0]undec-7-ene and the like. As the compounds with an onium hydroxide structure, there can be mentioned tetrabutylammonium hydroxide, triarylsulfonium hydroxide, phenacylsulfonium hydroxide, and sulfonium hydroxides having a 2-oxoalkyl group such as triphenylsulfonium hydroxide, tris(t-butylphenyl)sulfonium hydroxide, bis(t-butylphenyl)iodonium hydroxide, phenacylthiophenium hydroxide, 2-oxopropylthiophenium hydroxide and the like. As the compounds with an onium carboxylate structure, there can be mentioned those having a carboxylate at the anion moiety of the compounds with an onium hydroxide structure, for example, acetate, adamantane-1-carboxylate, perfluoroalkyl carboxylate and the like. As the compounds with a trialkylamine structure, there can be mentioned tri(n-butyl)amine, tri(n-octyl)amine and the like. As the aniline compounds, there can be mentioned 2,6-diisopropylaniline, N,N-dimethylaniline, N,N-dibutylaniline, N,N-dihexylaniline and the like. As the alkylamine derivatives having a hydroxyl group and/or an ether bond, there can be mentioned ethanolamine, diethanolamine, triethanolamine, N-phenyldiethanolamine, tris(methoxyethoxyethyl)amine and the like. As the aniline derivatives having a hydroxyl group and/or an ether bond, there can be mentioned N,N-bis(hydroxyethyl)aniline and the like.

As preferred basic compounds, there can be further mentioned an amine compound having a phenoxy group, an ammonium salt compound having a phenoxy group, an amine compound having a sulfonic ester group and an ammonium salt compound having a sulfonic ester group.

Each of the above amine compound having a phenoxy group, ammonium salt compound having a phenoxy group, amine compound having a sulfonic ester group and ammonium salt compound having a sulfonic ester group preferably has at least one alkyl group bonded to the nitrogen atom thereof. Further preferably, the alkyl group in its chain contains an oxygen atom, thereby forming an oxyalkylene group. The number of oxyalkylene groups in each molecule is one or more, preferably 3 to 9 and more preferably 4 to 6. Oxyalkylene groups having the structure of —CH₂CH₂O—, —CH(CH₃)CH₂O— or —CH₂CH₂CH₂O— are preferred.

As specific examples of the above amine compound having a phenoxy group, ammonium salt compound having a phenoxy group, amine compound having a sulfonic ester group and ammonium salt compound having a sulfonic ester group, there can be mentioned the compounds (C1-1) to (C3-3) shown as examples in Section [0066] of US 2007/0224539 A, which are however nonlimiting.

These basic compounds may be used either individually or in combination.

The content of the basic compounds is typically in the range of 0.001 to 10 mass %, preferably 0.01 to 5 mass % based on the total solids of the composition.

With respect to the ratio of the acid generator to the basic compound used in the composition, preferably, the acid generator/the basic compound (molar ratio)=2.5 to 300. The reason for this is that the molar ratio is preferred to be 2.5 or higher from the viewpoint of sensitivity and resolving power. The molar ratio is preferred to be 300 or below from the viewpoint of the inhibition of any resolving power deterioration due to thickening of resist pattern over time from exposure to heating treatment. The acid generator/the basic compound (molar ratio) is more preferably in the range of 5.0 to 200, still more preferably 7.0 to 150.

<Low-Molecular Compound Containing a Group Cleaved By the Action of an Acid that Upon the Cleavage, Exhibits an Increased Basicity>

It is preferred for the composition of the present invention to contain a low-molecular compound containing a group cleaved by the action of an acid that upon the cleavage, exhibits an increased basicity (hereinafter also referred to as a “low-molecular compound (D).”

The group that is cleaved when acted on by an acid is not particularly limited. However, an acetal group, a carbonate group, a carbamate group, a tertiary ester group, a tertiary hydroxyl group and a hemiaminal ether group are preferably used. A carbamate group and a hemiaminal ether group are especially preferred.

The molecular weight of the compound (D) is preferably in the range of 100 to 1000, more preferably 100 to 700 and most preferably 100 to 500.

As the compound (D), an amine derivative containing a group that is cleaved when acted on by an acid being connected to a nitrogen atom.

The compound (D) may contain a carbamate group with a protective group, the carbamate group being connected to a nitrogen atom. The protective group contained in the carbamate group can be represented, for example, by the following formula (d-1).

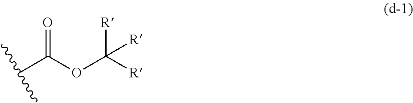

In formula (d-1),

Each of R′s independently represents a hydrogen atom, a linear or branched alkyl group, a cycloalkyl group, an aryl group, an aralkyl group, or an alkoxyalkyl group. At least two of R′s may be connected to each other to form a ring.

Preferably, R′ represents a linear or branched alkyl group, a cycloalkyl group, or an aryl group. More preferably, R′ represents a linear or branched alkyl group, or a cycloalkyl group.

The low-molecular compound (D) may have a structure in which any of the above-mentioned basic compounds are combined with the structure represented by general formula (d-1).

The low-molecular compound (D) is especially preferred to be the one represented by general formula (A) below. Note that, the low-molecular compound (D) may be any of the basic compounds described above as long as it is a low-molecular compound containing a group that is cleaved when acted on by an acid.

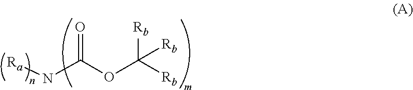

In the general formula (A), Ra represents a hydrogen atom, an alkyl group, a cycloalkyl group, an aryl group, or an aralkyl group. When n=2, two Ra's may be the same or different from each other, and may be connected to each other to form a bivalent heterocyclic hydrocarbon group (preferably having 20 or less carbon atoms) or its derivatives.

Each of Rb's independently represents a hydrogen atom, an alkyl group, a cycloalkyl group, an aryl group, an aralkyl group, or an alkoxyalkyl group, with the proviso that when at least one of Rb's are hydrogen atoms, at least one of the remainder represents a cyclopropyl group, 1-alkoxyalkyl group, or an aryl group.

At least two of Rb's may be connected to each other to form a alicyclic hydrocarbon group, an aromatic hydrocarbon group, a heterocyclic hydrocarbon group, or their derivatives.

In the formula (A), n represents an integer of 0 to 2, m represents an integer of 1 to 3, and n+m=3.

In the formula (A), the alkyl group, the cycloalkyl group, the aryl group, and the aralkyl group represented by Ra and Rb may be substituted with a functional group such as a hydroxyl group, a cyano group, an amino group, a pyrrolidino group, a piperidino group, a morpholino group, and an oxo group; an alkoxy group; or a halogen atom. The same applies to the alkoxyalkyl group represented by Rb.

As the alkyl group, the cycloalkyl group, the aryl group, and the aralkyl group (these groups may be substituted with the above functional group, an alkoxy group, or a halogen atom) represented by Ra and/or Rb, the following groups can be exemplified:

a group derived from a linear or branched alkane such as methane, ethane, propane, butane, pentane, hexane, heptane, octane, nonane, decane, undecane, or dodecane; and the group derived from the alkane and substituted with one or more cycloalkyl groups such as a cyclobutyl group, a cyclopentyl group, or a cyclohexyl group;

a group derived from cycloalkane such as cyclobutane, cyclopentane, cyclohexane, cycloheptane, cyclooctane, norbornane, adamantane, or noradamantane; and the group derived from the cycloalkane and substituted with one or more linear or branched alkyl group such as a methyl group, an ethyl group, a n-propyl group, an i-propyl group, a n-butyl group, a 2-methylpropyl group, a 1-methylpropyl group, or a t-butyl group;

a group derived from aromatic compound such as benzene, naphthalene, or anthracene; and the group derived from the atomatic compound and substituted with one or more linear or branched alkyl group such as a methyl group, an ethyl group, a n-propyl group, an i-propyl group, a n-butyl group, a 2-methylpropyl group, a 1-methylpropyl group, or a t-butyl group;

a group derived from heterocyclic compound such as pyrrolidine, piperidine, morpholine, tetrahydrofuran, tetrahydropyrane, indole, indoline, quinoline, perhydroquinoline, indazole, or benzimidazole; the group derived from heterocyclic compound and substituted with one or more linear or branched alkyl group or a group derived from the aromatic compound;

a group derived from linear or branched alkane and substituted with a group derived from aromatic compound such as a phenyl group, a naphthyl group, or an anthracenyl group;

a group derived from cycloalkane and substituted with a group derived from aromatic compound such as a phenyl group, a naphthyl group, or an anthracenyl group; or

each of these groups substituted with a functional group such as a hydroroxyl group, a cyano group, an amino group, a pyrrolidino group, a piperidino group, a morpholino group, or an oxo group.

Further, as the bivalent heterocyclic hydrocarbon group (preferably having 1 to 20 carbon atoms) or its derivative, formed by mutual binding of Ra's, for example, the followings can be exemplified:

a group derived from heterocyclic compound such as pyrrolidine, piperidine, morpholine, 1,4,5,6-tetrahydropyrimidine, 1,2,3,4-tetrahydroquinoline, 1,2,3,6-tetrahydroquinoline, homopiperadine, 4-azabenzimidazole, benztriazole, 5-azabenztriazole, 1H-1,2,3-triazole, 1,4,7-triazacyclononane, tetrazole, 7-azaindole, indazole, benzimidazole, imidazo[1,2-a]pyridine, (1S,4S)-(+)2,5-azabicyclo[2.2.1]heptane, 1,5,7-triazabicyclo[4.4.0]dec-5-en, indole, indoline, 1,2,3,4-tetrahydroquinoxaline, perhydroquinoline, or 1,5,9-triazacyclododecane; or

the group derived from heterocyclic compound and substituted with at least one of a group derived from linear or branched alkane, a group derived from cycloalkane, a group derived from aromatic compound, a group derived from heterocyclic compound, or a functional group such as a hydroxyl group, a cyano group, an amino group, a pyrrolidino group, a piperidino group, a morpholino group, or an oxo group.

Particularly preferred examples of the low-molecular compound (D) will be shown below, which however in no way limit the scope of the present invention.

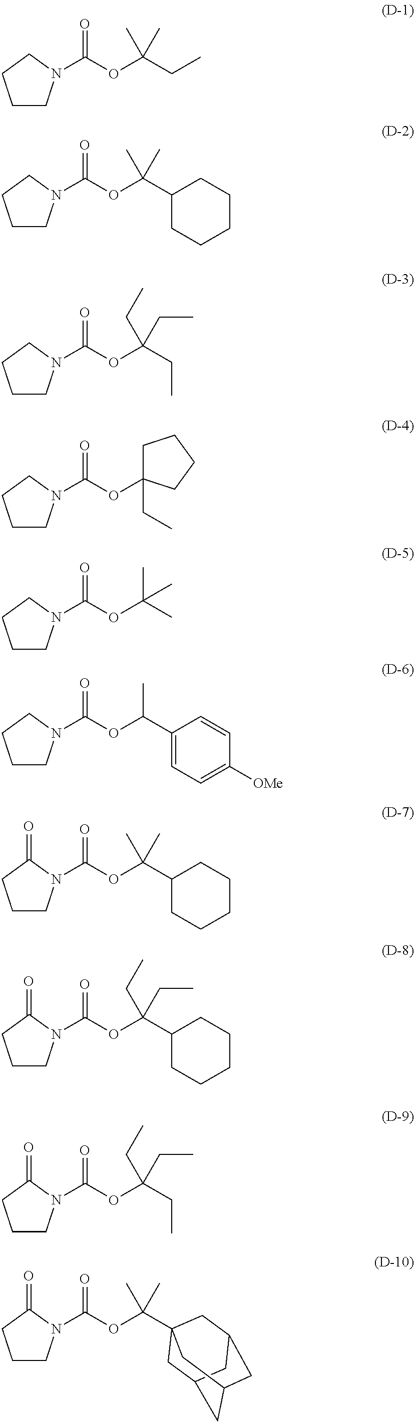

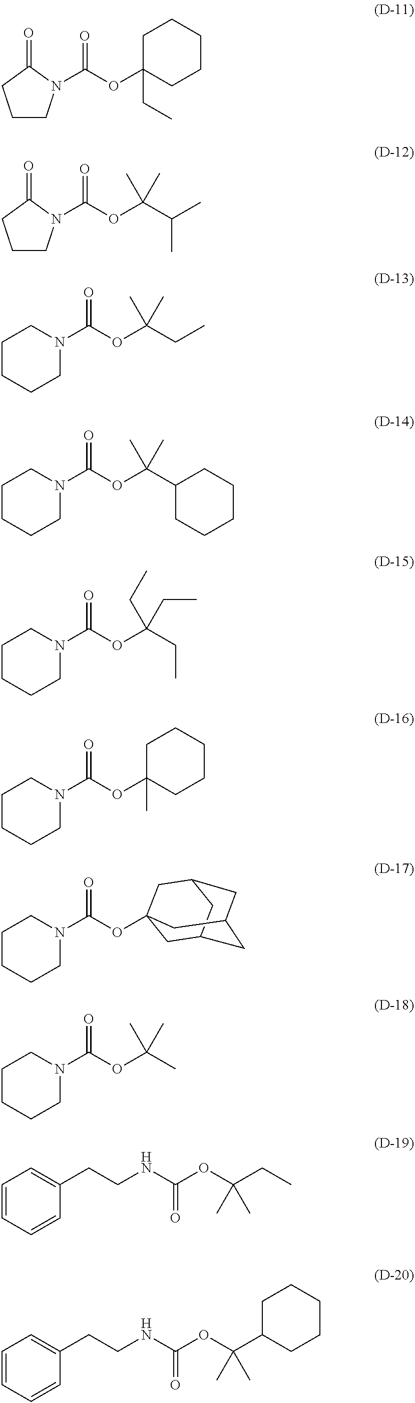

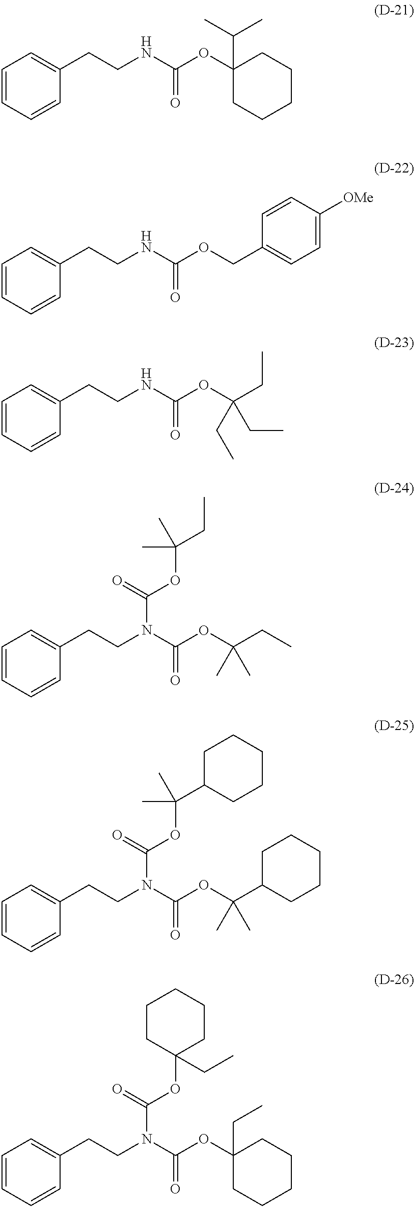

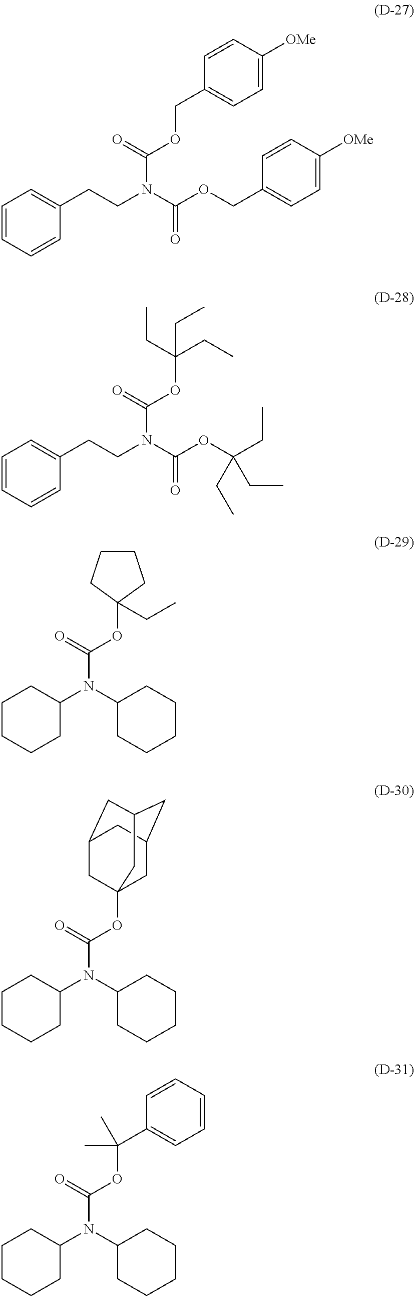 [SMILES: COc1ccc(COC(=O)N(CCc2ccccc2)C(=O)OCc2ccc(OC)cc2)cc1 ; CCC(CC)(CC)OC(=O)N(CCc1ccccc1)C(=O)OC(CC)(CC)CC ; CCC1(OC(=O)N(C2CCCCC2)C2CCCCC2)CCCC1 ; O=C(OC12CC3CC(CC(C3)C1)C2)N(C1CCCCC1)C1CCCCC1 ; CC(C)(OC(=O)N(C1CCCCC1)C1CCCCC1)c1ccccc1]

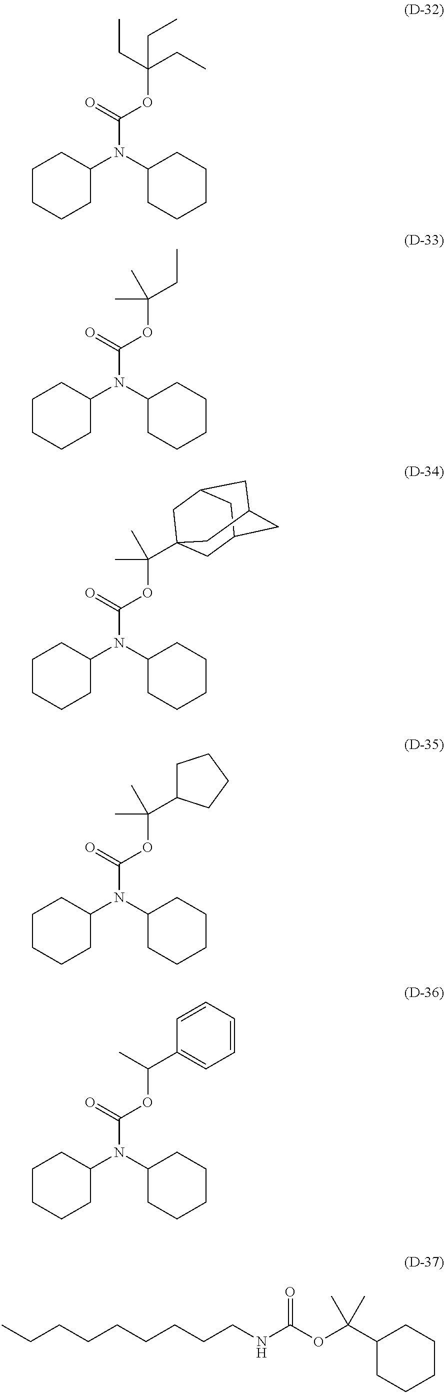

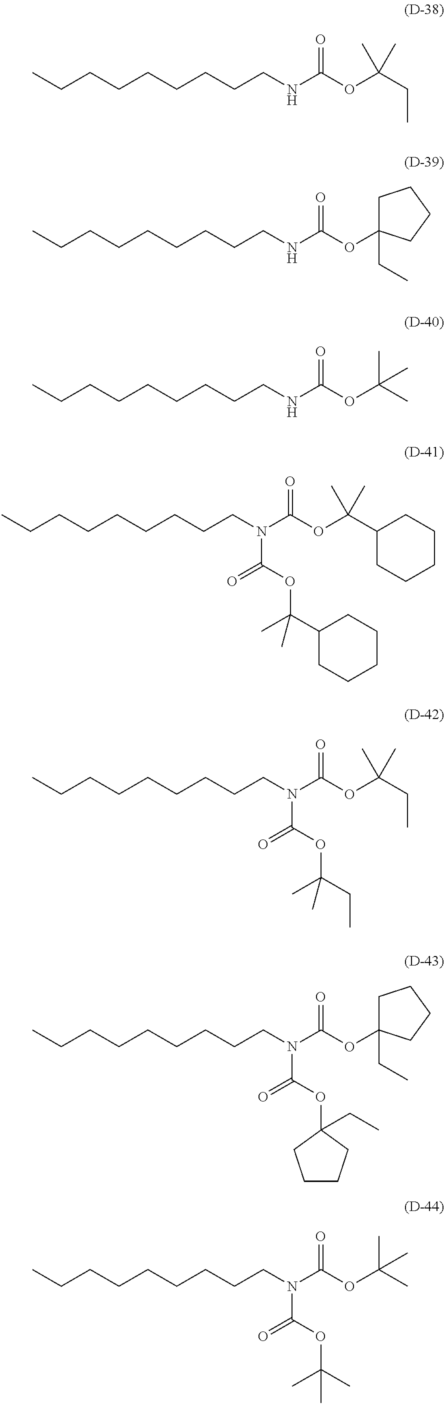

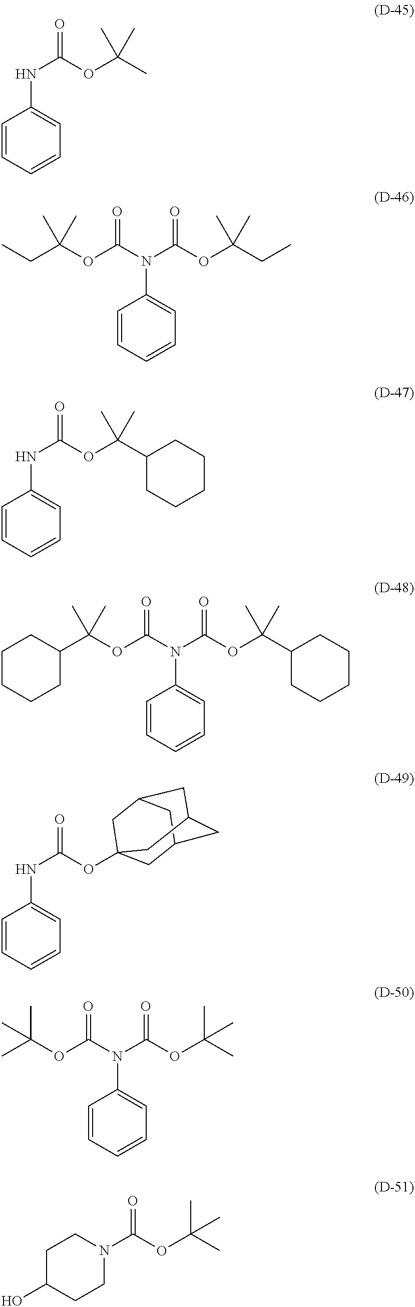

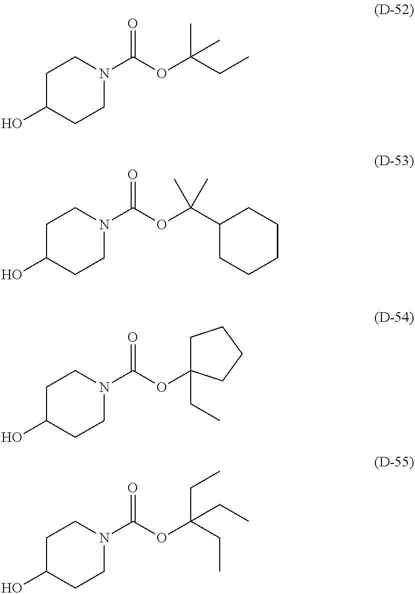 [SMILES: CCC(C)(C)OC(=O)N1CCC(O)CC1 ; CC(C)(OC(=O)N1CCC(O)CC1)C1CCCCC1 ; CCC1(OC(=O)N2CCC(O)CC2)CCCC1 ; CCC(CC)(CC)OC(=O)N1CCC(O)CC1]

The compounds of general formula (A) can be synthesized by, for example, the method described in JP-A-2009-199021.

In the present invention, one type of low-molecular compound (D) may be used alone, or two or more types thereof may be used in a mixture.

In the present invention, the content of low-molecular compound (D), based on the total solids of the composition mixed with the above-mentioned basic compound, is generally in the range of 0.001 to 20 mass %, preferably 0.001 to 10 mass % and more preferably 0.01 to 5 mass %.

With respect to the ratio between acid generator and low-molecular compound (D) used in the composition, it is preferred for the molar ratio of acid generator/[low-molecular compound (D)+above-mentioned basic compound] to be in the range of 2.5 to 300. Namely, the molar ratio is preferred to be 2.5 or higher from the viewpoint of sensitivity and resolution, and the molar ratio is preferred to be 300 or below from the viewpoint of inhibiting the lowering of resolution by thickening of resist pattern over time from exposure to baking treatment. The molar ratio of acid generator/[low-molecular compound (D)+above-mentioned basic compound] is more preferably in the range of 5.0 to 200, further more preferably 7.0 to 150.

<Solvent>

The composition according to the present invention may further contain solvent. As the solvent, an organic solvent such as an alkylene glycol monoalkyl ether carboxylate, an alkylene glycol monoalkyl ether, an alkyl lactate, an alkyl alkoxypropionate, a cyclolactone (preferably having 4 to 10 carbon atoms), an optionally cyclized monoketone compound (preferably having 4 to 10 carbon atoms), an alkylene carbonate, an alkyl alkoxyacetate and an alkyl pyruvate can be exemplified.

As alkylene glycol monoalkyl ether carboxylates, propylene glycol monomethyl ether acetate, propylene glycol monoethyl ether acetate, propylene glycol monopropyl ether acetate, propylene glycol monobutyl ether acetate, propylene glycol monomethyl ether propionate, propylene glycol monoethyl ether propionate, ethylene glycol monomethyl ether acetate, and ethylene glycol monoethyl ether acetate can be exemplified.

As alkylene glycol monoalkyl ethers, propylene glycol monomethyl ether, propylene glycol monoethyl ether, propylene glycol monopropyl ether, propylene glycol monobutyl ether, ethylene glycol monomethyl ether, and ethylene glycol monoethyl ether can be exemplified.

As alkyl lactates, methyl lactate, ethyl lactate, propyl lactate and butyl lactate can be exemplified.

As alkyl alkoxypropionates, ethyl 3-ethoxypropionate, methyl 3-methoxypropionate, methyl 3-ethoxypropionate, and ethyl 3-methoxypropionate can be exemplified.

As cyclolactones, β-propiolactone, β-butyrolactone, γ-butyrolactone, α-methyl-γ-butyrolactone, β-methyl-γ-butyrolactone, γ-valerolactone, γ-caprolactone, γ-octanoic lactone, and α-hydroxy-γ-butyrolactone can be exemplified.

As optionally cyclized monoketone compounds, 2-butanone, 3-methylbutanone, pinacolone, 2-pentanone, 3-pentanone, 3-methyl-2-pentanone, 4-methyl-2-pentanone, 2-methyl-3-pentanone, 4,4-dimethyl-2-pentanone, 2,4-dimethyl-3-pentanone, 2,2,4,4-tetramethyl-3-pentanone, 2-hexanone, 3-hexanone, 5-methyl-3-hexanone, 2-heptanone, 3-heptanone, 4-heptanone, 2-methyl-3-heptanone, 5-methyl-3-heptanone, 2,6-dimethyl-4-heptanone, 2-octanone, 3-octanone, 2-nonanone, 3-nonanone, 5-nonanone, 2-decanone, 3-decanone, 4-decanone, 5-hexen-2-one, 3-penten-2-one, cyclopentanone, 2-methylcyclopentanone, 3-methylcyclopentanone, 2,2-dimethylcyclopentanone, 2,4,4-trimethylcyclopentanone, cyclohexanone, 3-methylcyclohexanone, 4-methylcyclohexanone, 4-ethylcyclohexanone, 2,2-dimethylcyclohexanone, 2,6-dimethylcyclohexanone, 2,2,6-trimethylcyclohexanone, cycloheptanone, 2-methylcycloheptanone, and 3-methylcycloheptanone can be exemplified.

As alkylene carbonates, propylene carbonate, vinylene carbonate, ethylene carbonate, and butylene carbonate can be exemplified.

As alkyl alkoxyacetates, acetic acid 2-methoxyethyl ester, acetic acid 2-ethoxyethyl ester, acetic acid 2-(2-ethoxyethoxy)ethyl ester, acetic acid 3-methoxy-3-methylbutyl ester, and acetic acid 1-methoxy-2-propyl ester can be exemplified.

As alkyl pyruvates, methyl pyruvate, ethyl pyruvate and propyl pyruvate can be exemplified.

As a preferably employable solvent, a solvent having a boiling point measured at ordinary temperature under ordinary pressure of 130° C. or above can be mentioned. As the solvent, cyclopentanone, γ-butyrolactone, cyclohexanone, ethyl lactate, ethylene glycol monoethyl ether acetate, propylene glycol monomethyl ether acetate, ethyl 3-ethoxypropionate, ethyl pyruvate, acetic acid 2-ethoxyethyl ester, acetic acid 2-(2-ethoxyethoxy)ethyl ester, and propylene carbonate can be exemplified.

These solvents may be used either individually or in combination.

In the present invention, a mixed solvent comprising a mixture of a solvent having a hydroxyl group in its structure and a solvent having no hydroxyl group may be used as an organic solvent.

The solvent having a hydroxyl group and solvent having no hydroxyl group can appropriately be selected from among the compounds set forth above as examples. The solvent having a hydroxyl group is preferably an alkylene group monoalkyl ether, an alkyl lactate or the like, more preferably propylene glycol monomethyl ether or ethyl lactate. The solvent having no hydroxyl group is preferably an alkylene glycol monoalkyl ether acetate, an alkyl alkoxypropionate, an optionally cyclized monoketone compound, a cyclolactone, an alkyl acetate or the like. Of these, propylene glycol monomethyl ether acetate, ethyl ethoxypropionate, 2-heptanone, γ-butyrolactone, cyclohexanone and butyl acetate are especially preferred. Propylene glycol monomethyl ether acetate, ethyl ethoxypropionate and 2-heptanone are most preferred.

The mixing ratio (mass) of a solvent having a hydroxyl group and a solvent having no hydroxyl group is in the range of 1/99 to 99/1, preferably 10/90 to 90/10 and more preferably 20/80 to 60/40. Mixed solvents each containing 50 mass % or more of solvent having no hydroxyl group are especially preferred from the viewpoint of uniform applicability.

It is preferred for the solvent to be a mixed solvent consisting of two or more types of solvents containing propylene glycol monomethyl ether acetate.

<Surfactant>

The composition of the present invention may further contain a surfactant. When the composition contains a surfactant, the composition preferably contains any one, or two or more members, of fluorinated and/or siliconized surfactants (fluorinated surfactant, siliconized surfactant and surfactant containing both fluorine and silicon atoms).

The composition of the present invention when containing the above surfactant would, in the use of an exposure light source of 250 nm or below, especially 220 nm or below, realize favorable sensitivity and resolving power and produce a resist pattern with less adhesion and development defects.

As fluorinated and/or siliconized surfactants, there can be mentioned, for example, those described in section [0276] of US 2008/0248425 A1. As useful commercially available surfactants, there can be mentioned, for example, fluorinated surfactants/siliconized surfactants, such as Eftop EF301 and EF303 (produced by Shin-Akita Kasei Co., Ltd.), Florad FC 430, 431 and 4430 (produced by Sumitomo 3M Ltd.), Megafac F171, F173, F176, F189, F113, F110, F177, F120 and R08 (produced by Dainippon Ink & Chemicals, Inc.), Surflon S-382, SC101, 102, 103, 104, 105 and 106 (produced by Asahi Glass Co., Ltd.), Troy Sol S-366 (produced by Troy Chemical Co., Ltd.), GF-300 and GF-150 (produced by TOAGOSEI CO., LTD.), Sarfron S-393 (produced by SEIMI CHEMICAL CO., LTD.), Eftop EF121, EF122A, EF122B, RF122C, EF125M, EF135M, EF351, EF352, EF801, EF802 and EF601 (produced by JEMCO INC.), PF636, PF656, PF6320 and PF6520 (produced by OMNOVA), and FTX-204G, 208G, 218G, 230G, 204D, 208D, 212D, 218D and 222D (produced by NEOS). Further, polysiloxane polymer KP-341 (produced by Shin-Etsu Chemical Co., Ltd.) can be employed as the siliconized surfactant.

As the surfactant, besides the above publicly known surfactants, use can be made of a surfactant based on a polymer having a fluorinated aliphatic group derived from a fluorinated aliphatic compound, produced by a telomerization technique (also called a telomer process) or an oligomerization technique (also called an oligomer process). The fluorinated aliphatic compound can be synthesized by the process described in JP-A-2002-90991.

The polymer containing a fluorinated aliphatic group is preferably a copolymer from a monomer containing a fluorinated aliphatic group and a poly(oxyalkylene) acrylate and/or poly(oxyalkylene) methacrylate, which copolymer may have an irregular distribution or may result from block copolymerization. As the poly(oxyalkylene) group, there can be mentioned a poly(oxyethylene) group, a poly(oxypropylene) group, a poly(oxybutylene) group or the like. Further, use can be made of a unit comprising alkylenes of different chain lengths in a single chain, such as poly(oxyethylene-oxypropylene-oxyethylene block concatenation) or poly(oxyethylene-oxypropylene block concatenation). Moreover, the copolymer from a monomer containing a fluorinated aliphatic group and a poly(oxyalkylene) acrylate (or methacrylate) is not limited to two-monomer copolymers and may be a three- or-more-monomer copolymer obtained by simultaneous copolymerization of two or more different monomers having a fluorinated aliphatic group, two or more different poly(oxyalkylene) acrylates (or methacrylates), etc.

For example, as a commercially available surfactant, there can be mentioned, for example, Megafac F178, F-470, F-473, F-475, F-476 or F-472 (produced by Dainippon Ink & Chemicals, Inc.). Further, there can be mentioned a copolymer from an acrylate (or methacrylate) having a C₆F₁₃ group and a poly(oxyalkylene) acrylate (or methacrylate), a copolymer from an acrylate (or methacrylate) having a C₃F₇ group, poly(oxyethylene) acrylate (or methacrylate) and poly(oxypropylene) acrylate (or methacrylate), or the like.

In the present invention, surfactants other than the fluorinated and/or siliconized surfactants can also be employed. In particular, there can be mentioned, for example, those described in section [0280] of US 2008/0248425 A1.

These surfactants may be used either individually or in combination.

The content of the surfactant based on the total solids of the composition is preferably in the range of 0 to 2 mass %, more preferably 0 to 1.5 mass %, and most preferably 0 to 1 mass %.

(Carboxylic Acid Onium Salt)

The composition according to the present invention may further contain a carboxylic acid onium salt. Preferred carboxylic acid onium salt is a sulfonium salt and an iodonium salt. A preferred anion moiety thereof is a linear, branched, monocyclic or polycyclic alkylcarboxylate anion having 1 to 30 carbon atoms. A more preferred anion moiety is an anion of carboxylic acid wherein the alkyl group is partially or wholly fluorinated. The alkyl chain may contain an oxygen atom. If so, the transparency to light of wavelength 220 nm or shorter can be ensured, the sensitivity and resolving power can be enhanced, and the iso/dense bias and exposure margin can also be enhanced.

As the fluorinated carboxylic acid anion, any of the anions of fluoroacetic acid, difluoroacetic acid, trifluoroacetic acid, pentafluoropropionic acid, heptafluorobutyric acid, nonafluoropentanoic acid, perfluorododecanoic acid, perfluorotridecanoic acid, perfluorocyclohexanecarboxylic acid, and 2,2-bistrifluoromethylpropionic acid can be exemplified.

The content of the carboxylic acid onium salt based on the total solids of the composition is preferably in the range of 0.1 to 20 mass %, more preferably 0.5 to 10 mass %, and most preferably 1 to 7 mass %.

(Dissolution Inhibiting Compound)

The composition according to the present invention may further contain a dissolution inhibiting compound. Here the “dissolution inhibiting compound” means compound having 3000 or less molecular weight that is decomposed by the action of an acid to increase the solubility in an alkali developer.

From the viewpoint of preventing lowering of the transmission at the wavelength of 220 nm or shorter, the dissolution inhibiting compound is preferably an alicyclic or aliphatic compound having an acid-decomposable group, such as any of cholic acid derivatives having an acid-decomposable group described in Proceeding of SPIE, 2724, 355 (1996). The acid-decomposable group and alicyclic structure can be the same as described earlier.

When the composition according to the present invention is exposed to a KrF excimer laser or irradiated with electron beams, preferred use is made of one having a structure resulting from substitution of the phenolic hydroxy group of a phenol compound with an acid-decomposable group. The phenol compound preferably contains 1 to 9 phenol skeletons, more preferably 2 to 6 phenol skeletons.

The content of the dissolution inhibiting compound based on the total solids of the composition is preferably in the range of 3 to 50 mass %, and more preferably 5 to 40 mass %.

Specific examples of the dissolution inhibiting compound will be shown below, which however in no way limit the scope of the present invention.

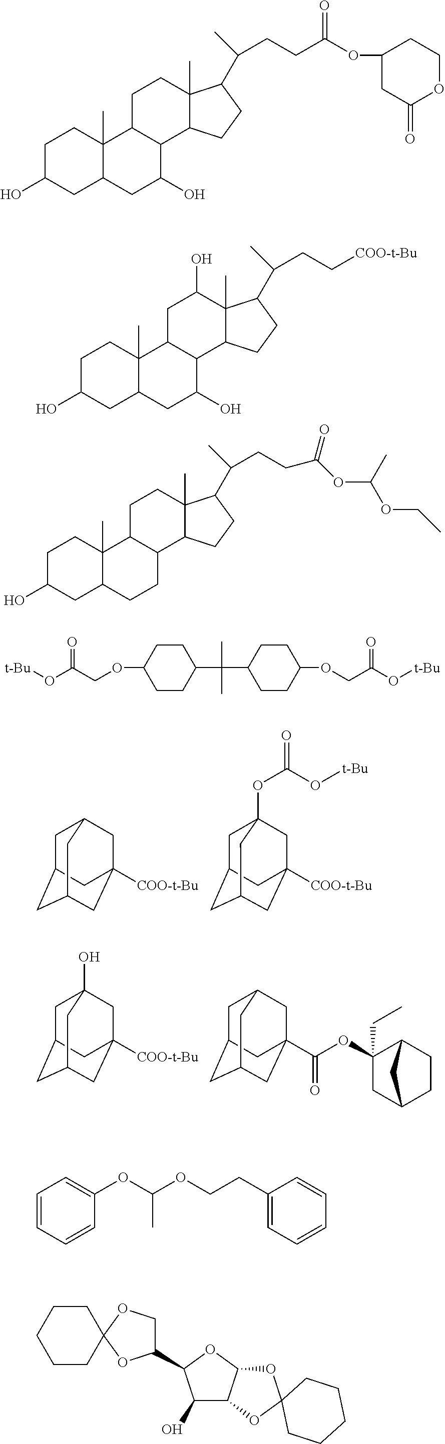

<Other Additives>

The composition according to the present invention may further contain a dye, a plasticizer, a photosensitizer, a light absorber, and/or a compound capable of increasing the solubility in a developer (for example, a phenolic compound of 1000 or less molecular weight or a carboxylated alicyclic or aliphatic compound), etc.

The above phenolic compound of 1000 or less molecular weight can be easily synthesized by persons of ordinary skill in the art while consulting the processes described in, for example, JP-As 4-122938 and 2-28531, U.S. Pat. No. 4,916,210, and EP 219294.

As the nonlimiting examples of the carboxylated alicyclic or aliphatic compound, a carboxylic acid derivative of steroid structure such as cholic acid, deoxycholic acid or lithocholic acid, an adamantanecarboxylic acid derivative, adamantanedicarboxylic acid, cyclohexanecarboxylic acid, and cyclohexanedicarboxylic acid can be exemplified.

<Method of Forming Pattern>

From the viewpoint of enhancing the resolving power, it is preferred for the composition of the present invention to be used with a film thickness of 30 to 250 nm. More preferably, the composition is used with a film thickness of 30 to 200 nm. This film thickness can be attained by setting the solid content of the actinic-ray- or radiation-sensitive resin composition within an appropriate range so as to cause the composition to have an appropriate viscosity, thereby improving the applicability and film forming property.

The total solid content of the composition of the present invention is generally in the range of 1 to 10 mass %, preferably 1 to 8.0 mass % and more preferably 1.0 to 7.0 mass %.

The composition of the present invention is used in such a manner that the above components are dissolved in a given organic solvent, preferably the above mixed solvent, and filtered and applied onto a given support in the following manner. Preferably, the filter medium for the filtration is made of a polytetrafluoroethylene, polyethylene or nylon having a pore size of 0.1 μm or less, especially 0.05 μm or less and further especially 0.03 μm or less.

For example, the actinic-ray- or radiation-sensitive resin composition is applied onto a substrate, such as one for use in the production of precision integrated circuit elements (e.g., silicon/silicon dioxide coating), by appropriate application means, such as a spinner or coater, and dried to thereby form a film.

The obtained film is exposed through a given mask to actinic rays or radiation, preferably baked (heated), developed and rinsed. Thus, a desirable pattern can be obtained.

As the actinic rays or radiation, infrared rays, visible light, ultraviolet rays, far ultraviolet rays, extreme ultraviolet rays (EUV), X-rays, and electron beams can be exemplified. Among them, preferred use is made of far ultraviolet rays with wavelength of preferably 250 nm or less, more preferably 220 nm or less, and still more preferably 1 to 200 nm, such as a KrF excimer laser (248 nm), an ArF excimer laser (193 nm) and an F₂ excimer laser (157 nm), EUV (13 nm) and electron beams.

The application of the composition to the substrate can be preceded by the application of an antireflection film.

As the anti-reflection film, use can be made of not only an inorganic film of titanium, titanium oxide, titanium nitride, chromium oxide, carbon, amorphous silicon or the like but also an organic film composed of a light absorber and a polymer material. Also, as the organic anti-reflection film, use can be made of commercially available organic anti-reflection films, such as the DUV30 Series and DUV40 Series produced by Brewer Science Inc. and AR-2, AR-3 and AR-5 produced by Shipley Co., Ltd.

Generally, an aqueous solution of any of quaternary ammonium salts, a typical example thereof being tetramethylammonium hydroxide, is employed as the alkali developer for use in the development operation. However, other aqueous alkali solutions of an inorganic alkali, a primary amine, a secondary amine, a tertiary amine, an alcoholamine, a cycloamine, etc. can also be employed.

An appropriate amount of alcohol and/or surfactant may be added to the alkali developer.

The alkali concentration of the alkali developer is generally in the range of 0.1 to 20 mass %.

The pH value of the alkali developer is generally in the range of 10.0 to 15.0.

Pure water is used as the rinse liquid. An appropriate amount of surfactant may be added to the rinse liquid before use.

The development operation or rinse operation may be followed by the operation for removing any portion of developer or rinse liquid adhering onto the pattern by use of a supercritical fluid.

A liquid immersion exposure may be carried out for the film produced from the composition of the present invention. Namely, the film may be exposed to actinic rays or radiation under the conditions that the space between the film and a lens is filled with a liquid whose refractive index is higher than that of air. If so, an enhanced resolution can be attained.

The liquid for liquid immersion for use in the liquid immersion exposure will now be described.

The liquid for liquid immersion preferably consists of a liquid being transparent in exposure wavelength whose temperature coefficient of refractive index is as low as possible so as to ensure minimization of any distortion of optical image projected on the resist film. Especially in the use of an ArF excimer laser (wavelength: 193 nm) as an exposure light source, however, it is more preferred to use water from not only the above viewpoints but also the viewpoints of easy procurement and easy handling.

For the attainment of further wavelength shortening, use can be made of a medium whose refractive index is 1.5 or higher. This medium may be an aqueous solution or an organic solvent.

In the use of water as a liquid for liquid immersion, a slight proportion of additive (liquid) that would not dissolve the resist film on a wafer and would be negligible with respect to its influence on an optical coat for an under surface of lens element may be added in order to not only decrease the surface tension of water but also increase a surface activating power.

The additive is preferably an aliphatic alcohol with a refractive index approximately equal to that of water, for example, methyl alcohol, ethyl alcohol, isopropyl alcohol or the like. The addition of an alcohol with a refractive index approximately equal to that of water is advantageous in that even when the alcohol component is evaporated from water to thereby cause a change of content concentration, the change of refractive index of the liquid as a whole can be minimized. On the other hand, when a substance being opaque in 193 nm rays or an impurity whose refractive index is greatly different from that of water is mixed therein, the mixing would invite a distortion of optical image projected on the resist film. Accordingly, it is preferred to use distilled water as the liquid immersion water. Furthermore, use may be made of pure water having been filtered through an ion exchange filter or the like.

Desirably, the electrical resistance of the water is 18.3 MQcm or higher, and the TOC (organic matter concentration) thereof is 20 ppb or below. Prior deaeration of the water is desired.

Raising the refractive index of the liquid for liquid immersion would enable an enhancement of lithography performance. From this viewpoint, an additive suitable for refractive index increase may be added to the water, or heavy water (D₂O) may be used in place of water.

### EXAMPLE

Embodiments of the present invention will be described in greater detail below by way of Examples thereof. The scope of the present invention is in no way limited to these Examples.

### Resin (A)

### Resin Synthetic Example 1

### Synthesis Of Resin (A1)

In a nitrogen gas stream, 8.6 g of cyclohexanone was placed in a three-necked flask and heated at 80° C. A solution obtained by dissolving 9.8 g of 2-adamantylisopropyl methacrylate, 4.4 g of dihydroxyadamantyl methacrylate, 8.9 g of norbornane lactone methacrylate and further, 8 mol % based on the monomers, of polymerization initiator V601 (produced by Wako Pure Chemical Industries, Ltd.) in 79 g of cyclohexanone was dropped thereinto over a period of 6 hours. After the completion of the dropping, reaction was continued at 80° C. for 2 hours. The thus obtained reaction liquid was allowed to stand still to cool and was dropped into a mixed liquid consisting of 800 g of hexane and 200 g of ethyl acetate over a period of 20 minutes. The thus precipitated powder was collected by filtration and dried, thereby obtaining 19 g of resin (A1). The weight average molecular weight of the obtained resin in terms of standard polystyrene equivalent was 8800 and the dispersity (Mw/Mn) thereof was 1.9.

In the same manner as described above, the following other resins (A2) to (A25) were synthesized.

The structures of the acid-decomposable resins (A) employed in the Examples are shown below. Further, Table 1 below gives the molar ratios of individual repeating units (in order from the left in structural formulae), the weight average molecular weight (Mw) and the dispersity (Mw/Mn) with respect to each of the resins.

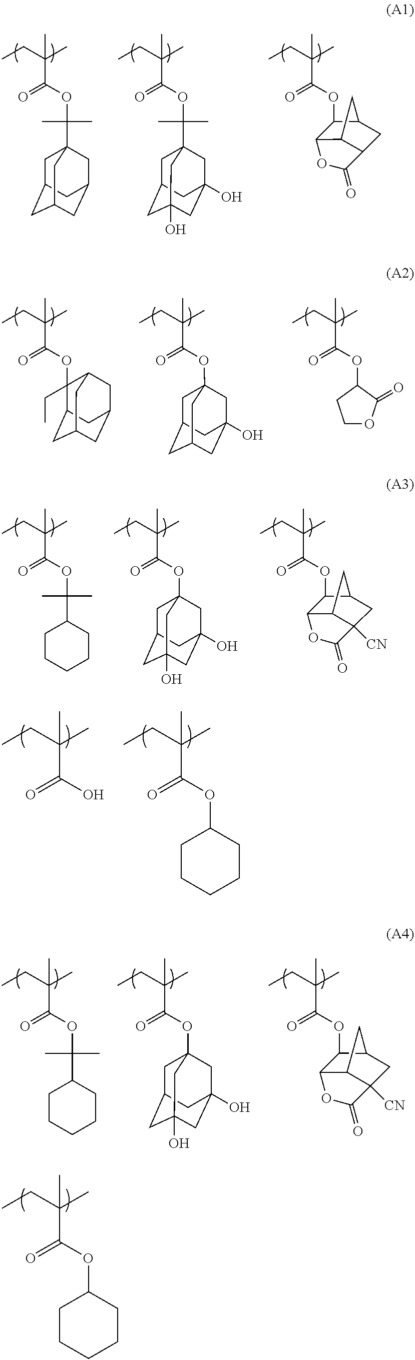

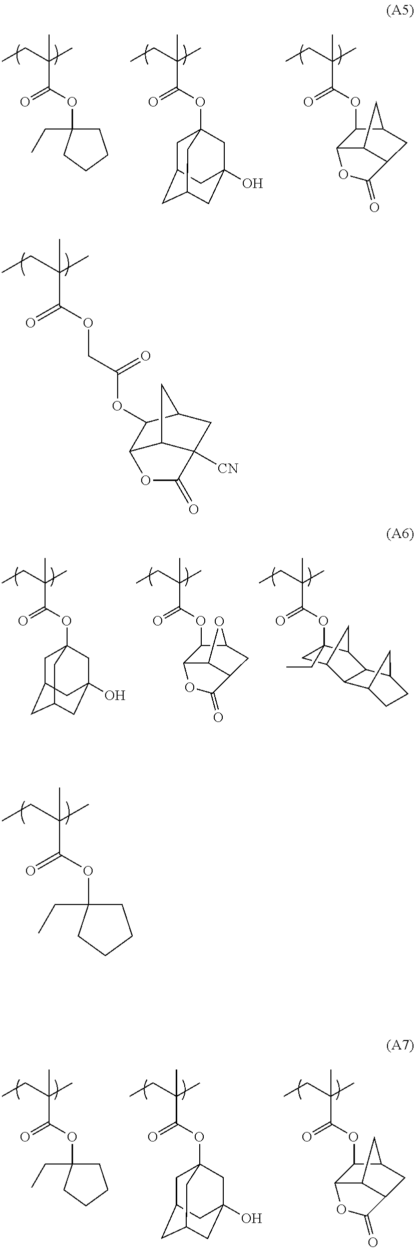

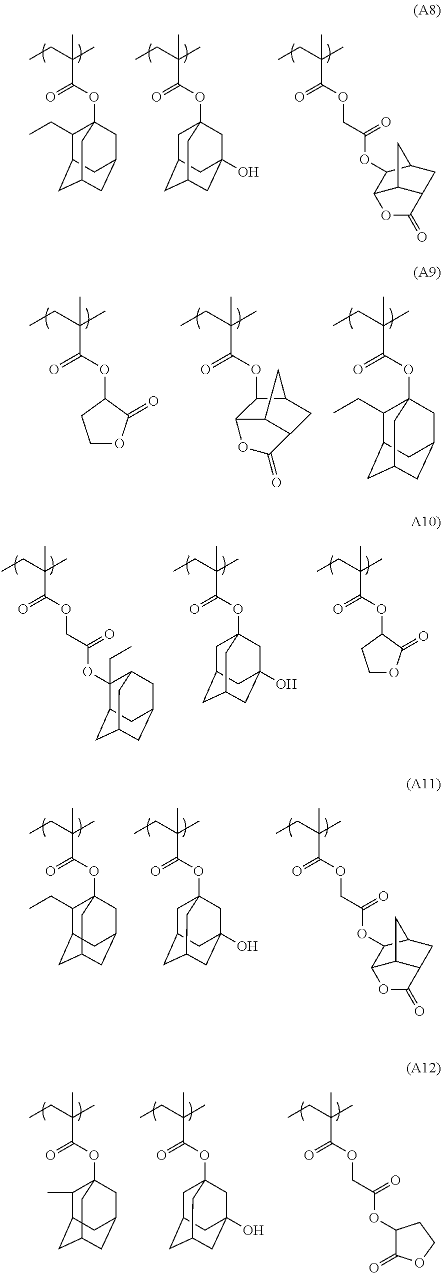

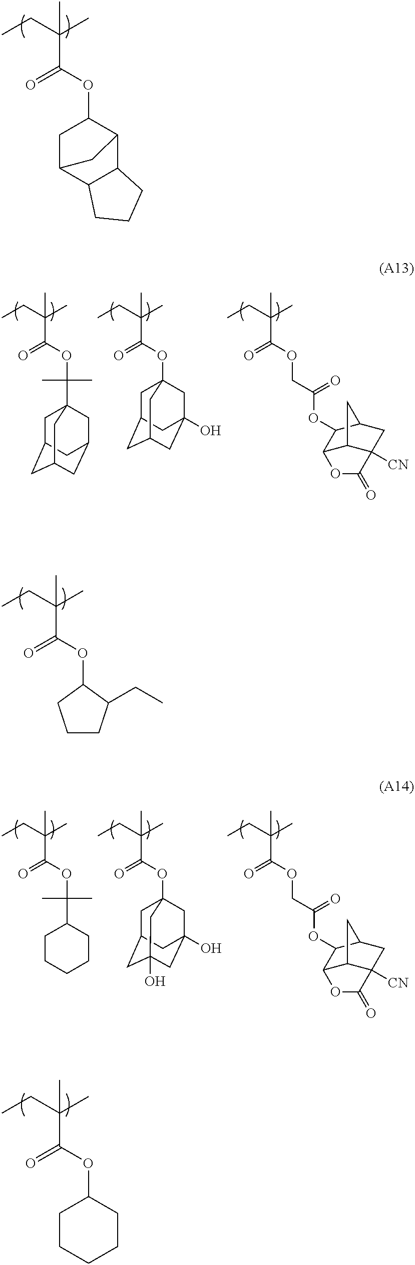

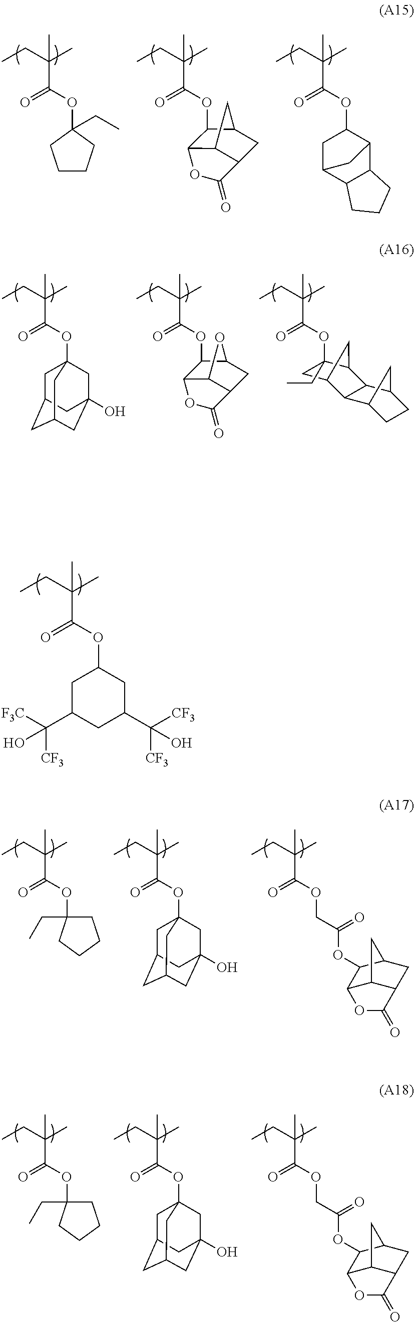

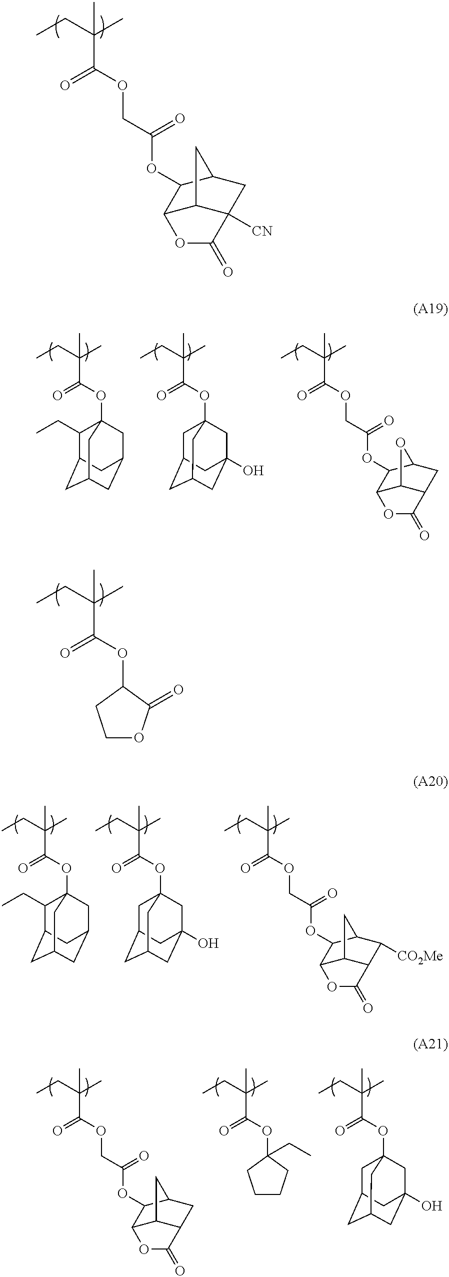

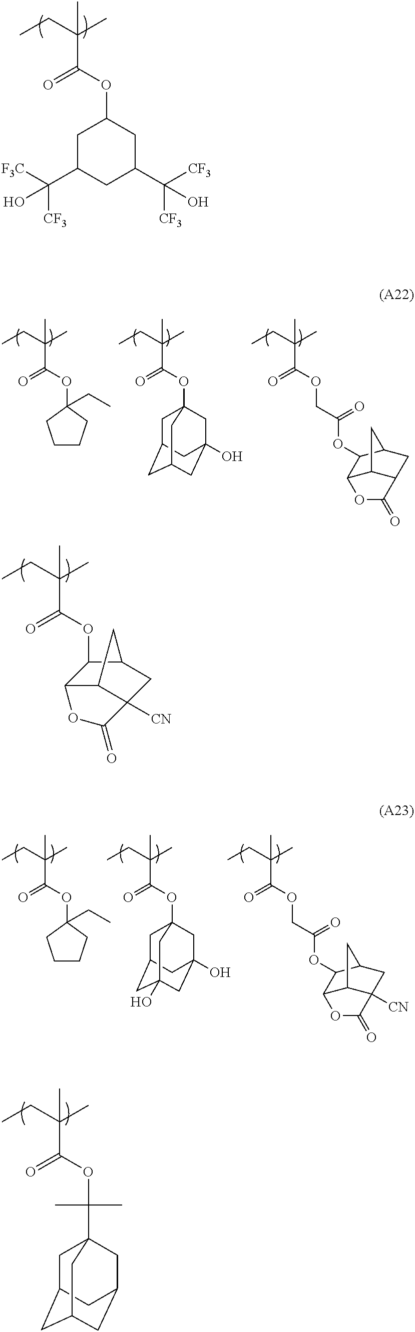

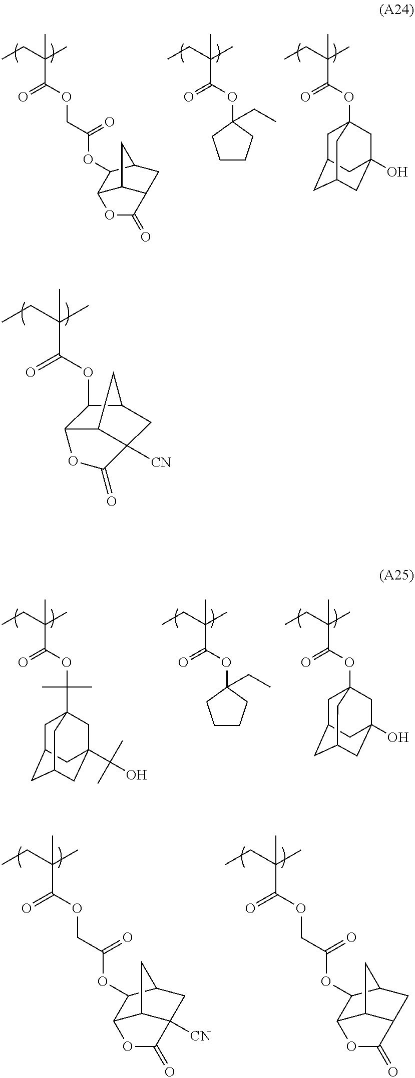

TABLE 1

| Resin | Composition | | |
|---|---|---|---|
| (A) | (molar ratio) | Mw | Mw/Mn |
| A1 | 39/18/43 | 8800 | 1.9 |
| A2 | 40/20/40 | 7000 | 1.6 |
| A3 | 40/10/35/5/10 | 10000 | 1.7 |
| A4 | 40/10/40/10 | 11000 | 1.8 |
| A5 | 40/15/20/25 | 8500 | 1.6 |
| A6 | 10/40/25/25 | 12000 | 1.8 |
| A7 | 50/20/30 | 6500 | 1.6 |
| A8 | 40/10/50 | 8000 | 1.7 |
| A9 | 25/25/50 | 9000 | 1.8 |
| A10 | 50/10/40 | 11000 | 1.8 |
| A11 | 50/10/40 | 8000 | 1.7 |
| A12 | 40/10/40/10 | 7000 | 1.7 |
| A13 | 20/15/35/30 | 10000 | 1.7 |
| A14 | 45/10/35/10 | 8500 | 1.7 |
| A15 | 50/40/10 | 10000 | 1.6 |
| A16 | 10/40/40/10 | 9000 | 1.8 |
| A17 | 55/10/35 | 12000 | 1.8 |
| A18 | 40/15/20/25 | 9000 | 1.7 |
| A19 | 40/15/30/15 | 7500 | 1.6 |
| A20 | 40/15/45 | 8000 | 1.6 |
| A21 | 40/40/10/10 | 9500 | 1.8 |
| A22 | 35/15/25/25 | 10000 | 1.7 |
| A23 | 30/15/40/15 | 8000 | 1.6 |
| A24 | 25/35/15/25 | 9000 | 1.8 |
| A25 | 15/30/10/23/22 | 10000 | 1.7 |

### Resin (B)

### Monomer Synthetic Example 1

### Synthesis Of Monomer 1

Monomer 1 of the formula below was synthesized in accordance with the process described in, for example, US 2010/0152400 A, WO 2010/067905 A and WO 2010/067898 A.

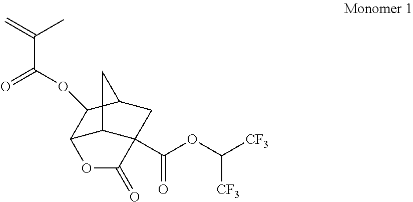 [SMILES: C=C(C)C(=O)OC1C2CC3C1OC(=O)C3(C(=O)OC(C(F)(F)F)C(F)(F)F)C2]

### Monomer Synthetic Example 2

### Synthesis Of Monomer 2

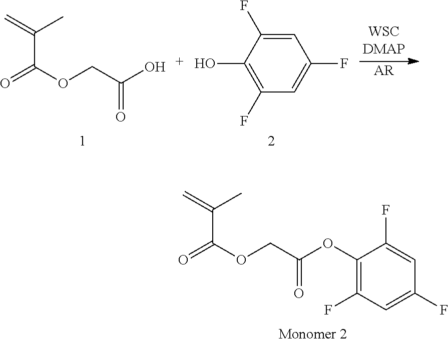

Compound 1 was synthesized in accordance with the process described in, for example, JP-A-2009-175363 and JP-A-2010-2870.

Then, 3.50 g of compound 1, 3.60 g of compound 2 and 0.29 g of 4-dimethylaminopyridine (DMAP) were dissolved in 30 g of acetonitrile (AR). Under agitation, 5.12 g of 1-ethyl-3-(3-dimethylaminopropyl)carbodiimide hydrochloride (WSC) was added to the solution, and agitated for 3 hours. The thus obtained reaction solution was poured into 500 ml of 1N HCl to thereby terminate the reaction. The thus obtained organic phase was washed with 1N HCl, then with water. The organic phase was concentrated and purified through column chromatography. As a result, 4.33 g of monomer 2 was obtained (yield 65%).

The following monomers 3 to 9 were synthesized in the same manner as above except that the corresponding phenol or alcohol was used.

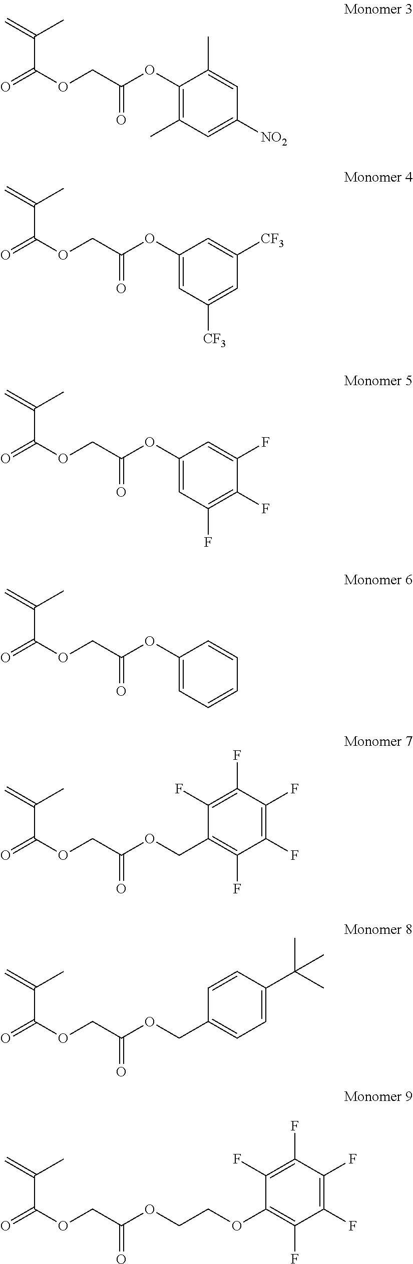

### Monomer Synthetic Example 3

### Synthesis Of Monomer 10

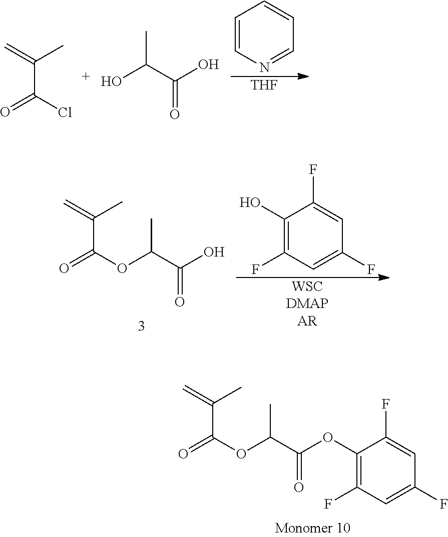

First, 1.0 g of DL-lactic acid and 1.3 g of pyridine were dissolved in 10 g of tetrahydrofuran, and cooled to 10° C. or below. While maintaining the temperature of the reaction liquid at 10° C. or below, 1.2 g of methacrylic chloride was dropped thereinto. After the completion of the dropping, the temperature was returned to room temperature, and agitated for 3 hours. Thereafter, 50 ml of 1N aqueous HCl solution was added to the reaction liquid, and extracted with 100 ml of ethyl acetate. Magnesium sulfate was added to the thus obtained organic phase, and filtered. The filtrate was concentrated, thereby obtaining 1.5 g of compound 3 (crude product).

Monomer 10 was synthesized in the same manner as in the Monomer Synthetic Example 2 except that compound 3 was used in place of the above compound 1.

Monomer 11 of the formula below was synthesized in the same manner as above except that the corresponding phenol was used.

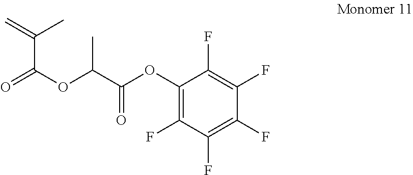 [SMILES: C=C(C)C(=O)OC(C)C(=O)Oc1c(F)c(F)c(F)c(F)c1F]

### Monomer Synthetic Example 4

### Synthesis Of Monomer 12

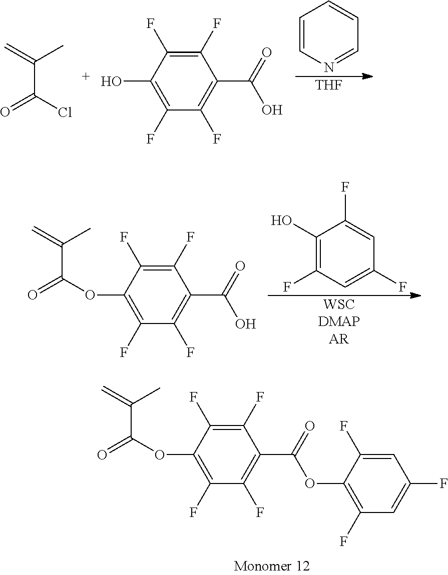

Monomer 12 was synthesized in the same manner as in the Monomer Synthetic Example 3 except that 2,3,5,6-tetrafluoro-4-hydroxybenzoic acid was used in place of DL-lactic acid.

Monomers 13 and 14 of the formulae below were synthesized in the same manner as above except that the corresponding phenols were used.

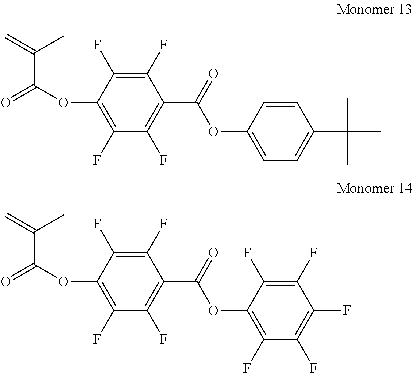

### Monomer Synthetic Example 5

### Synthesis of Monomer 15

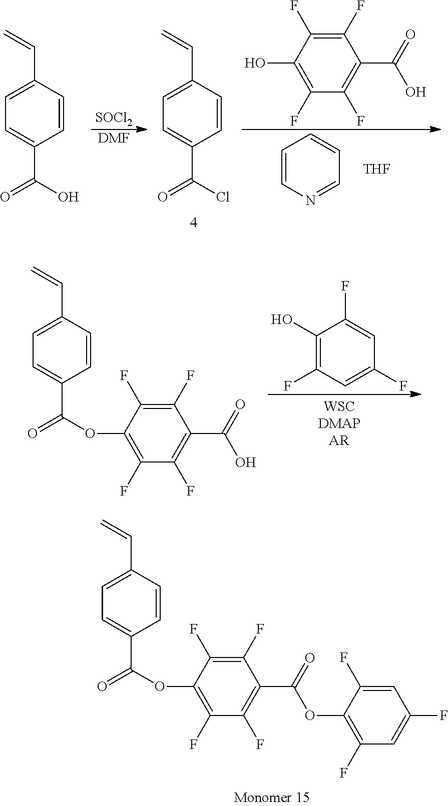

First, 0.13 ml of dimethylformamide and 2.00 g of thionyl chloride were added to 2.00 g of 4-vinylbenzoic acid. The reaction solution was heated to 75° C. and agitated over a period of an hour. After the completion of the reaction, in vacuum, any unreacted thionyl chloride was removed. As a result, compound (4) was obtained.

Monomer 15 was synthesized in the same manner as in the Monomer Synthetic Example 4 except that compound (4) was used in place of methacrylic chloride.

Monomers 16 and 17 of the formulae below were synthesized in the same manner as above except that the corresponding phenols were used.

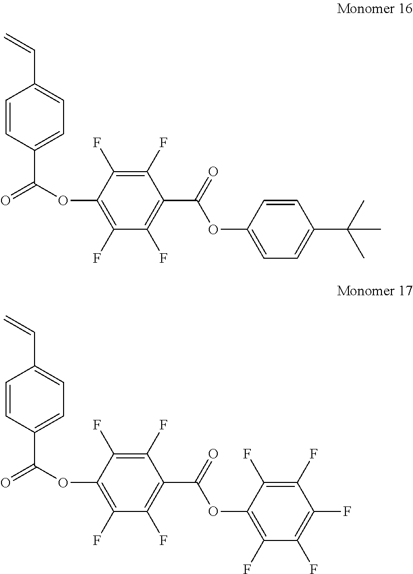 [SMILES: C=Cc1ccc(C(=O)Oc2c(F)c(F)c(C(=O)Oc3ccc(C(C)(C)C)cc3)c(F)c2F)cc1 ; C=Cc1ccc(C(=O)Oc2c(F)c(F)c(C(=O)Oc3c(F)c(F)c(F)c(F)c3F)c(F)c2F)cc1]

### Resin Synthetic Example 2

### Synthesis Of Resin (B1)

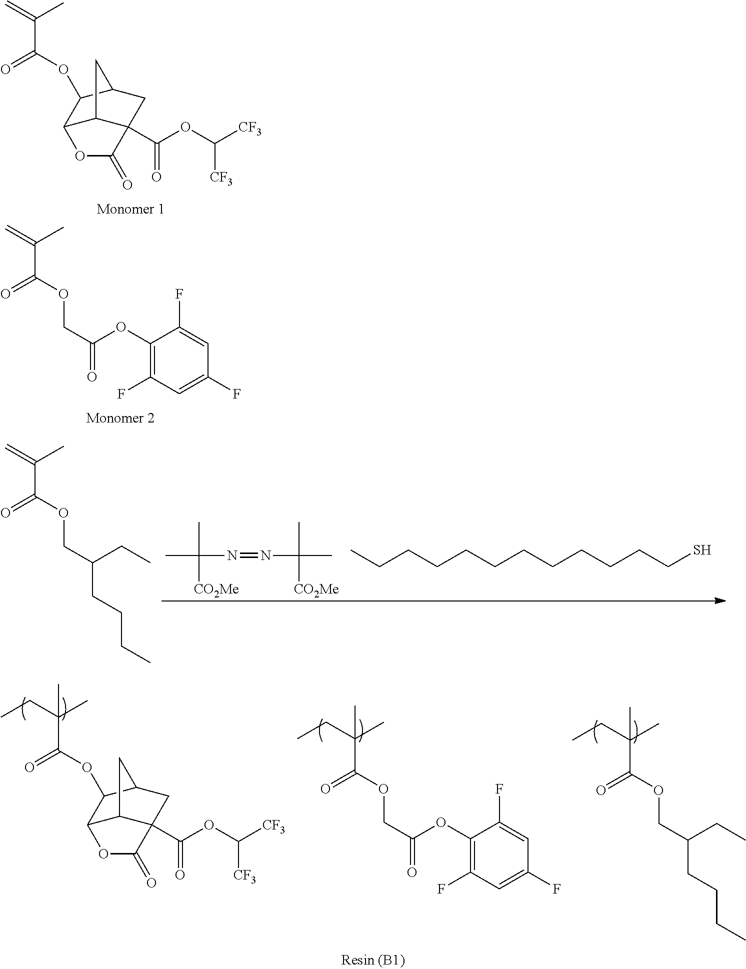

In a nitrogen gas stream, 2.00 g of methyl ethyl ketone as a solvent was placed in a flask, and heated to 78° C. A solution obtained by dissolving 3.75 g of monomer 1, 1.56 g of monomer 2, 0.06 g of 2-ethylhexyl methacrylate, 0.10 g of polymerization initiator V-601 (produced by Wako Pure Chemical Industries, Ltd.) and 0.09 g or 1-dodecanethiol in 8.00 g of methyl ethyl ketone was dropped into the heated solvent over a period of four hours. After the completion of the dropping, reaction was continued at 78° C. for 2 hours. The thus obtained reaction liquid was allowed to stand still to cool, and was dropped into a liquid mixture consisting of 87.00 g of heptane and 21.70 g of ethyl acetate. The thus precipitated powder was collected by filtration, and dried, thereby obtaining 3.81 g of resin (B1) (yield 71.0%). With respect to the obtained resin, the standard-polystyrene-equivalent weight average molecular weight was 10,700 and the dispersity (Mw/Mn) was 1.4.

The following other resins (B2) to (B21) and (B23) to (B27) were synthesized in the same manner as described above.

### Resin Synthetic Example 3

### Synthesis of Resin (B22)

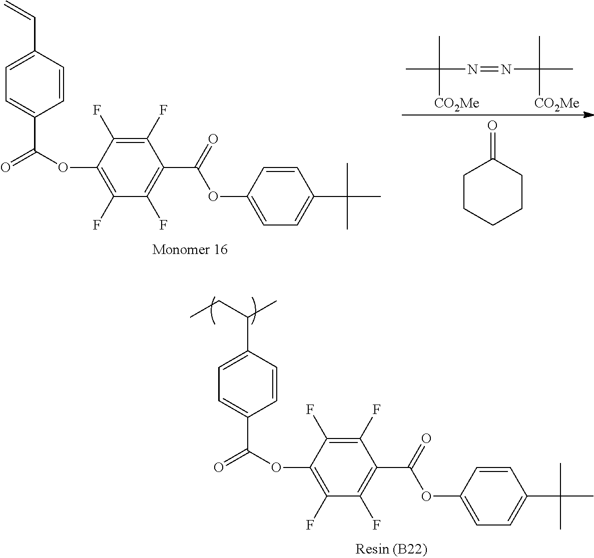

First, 4.72 g of monomer 16 and 8.80 g of cyclohexanone were placed in a flask, and the monomer was dissolved in the cyclohexanone. The solution was heated to 85° C. in a nitrogen gas stream, and 0.16 g of polymerization initiator V-601 (produced by Wako Pure Chemical Industries, Ltd.) was added to the heated solution. Reaction was continued for 6 hours. The thus obtained reaction liquid was allowed to stand still to cool and diluted with 9.94 g of cyclohexanone. The dilution was dropped into 165.20 g of methanol. The thus precipitated powder was collected by filtration, and dried, thereby obtaining 3.54 g of resin (B22) (yield 74.9%). With respect to the obtained resin, the standard-polystyrene-equivalent weight average molecular weight was 21,300, and the dispersity (Mw/Mn) was 1.9.

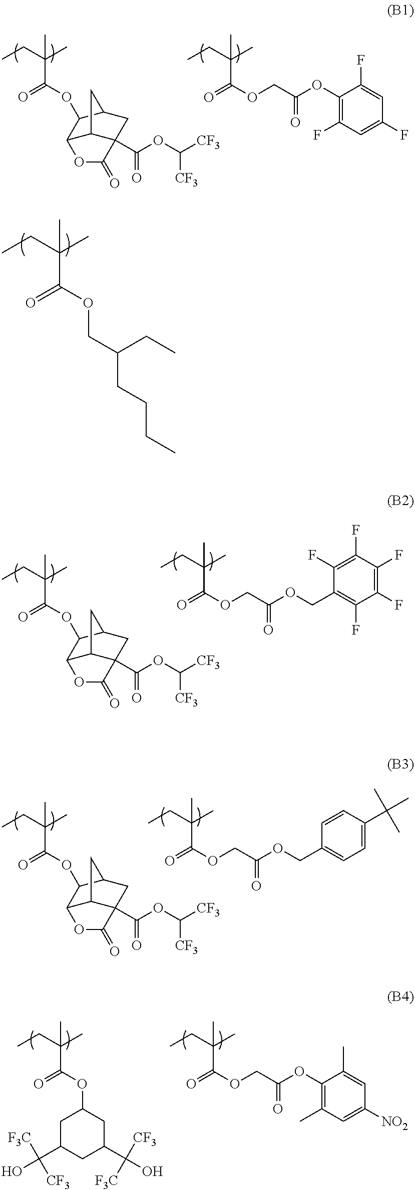

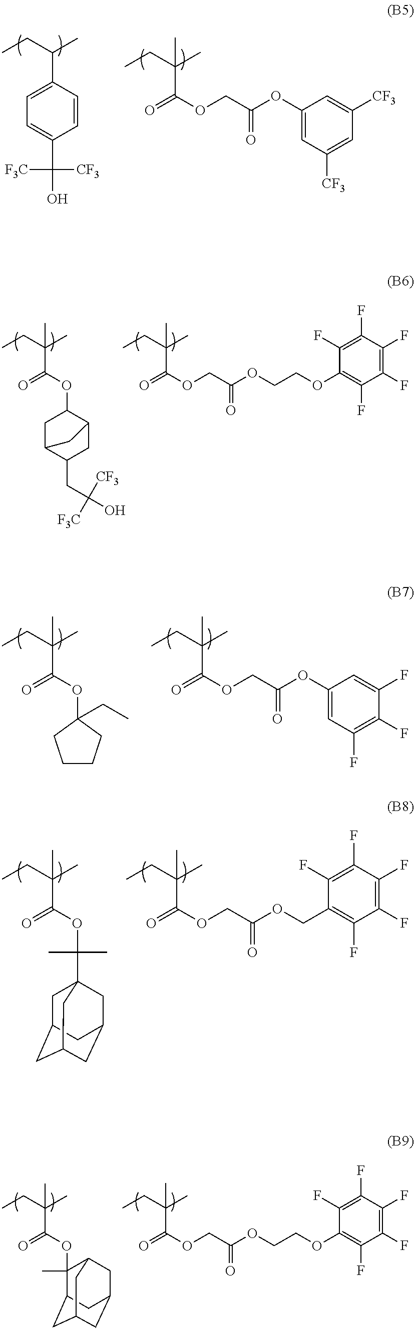

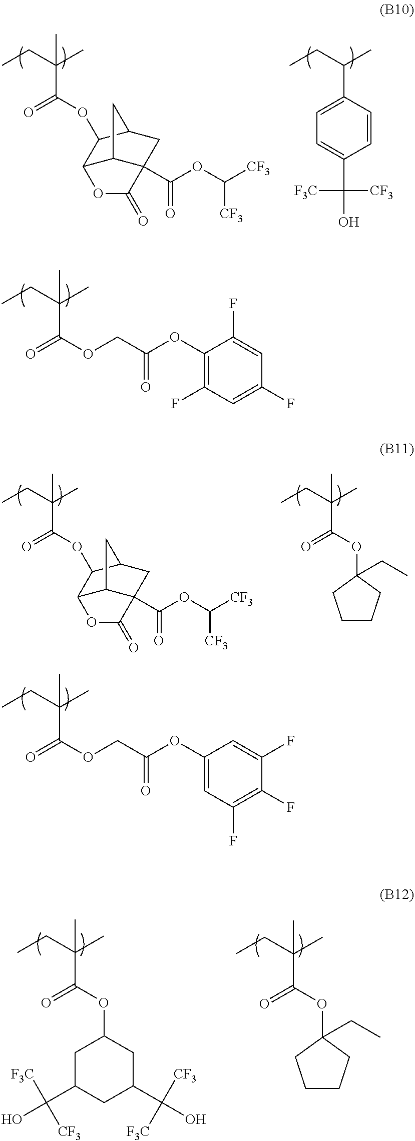

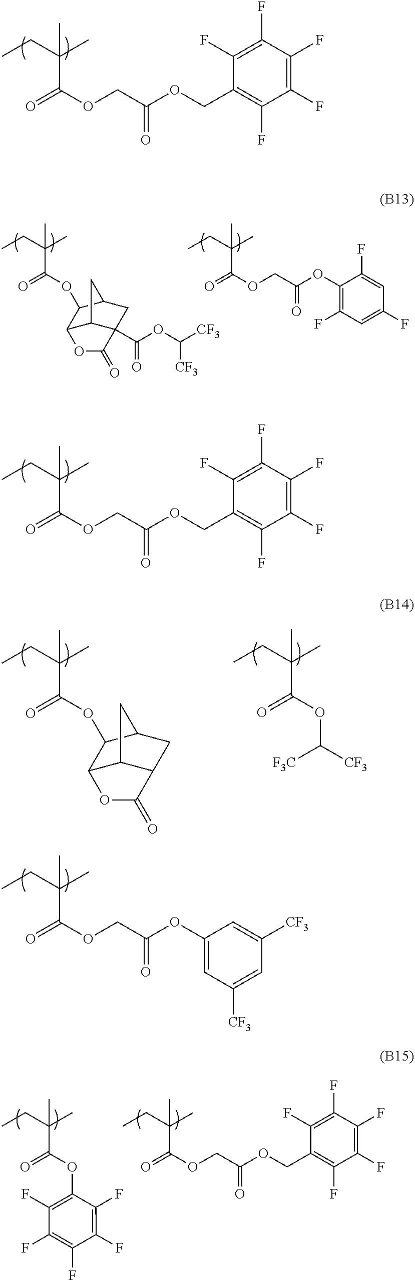

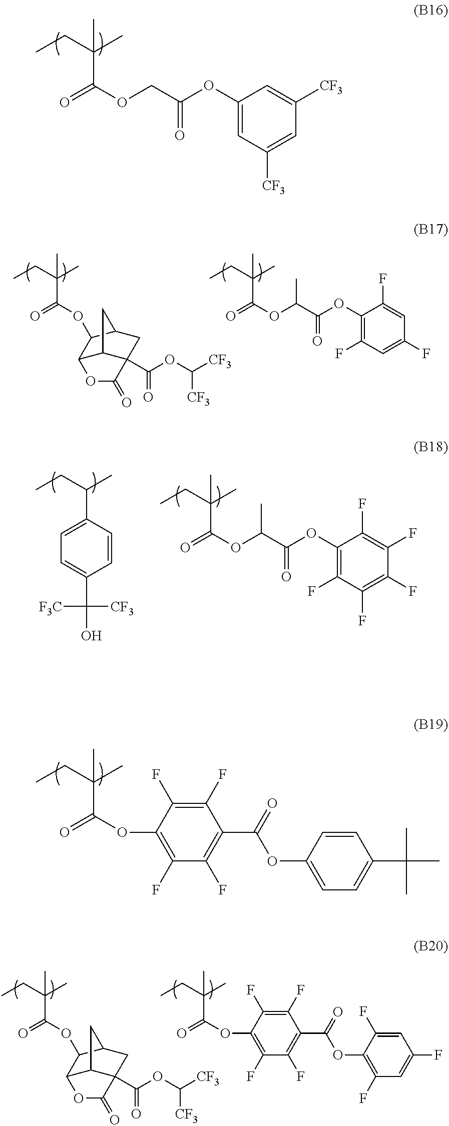

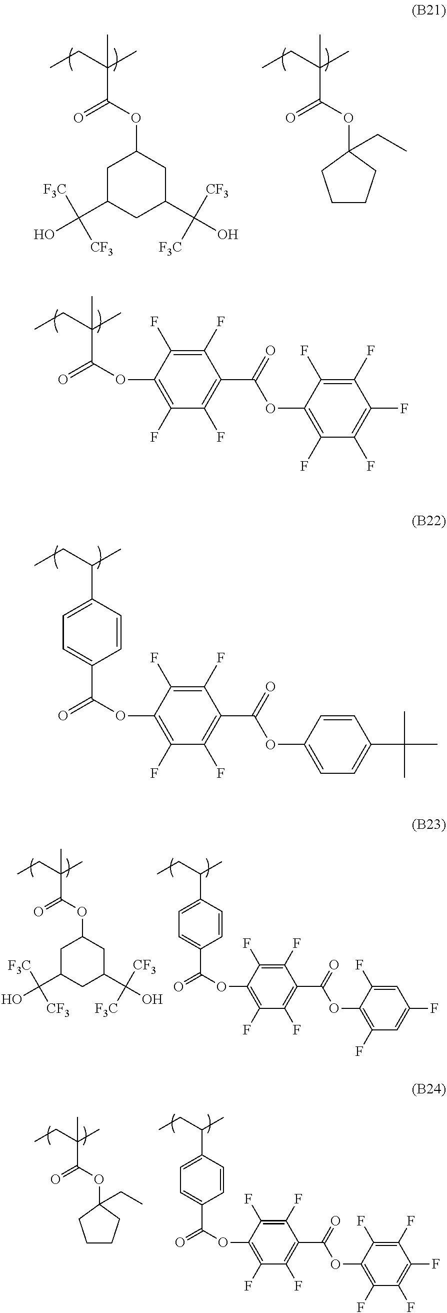

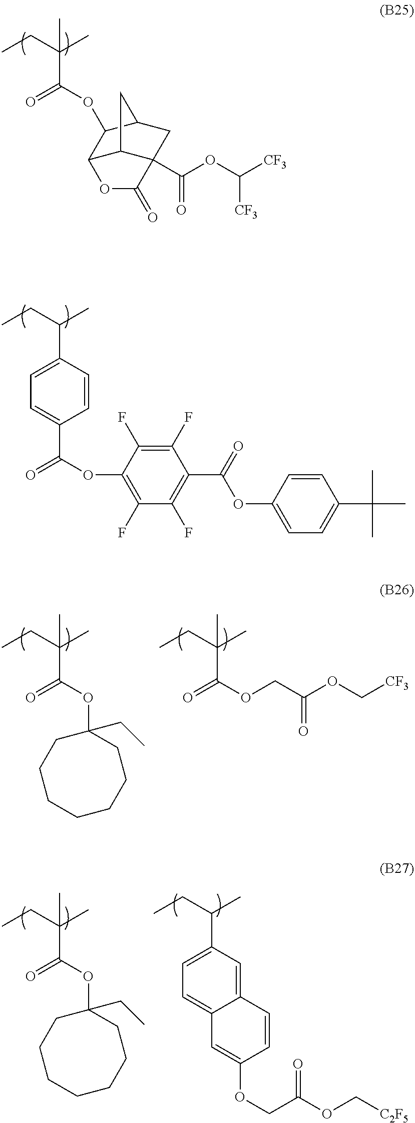

TABLE 2

| | Charged amt. ratio | | | | |
|---|---|---|---|---|---|
| Polymer | (mol %) | | | Mw | Mw/Mn |
| B1 | 60 | 38 | 2 | 10700 | 1.4 |
| B2 | 80 | 20 | — | 11300 | 1.5 |
| B3 | 70 | 30 | — | 11800 | 1.4 |
| B4 | 50 | 50 | — | 9500 | 1.6 |
| B5 | 70 | 30 | — | 8700 | 1.6 |
| B6 | 40 | 60 | — | 12100 | 1.5 |
| B7 | 50 | 50 | — | 8700 | 1.6 |
| B8 | 40 | 60 | — | 12000 | 1.6 |
| B9 | 30 | 70 | — | 11500 | 1.5 |
| B10 | 50 | 10 | 40 | 9700 | 1.6 |
| B11 | 50 | 10 | 40 | 11100 | 1.7 |
| B12 | 40 | 20 | 40 | 11600 | 1.6 |
| B13 | 70 | 20 | 10 | 12100 | 1.5 |
| B14 | 50 | 20 | 30 | 7500 | 1.7 |
| B15 | 80 | 20 | — | 13300 | 1.5 |
| B16 | 100 | — | — | 11600 | 1.5 |
| B17 | 70 | 30 | | 11000 | 1.4 |
| B18 | 85 | 15 | — | 10500 | 1.5 |
| B19 | 100 | — | — | 12100 | 1.8 |
| B20 | 50 | 50 | | 10100 | 1.3 |
| B21 | 20 | 30 | 50 | 13000 | 1.4 |
| B22 | 100 | — | — | 21300 | 1.9 |
| B23 | 30 | 70 | — | 10500 | 1.4 |
| B24 | 30 | 70 | — | 11000 | 1.3 |
| B25 | 40 | 60 | | 9500 | 1.4 |
| B26 | 43 | 57 | — | 12100 | 1.6 |
| B27 | 25 | 75 | — | 12500 | 1.5 |

<Preparation of Actinic-Ray- or Radiation-Sensitive Resin Composition>

As listed in Table 3 below, individual components were dissolved in solvents, thereby obtaining solutions of 5 mass % solid content. The solutions were each passed through a polyethylene filter of 0.1 μm pore size, thereby obtaining actinic-ray- or radiation-sensitive resin compositions (positive photosensitive resin compositions). The thus obtained positive photosensitive resin compositions were evaluated by the following methods, and the evaluation results are given in Table 3.

<Image Performance Test>

[Exposure Condition: ArF Liquid-Immersion Exposure]

An organic antireflection film ARC29SR (produced by Nissan Chemical Industries, Ltd.) was applied onto a silicon wafer (12 inch caliber) and baked at 205° C. for 60 seconds, thereby forming a 98 nm-thick antireflection film. Each of the prepared positive photosensitive resin compositions was applied thereonto and baked at 120° C. for 60 seconds, thereby forming a 120 nm-thick photosensitive film. The resultant wafer was exposed through a 6% half-tone mask of 1:1 line and space pattern of 75 nm line width by means of an ArF excimer laser liquid-immersion scanner (manufactured by ASML, XT1700i, NA 1.20, C-Quad, outer sigma 0.981, inner sigma 0.895, XY deflection). Ultrapure water was used as the immersion liquid. Thereafter, the exposed wafer was baked at 120° C. for 60 seconds, developed with an aqueous solution of tetramethylammonium hydroxide (2.38 mass %) for 30 seconds, rinsed with pure water and spin dried, thereby obtaining a resist pattern.

[Development Defect]

With respect to each of the patterns formed on a silicon wafer (12 inch caliber) in the above-mentioned manner, random-mode measurement was carried out by means of a defect inspection apparatus KLA2360 (trade name) manufactured by KLA-Tencor Corporation. In the defect inspection apparatus, the pixel size was set at 0.16 μm and the threshold value at 20. Any development defects extracted from differences generated by superimposition between a comparative image and the pixel unit were detected, and the number of development defects per area was calculated. The evaluation marks ∘* (excellent), ∘ (good), Δ (fair) and x (insufficient) were given when the calculated value was less than 0.5, 0.5 to less than 1.0, 1.0 to less than 5.0 and 5.0 or greater, respectively. The less the value thereof, the better the performance exhibited.

[Receding Contact Angle]

Each of the prepared positive photosensitive resin compositions was applied onto a silicon wafer (8 inch caliber), and baked at 120° C. for 60 seconds, thereby forming a 120 nm-thick photosensitive film. The receding contact angle of each of the films with respect to a water droplet was measured in accordance with a dilation/contraction method by means of a dynamic contact angle meter (manufactured by Kyowa Interface Science Co., Ltd.). The receding contact angle was defined as the value of dynamic contact angle at which, in the five-seconds suction of a droplet of 35 μL initial size at a rate of 6 μL/second, the dynamic contact angle during suction was stabilized. The measurement was performed in an atmosphere of 23±3° C. and 45±5% relative humidity. The greater the value of the receding contact angle, the greater the scan speed at which water tracking is ensured.

TABLE 3

| | | | Acid | Basic | Surfac- | Organic | Devel- | Receding |
|---|---|---|---|---|---|---|---|---|
| | Resin A | Resin B | generator | comp. | tant | solvent | opment | contact |
| Ex. | (2 g) | (mg) | (mg) | (mg) | (mg) | (mass ratio) | defect | angle(°) |
| 1 | A1 | B1 | PAG1 | TMEA(10) | — | S1-1/S2-1 | ∘* | 82 |
| | | (80) | (600) | | | (8/2) | | |
| 2 | A2 | B2 | PAG2 | DIA(6) | W-1 | S1-1/S2-1 | ∘* | 82 |
| | | (80) | (400) | | (3) | (6/4) | | |
| 3 | A3 | B3 | PAG3/PAG5 | DIA(14) | W-3 | S1-1/S2-1 | ∘ | 80 |
| | | (100) | (610/50) | | (3) | (7/3) | | |
| 4 | A4 | B4 | PAG4 | DIA(10) | W-4 | S1-1/S2-1 | ∘* | 75 |
| | | (20) | (400) | | (2) | (8/2) | | |
| 5 | A5 | B5 | PAG5 | TOA(6) | — | S1-1/S2-1 | ∘* | 75 |
| | | (80) | (400) | | | (7/3) | | |
| 6 | A6 | B6 | PAG6 | DIA(10) | W-2 | S1-1/S2-2 | ∘ | 76 |
| | | (80) | (400) | | (2) | (9.5/0.5) | | |
| 7 | A7 | B7 | PAG7 | PEA(5) | W-4 | S1-1/S2-1 | ∘ | 80 |
| | | (20) | (550) | | (2) | (8/2) | | |
| 8 | A8 | B8 | PAG8 | DIA(5) | W-5 | S1-1/S2-1 | ∘ | 78 |
| | | (40) | (400) | | (3) | (8/2) | | |
| 9 | A9 | B9 | PAG1 | DIA(10) | W-5 | S1-1/S2-2 | Δ | 77 |
| | | (40) | (600) | | (3) | (9/1) | | |
| 10 | A10 | B10 | PAG2 | DHA(14) | W-1 | S1-1 | ∘* | 79 |
| | | (80) | (400) | | (3) | | | |
| 11 | A11 | B11 | PAG3 | PBI(8) | W-5 | S1-1/S2-1 | ∘ | 80 |
| | | (40) | (610) | | (3) | (8/2) | | |
| 12 | A12 | B12 | PAG4 | DIA(7) | W-5 | S1-1/S2-1 | ∘ | 79 |
| | | (80) | (400) | | (3) | (7/3) | | |
| 13 | A13 | B13 | PAG5 | DIA(10) | W-1 | S1-1/S2-1 | ∘* | 80 |
| | | (100) | (400) | | (3) | (8/2) | | |
| 14 | A14 | B14 | PAG6 | DIA(15) | W-5 | S1-1/S2-1 | ∘ | 78 |
| | | (80) | (400) | | (3) | (8/2) | | |
| 15 | A15 | B15 | PAG7 | DIA(10) | W-2 | S1-1/S2-3 | Δ | 79 |
| | | (40) | (550) | | (2) | (8/2) | | |
| 16 | A7 | B16 | PAG5 | DIA(10) | W-4 | S1-1/S2-1 | ∘ | 75 |
| | | (50) | (400) | | (2) | (8/2) | | |
| 17 | A8 | B17 | PAG6 | DHA(14) | W-1 | S1-1/S2-1 | ∘ | 82 |
| | | (60) | (400) | | (3) | (6/4) | | |
| 18 | A9 | B18 | PAG7 | PBI(8) | W-3 | S1-1/S2-1 | ∘ | 76 |
| | | (50) | (550) | | (3) | (7/3) | | |
| 19 | A10 | B19 | PAG5 | DIA(10) | W-2 | S1-1/S2-3 | ∘ | 77 |
| | | (60) | (400) | | (2) | (9/1) | | |
| 20 | A11 | B20 | PAG6 | DHA(14) | — | S1-1/S2-1 | ∘* | 82 |
| | | (50) | (400) | | | (6/4) | | |
| 21 | A12 | B21 | PAG7 | PBI(8) | — | S1-1/S2-3 | ∘ | 79 |
| | | (80) | (550) | | | (9/1) | | |
| 22 | A13 | B22 | PAG1 | TMEA(10) | W-1 | S1-1/S2-3 | ∘ | 78 |
| | | (40) | (600) | | (3) | (9/1) | | |
| 23 | A14 | B23 | PAG2 | DIA(6) | — | S1-1/S2-1 | ∘ | 76 |
| | | (75) | (400) | | | (9/1) | | |
| 24 | A15 | B24 | PAG1 | DIA(14) | — | S1-1/S2-2 | Δ | 79 |
| | | (60) | (600) | | | (9.8/0.2) | | |
| 25 | A16 | B25 | PAG4 | DIA(10) | W-4 | S1-1 | ∘* | 80 |
| | | (80) | (400) | | (2) | | | |
| 26 | A16 | B1 | PAG2/PAG7 | PEA(9) | W-1 | S1-1/S2-1 | ∘* | 82 |
| | | (80) | (50/550) | | (3) | (6/4) | | |
| 27 | A17 | B2 | PAG1/PAG8 | PEA(6) | W-4 | S1-1/S2-1 | ∘* | 82 |
| | | (80) | (600/60) | | (2) | (8/2) | | |
| 28 | A18 | B3 | PAG2/PAG7 | DIA(5) | W-2 | S1-1/S2-3 | ∘ | 80 |
| | | (100) | (50/550) | | (2) | (9/1) | | |
| 29 | A19 | B1/B3 | PAG3 | DIA(10) | W-3 | S1-1/S2-1 | ∘ | 81 |
| | | (40/5) | (610) | | (3) | (9/1) | | |
| 30 | A20 | B4/B5 | PAG4 | TMEA(10) | W-4 | S1-1/S2-1 | ∘* | 75 |
| | | (80/5) | (400) | | (2) | (9/1) | | |
| 31 | A21 | B7/B9 | PAG5 | DIA(6) | — | S1-1/S2-2 | ∘ | 78 |
| | | (40/5) | (400) | | | (9.8/0.2) | | |
| 32 | A22 | B1/B4 | PAG2/PAG7 | DIA(14) | W-1 | S1-1/S2-1 | ∘ | 79 |
| | | (80/5) | (50/550) | | (3) | (8/2) | | |
| 33 | A23 | B1/B7 | PAG1/PAG8 | DIA(10) | W-3 | Sl-1 | ∘ | 80 |
| | | (80/5) | (600/60) | | (3) | | | |
| 34 | A24 | B7/B4 | PAG2/PAG7 | TOA(6) | W-1 | S1-1/S2-1 | ∘ | 79 |
| | | (80/5) | (50/550) | | (3) | (7/3) | | |
| 35 | A25 | B7/B17 | PAG1 | DIA(10) | — | S1-1/S2-1 | ∘ | 80 |
| | | (80/5) | (600) | | | (8/2) | | |
| 36 | A16/A17 | B1 | PAG2 | PEA(5) | W-3 | S1-1/S2-2 | ∘* | 81 |
| | (1 g/1 g) | (80) | (400) | | (3) | (9.8/0.2) | | |
| 37 | A15/A19 | B2 | PAG3 | DIA(5) | W-1 | S1-1 | ∘* | 82 |
| | (1 g/1 g) | (80) | (610) | | (3) | | | |
| 38 | A14/A15 | B3 | PAG4 | DIA(10) | — | S1-1/S2-2 | ∘ | 81 |
| | (0.5 g/1.5 g) | (100) | (400) | | | (9.8/0.2) | | |
| Com. 1 | A1 | B26 | PAG5 | DIA(10) | W-1 | S1-1/S2-1 | x | 65 |
| | | (80) | (400) | | (3) | (8/2) | | |
| Com. 2 | A1 | B27 | PAG5 | DIA(10) | W-1 | S1-1/S2-1 | x | 66 |
| | | (80) | (400) | | (3) | (8/2) | | |

The resins (A) and resins (B) correspond to those set forth hereinbefore by way of example.

The employed acid generators, basic compounds, surfactants and solvents are as follows.

### (Acid Generator)

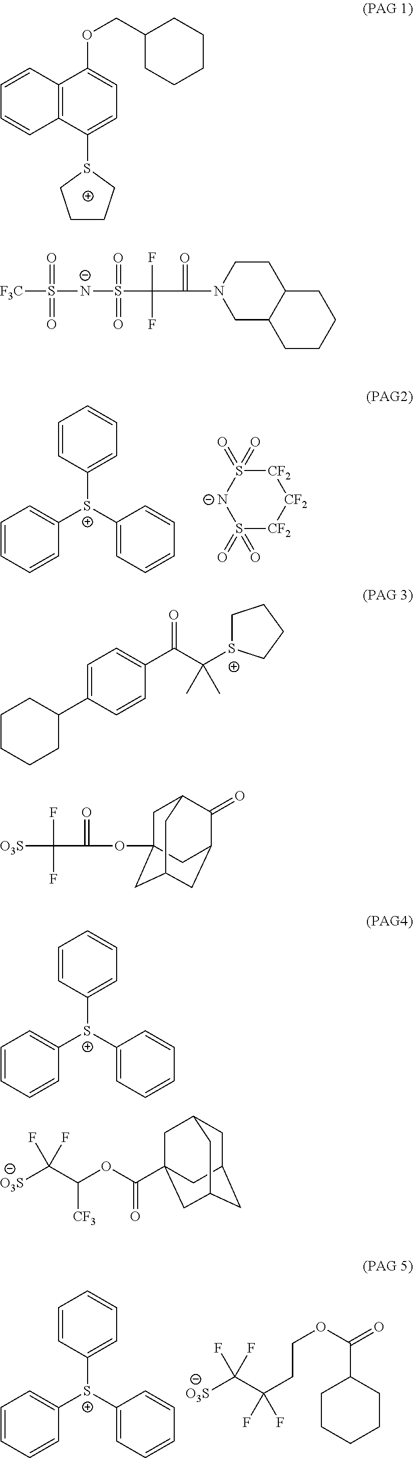

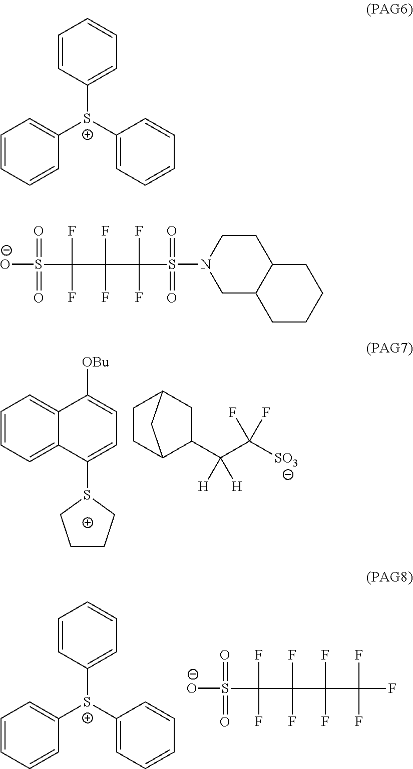

(Basic Compound)

DIA: 2,6-diisopropylaniline,

TMEA: tris(methoxyethoxyethyl)amine,

PEA: N-phenyldiethanolamine,

TOA: trioctylamine,

PBI: 2-phenylbenzimidazole, and

DHA: N,N-dihexylaniline.

(Surfactant)

W-1: Megafac F176 (produced by Dainippon Ink & Chemicals, Inc.) (fluorinated),

W-2: Megafac R08 (produced by Dainippon Ink & Chemicals, Inc.) (fluorinated and siliconized),

W-3: Troy Sol S-366 (produced by Troy Chemical Co., Ltd., fluorinated),

W-4: PF656 (produced by OMNOVA SOLUTIONS, INC., fluorinated), and

W-5: PF6320 (produced by OMNOVA SOLUTIONS, INC., fluorinated).

(Solvent)

S1-1: propylene glycol monomethyl ether acetate,

S1-2: cyclohexanone,

S2-1: propylene glycol monomethyl ether,

S2-2: propylene carbonate, and

S2-3: γ-butyrolactone.

As apparent from Table 3, a pattern with less development defects and a film exhibiting a high receding contact angle were formed by using the compositions of the present invention. Namely, it has been proved that excellent developability and excellent immersion-liquid tracking properties can be simultaneously attained by using the compositions of the present invention.

1. An actinic-ray- or radiation-sensitive resin composition comprising a resin (B) containing at least either a fluorine atom or a silicon atom, the resin (B) containing any of repeating units of general formulae (I-1) and (I-2) below: 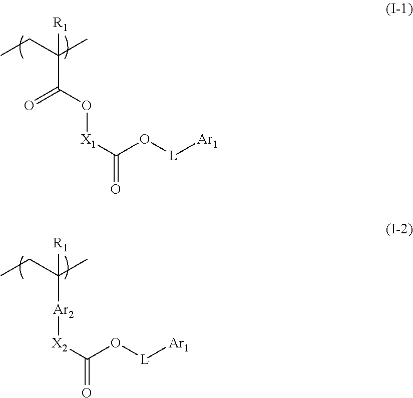
wherein
each of R₁s independently represents a hydrogen atom, an alkyl group or a halogen atom,
X₁ represents a bivalent organic group,
X₂ represents a single bond or a bivalent organic
group,
each of Ar₁s independently represents a monovalent aromatic ring group,
Ar₂ represents a bivalent aromatic ring group, and
each of L's independently represents a single bond or a bivalent organic group.

2. The composition according to claim 1, wherein the resin (B) is contained in a content of 0.01 to 20 mass % based on total solids of the composition.

3. The composition according to claim 1, wherein the resin (B) further contains a repeating unit containing at least one group selected from the group consisting of:
(x) an alkali-soluble group,
(y) a group that when acted on by an alkali developer, is decomposed to thereby increase its solubility in the alkali developer, and
(z) a group that when acted on by an acid, is decomposed to thereby increase its solubility in an alkali developer.

4. The composition according to claim 1, wherein the resin (B) further contains a repeating unit containing (y) a group that when acted on by an alkali developer, is decomposed to thereby increase its solubility in the alkali developer.

5. The composition according to claim 1, wherein the monovalent aromatic ring group represented by Ar₁ is substituted with an electron withdrawing group.

6. The composition according to claim 5, wherein the electron withdrawing group is at least one member selected from the group consisting of a halogen atom, a halogenated hydrocarbon group and a nitro group.

7. The composition according to claim 1, further comprising:
a resin (A) that when acted on by an acid, is decomposed to thereby increase its solubility in an alkali developer, and
a compound (C) that when exposed to actinic rays or radiation, generates an acid.

8. A resist film formed from the composition according to claim 1.

9. A method of forming a pattern, comprising:
forming the composition according to claim 1 into a film,
exposing the film to light, and
developing the exposed film.

10. The method according to claim 9, wherein the exposure is performed through an immersion liquid.
